(19) United States
(12) Patent Application Publication
(10) Pub. No.: US 2023/0331754 A1
(43) Pub. Date: Oct. 19, 2023

(54) MONONUCLEAR TRIPODAL HEXADENTATE IRIDIUM COMPLEXES FOR USE IN OLEDS

(71) Applicant: Merck Patent GmbH, Darmstadt (DE)

(72) Inventors: Philipp STOESSEL, Darmstadt (DE); Falk MAY, Darmstadt (DE); Armin AUCH, Darmstadt (DE)

(21) Appl. No.: 18/028,770

(22) PCT Filed: Sep. 27, 2021
(86) PCT No.: PCT/EP2021/076429

§ 371 Date: Mar. 28, 2023

(30) Foreign Application Priority Data
Sep. 29, 2020 (EP) 20198952.2

(51) Int. Cl. C07F 15/00; H10K 85/30; H10K 50/11; C09K 11/06

(52) U.S. Cl. CPC C07F 15/0033; H10K 85/342; H10K 50/11; C09K 11/06; C09K 2211/1029

(57) ABSTRACT

The present invention relates to iridium complexes that are suitable for use in organic electroluminescent devices, in particular as emitters.

The present invention relates to iridium complexes suitable for use in organic electroluminescent devices, especially as emitters.

According to the prior art, triplet emitters used in phosphorescent organic electroluminescent devices (OLEDs) are, in particular, bis- and tris-ortho-metalated iridium complexes having aromatic ligands, where the ligands via a negatively charged carbon atom and an uncharged nitrogen atom. Examples of such complexes are tris(phenylpyridyl)iridium(III) and derivatives thereof. Complexes of this kind are also known with polypodal ligands, as described, for example, in U.S. Pat. No. 7,332,232, WO 2016/124304 and WO 2019/158453. Even though these complexes having polypodal ligands show advantages over the complexes which otherwise have the same ligand structure without polypodal bridging of the individual ligands therein, there is also still need for improvement, for example with regard to efficiency, voltage and lifetime.

The problem addressed by the present invention is therefore that of providing improved iridium complexes suitable as emitters for use in OLEDs.

It has been found that, surprisingly, this problem is solved by iridium complexes with a hexadentate tripodal ligand having the structure described below, which are of very good suitability for use in an organic electroluminescent device. The present invention therefore provides these iridium complexes and organic electroluminescent devices comprising these complexes.

The invention thus provides a compound of the formula (1)

Ir(L) Formula (1)

where the ligand L has a structure of the following formula (2):

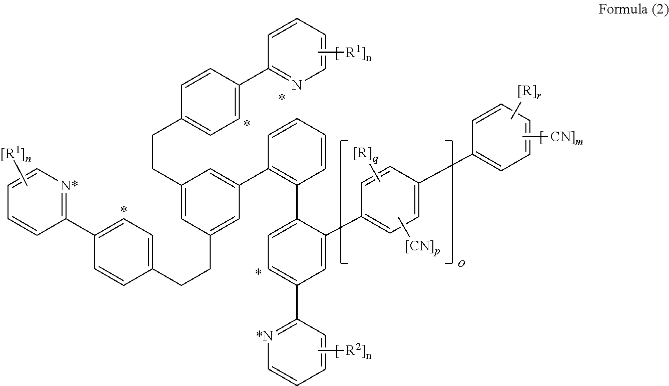

where the ligand L coordinates to the iridium atom via the positions identified by * and where the hydrogen atoms not shown explicitly may also be replaced by D, and where the symbols and indices used are as follows:
R is the same or different at each instance and is H, D, F, a linear alkyl group having 1 to 10 carbon atoms or a branched or cyclic alkyl group having 3 to 10 carbon atoms, where the alkyl group in each case may also be deuterated; it is possible here for two adjacent R radicals together to form a ring system;
R¹ is the same or different at each instance and is H, D, a linear alkyl group having 1 to 10 carbon atoms or a branched or cyclic alkyl group having 3 to 10 carbon atoms, where the alkyl group in each case may also be deuterated; it is possible here for two adjacent R¹ radicals together to form a ring system;
R² is the same or different at each instance and is H, D, a linear alkyl group having 1 to 10 carbon atoms, a branched or cyclic alkyl group having 3 to 10 carbon atoms, where the alkyl group in each case may also be deuterated, or a phenyl or biphenyl group, each of which may be substituted by one or more alkyl groups having 1 to 10 carbon atoms, where the phenyl or biphenyl group, or the alkyl groups, may each also be deuterated; it is possible here for two adjacent R² radicals together to form a ring system;
m is 1, 2 or 3;
n is the same or different at each instance and is 0, 1, 2 or 3;
is 0 or 1;
p is 0, 1 or 2;
q is 0, 1 or 2;
r is 0, 1 or 2.

The ligand L of the formula (2) is thus a hexadentate tripodal ligand having the three bidentate phenylpyridine subligands. The complex Ir(L) of the formula (1) formed by that ligand thus has the following structure:

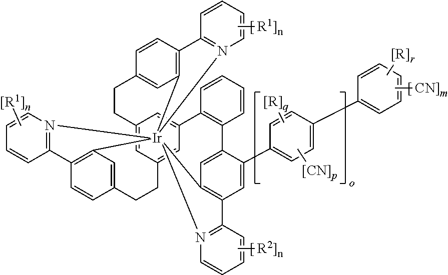

where the symbols and indices have the definitions given above.

When two R radicals or two R¹ radicals or two R² radicals together form a ring system, it may be mono- or polycyclic. In this case, the radicals which together form a ring system are adjacent, meaning that these radicals bind to carbon atoms bonded directly to one another. The wording that two R radicals together may form a ring, in the context of the present description, should be understood to mean, inter alia, that the two radicals are joined to one another by a chemical bond with formal elimination of two hydrogen atoms. This is illustrated by the following scheme:

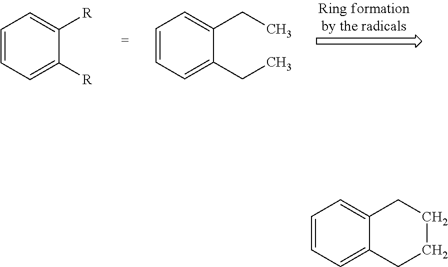

A cyclic alkyl group in the context of this invention is understood to mean a monocyclic, bicyclic or polycyclic group.

In the context of the present invention, a C₁- to C₁₀-alkyl group is understood to mean, for example, the methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neopentyl, cyclopentyl, n-hexyl, s-hexyl, t-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, adamantyl, 1,1-dimethyl-n-hex-1-yl, 1,1-dimethyl-n-hept-1-yl, 1,1-dimethyl-n-oct-1-yl, 1,1-diethyl-n-hex-1-yl, 1-(n-propyl)cyclohex-1-yl and 1-(n-butyl)cyclohex-1-yl radicals.

When the indices n, p, q and r are 0, in place of the corresponding substituents, a hydrogen or deuterium atom is bonded in each case to the corresponding phenyl or pyridine group.

When m=1 the ligand L is preferably a structure of the following formula (3a), when m=2 the ligand L is preferably a structure of the following formula (3b) or (3c), and when m=3 the ligand L is preferably a structure of the following formula (3d) or (3e):

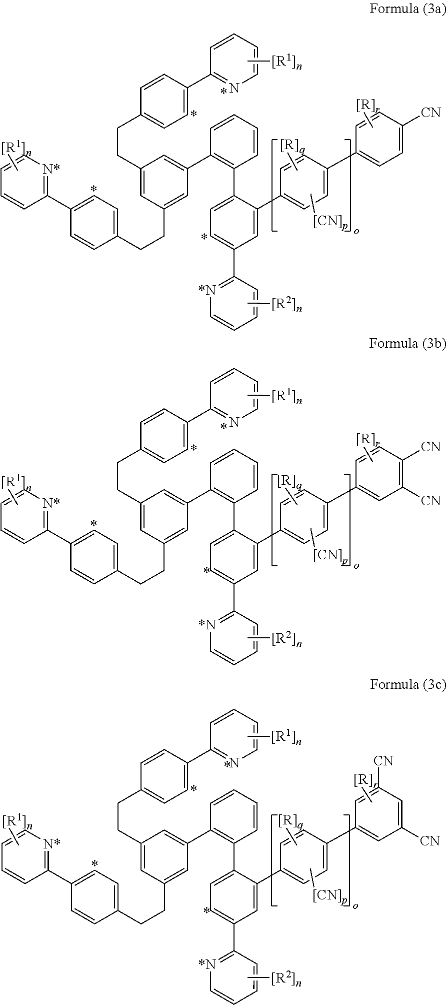

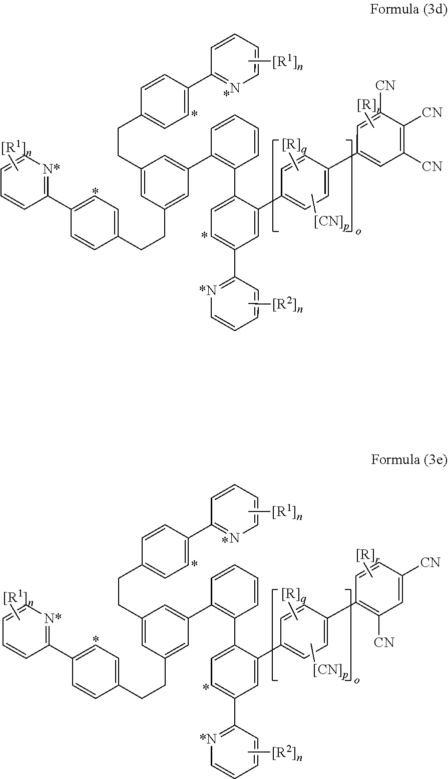

where the symbols and indices have the definitions given above, and the hydrogen atoms not shown explicitly may also be replaced by deuterium.

Preference is given to the structure of the formula (3a).

When o=1, preferred embodiments are q=0 and p=0, 1 or 2, or q=0, 1 or 2 and p=0. When o=1 and p=1 the ligand preferably has a structure of the following formula (4a), and when o=1 and p=2 the ligand preferably has a structure of the following formula (4b):

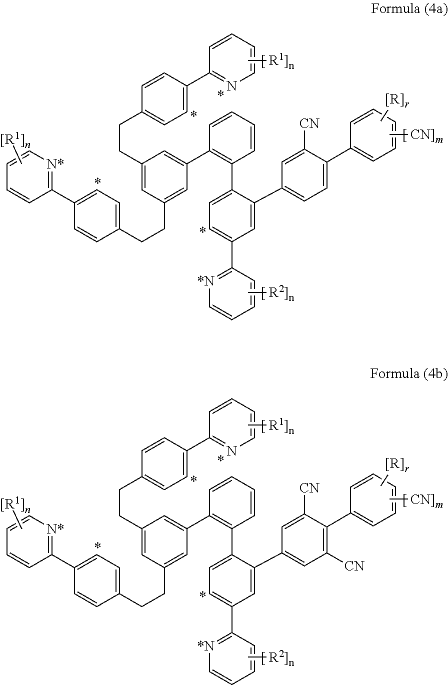

where the symbols and indices have the definitions given above, and the hydrogen atoms not shown explicitly may also be replaced by deuterium.

In a preferred embodiment of the invention, the indices n on the two phenylpyridine subligands not substituted by the cyanophenyl or cyanobiphenyl group are 0. In a further preferred embodiment of the invention, these indices n are 1 or 2, and the corresponding R¹ radicals are not H or D. When these indices n are 1 the ligand preferably has a structure of the following formula (5a) or (5b), and when these indices n are 2 the ligand preferably has a structure of the following formula (5c):

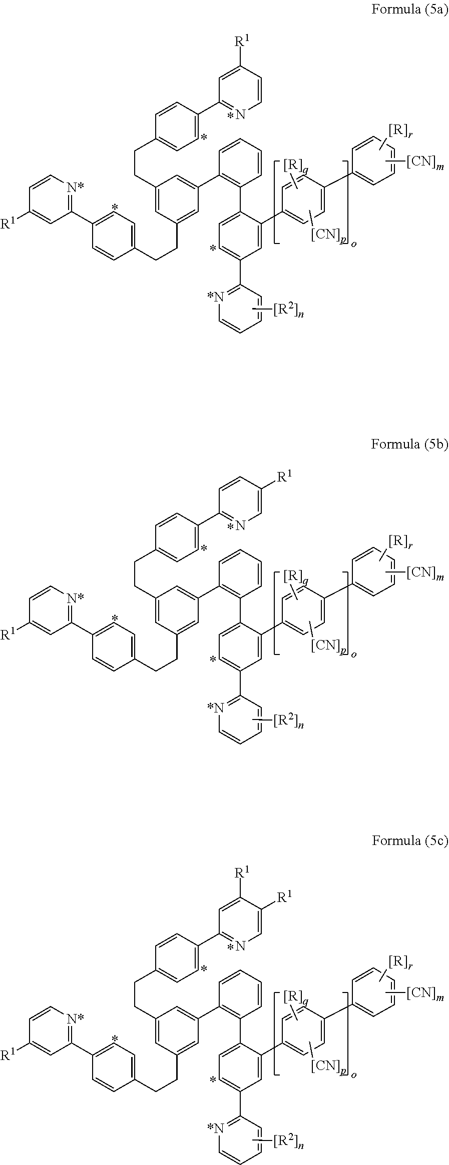

where the symbols and indices have the definitions given above and R¹ is not H or D, and the hydrogen atoms not shown explicitly may also be replaced by deuterium.

In a further preferred embodiment of the invention, the index n on the phenylpyridine subligands substituted by the cyanophenyl or cyanobiphenyl group is 0. In a further preferred embodiment of the invention, this index n is 1 or 2, and the corresponding R² radicals are not H or D. When this index n is 1 the ligand preferably has a structure of the following formula (6a) or (6b), and when this index n is 2 the ligand preferably has a structure of the following formula (6c):

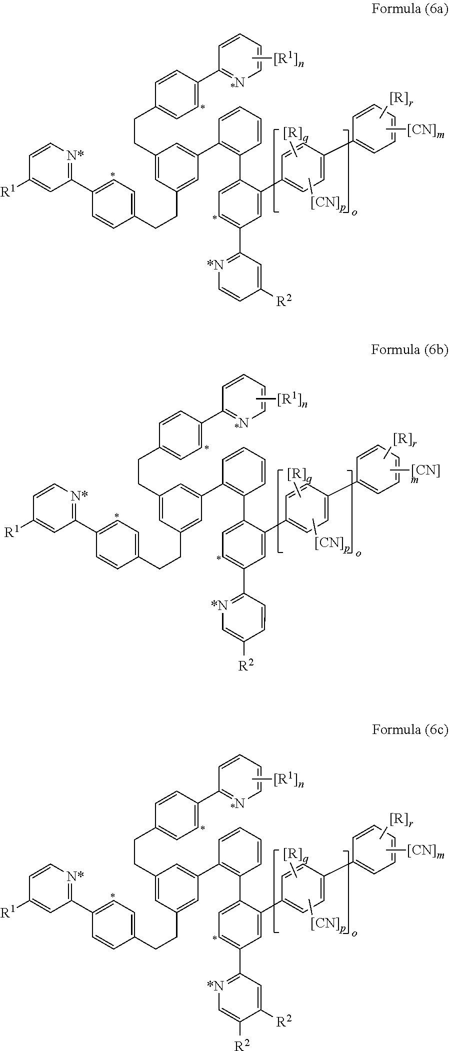

where the symbols and indices have the definitions given above and R² is not H or D, and the hydrogen atoms not shown explicitly may also be replaced by deuterium.

The ligand L preferably has a structure of the following formula (7):

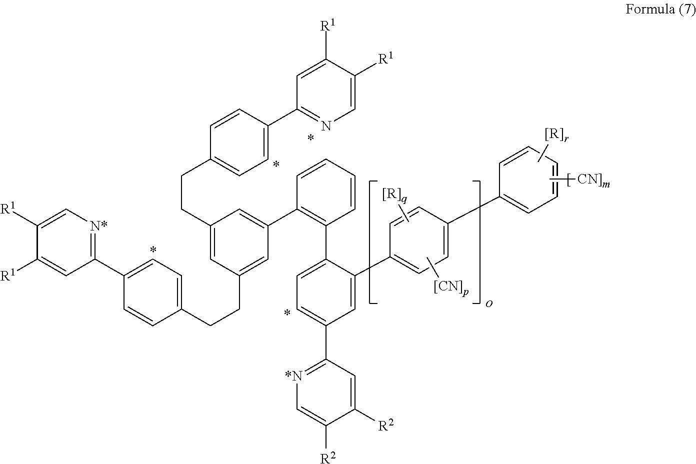

where the symbols and indices have the definitions given above, and the hydrogen atoms not shown explicitly may also be replaced by deuterium.

In a preferred embodiment of the invention, the substituents R are the same or different at each instance and are selected from the group consisting of D, a linear alkyl group having 1 to 6 carbon atoms or a branched or cyclic alkyl group having 3 to 6 carbon atoms, where the alkyl groups may each also be deuterated. More preferably, the substituents R are the same or different at each instance and are selected from the group consisting of D, a linear alkyl group having 1 to 4 carbon atoms or a branched alkyl group having 3 or 4 carbon atoms, where the alkyl groups may each also be deuterated. Especially preferably, R is a methyl group or a CDs group.

In a further preferred embodiment of the invention, the substituents R¹ are the same or different at each instance and are selected from the group consisting of D, a linear alkyl group having 1 to 6 carbon atoms or a branched or cyclic alkyl group having 3 to 6 carbon atoms, where the alkyl groups may each also be deuterated; it is possible here for two adjacent R¹ radicals together to form a ring system. More preferably, the substituents R¹ are the same or different at each instance and are selected from the group consisting of D, a linear alkyl group having 1 to 4 carbon atoms or a branched alkyl group having 3 or 4 carbon atoms, where the alkyl groups may each also be deuterated; it is possible here for two adjacent R¹ radicals together to form a ring system. Especially preferably, R¹ is a methyl group or a CDs group.

In a further preferred embodiment of the invention, the substituents R² are the same or different at each instance and are selected from the group consisting of D, a linear alkyl group having 1 to 6 carbon atoms or a branched or cyclic alkyl group having 3 to 6 carbon atoms, where the alkyl groups may each also be deuterated, or an optionally deuterated phenyl group which may be substituted by one or more optionally deuterated alkyl groups having 1 to 4 carbon atoms; it is possible here for two adjacent R² radicals together to form a ring system. More preferably, the substituents R² are the same or different at each instance and are selected from the group consisting of D, a linear alkyl group having 1 to 4 carbon atoms or a branched alkyl group having 3 or 4 carbon atoms, where the alkyl groups may each also be deuterated; it is possible here for two adjacent R² radicals, when they are alkyl groups, together to form a ring system. Especially preferably, R² is a methyl group or a CDs group. When R² is an optionally deuterated phenyl group, this is preferably unsubstituted or substituted by one or two optionally deuterated alkyl groups, preferably methyl groups or CDs groups, where these alkyl groups are then preferably bonded in the ortho position to the linkage to the phenyl group.

In a further preferred embodiment of the invention, m=1 or 2, more preferably 1.

In a further preferred embodiment of the invention, n is the same or different at each instance and is 0, 1 or 2.

In a further preferred embodiment of the invention, o=1. When n on the same ligand is 1 and R² is a phenyl group, it is also preferable that o=1.

In a further preferred embodiment of the invention, p=0 or 1, more preferably 0.

In a further preferred embodiment of the invention, q=0 or 1.

In a further preferred embodiment of the invention, r=0 or 1.

Preferably, two or more of the abovementioned preferences occur simultaneously. Preferably, therefore, the symbols and indices are as follows:
R is the same or different at each instance and is selected from the group consisting of D, a linear alkyl group having 1 to 6 carbon atoms or a branched or cyclic alkyl group having 3 to 6 carbon atoms, where the alkyl groups may each also be deuterated;
R¹ is the same or different at each instance and is selected from the group consisting of D, a linear alkyl group having 1 to 6 carbon atoms or a branched or cyclic alkyl group having 3 to 6 carbon atoms, where the alkyl groups may each also be deuterated; it is possible here for two adjacent R¹ radicals together to form a ring system;
R² is the same or different at each instance and is selected from the group consisting of D, a linear alkyl group having 1 to 6 carbon atoms or a branched or cyclic alkyl group having 3 to 6 carbon atoms, where the alkyl groups may each also be deuterated, or an optionally deuterated phenyl group which may be substituted by one or more optionally deuterated alkyl groups having 1 to 4 carbon atoms; it is possible here for two adjacent R² radicals together to form a ring system;
m is 1 or 2;
n is the same or different at each instance and is 0, 1 or 2;
o is 1; or o is 0 or 1 when non the same ligand=1 and R² is a phenyl group;
p is 0 or 1;
q is 0 or 1;
r is 0 or 1.

More preferably, the symbols and indices are as follows:
R is the same or different at each instance and is selected from the group consisting of D, a linear alkyl group having 1 to 4 carbon atoms or a branched alkyl group having 3 or 4 carbon atoms, where the alkyl groups may each also be deuterated;
R¹ is the same or different at each instance and is selected from the group consisting of D, a linear alkyl group having 1 to 4 carbon atoms or a branched alkyl group having 3 or 4 carbon atoms, where the alkyl groups may each also be deuterated; it is possible here for two adjacent R¹ radicals together to form a ring system;
R² is the same or different at each instance and is selected from the group consisting of D, a linear alkyl group having 1 to 4 carbon atoms or a branched alkyl group having 3 or 4 carbon atoms, where the alkyl groups may each also be deuterated, or an optionally deuterated phenyl group which may be substituted by one or more optionally deuterated alkyl groups having 1 to 4 carbon atoms; it is possible here for two adjacent alkyl groups R² together to form a ring system;
m is 1;
n is the same or different at each instance and is 0, 1 or 2;
o is 1; or o is 0 or 1 when non the same ligand=1 and R² is a phenyl group;
p is 0;
q is 0 or 1;
r is 0 or 1.

When two R or R¹ or R² radicals are alkyl groups that form a ring system with one another, this ring system is preferably selected from the structures of the following formulae (Ring-1) to (Ring-7):

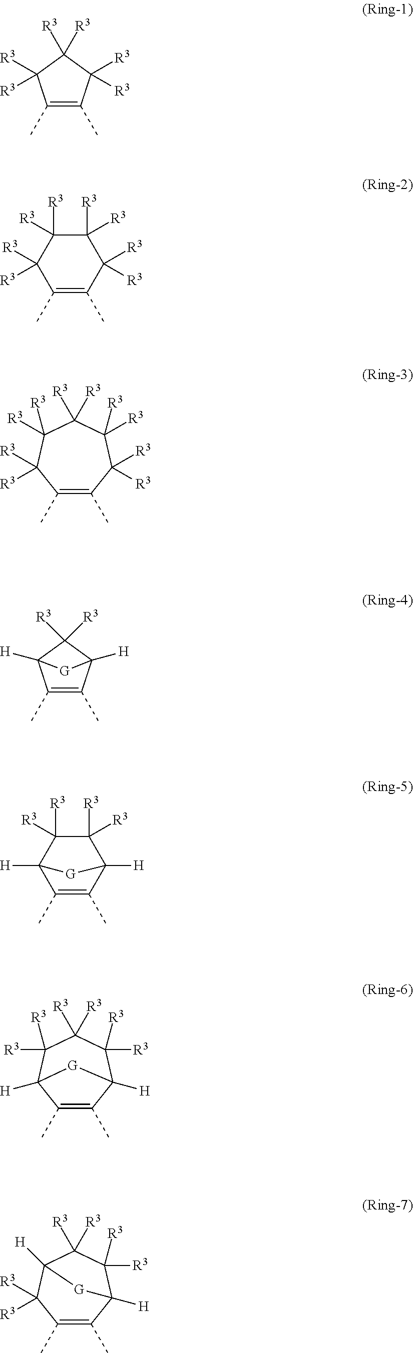

where the dotted bonds indicate the linkage of the two carbon atoms within the ligand, and in addition:
R³ is the same or different at each instance and is H, D or an alkyl group having 1, 2 or 3 carbon atoms;
G is an alkylene group having 1 or 2 carbon atoms.

In the above-depicted structures (Ring-1) to (Ring-7) and the further embodiments of these structures specified as preferred, a double bond is formed in a formal sense between the two carbon atoms. This is a simplification of the chemical structure since these two carbon atoms are incorporated into an aromatic or heteroaromatic system and hence the bond between these two carbon atoms is formally between the bonding level of a single bond and that of a double bond. The drawing of the formal double bond should thus not be interpreted so as to limit the structure; instead, it will be apparent to the person skilled in the art that this is an aromatic bond.

When adjacent radicals in the structures of the invention form an aliphatic ring system, it is preferable when the latter does not have any acidic benzylic protons. Benzylic protons are understood to mean protons which bind to a carbon atom bonded directly to the ligand. This can be achieved by virtue of the carbon atoms in the aliphatic ring system which bind directly to an aryl or heteroaryl group being fully substituted and not containing any bonded hydrogen atoms. For instance, the absence of acidic benzylic protons in the formulae (Ring-1) to (Ring-3) is achieved in that R³ in the benzylic positions is an alkyl group. This can additionally also be achieved by virtue of the carbon atoms in the aliphatic ring system which bind directly to a pyridine or phenyl group being the bridgeheads in a bi- or polycyclic structure. The protons bonded to bridgehead carbon atoms, because of the spatial structure of the bi- or polycycle, are significantly less acidic than benzylic protons on carbon atoms which are not bonded within a bi- or polycyclic structure, and are regarded as non-acidic protons in the context of the present invention.

Examples of suitable groups of the structure (Ring-1) are the structures listed below:

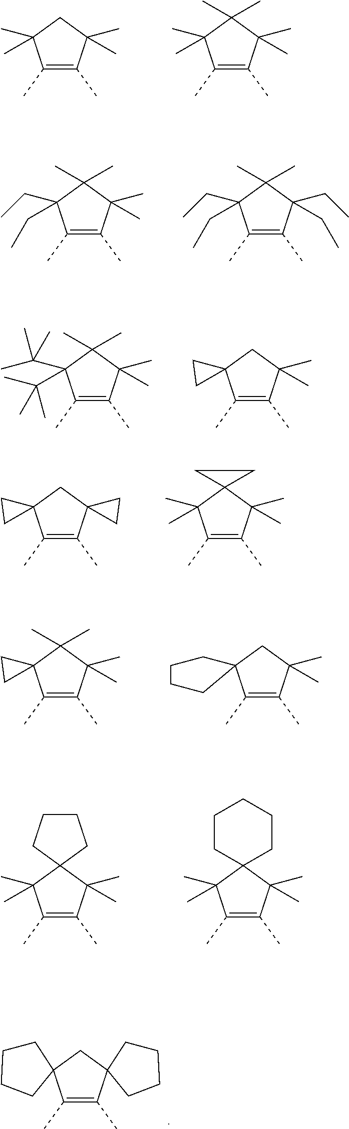

Examples of suitable groups of the formula (Ring-2) are the structures listed below:

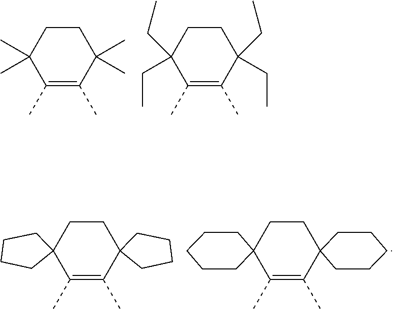

Examples of suitable groups of the formulae (Ring-3), (Ring-6) and (Ring-7) are the structures listed below:

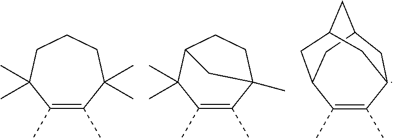

Examples of suitable groups of the formula (Ring-4) are the structures listed below:

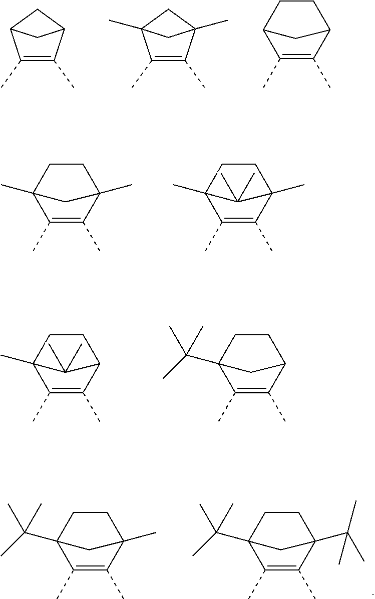

Examples of suitable groups of the formula (Ring-5) are the structures listed below:

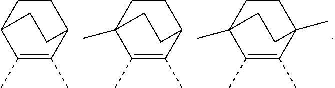

In a particularly preferred embodiment of the invention, the ligand L has a structure of the following formula (8):

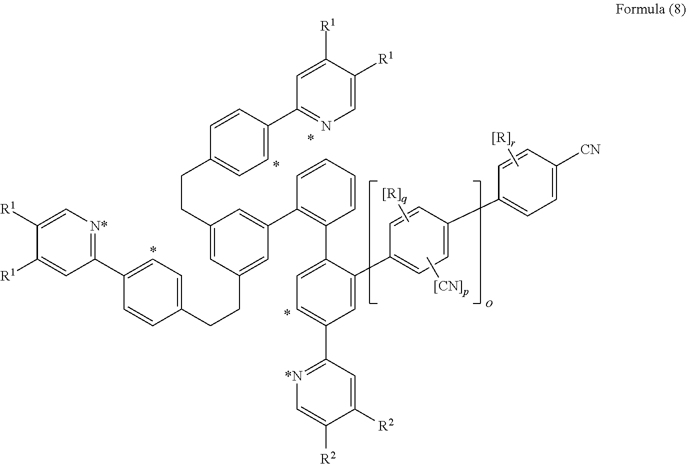

where R, R¹, R² and o have the definitions given above, especially the abovementioned preferred definitions or the abovementioned particularly preferred definitions, p=0 or 1, q=0 or 1 and r=0 or 1, and the hydrogen atoms not shown explicitly may also be replaced by deuterium.

Most preferably, the ligand L has a structure of the following formula (9):

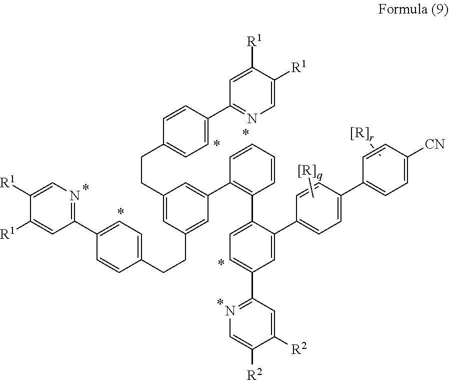

where R, R¹ and R² have the definitions given above, especially the abovementioned preferred definitions or the abovementioned particularly preferred definitions, q=0 or 1 and r=0 or 1, and the hydrogen atoms not shown explicitly may also be replaced by deuterium.

The abovementioned preferred embodiments can be combined with one another as desired. In a particularly preferred embodiment of the invention, the abovementioned preferred embodiments apply simultaneously.

Examples of suitable structures of the invention are the compounds depicted below.

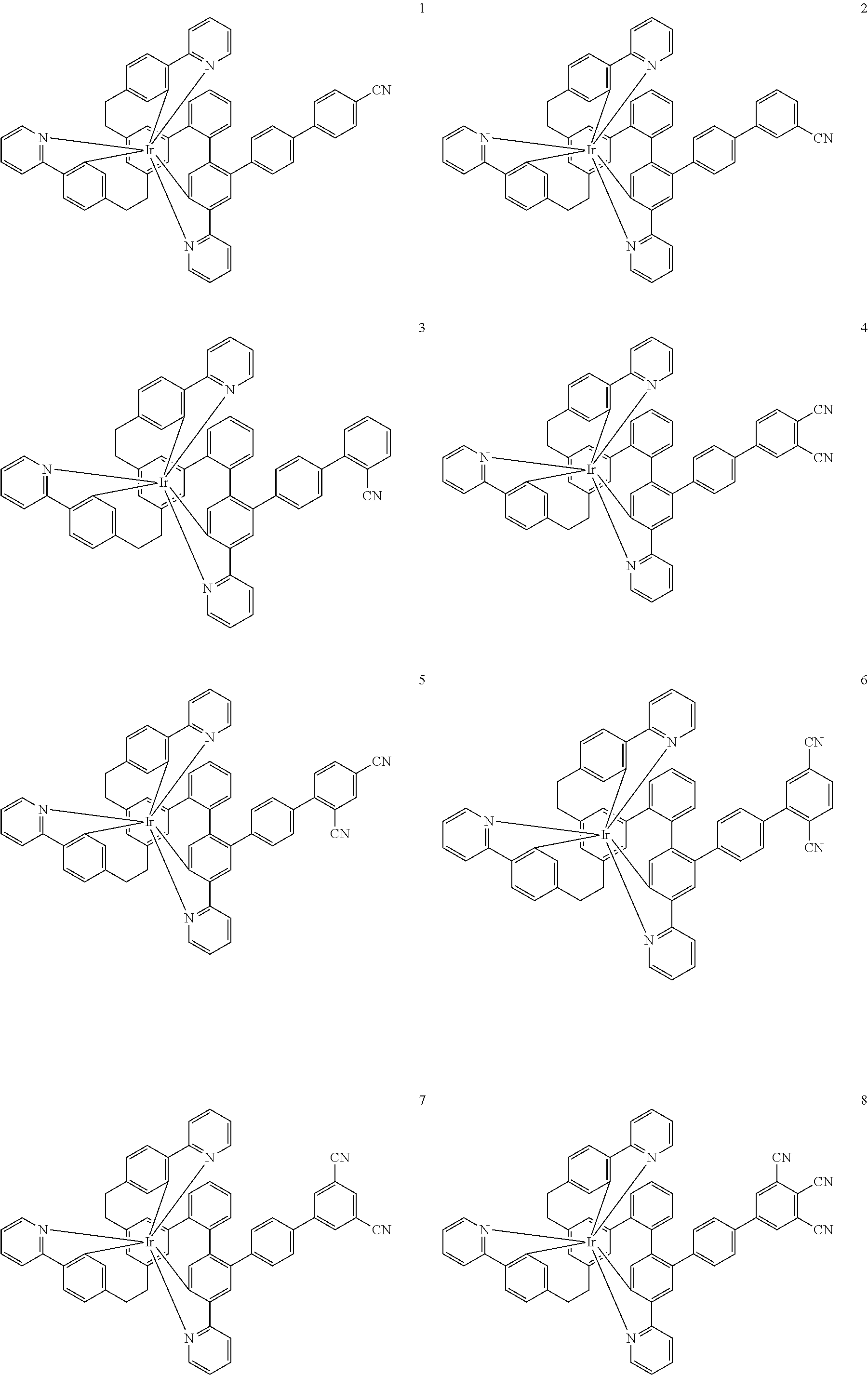

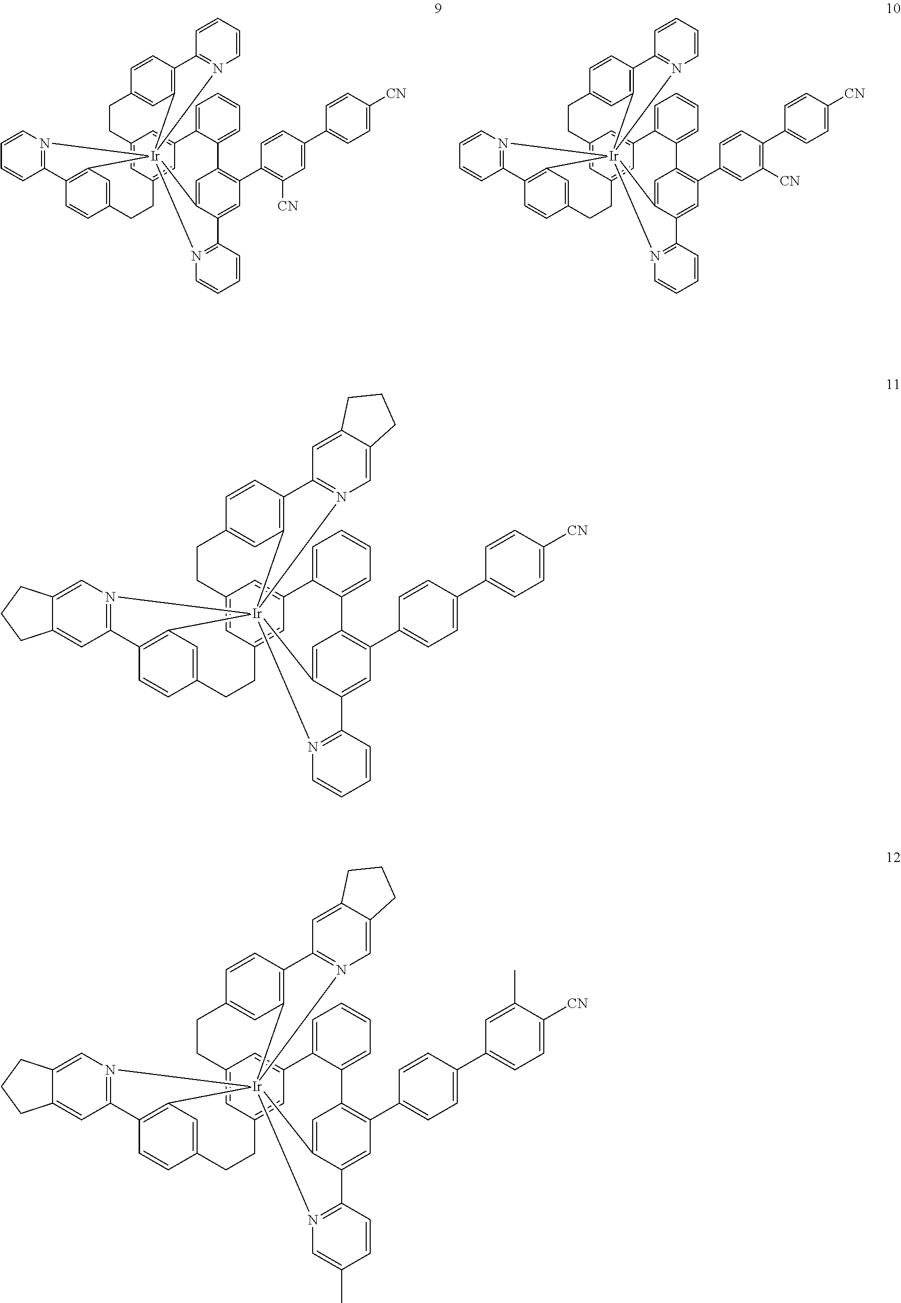

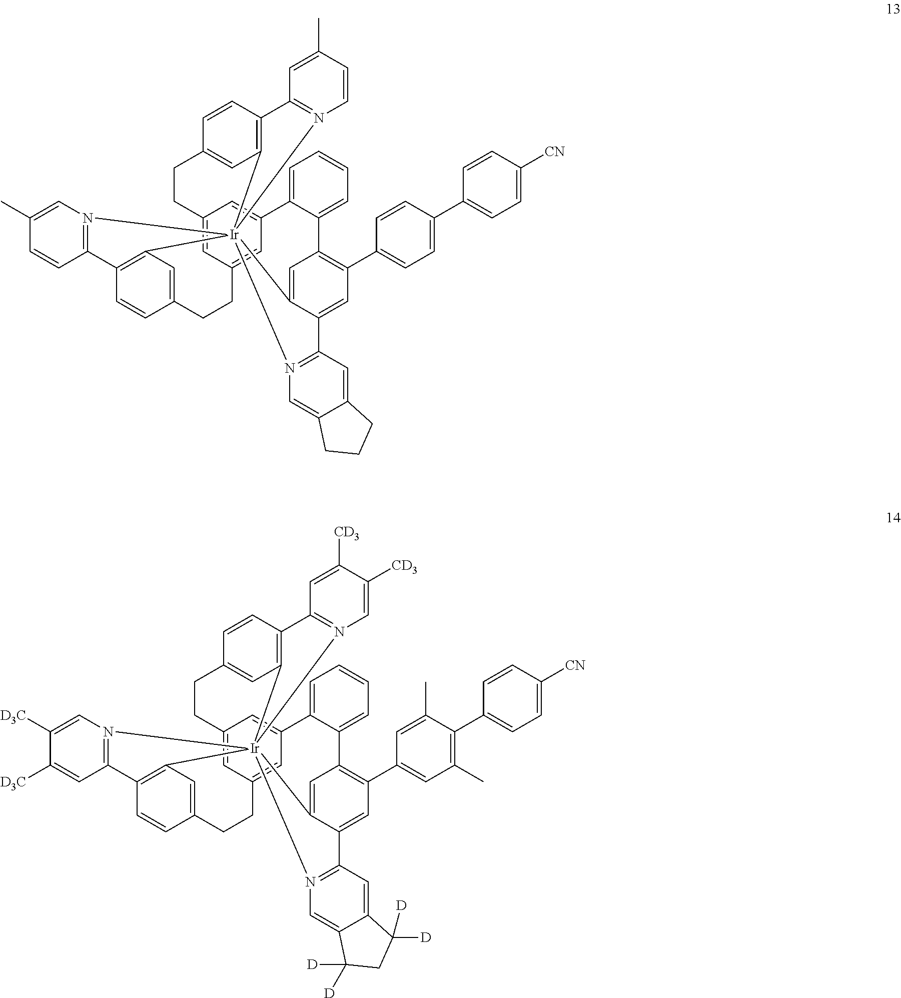

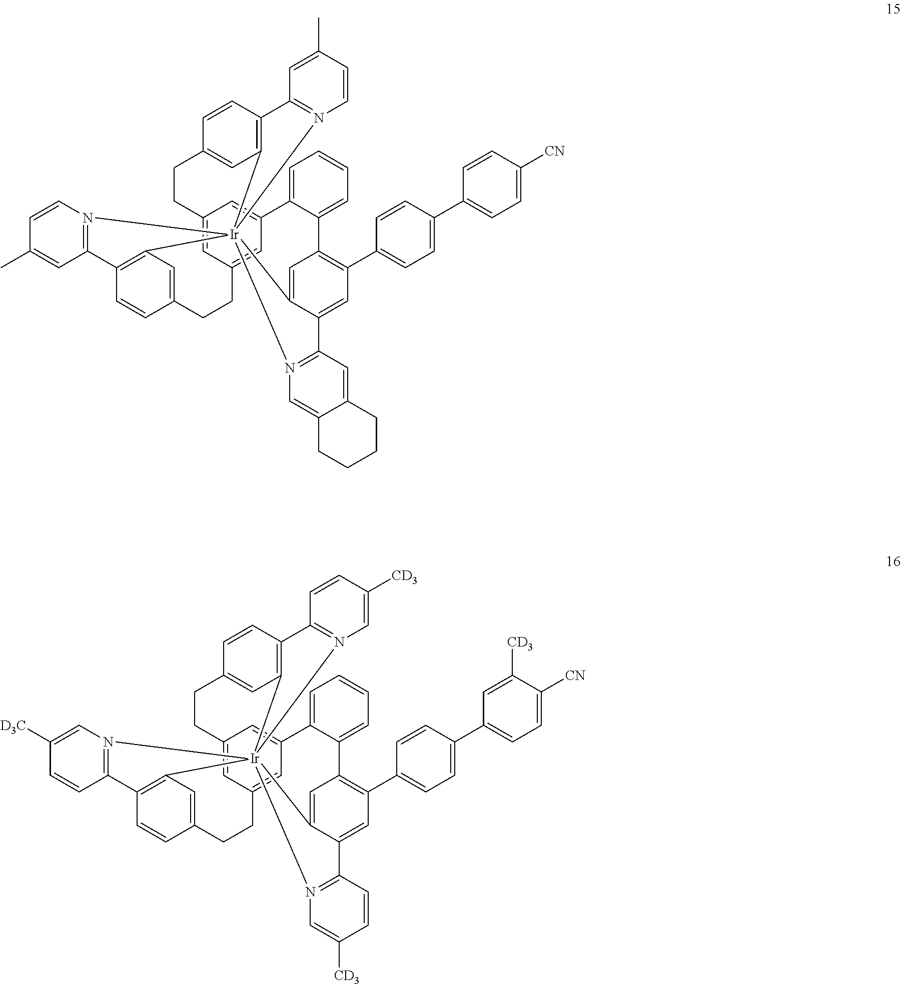

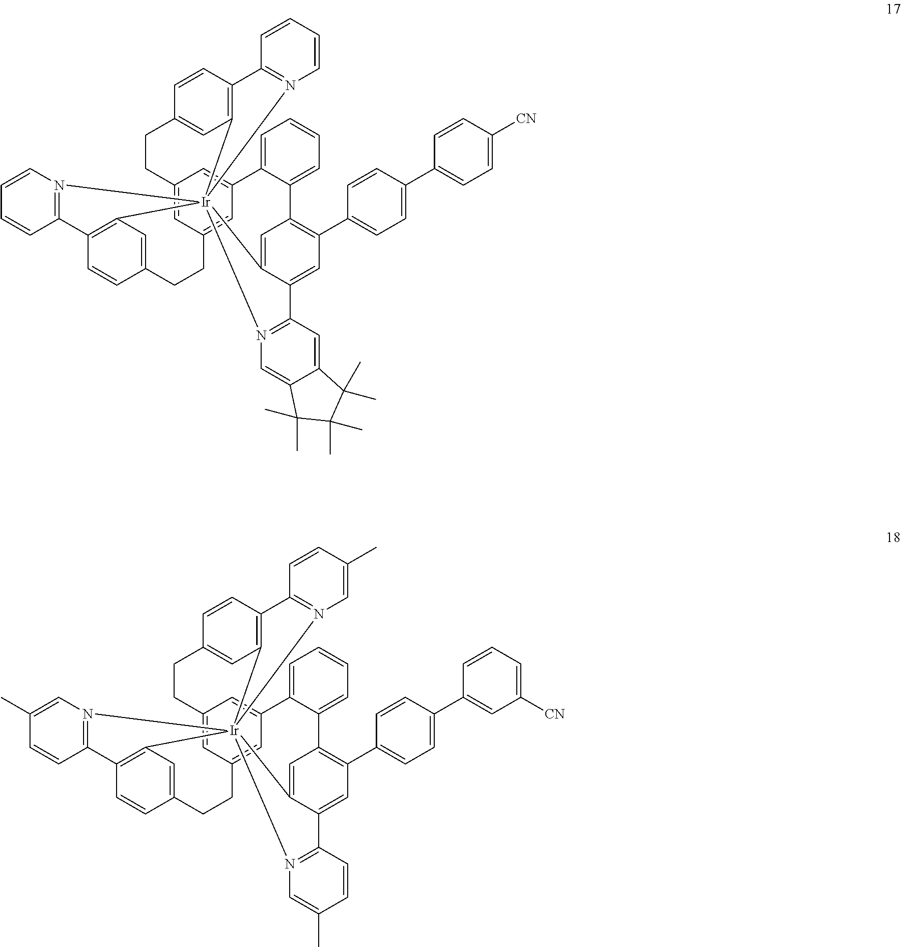

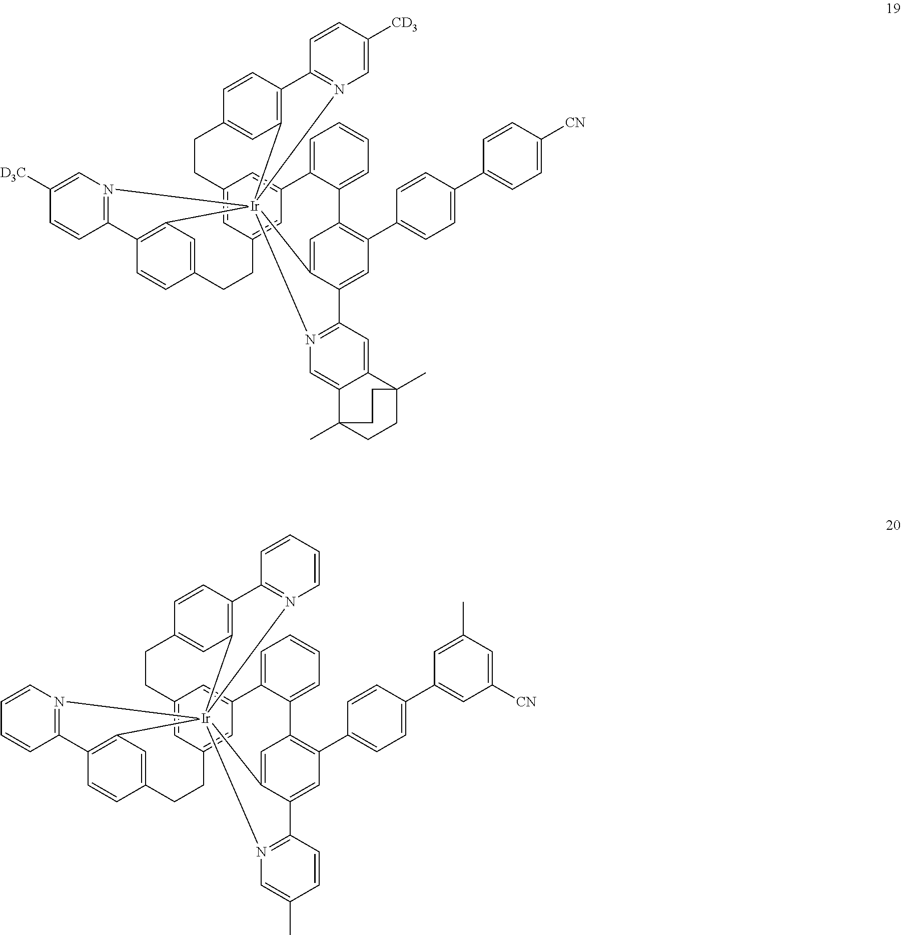

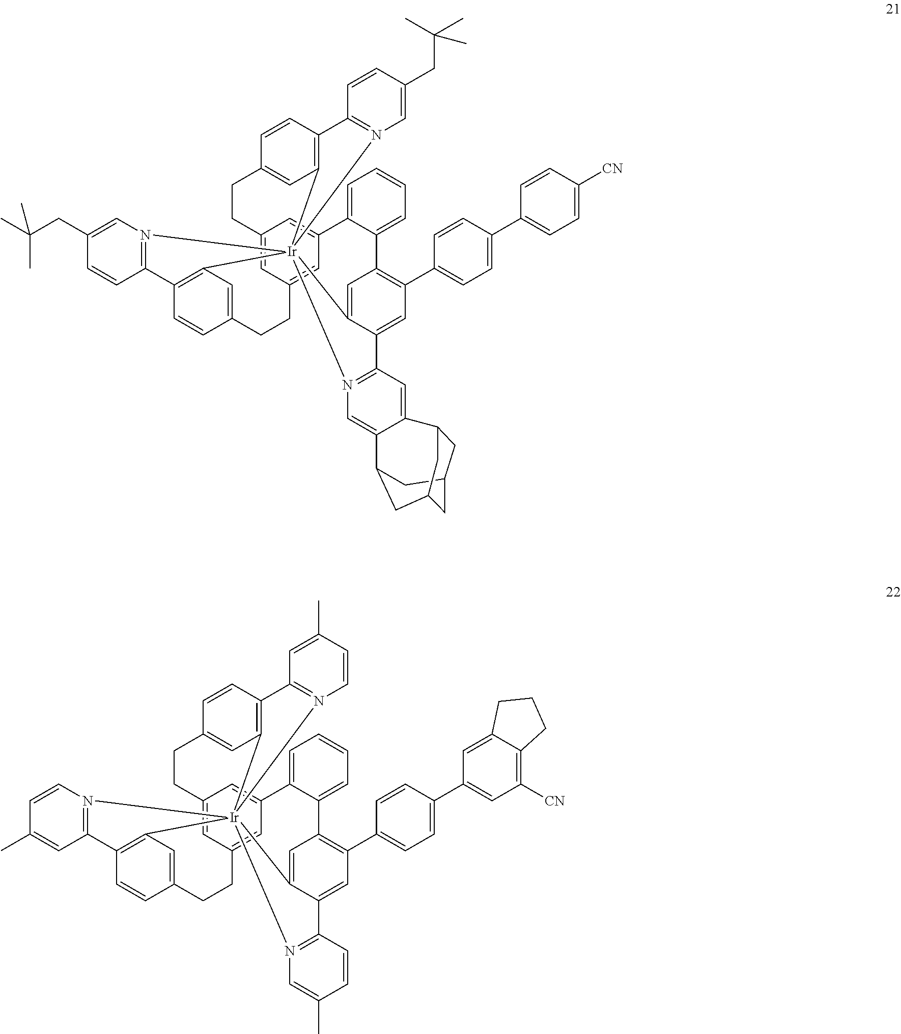

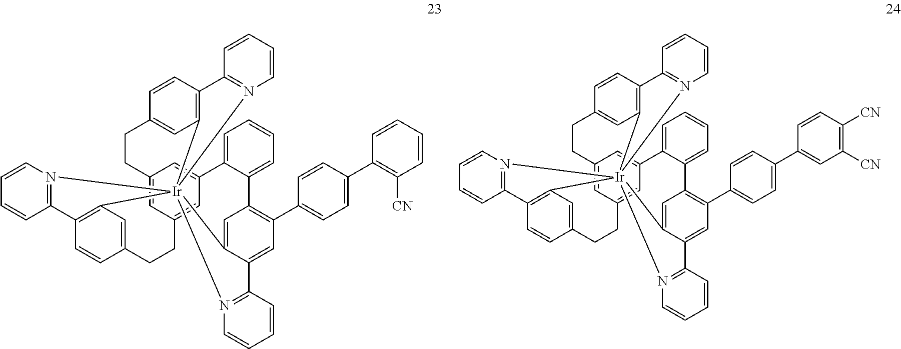

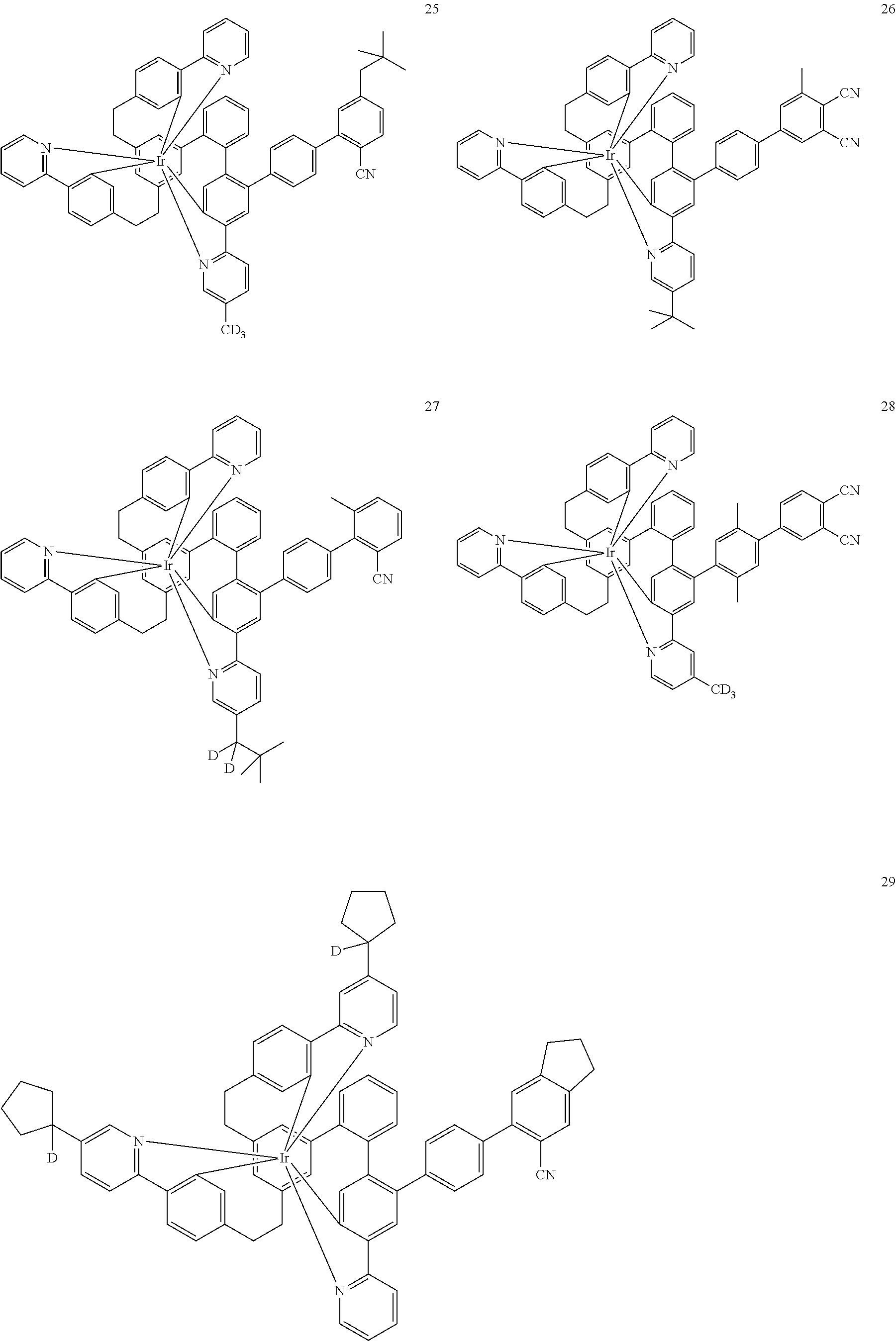

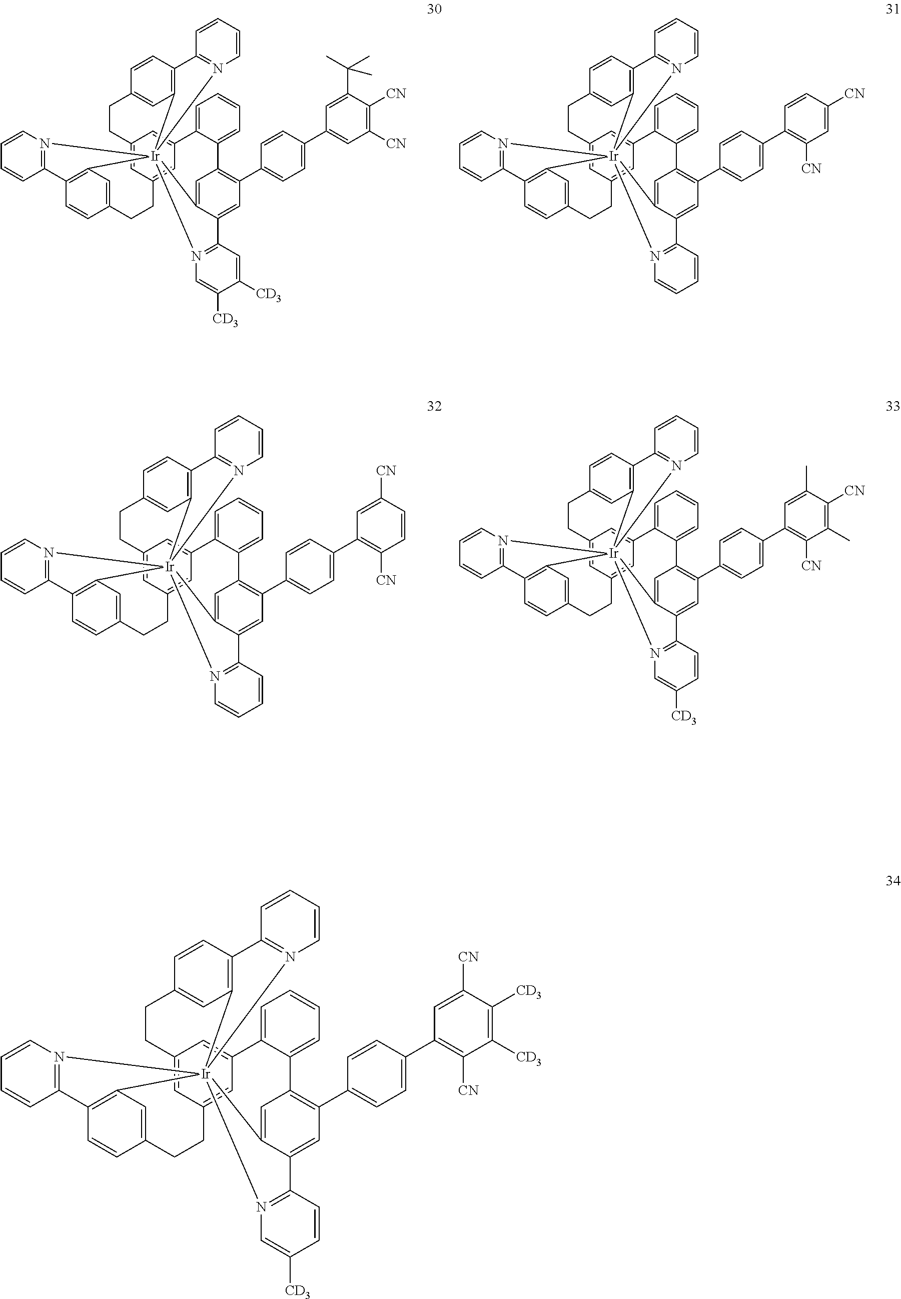

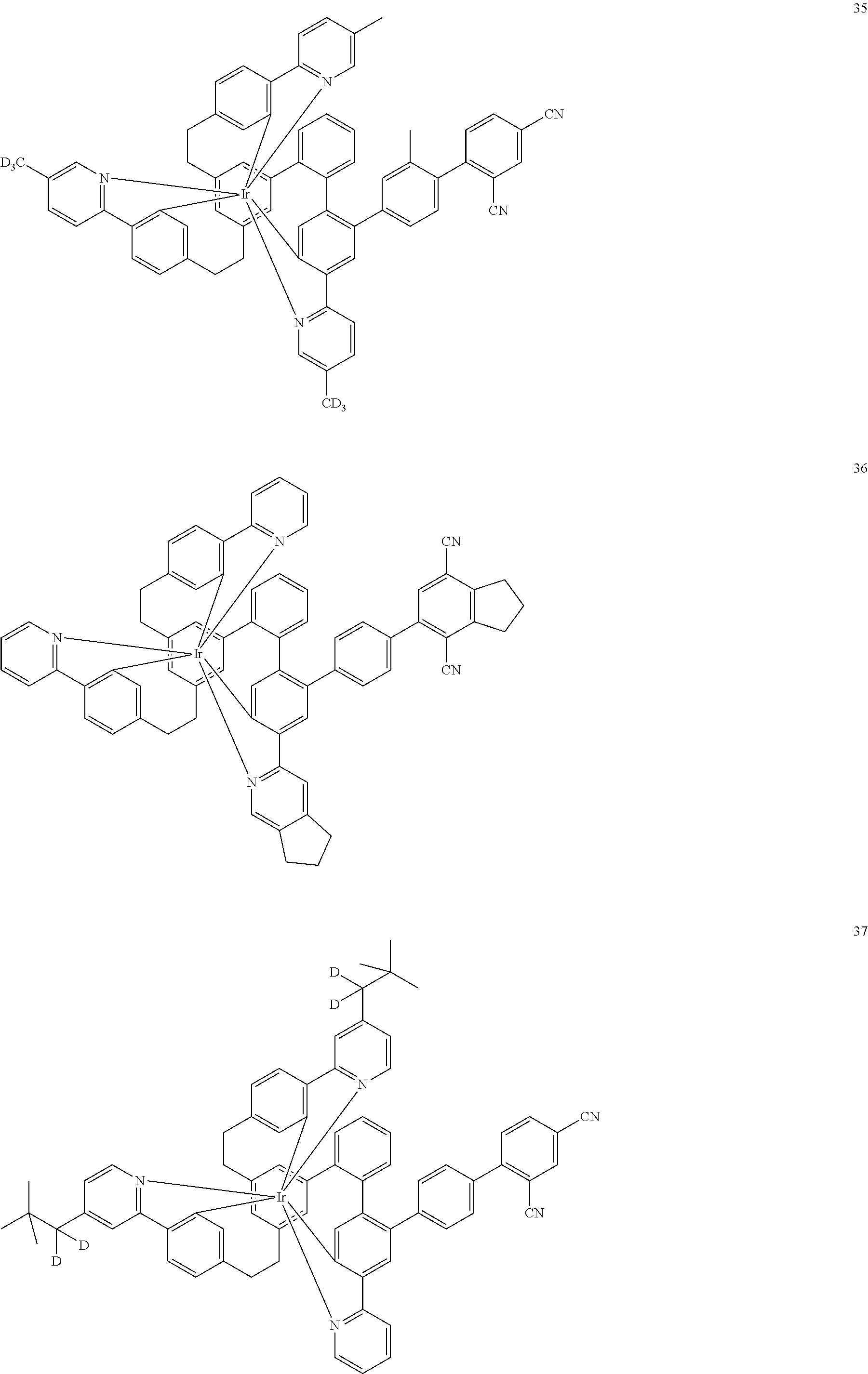

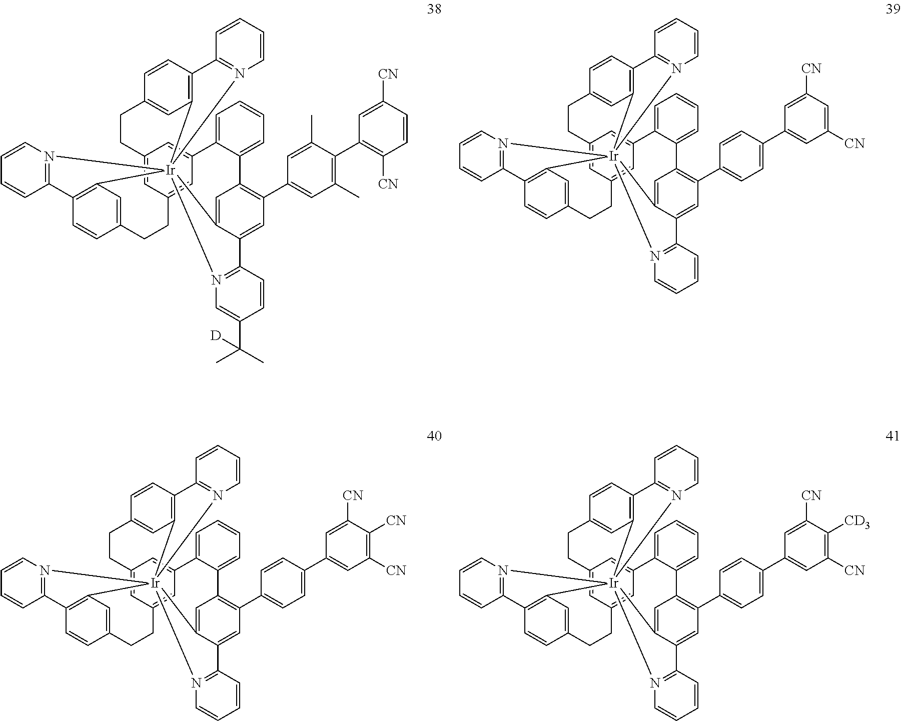

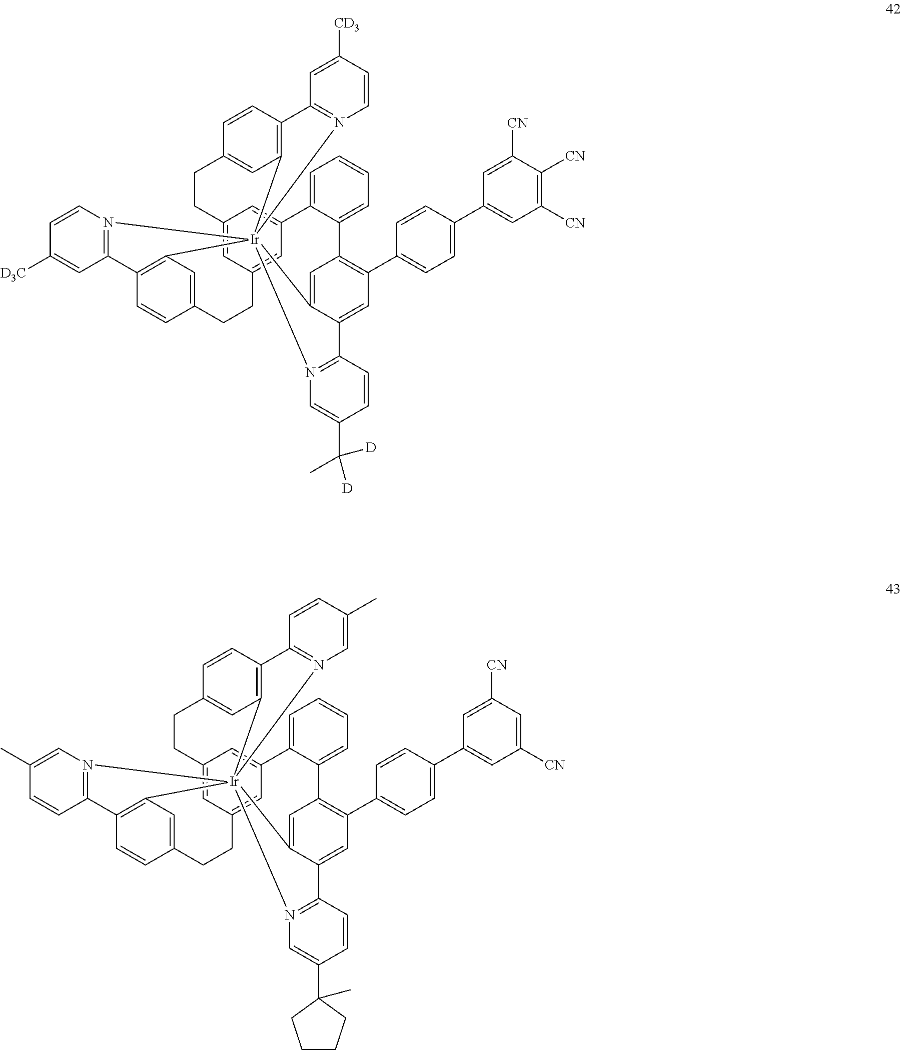

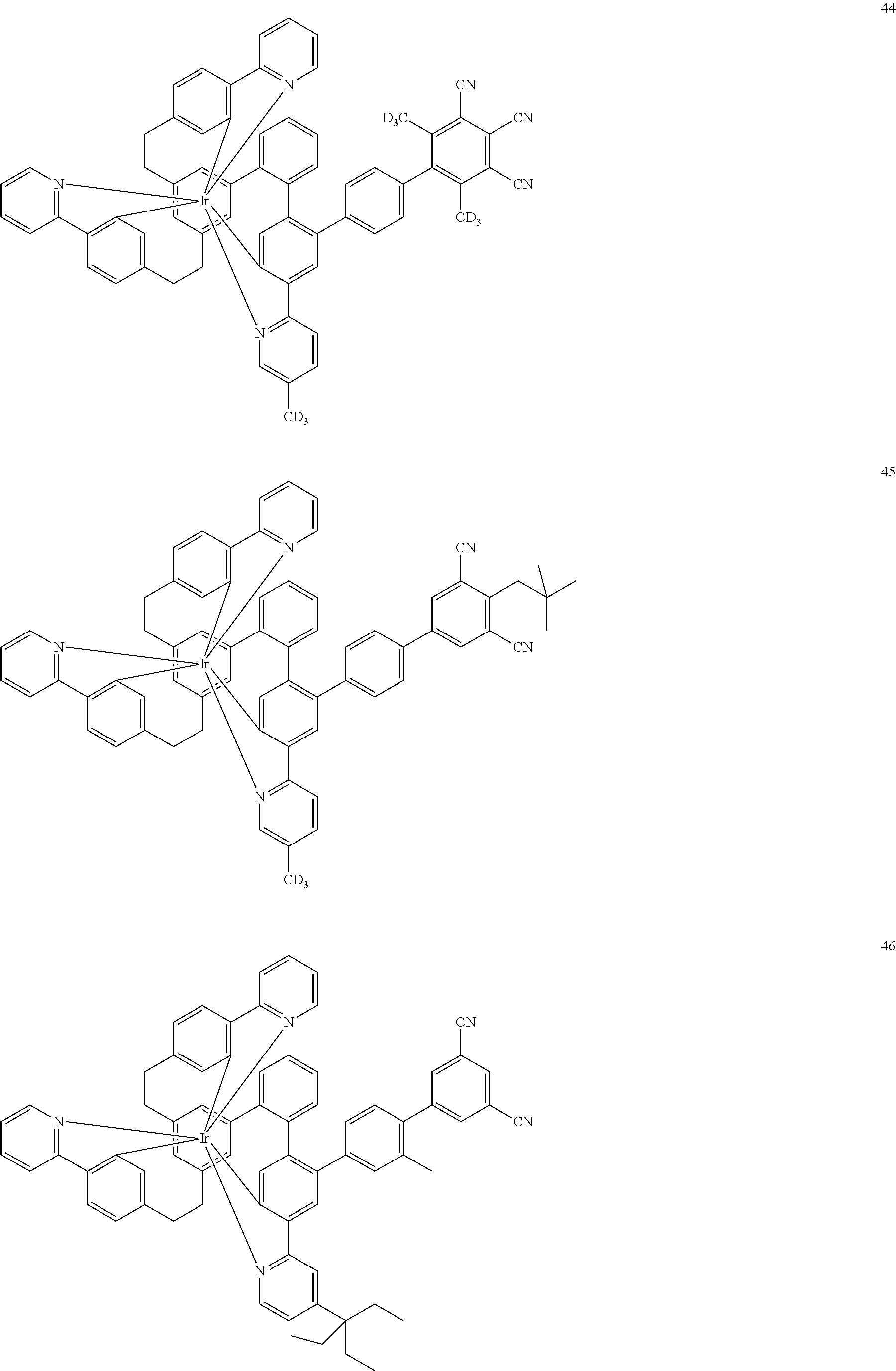

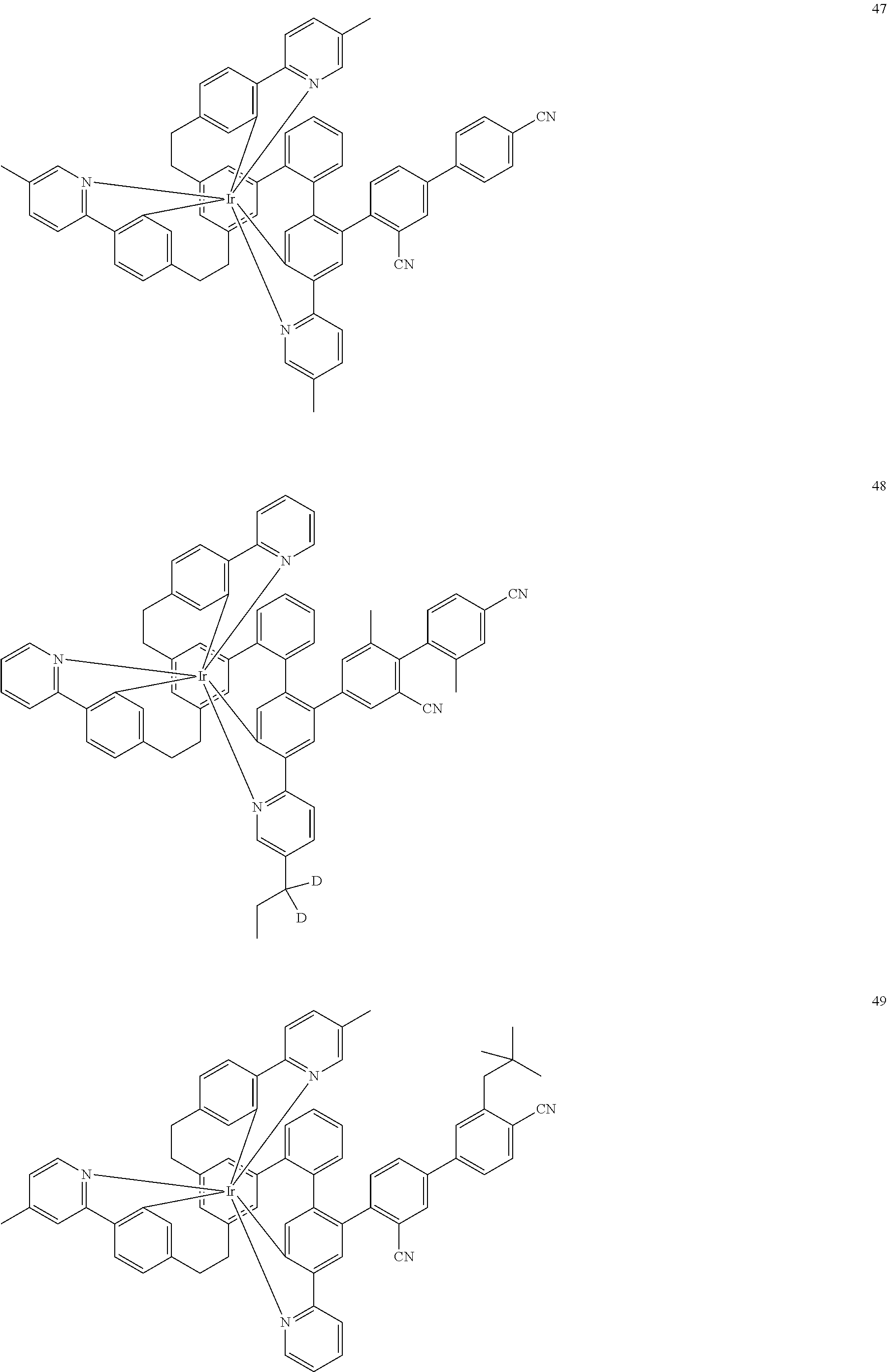

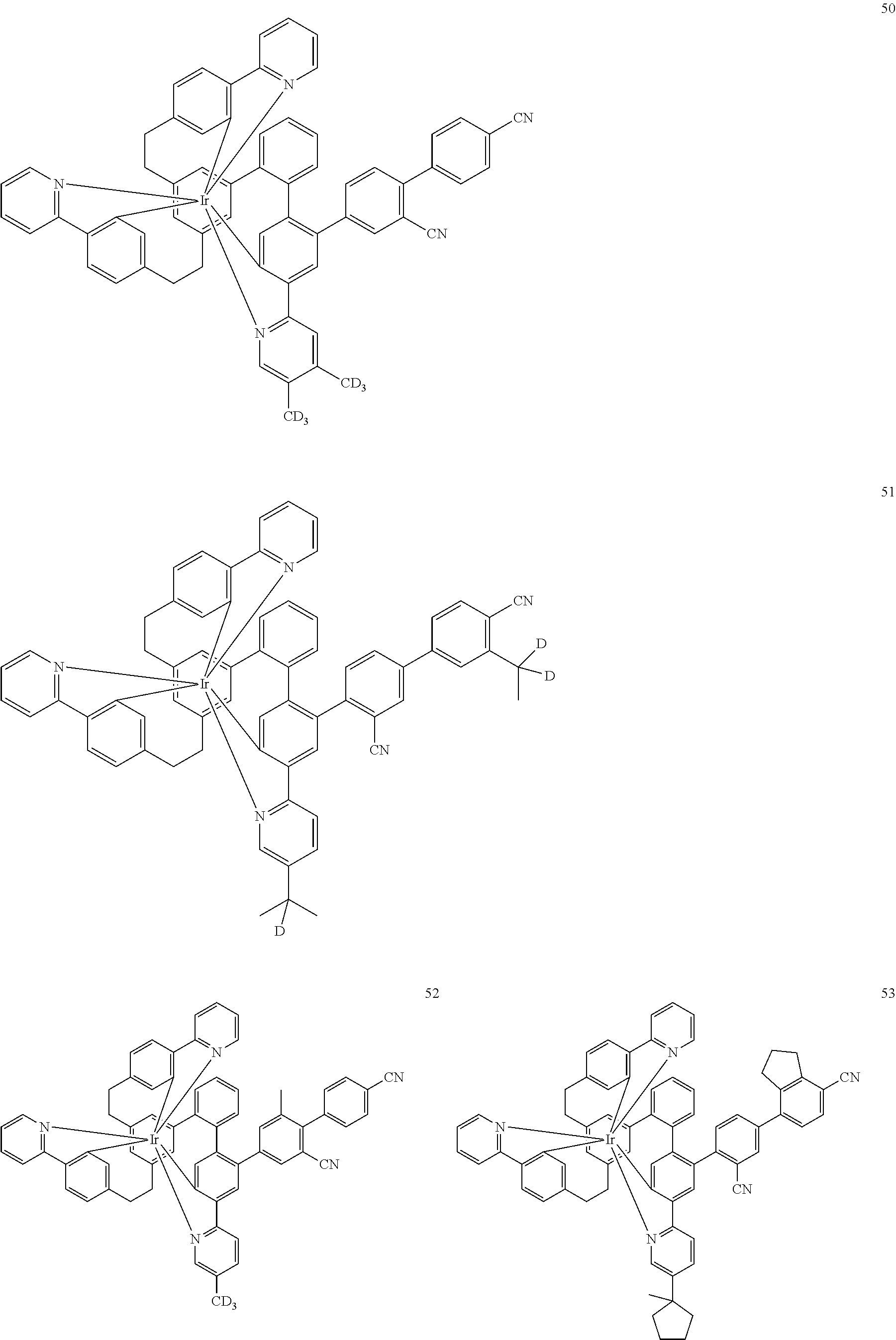

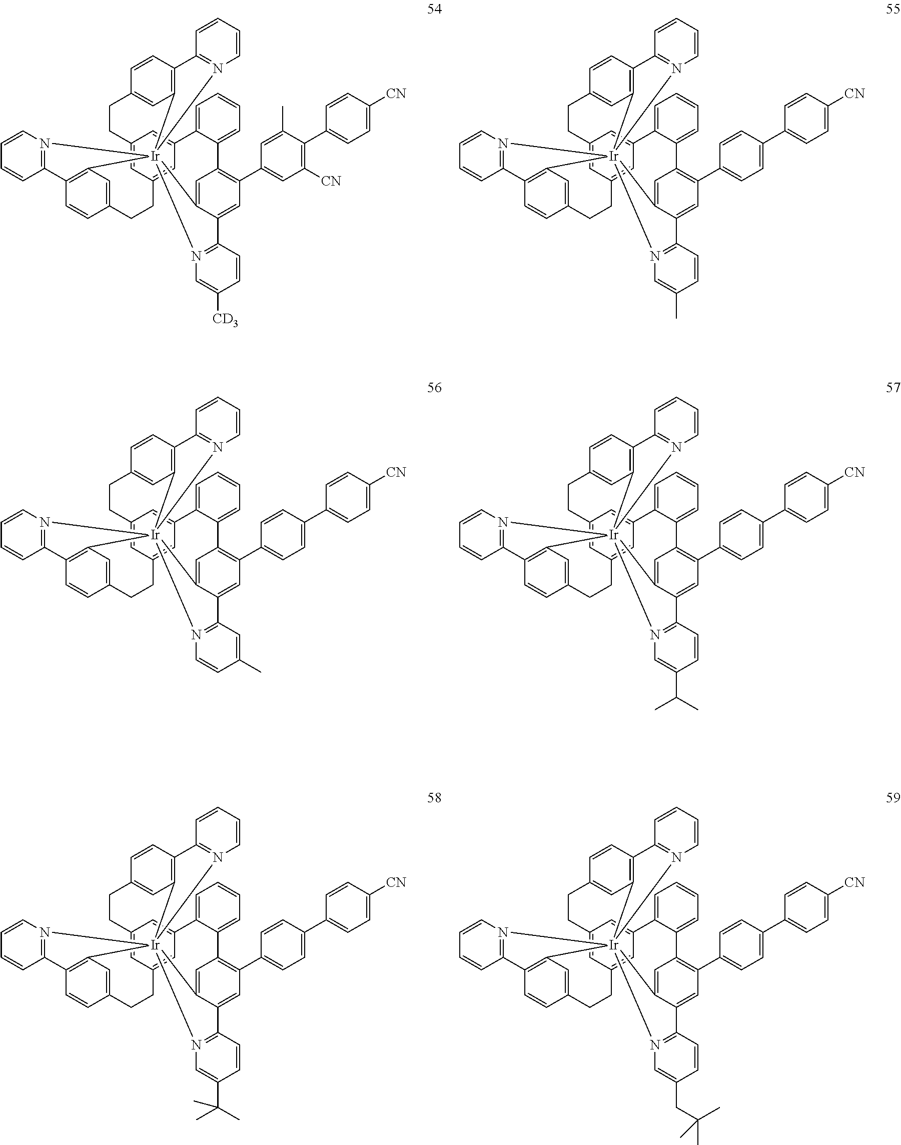

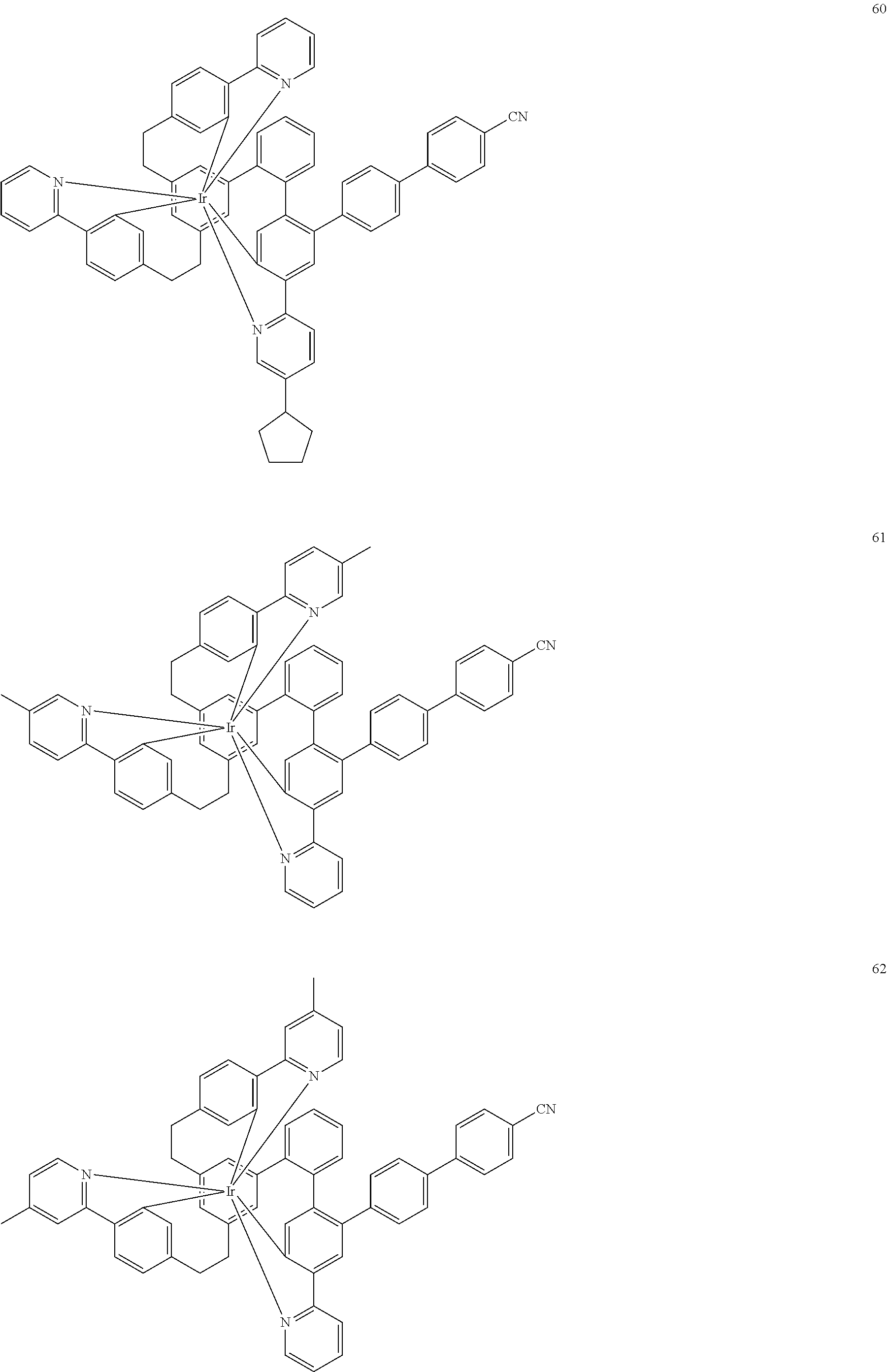

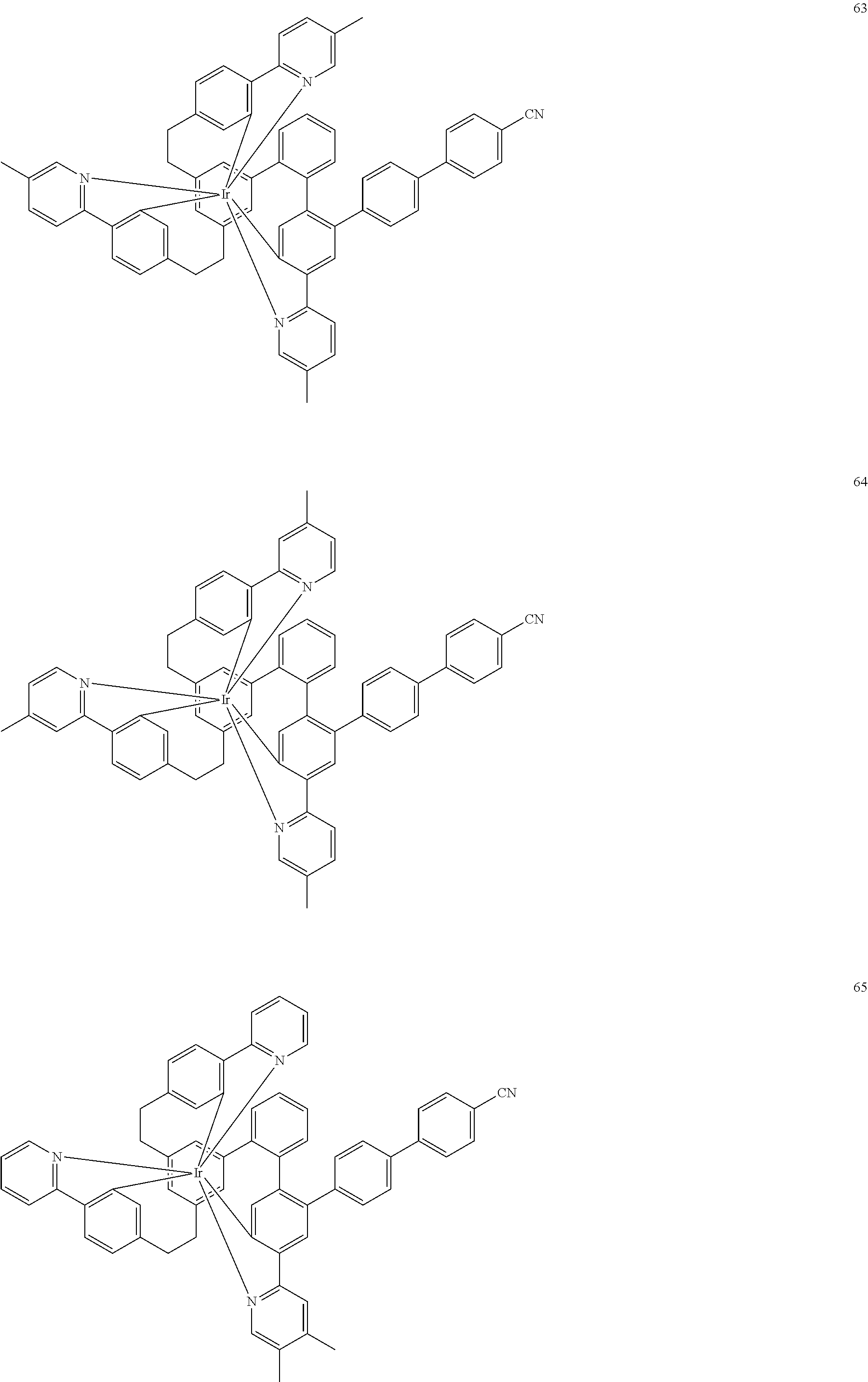

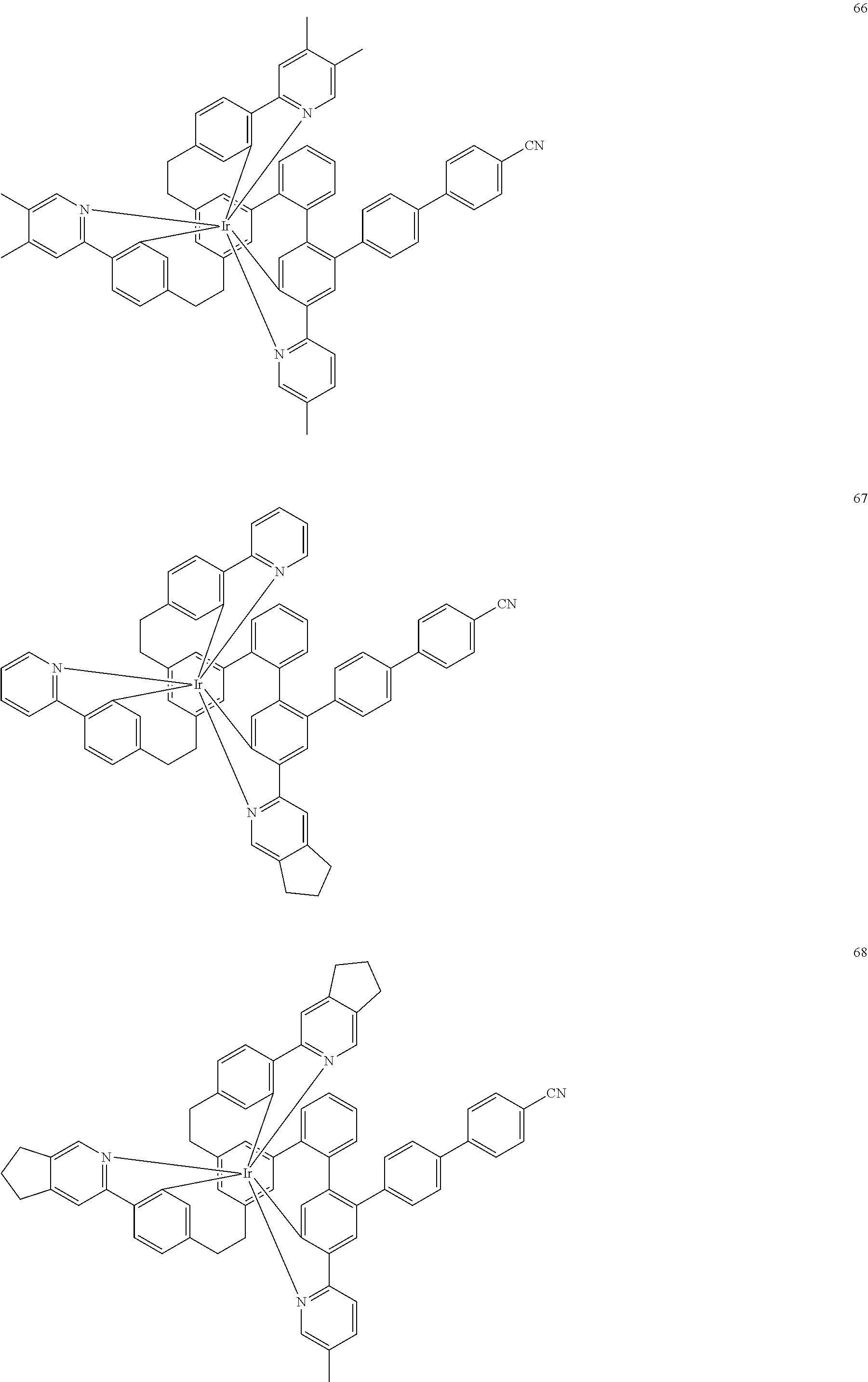

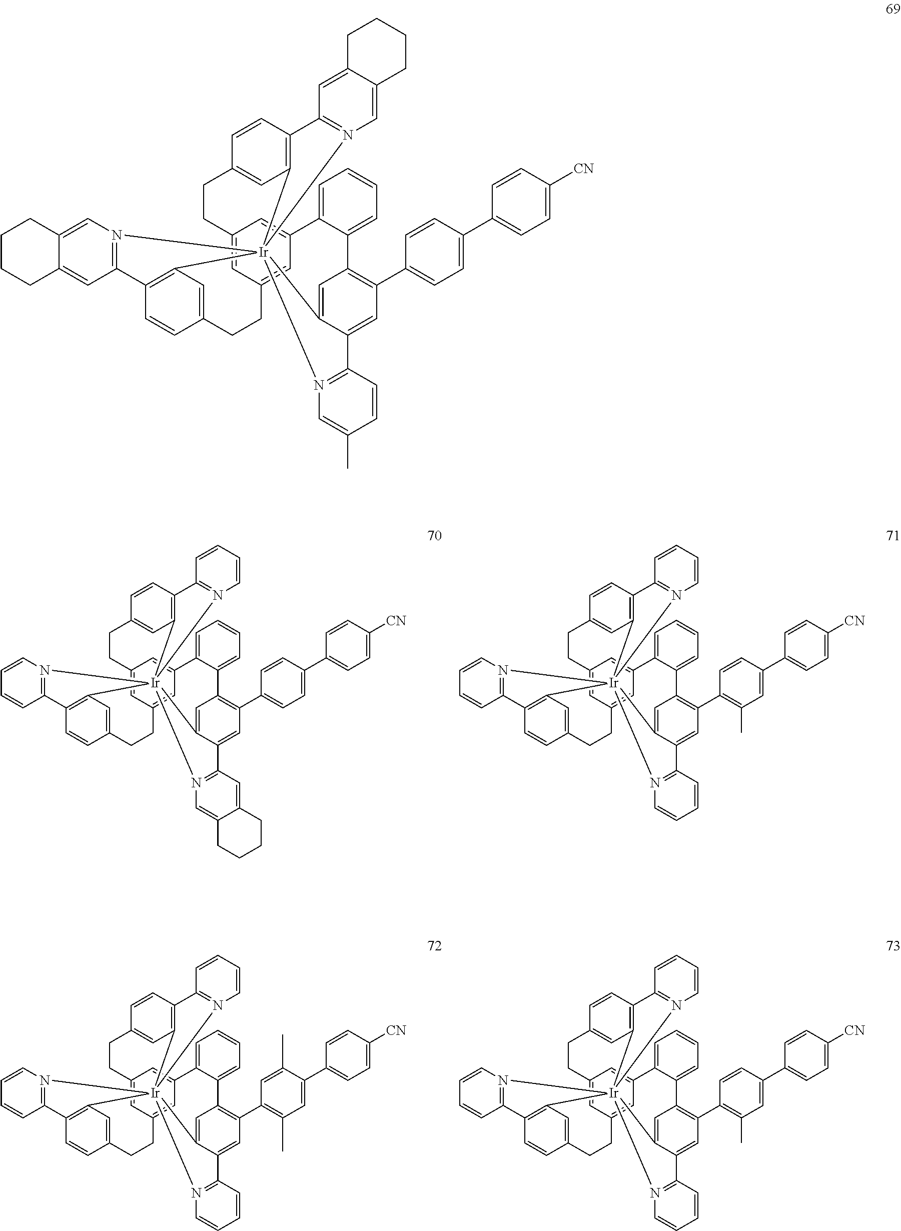

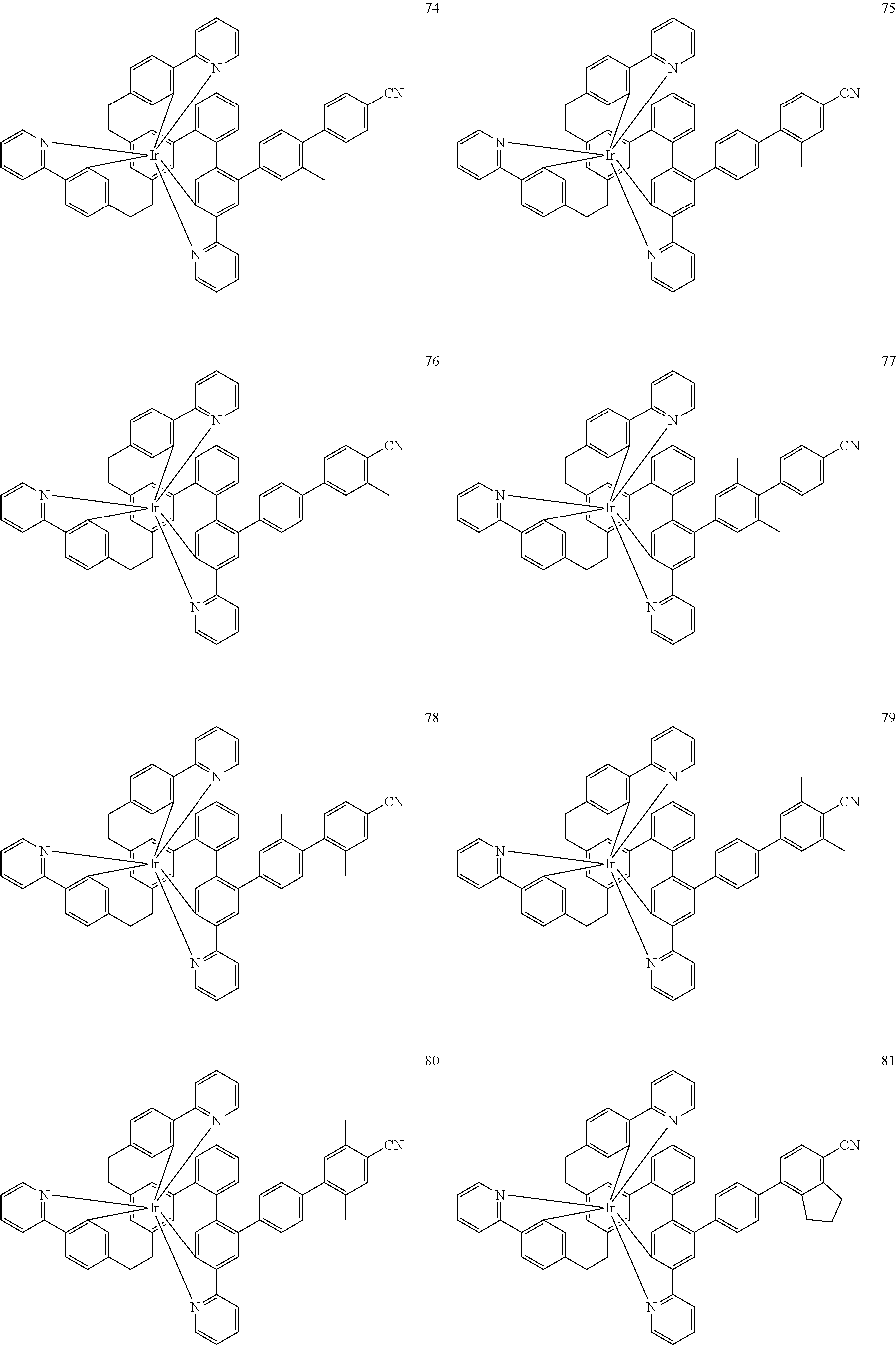

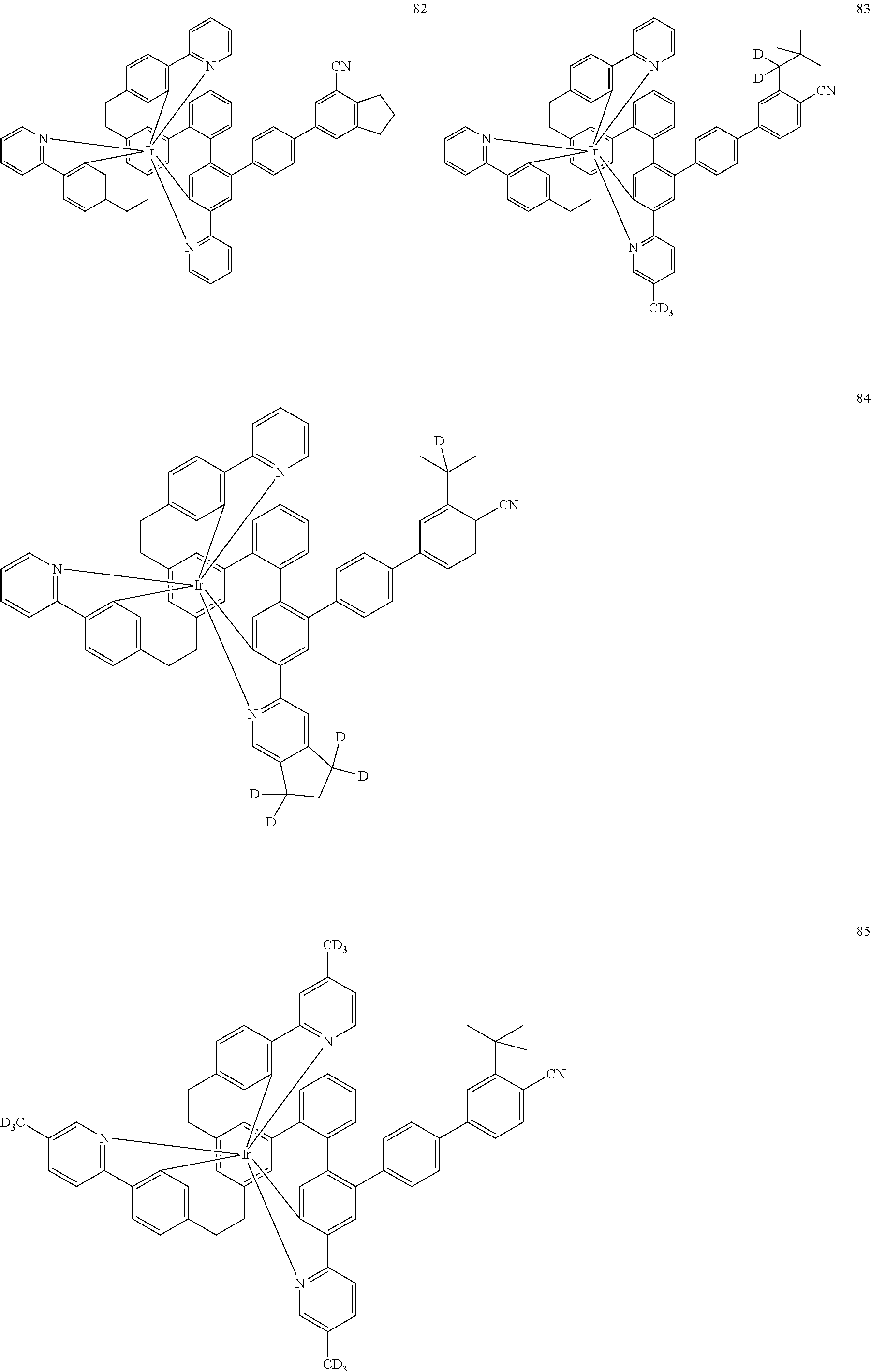

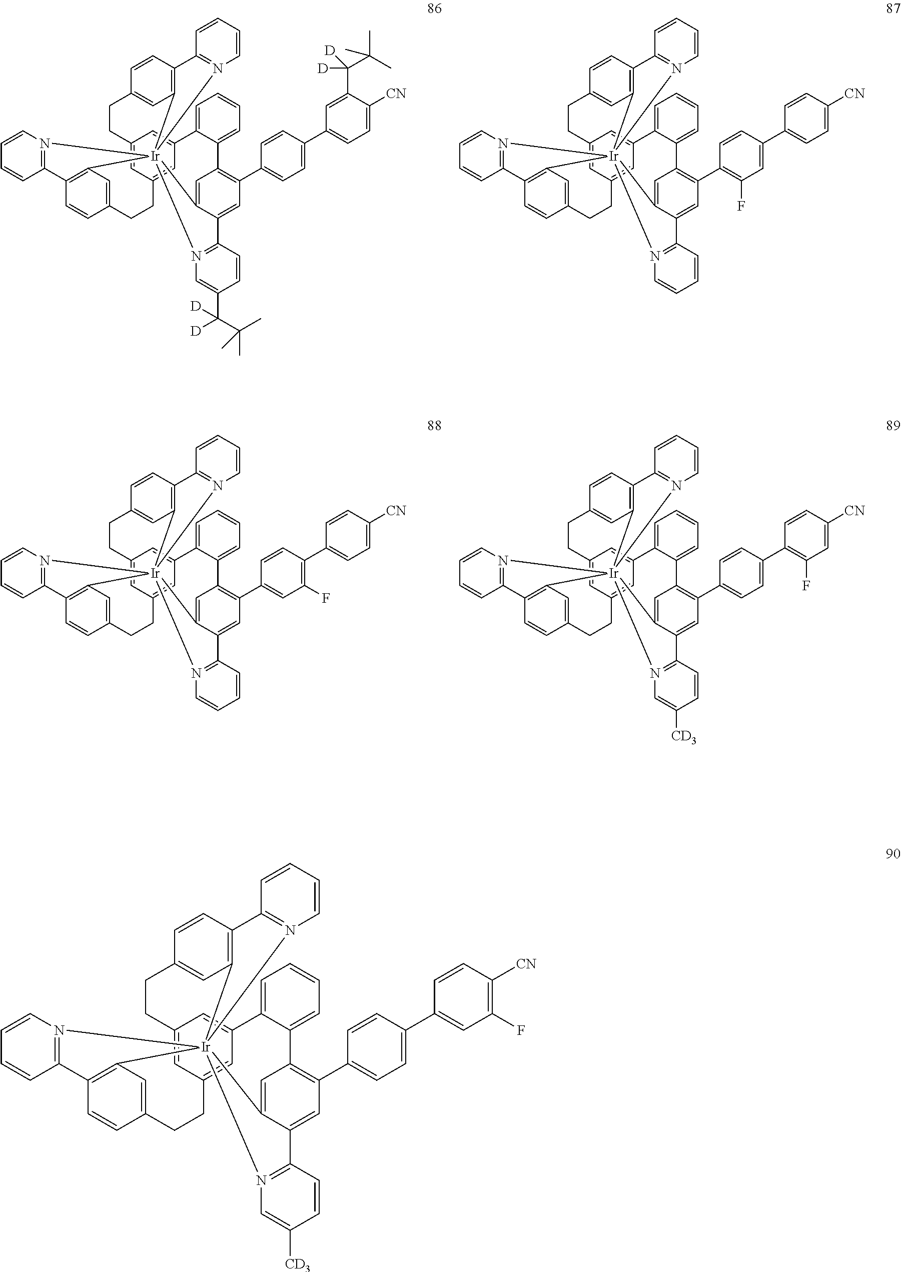

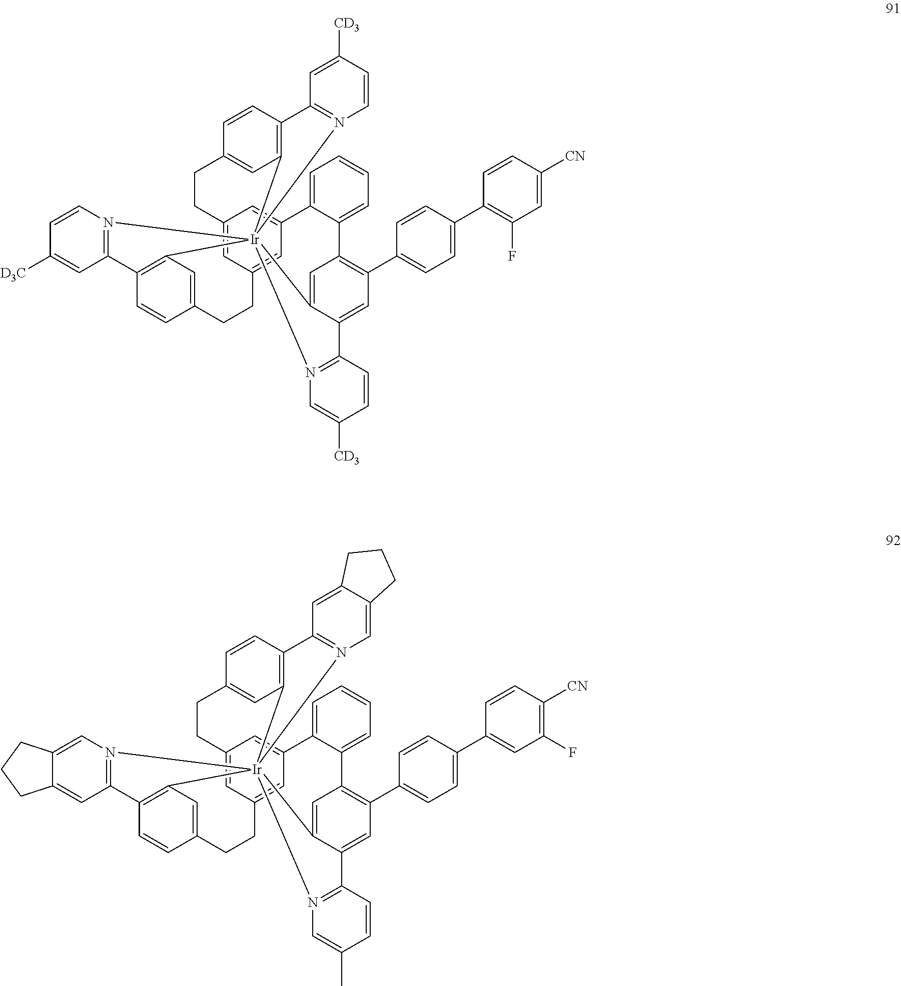

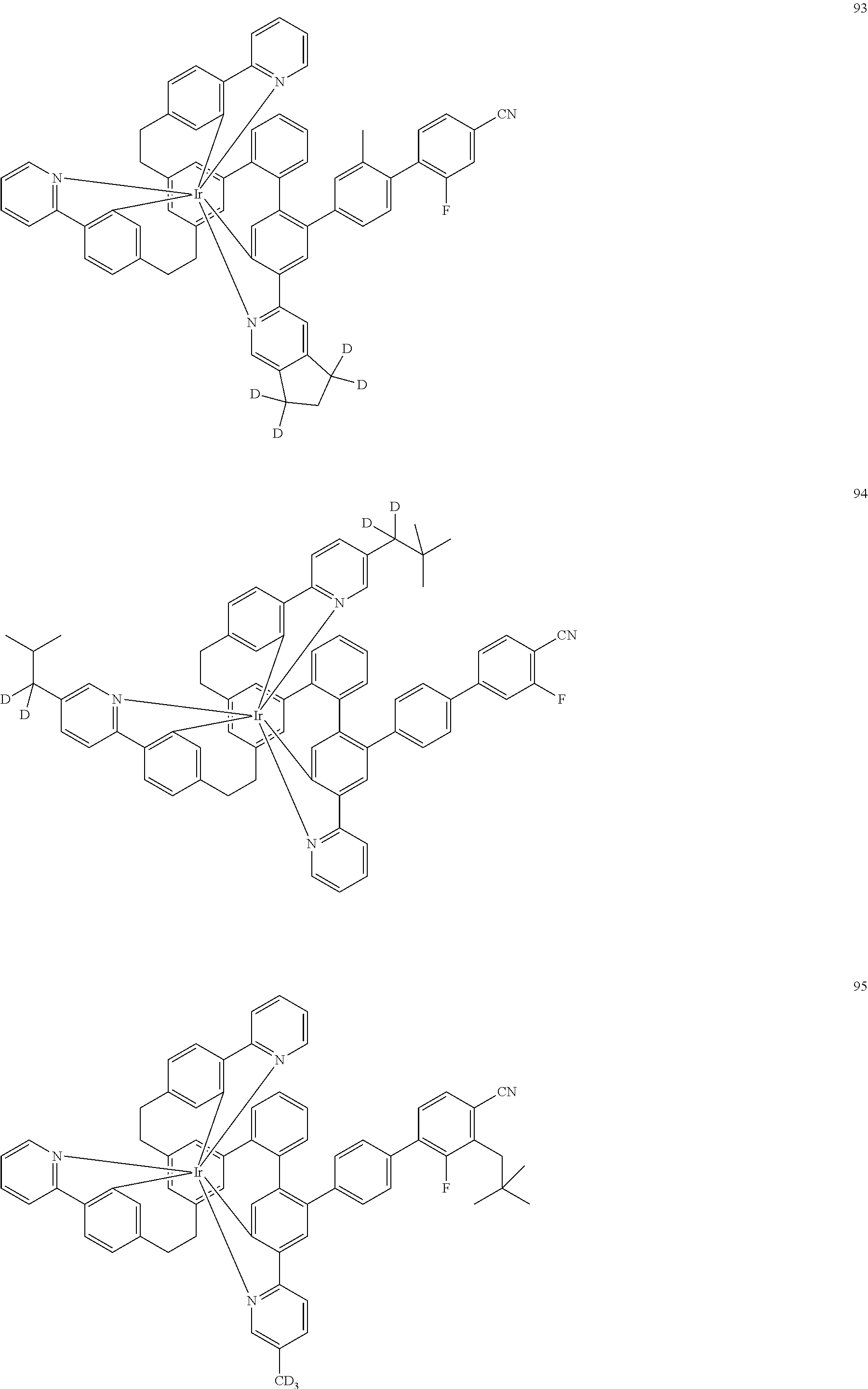

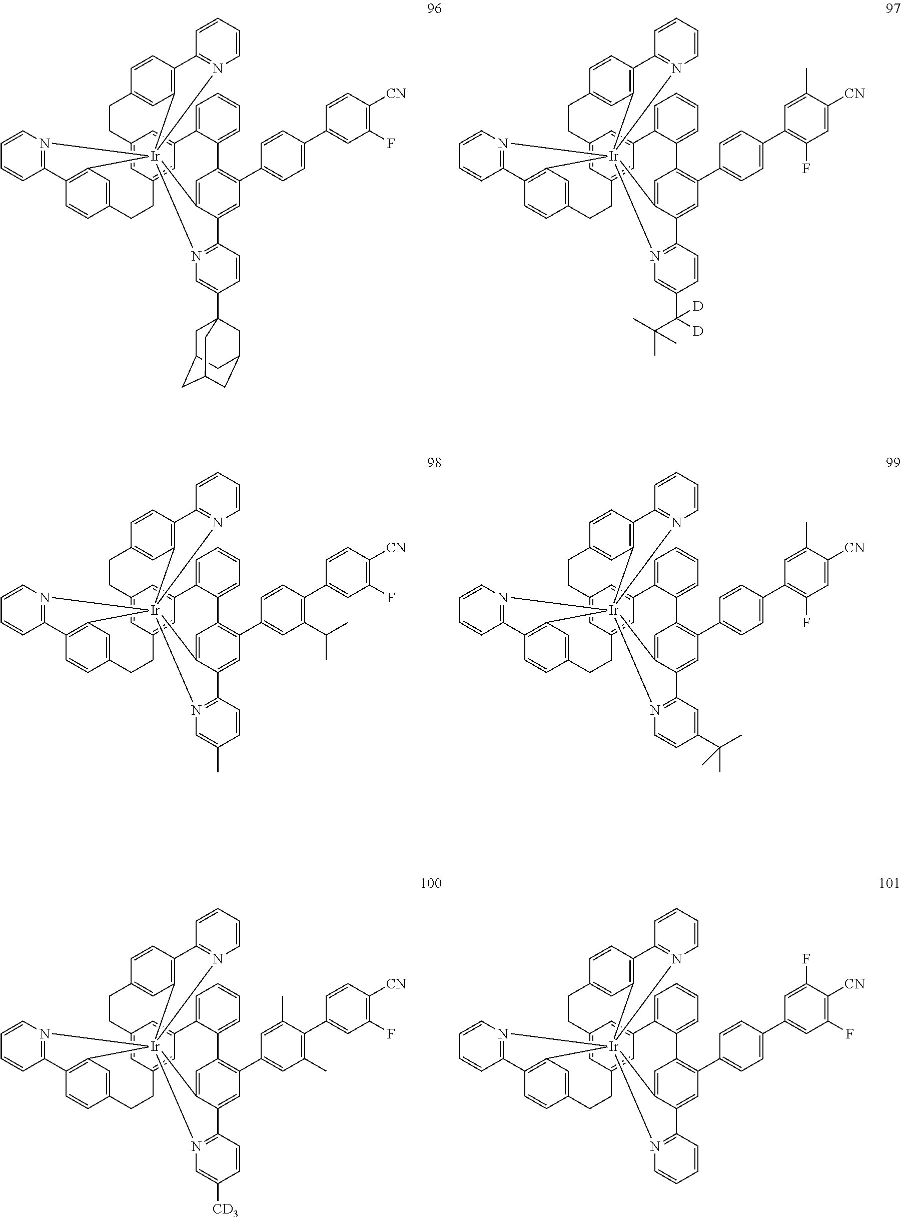

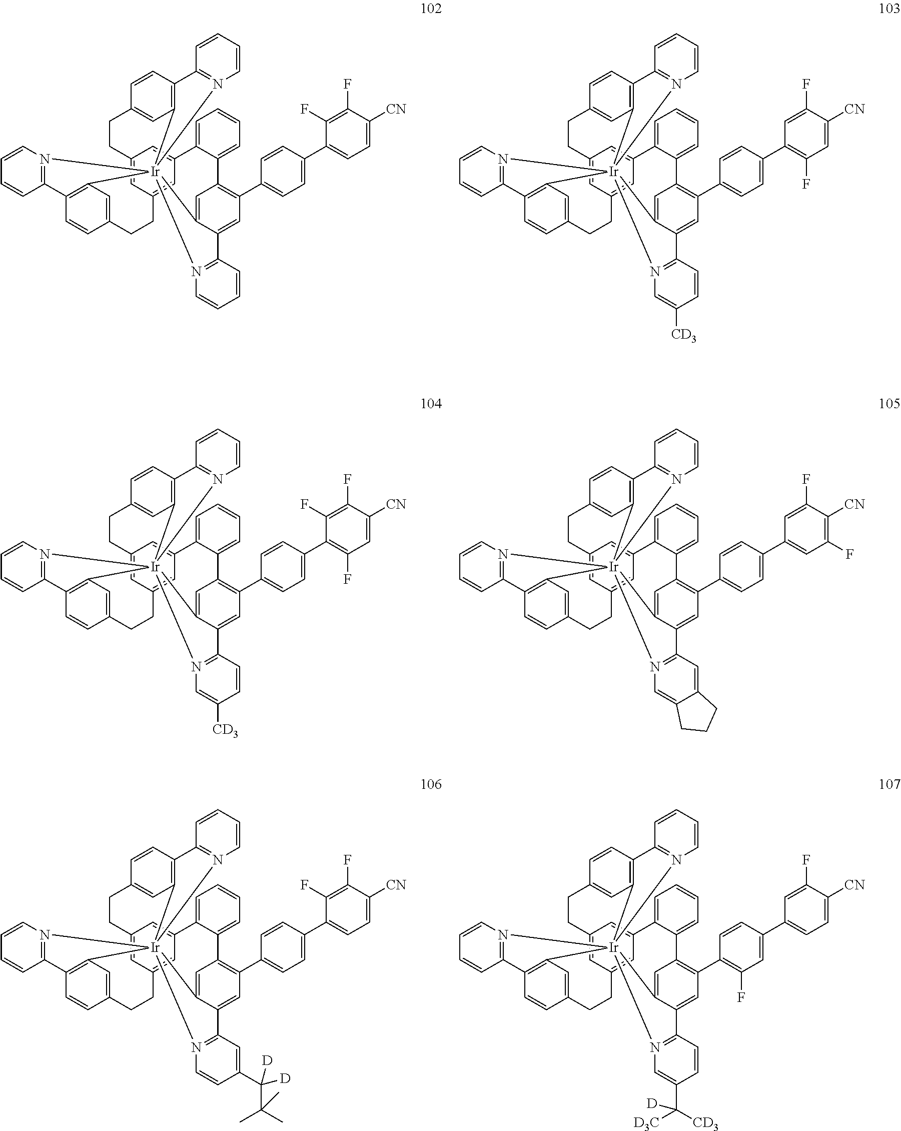

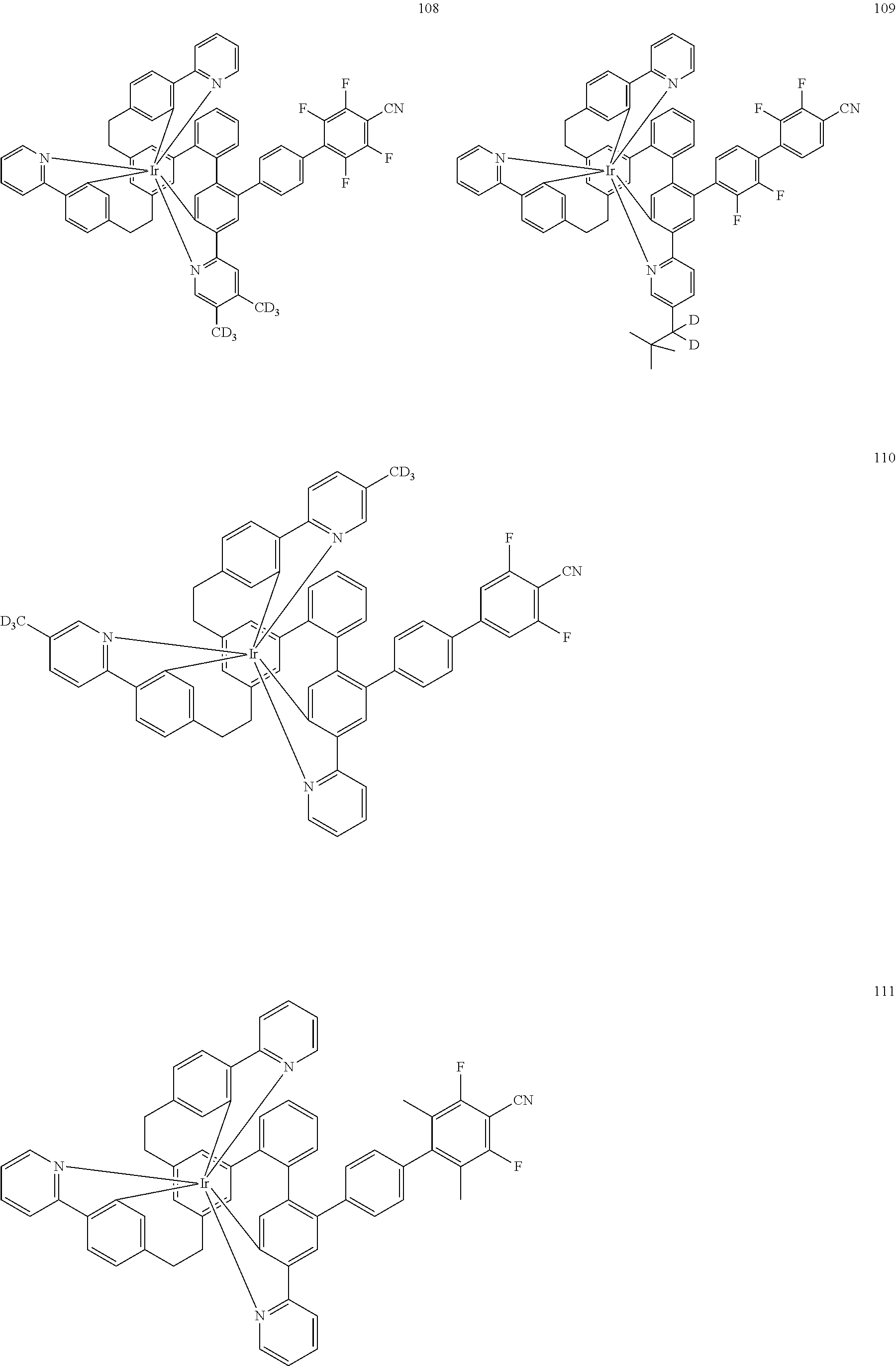

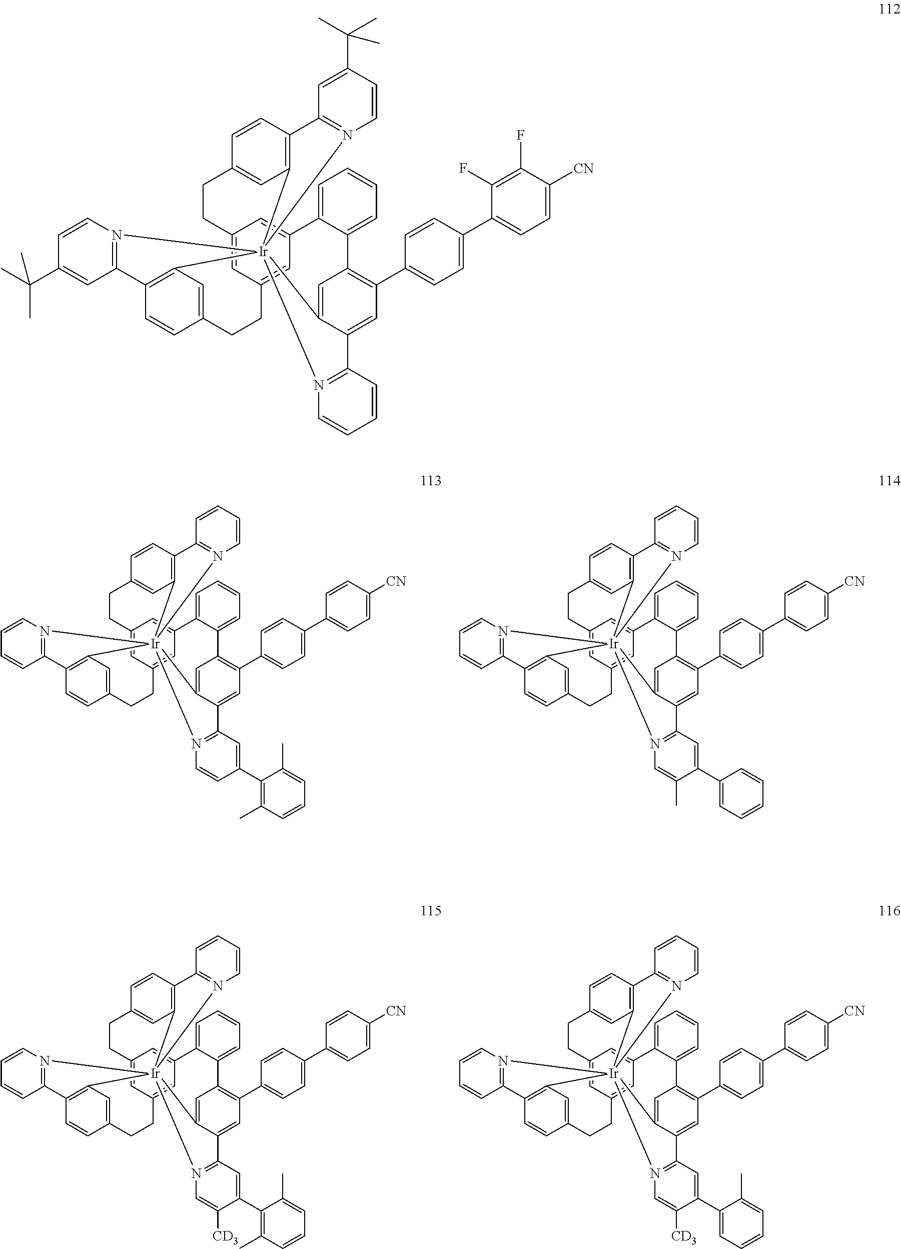

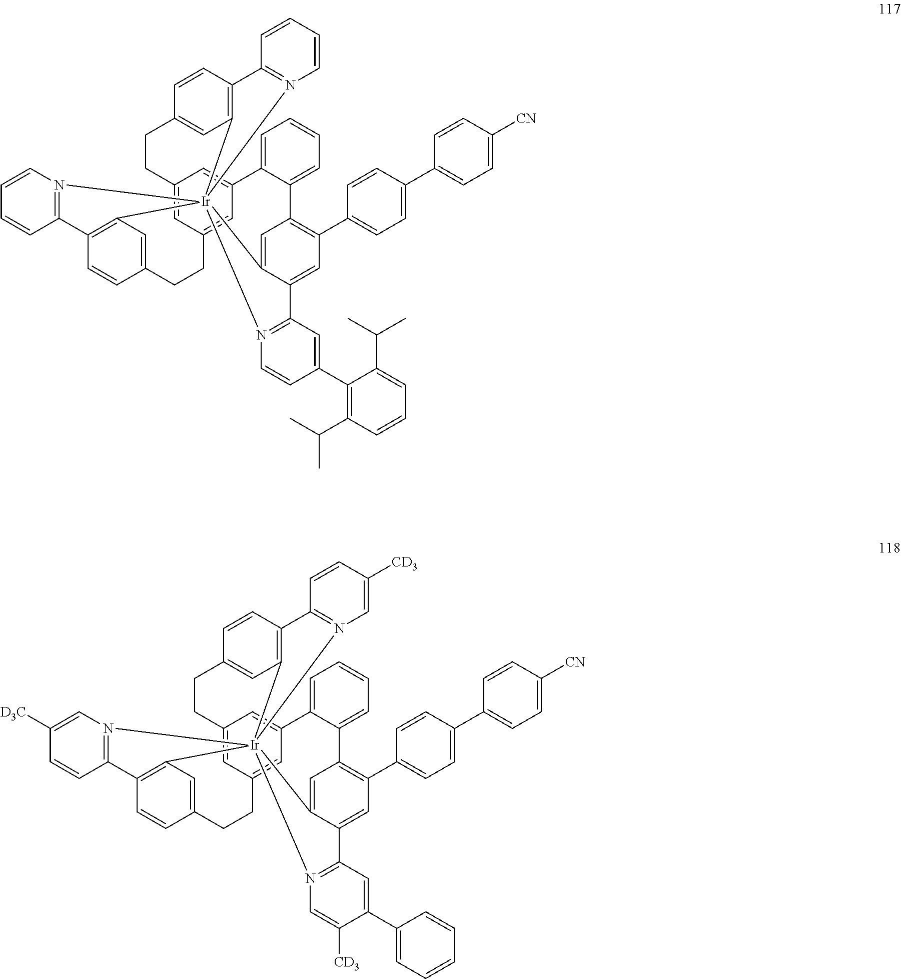

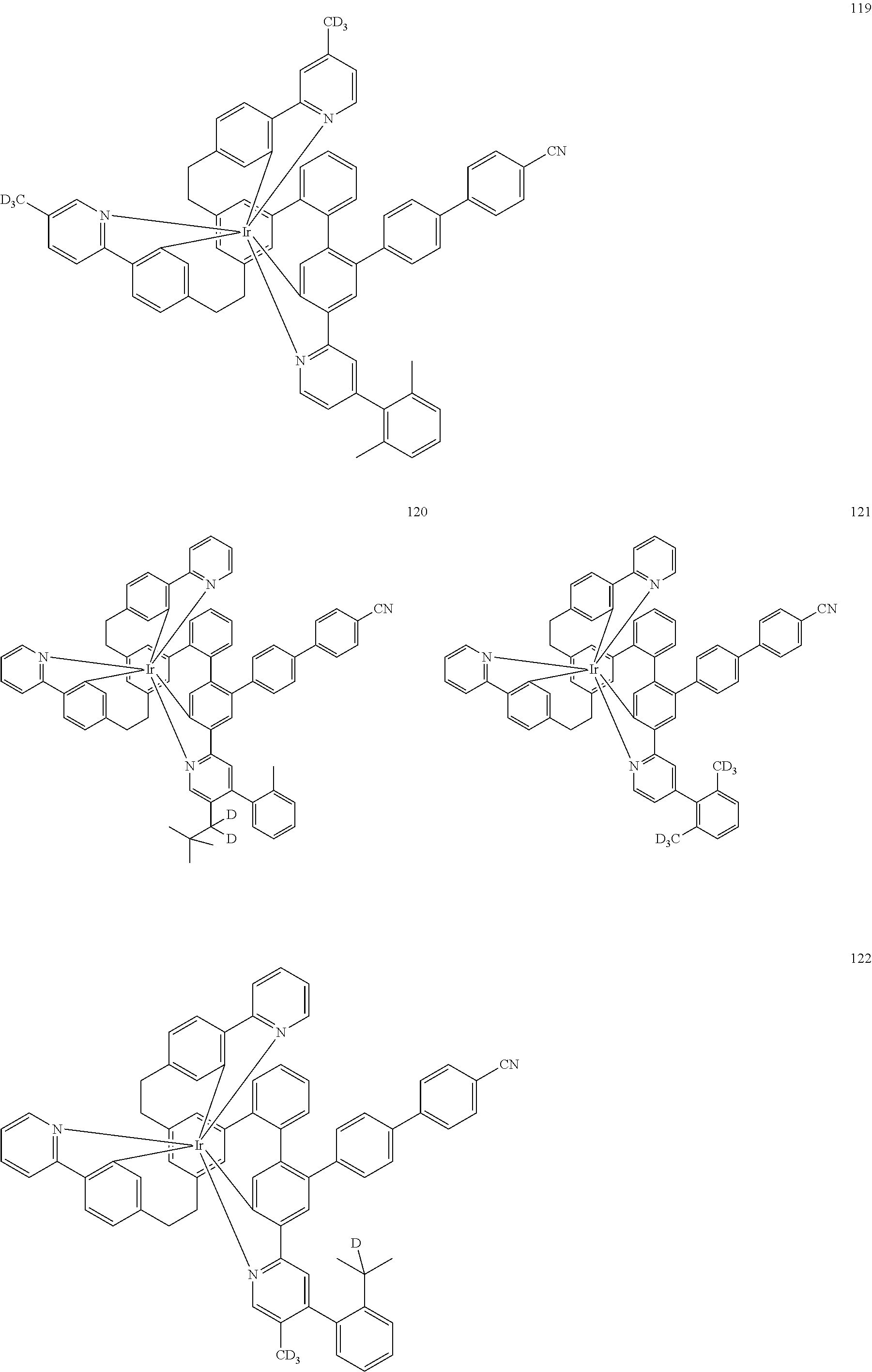

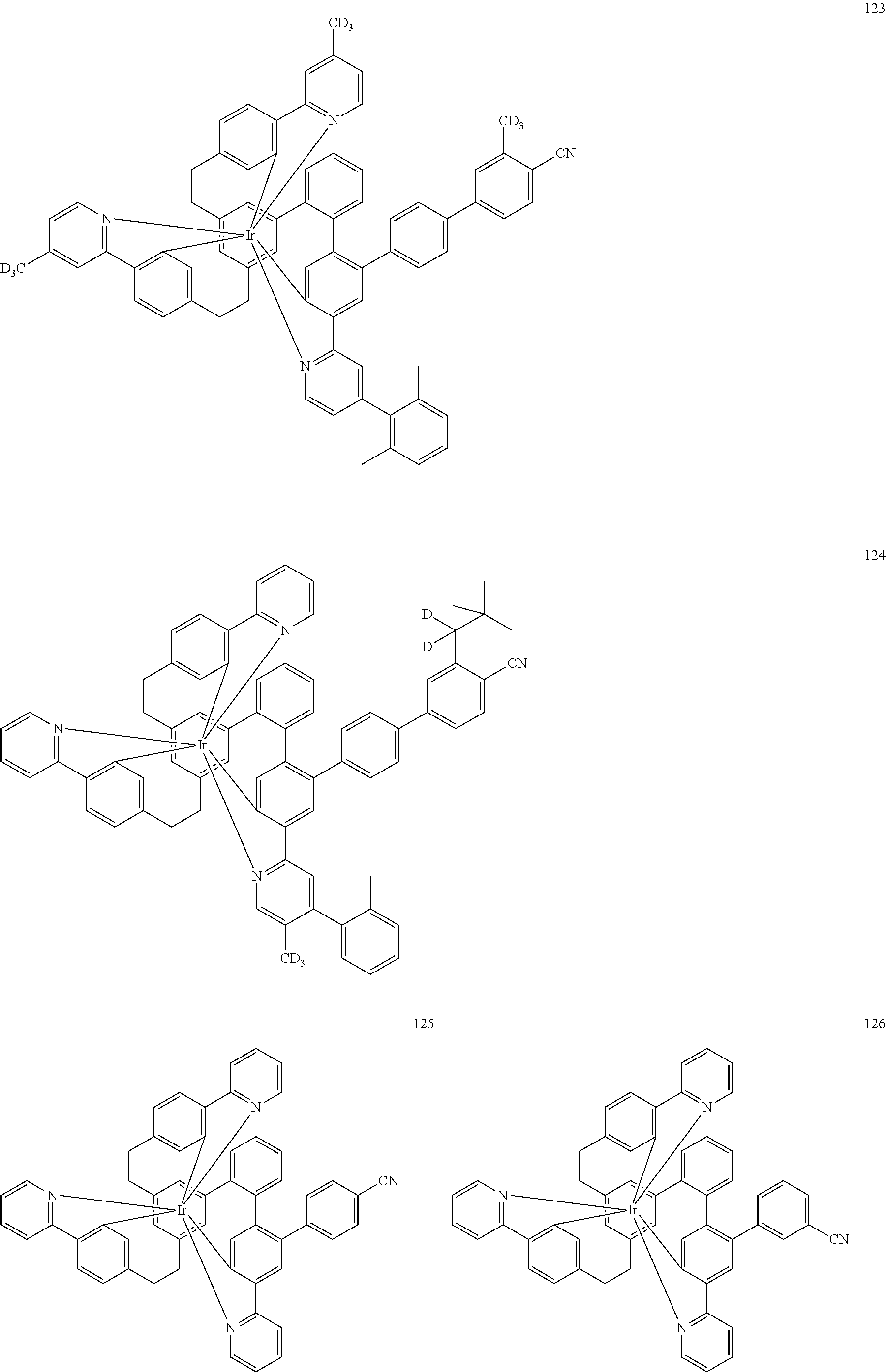

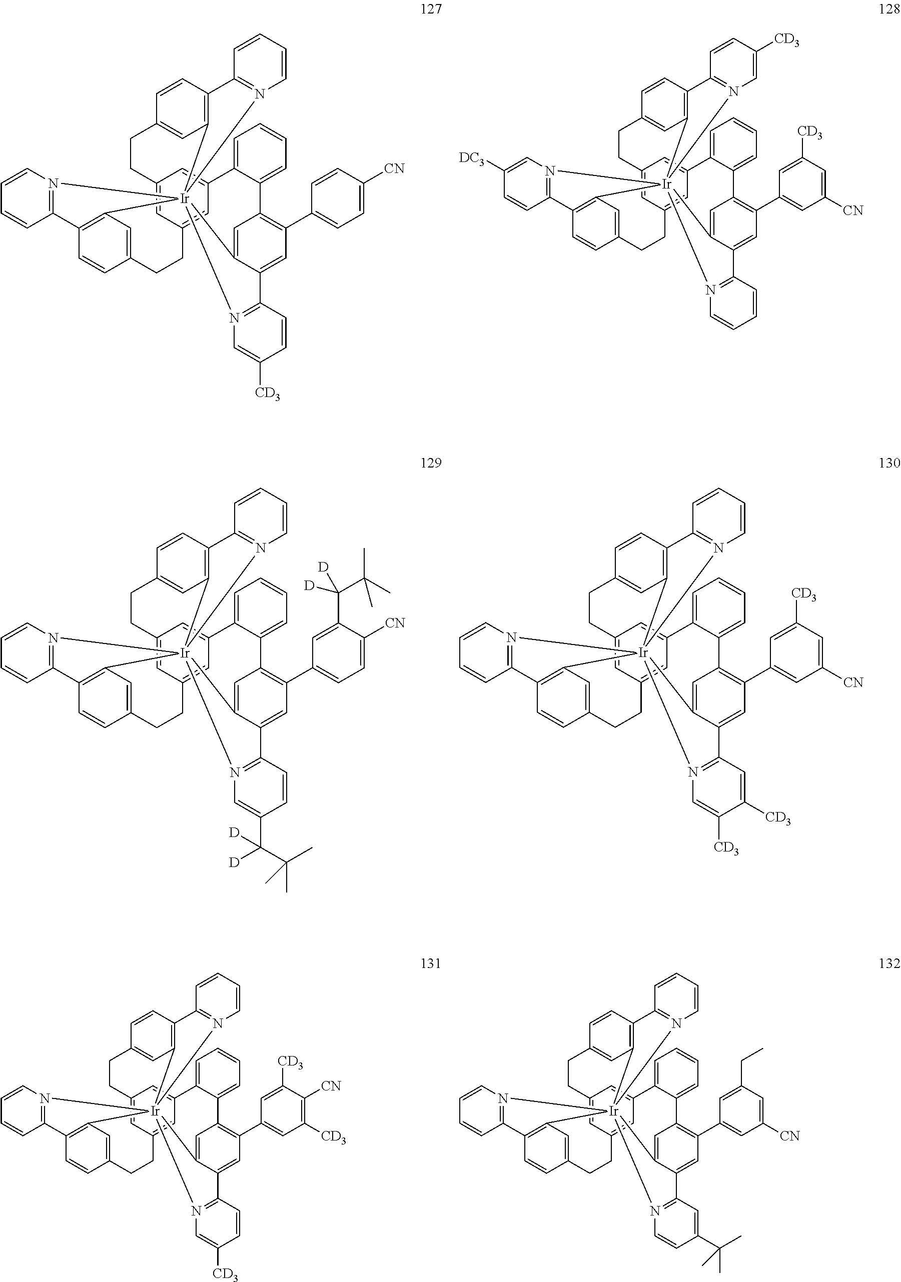

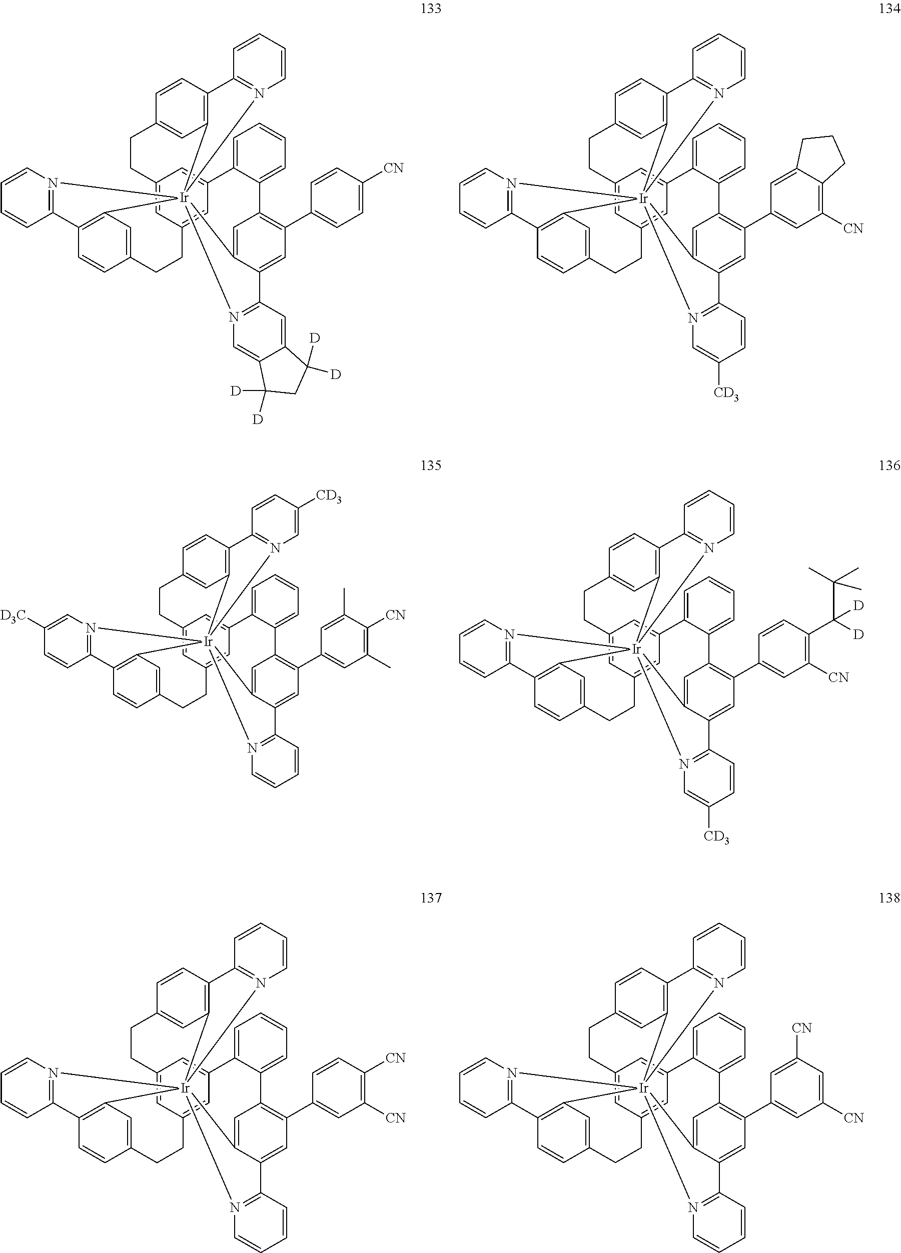

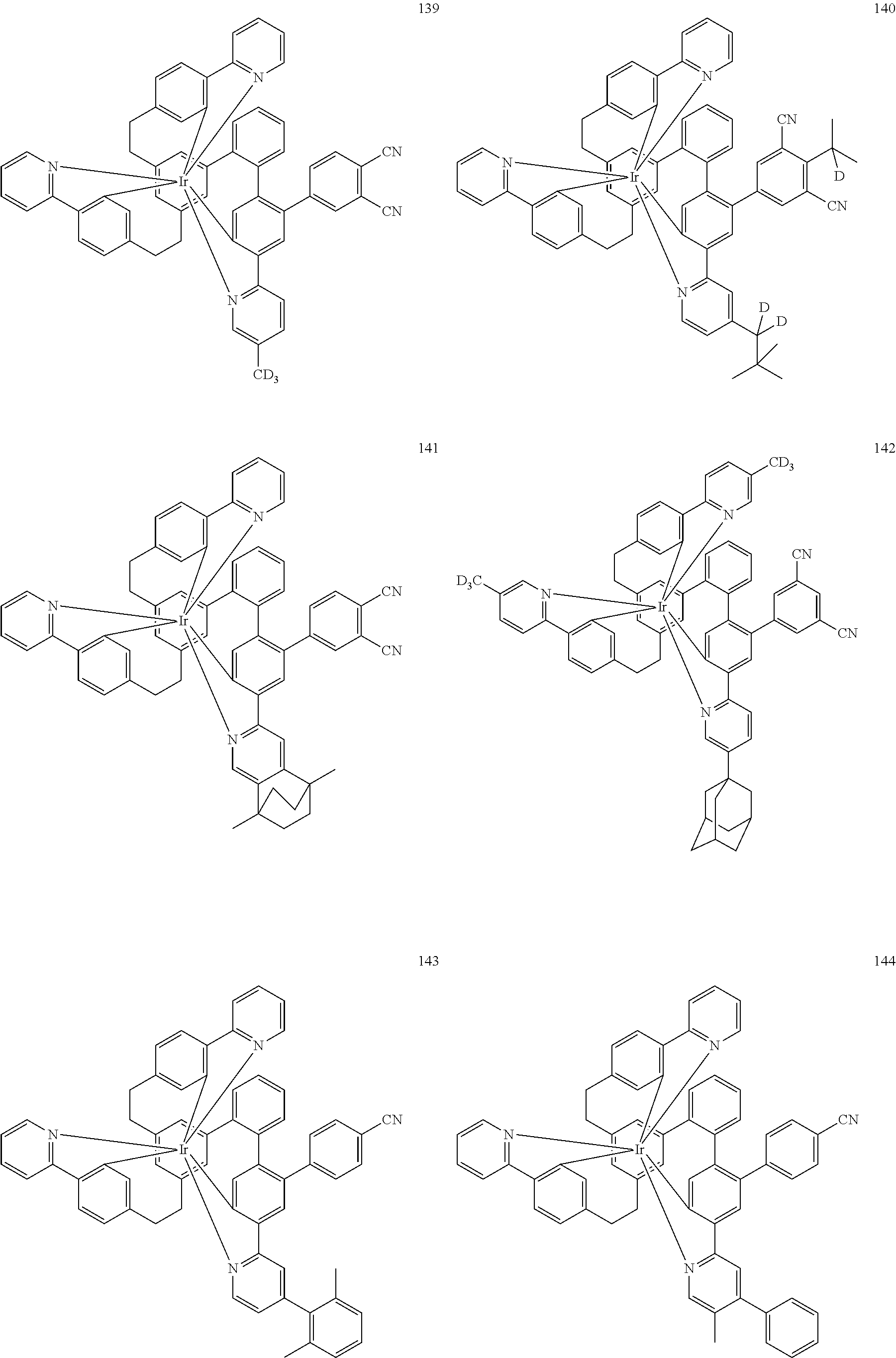

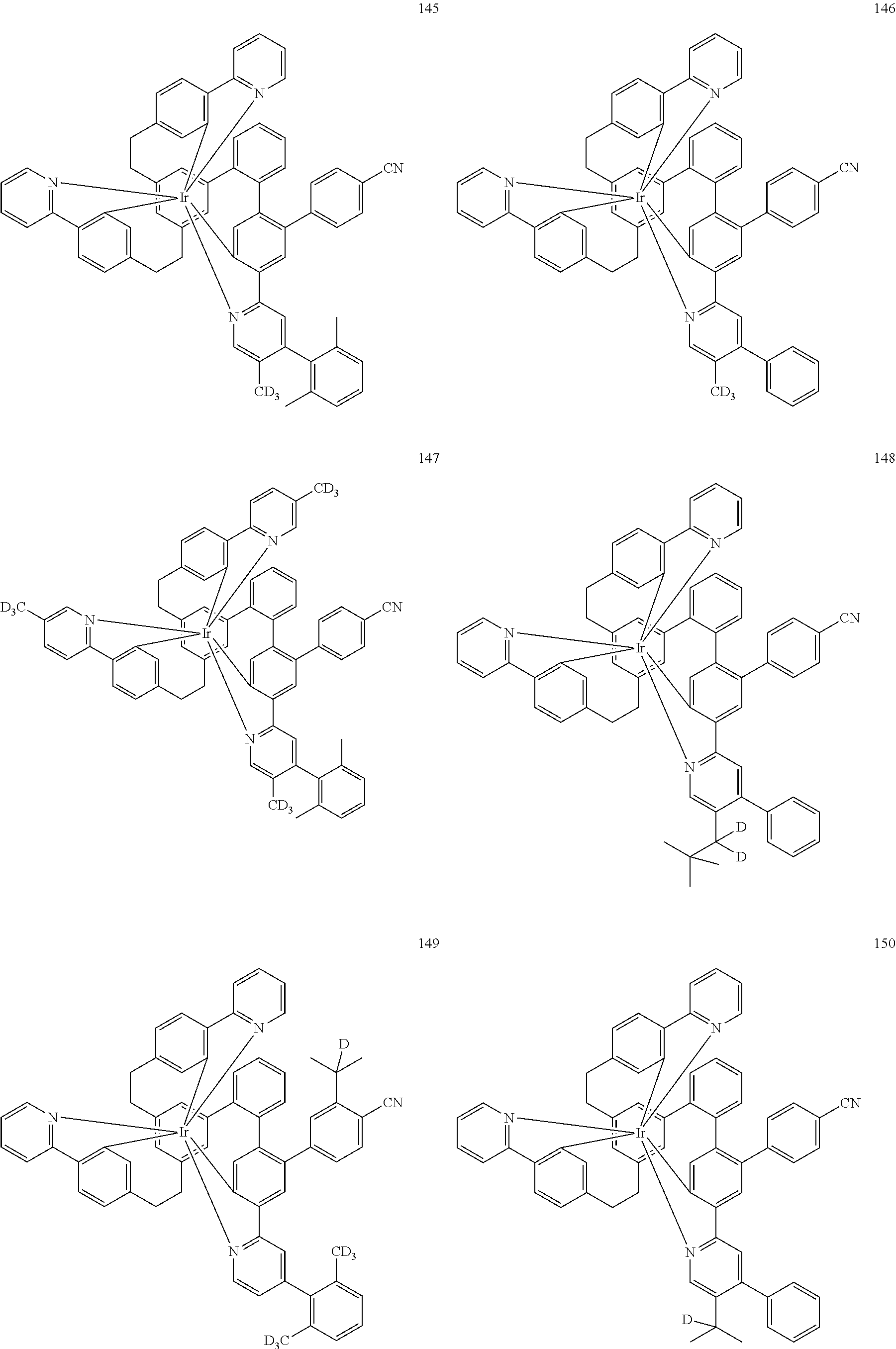

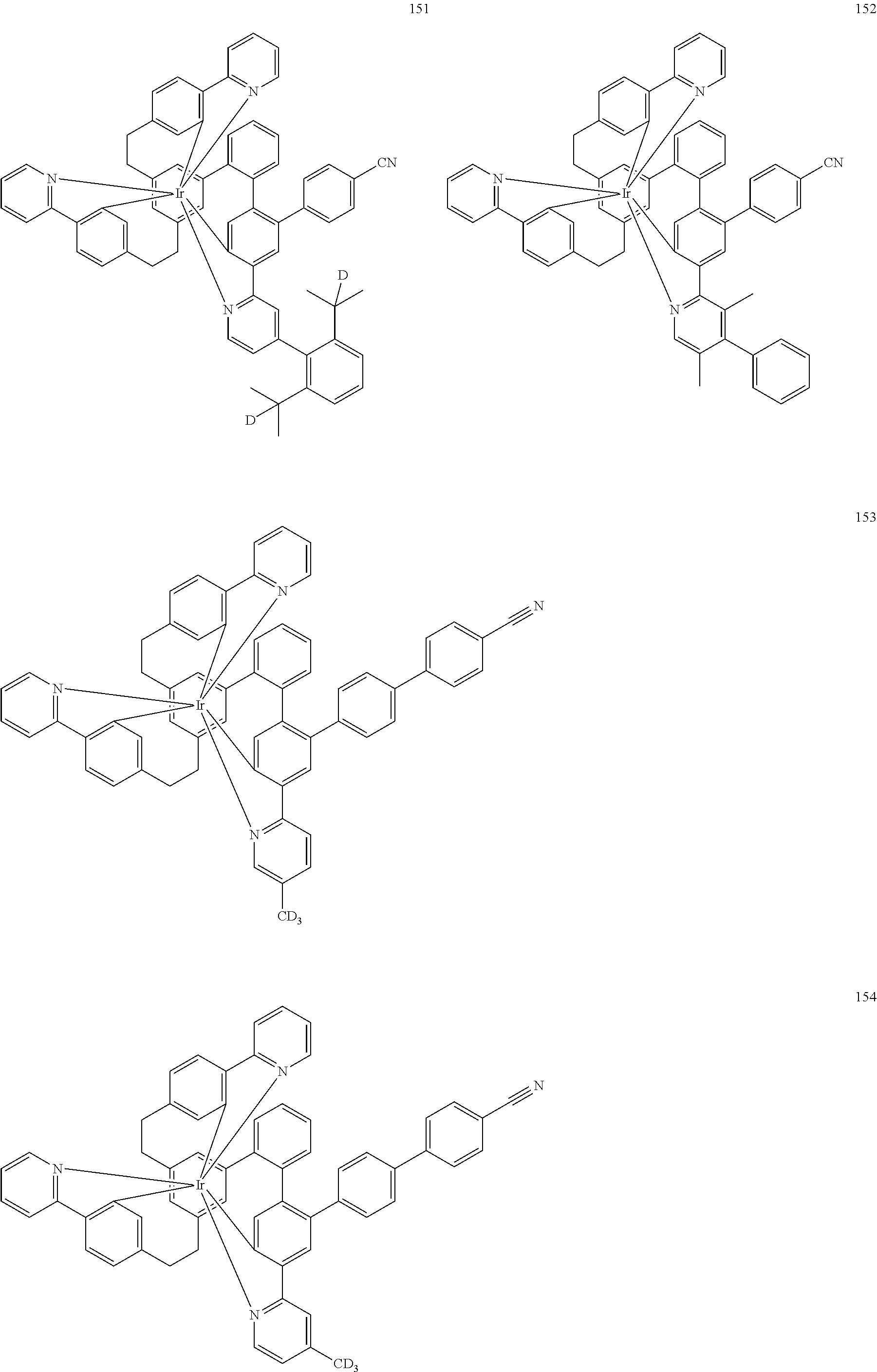

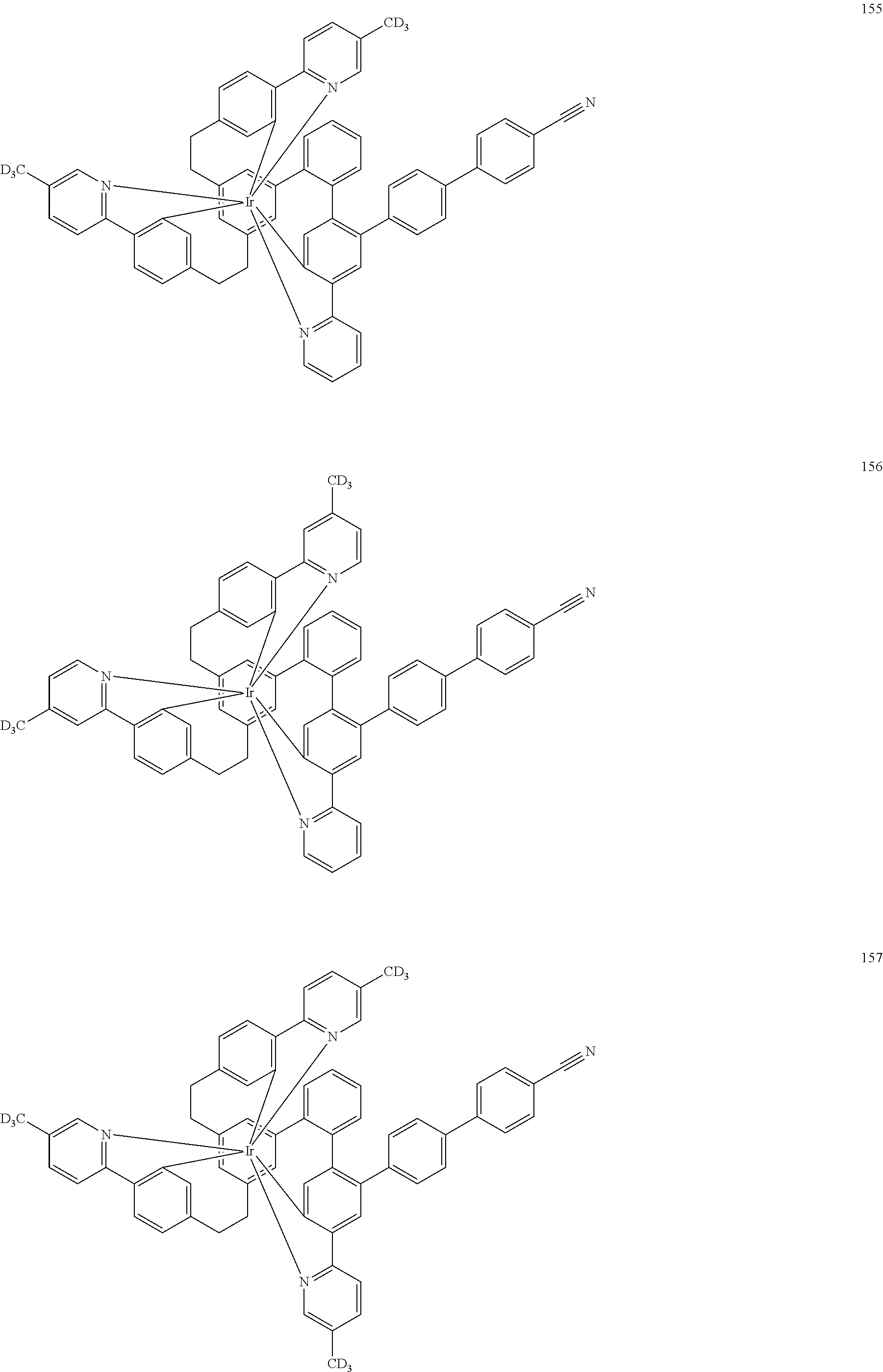

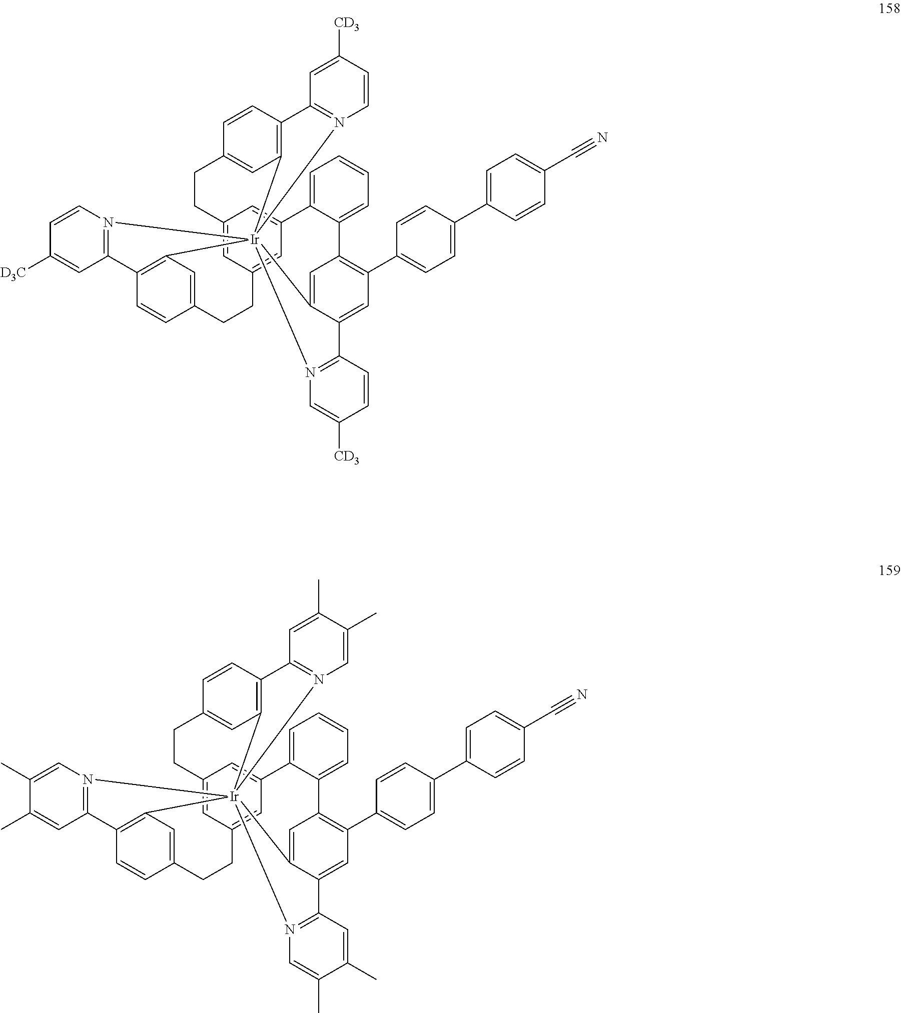

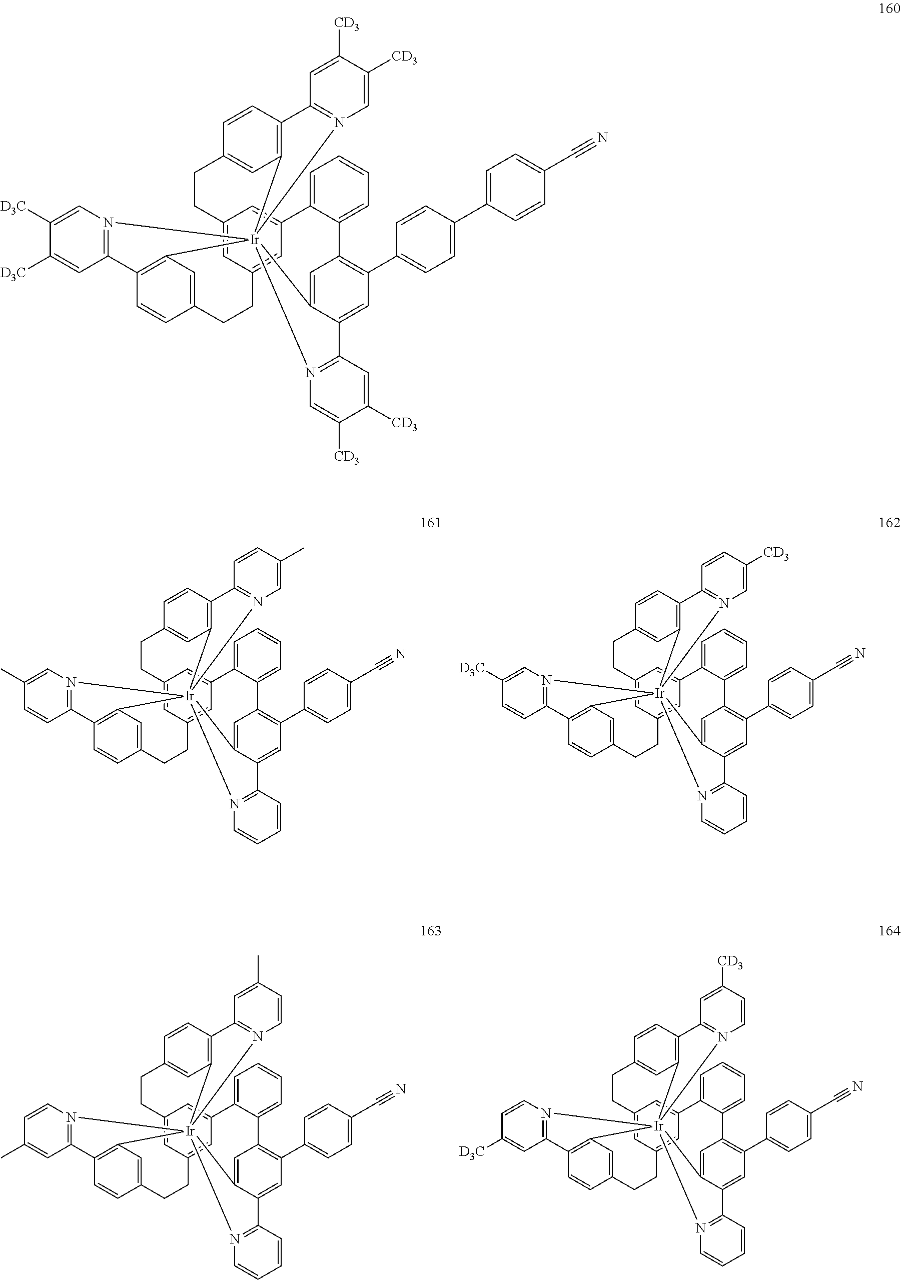

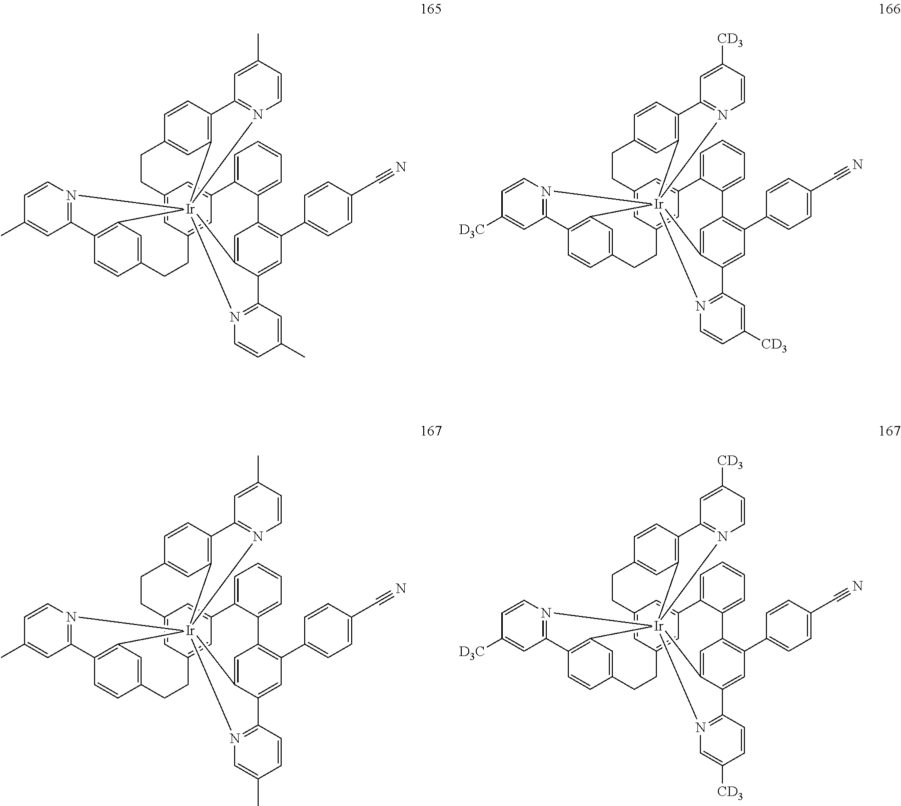

The metal complexes of the invention are chiral structures. If the ligand L is additionally also chiral, the formation of diastereomers and multiple enantiomer pairs is possible. In that case, the complexes of the invention include both the mixtures of the different diastereomers or the corresponding racemates and the individual isolated diastereomers or enantiomers.

If ligands having two identical subligands are used in the ortho-metalation, what is obtained is typically a racemic mixture of the C₁-symmetric complexes, i.e. of the A and A enantiomers. These may be separated by standard methods (chromatography on chiral materials/columns or optical resolution by crystallization), as shown in the following scheme:

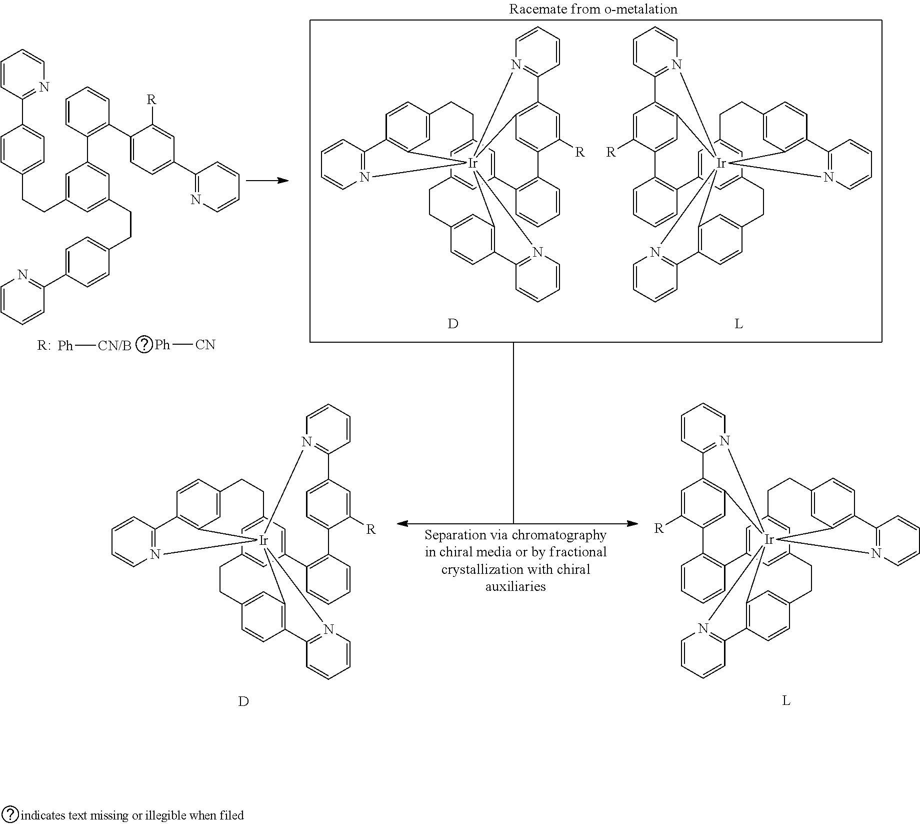

Optical resolution via fractional crystallization of diastereomeric salt pairs can be effected by customary methods. One option for this purpose is to oxidize the uncharged Ir(III) complexes (for example with peroxides or H₂O₂ or by electrochemical means), add the salt of an enantiomerically pure, monoanionic base (chiral base) to the cationic Ir(IV) complexes thus produced, separate the diastereomeric salts thus produced by fractional crystallization, and then reduce them with the aid of a reducing agent (e.g. zinc, hydrazine hydrate, ascorbic acid, etc.) to give the enantiomerically pure uncharged complex, as shown schematically below:

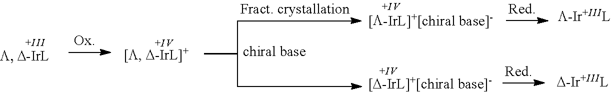

In addition, an enantiomerically pure or enantiomerically enriching synthesis is possible by complexation in a chiral medium (e.g. R- or S-1,1-binaphthol).

If ligands having three different sub-ligands are used in the complexation, what is typically obtained is a diastereomer mixture of the complexes which can be separated by standard methods (chromatography, crystallization, etc.).

Enantiomerically pure C₁-symmetric complexes can also be synthesized selectively, as shown in the scheme which follows. For this purpose, an enantiomerically pure C₁-symmetric ligand is prepared and complexed, the diastereomer mixture obtained is separated and then the chiral group is detached.

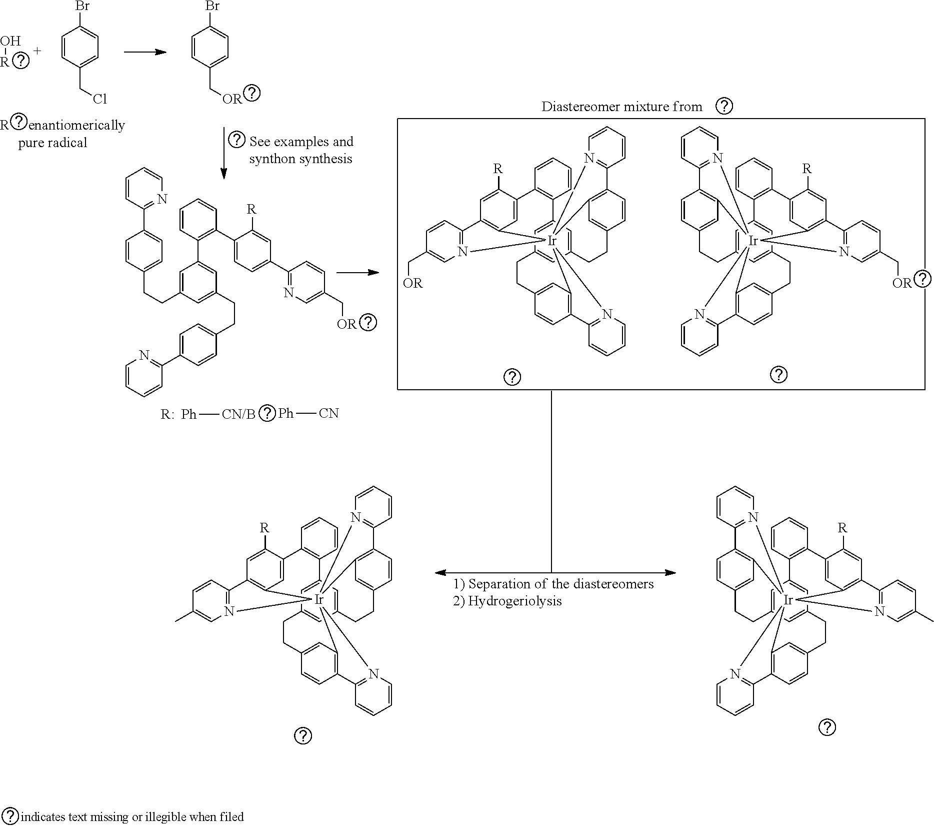

The compounds of the invention are preparable in principle by various processes. In general, for this purpose, an iridium salt is reacted with the corresponding free ligand.

Therefore, the present invention further provides a process for preparing the compounds of the invention by reacting the appropriate free ligands with iridium alkoxides of the formula (Ir-1), with iridium ketoketonates of the formula (Ir-2), with iridium halides of the formula (Ir-3) or with iridium carboxylates of the formula (Ir-4):

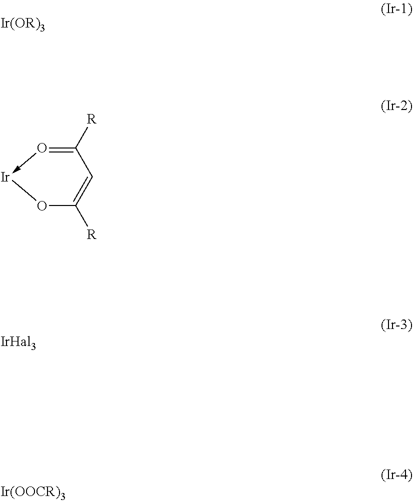

where R has the definitions given above, Hal=F, Cl, Br or I and the iridium reactants may also be in the form of the corresponding hydrates. R here is preferably an alkyl group having 1 to 4 carbon atoms.

It is likewise possible to use iridium compounds bearing both alkoxide and/or halide and/or hydroxyl and ketoketonate radicals. These compounds may also be charged. Corresponding iridium compounds of particular suitability as reactants are disclosed in WO 2004/085449. Particularly suitable are [IrCl₂(acac)₂]⁻, for example Na[IrCl₂(acac)₂], metal complexes with acetylacetonate derivatives as ligand, for example Ir(acac)₃ or tris(2,2,6,6-tetramethylheptane-3,5-dionato)iridium, and IrCl₃·xH₂O where x is typically a number from 2 to 4.

The synthesis of the complexes is preferably conducted as described in WO 2002/060910 and in WO 2004/085449. The synthesis is also particularly suitable in an organic acid or a mixture of an organic acid and an organic solvent, as described in as yet unpublished application EP19187468.4, and particularly suitable reaction media are, for example, acetic acid or a mixture of salicylic acid and an organic solvent, for example mesitylene. In this case, the synthesis can also be activated by thermal or photochemical means and/or by microwave radiation. In addition, the synthesis can also be conducted in an autoclave at elevated pressure and/or elevated temperature.

The reactions can be conducted without addition of solvents or melting aids in a melt of the corresponding ligands to be o-metalated. It is optionally also possible to add solvents or melting aids. Suitable solvents are protic or aprotic solvents such as aliphatic and/or aromatic alcohols (methanol, ethanol, isopropanol, t-butanol, etc.), oligo- and polyalcohols (ethylene glycol, propane-1,2-diol, glycerol, etc.), alcohol ethers (ethoxyethanol, diethylene glycol, triethylene glycol, polyethylene glycol, etc.), ethers (di- and triethylene glycol dimethyl ether, diphenyl ether, etc.), aromatic, heteroaromatic and/or aliphatic hydrocarbons (toluene, xylene, mesitylene, chlorobenzene, pyridine, lutidine, quinoline, isoquinoline, tridecane, hexadecane, etc.), amides (DMF, DMAC, etc.), lactams (NMP), sulfoxides (DMSO) or sulfones (dimethyl sulfone, sulfolane, etc.). Suitable melting aids are compounds that are in solid form at room temperature but melt when the reaction mixture is heated and dissolve the reactants, so as to form a homogeneous melt. Particularly suitable are biphenyl, m-terphenyl, triphenyls, R- or S-binaphthol or else the corresponding racemate, 1,2-, 1,3- or 1,4-bisphenoxybenzene, triphenylphosphine oxide, 18-crown-6, phenol, 1-naphthol, hydroquinone, etc. Particular preference is given here to the use of hydroquinone.

Alternatively, it is also possible first to synthesize the complex that bears a reactive leaving group, for example Cl, Br, I or a boronic acid derivative, in place of the cyanophenyl or cyanobiphenyl group, and in a next step to introduce the cyanophenyl or cyanobiphenyl group by a coupling reaction, for example a Suzuki coupling.

It is possible by these processes, if necessary followed by purification, for example recrystallization or sublimation, to obtain the inventive compounds of formula (1) in high purity, preferably more than 99% (determined by means of 1H NMR and/or HPLC).

For the processing of the iridium complexes of the invention from a liquid phase, for example by spin-coating or by printing methods, formulations of the iridium complexes of the invention are required. These formulations may, for example, be solutions, dispersions or emulsions. For this purpose, it may be preferable to use mixtures of two or more solvents. Suitable and preferred solvents are, for example, toluene, anisole, o-, m-or p-xylene, methyl benzoate, mesitylene, tetralin, veratrole, THF, methyl-THF, THP, chlorobenzene, dioxane, phenoxytoluene, especially 3-phenoxytoluene, (-)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, a-terpineol, benzothiazole, butyl benzoate, cumene, cyclohexanol, cyclohexanone, cyclohexylbenzene, decalin, dodecylbenzene, ethyl benzoate, indane, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane, hexamethylindane, methylbiphenyl, 3-methylbiphenyl, 1-methylnaphthalene, 1-ethylnaphthalene, ethyl octanoate, diethyl sebacate, octyl octanoate, heptylbenzene, menthyl isovalerate, cyclohexyl hexanoate or mixtures of these solvents.

The present invention therefore further provides a formulation comprising at least one compound of the invention and at least one further compound. The further compound may, for example, be a solvent, especially one of the abovementioned solvents or a mixture of these solvents. The further compound may alternatively be a further organic or inorganic compound which is likewise used in the electronic device, for example a matrix material. This further compound may also be polymeric.

The compound of the invention may be used in an electronic device as active component, preferably as emitter in the emissive layer of an organic electroluminescent device. The present invention thus further provides for the use of the compounds of the invention in an electronic device, especially in an organic electroluminescent device.

The present invention still further provides an electronic device comprising at least one compound of the invention, especially an organic electroluminescent device.

An electronic device is understood to mean any device comprising anode, cathode and at least one layer, said layer comprising at least one organic or organometallic compound. The electronic device of the invention thus comprises anode, cathode and at least one layer containing at least one iridium complex of the invention. Preferred electronic devices are selected from the group consisting of organic electroluminescent devices (OLEDs, PLEDs), organic integrated circuits (O-ICs), organic field-effect transistors (O-FETs), organic thin-film transistors (O-TFTs), organic light-emitting transistors (O-LETs), organic solar cells (O-SCs), the latter being understood to mean both purely organic solar cells and dye-sensitized solar cells, organic optical detectors, organic photoreceptors, organic field-quench devices (O-FQDs), light-emitting electrochemical cells (LECs), oxygen sensors and organic laser diodes (O-lasers), comprising at least one compound of the invention in at least one layer. Compounds that emit in the infrared are suitable for use in organic infrared electroluminescent devices and infrared sensors. Particular preference is given to organic electroluminescent devices. Active components are generally the organic or inorganic materials introduced between the anode and cathode, for example charge injection, charge transport or charge blocker materials, but especially emission materials and matrix materials. The compounds of the invention exhibit particularly good properties as emission material in organic electroluminescent devices. A preferred embodiment of the invention is therefore organic electroluminescent devices. In addition, the compounds of the invention can be used for production of singlet oxygen or in photocatalysis.

The organic electroluminescent device comprises cathode, anode and at least one emitting layer. Apart from these layers, it may comprise still further layers, for example in each case one or more hole injection layers, hole transport layers, hole blocker layers, electron transport layers, electron injection layers, exciton blocker layers, electron blocker layers, charge generation layers and/or organic or inorganic p/n junctions. In this case, it is possible that one or more hole transport layers are p-doped, for example with metal oxides such as MoO₃ or WO₃, or with (per)fluorinated electron-deficient aromatics or with electron-deficient cyano-substituted heteroaromatics (for example according to JP 4747558, JP 2006-135145, US 2006/0289882, WO 2012/095143), or with quinoid systems (for example according to EP1336208) or with Lewis acids, or with boranes (for example according to US 2003/0006411, WO 2002/051850, WO 2015/049030) or with carboxylates of the elements of main group 3, 4 or 5 (WO 2015/018539), and/or that one or more electron transport layers are n-doped.

It is likewise possible for interlayers to be introduced between two emitting layers, which have, for example, an exciton-blocking function and/or control charge balance in the electroluminescent device and/or generate charges (charge generation layer, for example in layer systems having two or more emitting layers, for example in white-emitting OLED components). However, it should be pointed out that not necessarily every one of these layers need be present.

In this case, it is possible for the organic electroluminescent device to contain an emitting layer, or for it to contain a plurality of emitting layers. If a plurality of emission layers are present, these preferably have several emission maxima between 380 nm and 750 nm overall, such that the overall result is white emission; in other words, various emitting compounds which may fluoresce or phosphoresce are used in the emitting layers. Especially preferred are three-layer systems where the three layers exhibit blue, green and orange or red emission (for the basic construction see, for example, WO 2005/011013), or systems having more than three emitting layers. The system may also be a hybrid system wherein one or more layers fluoresce and one or more other layers phosphoresce. A preferred embodiment is tandem OLEDs. White-emitting organic electroluminescent devices may be used for lighting applications or else with color filters for full-color displays.

In a preferred embodiment of the invention, the organic electroluminescent device comprises the compound of the invention as emitting compound in one or more emitting layers.

When the compound of the invention is used as emitting compound in an emitting layer, it is preferably used in combination with one or more matrix materials. The mixture of the compound of the invention and the matrix material contains between 0.1% and 99% by volume, preferably between 1% and 90% by volume, more preferably between 3% and 40% by volume and especially between 5% and 15% by volume of the compound of the invention, based on the overall mixture of emitter and matrix material. Correspondingly, the mixture contains between 99.9% and 1% by volume, preferably between 99% and 10% by volume, more preferably between 97% and 60% by volume and especially between 95% and 85% by volume of the matrix material, based on the overall mixture of emitter and matrix material.

The matrix material used may generally be any materials which are known for the purpose according to the prior art. The triplet level of the matrix material is preferably higher than the triplet level of the emitter.

Suitable matrix materials for the compounds of the invention are ketones, phosphine oxides, sulfoxides and sulfones, for example according to WO 2004/013080, WO 2004/093207, WO 2006/005627 or WO 2010/006680, triarylamines, carbazole derivatives, e.g. CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, biscarbazole derivatives, indolocarbazole derivatives, for example according to WO 2007/063754 or WO 2008/056746, indenocarbazole derivatives, for example according to WO 2010/136109 or WO 2011/000455, azacarbazoles, for example according to EP 1617710, EP 1617711, EP 1731584, JP 2005/347160, bipolar matrix materials, for example according to WO 2007/137725, silanes, for example according to WO 2005/111172, azaboroles or boronic esters, for example according to WO 2006/117052, diazasilole derivatives, for example according to WO 2010/054729, diazaphosphole derivatives, for example according to WO 2010/054730, triazine derivatives, for example according to WO 2010/015306, WO 2007/063754 or WO 2008/056746, zinc complexes, for example according to EP 652273 or WO 2009/062578, dibenzofuran derivatives, for example according to WO 2009/148015 or WO 2015/169412, or bridged carbazole derivatives, for example according to US 2009/0136779, WO 2010/050778, WO 2011/042107 or WO 2011/088877. Suitable matrix materials for solution-processed OLEDs are also polymers, for example according to WO 2012/008550 or WO 2012/048778, oligomers or dendrimers, for example according to Journal of Luminescence 183 (2017), 150-158.

It may also be preferable to use a plurality of different matrix materials as a mixture, especially at least one electron-conducting matrix material and at least one hole-conducting matrix material. A preferred combination is, for example, the use of an aromatic ketone, a triazine derivative, a pyrimidine derivative, a phosphine oxide derivative or an aromatic lactam with a triarylamine derivative or a carbazole derivative as mixed matrix for the compound of the invention. Preference is likewise given to the use of a mixture of a charge-transporting matrix material and an electrically inert matrix material (called a “wide bandgap host”) having no significant involvement, if any, in the charge transport, as described, for example, in

WO 2010/108579 or WO 2016/184540. Preference is likewise given to the use of two electron-transporting matrix materials, for example triazine derivatives and lactam derivatives, as described, for example, in WO 2014/094964.

Depicted below are examples of compounds that are suitable as matrix materials for the compounds of the invention.

Preferred biscarbazoles that can be used as matrix materials for the compounds of the invention are the structures of the following formulae (10) and (11):

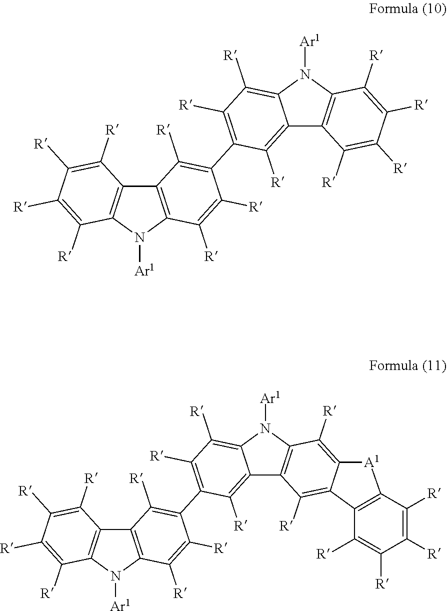

where the symbols used are as follows:
Ar¹ is the same or different at each instance and is an aromatic or heteroaromatic ring system having 5 to 40 aromatic ring atoms, preferably having 6 to 30 aromatic ring atoms, more preferably having 6 to 24 aromatic ring atoms, each of which may be substituted by one or more R′ radicals, preferably nonaromatic R′ radicals;
A¹ is NAr¹, C(R′)₂, O or S, preferably C(R′)₂,
R′ is the same or different at each instance and is H, D, F, CN, an alkyl group having 1 to 10 carbon atoms, preferably having 1 to 4 carbon atoms, or an aromatic or heteroaromatic ring system having 5 to 40 aromatic ring atoms, preferably having 6 to 30 aromatic ring atoms, more preferably having 6 to 24 aromatic ring atoms, which may be substituted by one or more substituents selected from the group consisting of D, F, CN or an alkyl group having 1 to 10 carbon atoms, preferably having 1 to 4 carbon atoms.

Preferred embodiments of the compounds of the formulae (10) and (11) are the compounds of the following formulae (10a) and (11a):

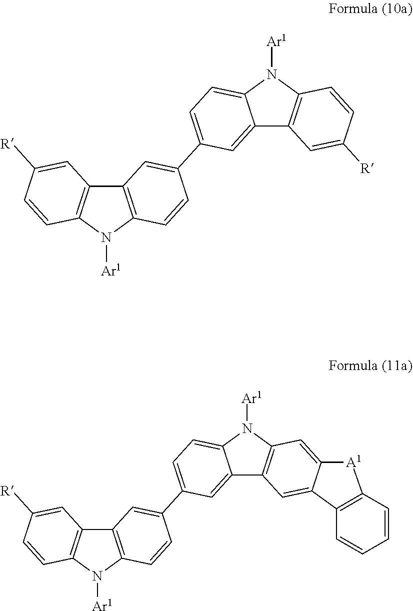

where the symbols used have the definitions given above.

Preferred dibenzofuran derivatives are the compounds of the following formula (12):

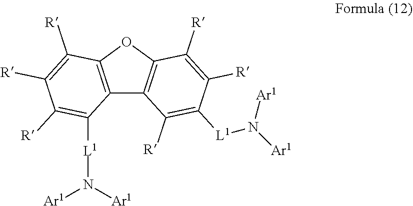

where the oxygen may also be replaced by sulfur so as to form a dibenzothiophene, L1 is a single bond or an aromatic or heteroaromatic ring system which has 5 to 30 aromatic ring atoms, preferably 6 to 24 aromatic ring atoms, and may also be substituted by one or more R′ radicals, but is preferably unsubstituted, and R′ and Ar¹ have the definitions given above. It is also possible here for the two Ar¹ groups that bind to the same nitrogen atom, or for one Ar¹ group and one L group that bind to the same nitrogen atom, to be bonded to one another, for example to give a carbazole.

Preferred carbazoleamines are the structures of the following formulae (13), (14) and (15):

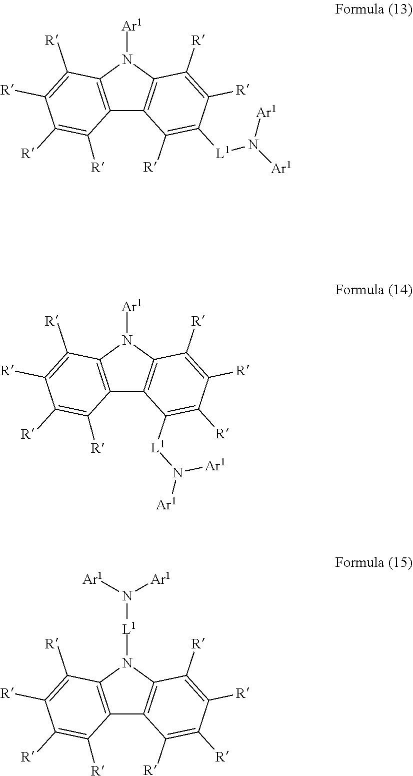

where L¹, R′ and Ar¹ have the definitions given above.

Examples of suitable hole-conducting matrix materials are the compounds depicted in the following table:

| | |
|---|---|
| 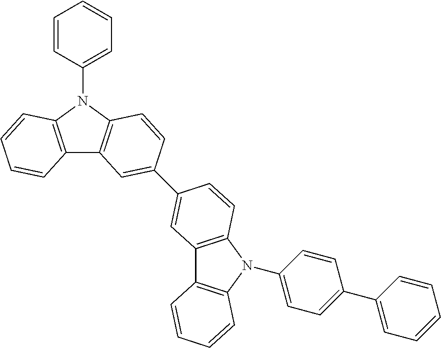 [SMILES: c1ccc(-c2ccc(-n3c4ccccc4c4cc(-c5ccc6c(c5)c5ccccc5n6-c5ccccc5)ccc43)cc2)cc1] | H1 |
| 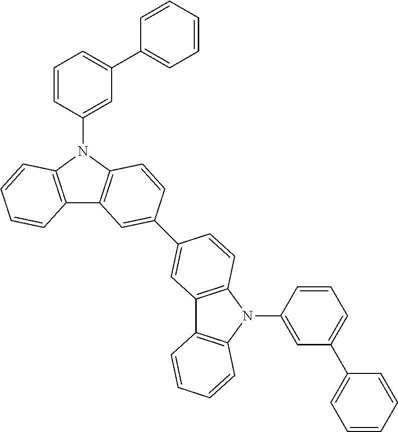 [SMILES: c1ccc(-c2cccc(-n3c4ccccc4c4cc(-c5ccc6c(c5)c5ccccc5n6-c5cccc(-c6ccccc6)c5)ccc43)c2)cc1] | H2 |
| 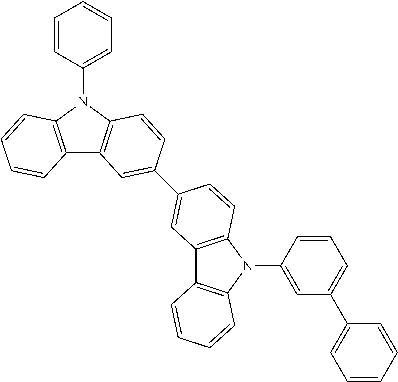 [SMILES: c1ccc(-c2cccc(-n3c4ccccc4c4cc(-c5ccc6c(c5)c5ccccc5n6-c5ccccc5)ccc43)c2)cc1] | H3 |
| 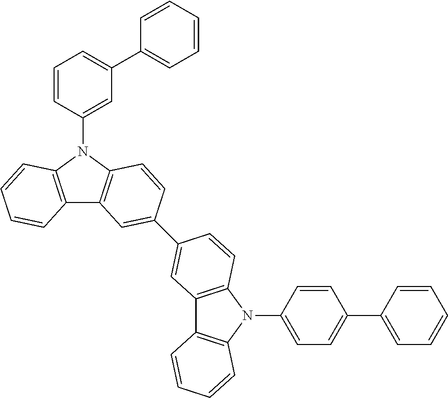 [SMILES: c1ccc(-c2ccc(-n3c4ccccc4c4cc(-c5ccc6c(c5)c5ccccc5n6-c5cccc(-c6ccccc6)c5)ccc43)cc2)cc1] | H4 |
| 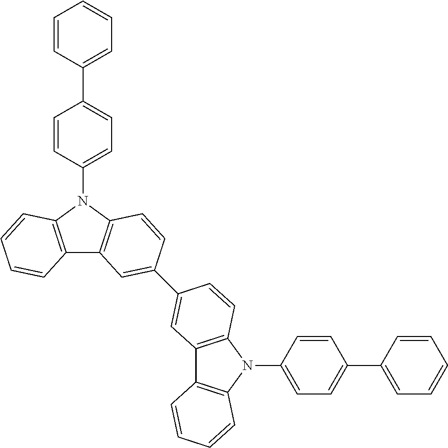 [SMILES: c1ccc(-c2ccc(-n3c4ccccc4c4cc(-c5ccc6c(c5)c5ccccc5n6-c5ccc(-c6ccccc6)cc5)ccc43)cc2)cc1] | H5 |
| 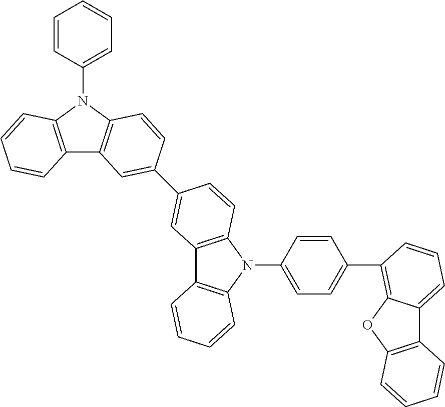 [SMILES: c1ccc(-n2c3ccccc3c3cc(-c4ccc5c(c4)c4ccccc4n5-c4ccc(-c5cccc6c5oc5ccccc56)cc4)ccc32)cc1] | H6 |
| 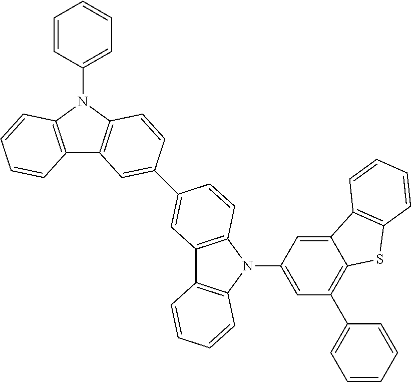 [SMILES: c1ccc(-c2cc(-n3c4ccccc4c4cc(-c5ccc6c(c5)c5ccccc5n6-c5ccccc5)ccc43)cc3c2sc2ccccc23)cc1] | H7 |
| 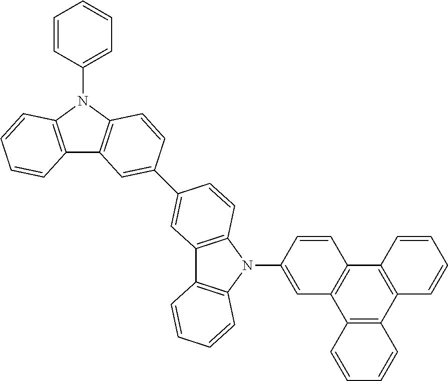 [SMILES: c1ccc(-n2c3ccccc3c3cc(-c4ccc5c(c4)c4ccccc4n5-c4ccc5c6ccccc6c6ccccc6c5c4)ccc32)cc1] | H8 |
| 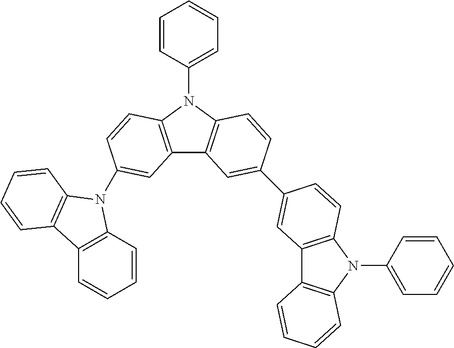 [SMILES: c1ccc(-n2c3ccccc3c3cc(-c4ccc5c(c4)c4cc(-n6c7ccccc7c7ccccc76)ccc4n5-c4ccccc4)ccc32)cc1] | H9 |
| 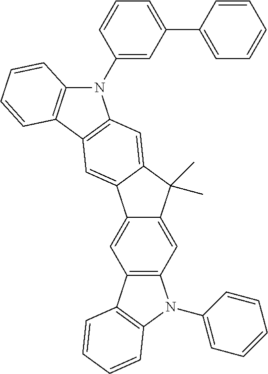 [SMILES: CC1(C)c2cc3c(cc2-c2cc4c5ccccc5n(-c5cccc(-c6ccccc6)c5)c4cc21)c1ccccc1n3-c1ccccc1] | H10 |
| 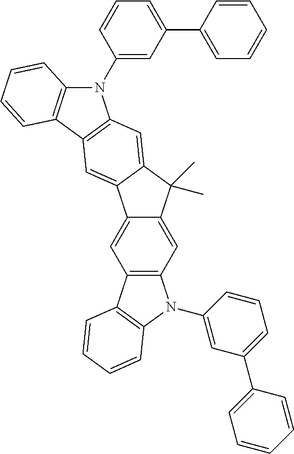 [SMILES: CC1(C)c2cc3c(cc2-c2cc4c5ccccc5n(-c5cccc(-c6ccccc6)c5)c4cc21)c1ccccc1n3-c1cccc(-c2ccccc2)c1] | H11 |
| 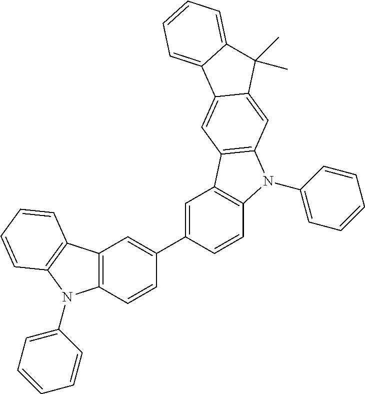 [SMILES: CC1(C)c2ccccc2-c2cc3c4cc(-c5ccc6c(c5)c5ccccc5n6-c5ccccc5)ccc4n(-c4ccccc4)c3cc21] | H12 |
| 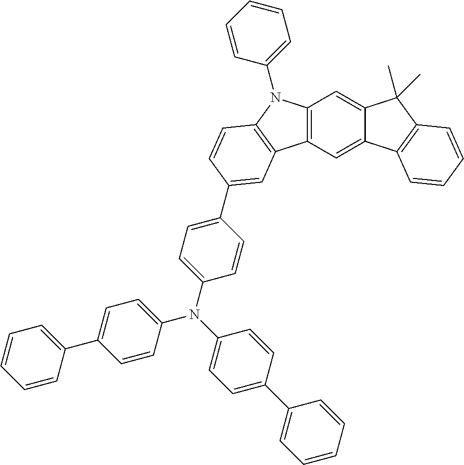 [SMILES: CC1(C)c2ccccc2-c2cc3c4cc(-c5ccc(N(c6ccc(-c7ccccc7)cc6)c6ccc(-c7ccccc7)cc6)cc5)ccc4n(-c4ccccc4)c3cc21] | H13 |
| 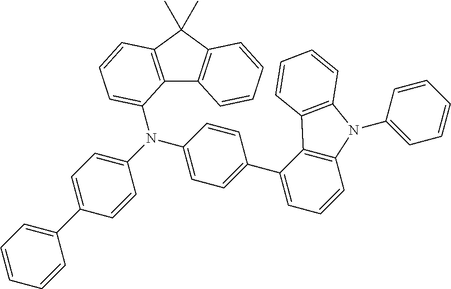 [SMILES: CC1(C)c2ccccc2-c2c(N(c3ccc(-c4ccccc4)cc3)c3ccc(-c4cccc5c4c4ccccc4n5-c4ccccc4)cc3)cccc21] | H14 |
| 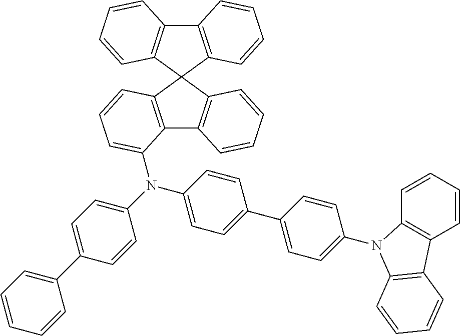 [SMILES: c1ccc(-c2ccc(N(c3ccc(-c4ccc(-n5c6ccccc6c6ccccc65)cc4)cc3)c3cccc4c3-c3ccccc3C43c4ccccc4-c4ccccc43)cc2)cc1] | H15 |
| 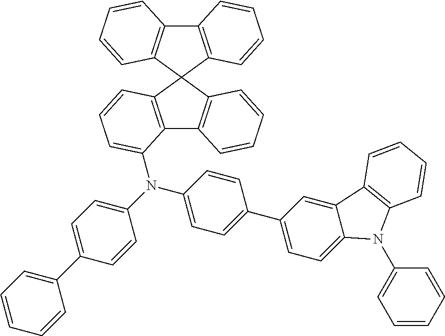 [SMILES: c1ccc(-c2ccc(N(c3ccc(-c4ccc5c(c4)c4ccccc4n5-c4ccccc4)cc3)c3cccc4c3-c3ccccc3C43c4ccccc4-c4ccccc43)cc2)cc1] | H16 |
| 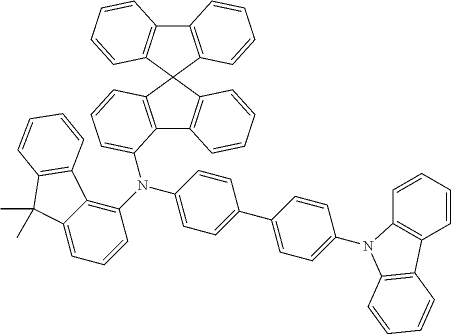 [SMILES: CC1(C)c2ccccc2-c2c(N(c3ccc(-c4ccc(-n5c6ccccc6c6ccccc65)cc4)cc3)c3cccc4c3-c3ccccc3C43c4ccccc4-c4ccccc43)cccc21] | H17 |
| 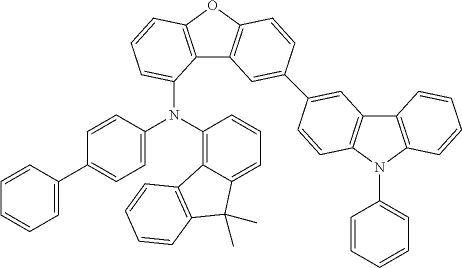 [SMILES: CC1(C)c2ccccc2-c2c(N(c3ccc(-c4ccccc4)cc3)c3cccc4oc5ccc(-c6ccc7c(c6)c6ccccc6n7-c6ccccc6)cc5c34)cccc21] | H18 |
| 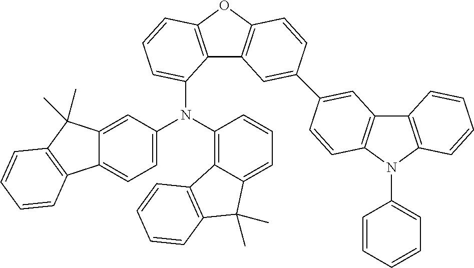 [SMILES: CC1(C)c2ccccc2-c2ccc(N(c3cccc4c3-c3ccccc3C4(C)C)c3cccc4oc5ccc(-c6ccc7c(c6)c6ccccc6n7-c6ccccc6)cc5c34)cc21] | H19 |
| 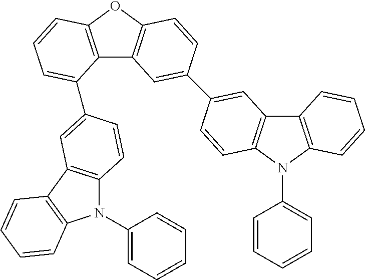 [SMILES: c1ccc(-n2c3ccccc3c3cc(-c4ccc5oc6cccc(-c7ccc8c(c7)c7ccccc7n8-c7ccccc7)c6c5c4)ccc32)cc1] | H20 |
| 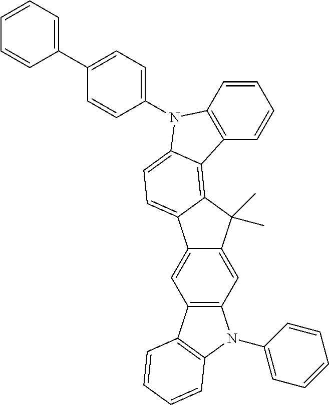 [SMILES: CC1(C)c2cc3c(cc2-c2ccc4c(c21)c1ccccc1n4-c1ccc(-c2ccccc2)cc1)c1ccccc1n3-c1ccccc1] | H21 |
| 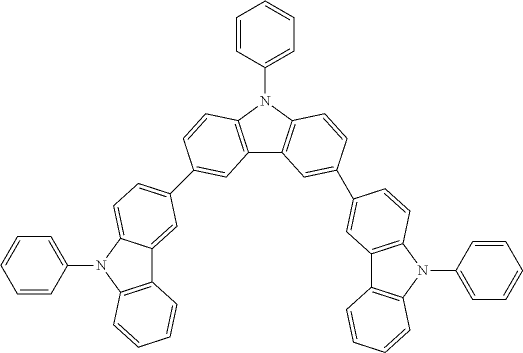 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1] | H22 |
| 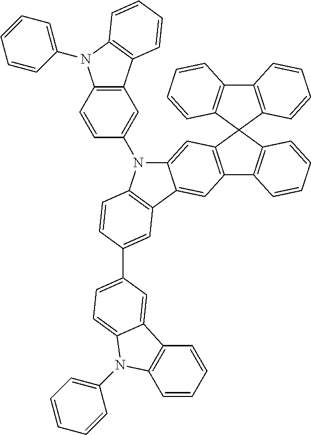 [SMILES: c1ccc(-n2c3ccccc3c3cc(-c4ccc5c(c4)c4cc6c(cc4n5-c4ccc5c(c4)c4ccccc4n5-c4ccccc4)C4(c5ccccc5-c5ccccc54)c4ccccc4-6)ccc32)cc1] | H23 |
| 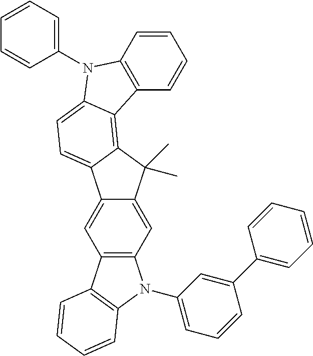 [SMILES: CC1(C)c2cc3c(cc2-c2ccc4c(c21)c1ccccc1n4-c1ccccc1)c1ccccc1n3-c1cccc(-c2ccccc2)c1] | H24 |
| 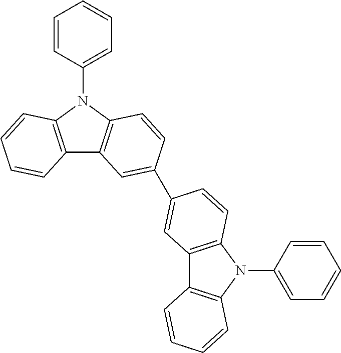 [SMILES: c1ccc(-n2c3ccccc3c3cc(-c4ccc5c(c4)c4ccccc4n5-c4ccccc4)ccc32)cc1] | H25 |
| 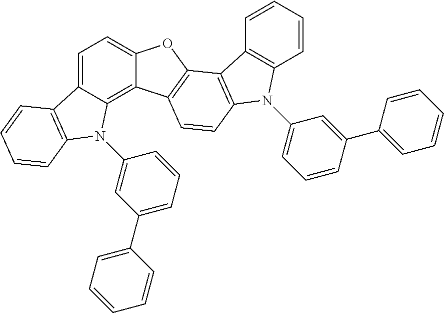 [SMILES: c1ccc(-c2cccc(-n3c4ccccc4c4c5oc6ccc7c8ccccc8n(-c8cccc(-c9ccccc9)c8)c7c6c5ccc43)c2)cc1] | H26 |
| 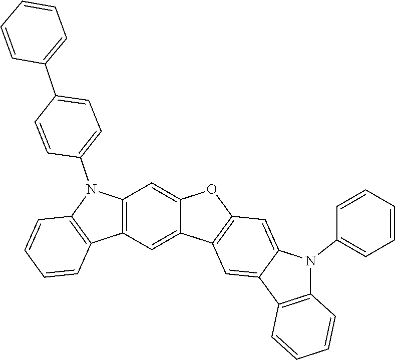 [SMILES: c1ccc(-c2ccc(-n3c4ccccc4c4cc5c(cc43)oc3cc4c(cc35)c3ccccc3n4-c3ccccc3)cc2)cc1] | H27 |
| 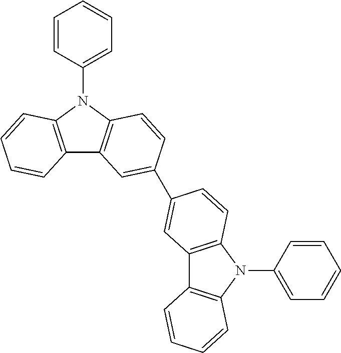 [SMILES: c1ccc(-n2c3ccccc3c3cc(-c4ccc5c(c4)c4ccccc4n5-c4ccccc4)ccc32)cc1] | H28 |
| 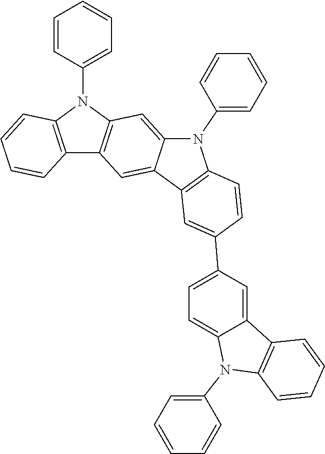 [SMILES: c1ccc(-n2c3ccccc3c3cc(-c4ccc5c(c4)c4cc6c7ccccc7n(-c7ccccc7)c6cc4n5-c4ccccc4)ccc32)cc1] | H29 |
| 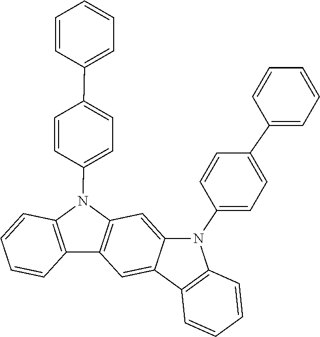 [SMILES: c1ccc(-c2ccc(-n3c4ccccc4c4cc5c6ccccc6n(-c6ccc(-c7ccccc7)cc6)c5cc43)cc2)cc1] | H30 |
| 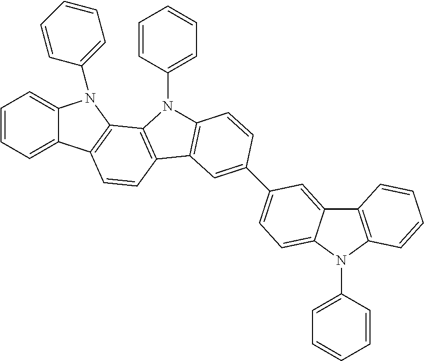 [SMILES: c1ccc(-n2c3ccccc3c3cc(-c4ccc5c(c4)c4ccc6c7ccccc7n(-c7ccccc7)c6c4n5-c4ccccc4)ccc32)cc1] | H31 |
| 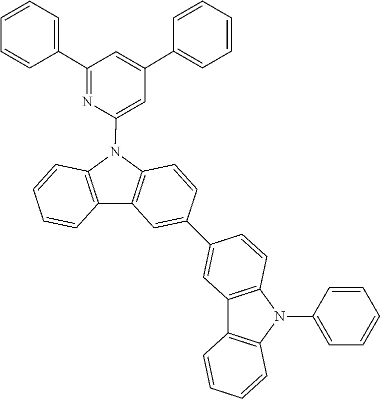 [SMILES: c1ccc(-c2cc(-c3ccccc3)nc(-n3c4ccccc4c4cc(-c5ccc6c(c5)c5ccccc5n6-c5ccccc5)ccc43)c2)cc1] | H32 |
| 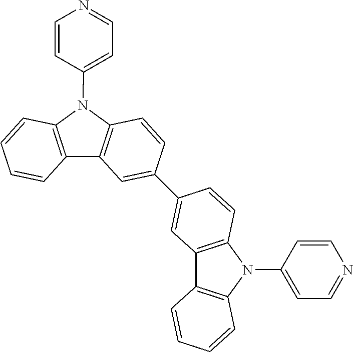 [SMILES: c1ccc2c(c1)c1cc(-c3ccc4c(c3)c3ccccc3n4-c3ccncc3)ccc1n2-c1ccncc1] | H33 |
| 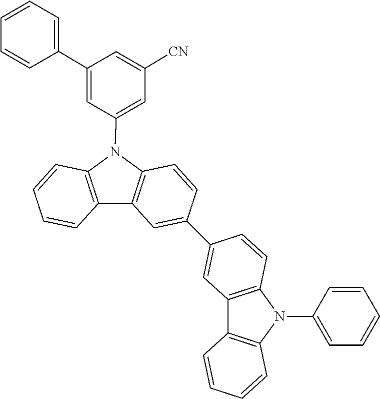 [SMILES: N#Cc1cc(-c2ccccc2)cc(-n2c3ccccc3c3cc(-c4ccc5c(c4)c4ccccc4n5-c4ccccc4)ccc32)c1] | H34 |
| 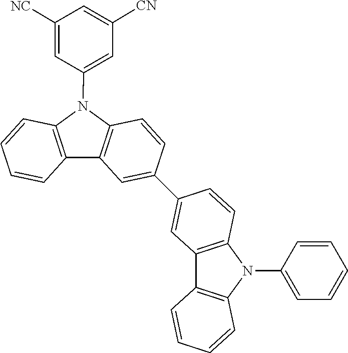 [SMILES: N#Cc1cc(C#N)cc(-n2c3ccccc3c3cc(-c4ccc5c(c4)c4ccccc4n5-c4ccccc4)ccc32)c1] | H35 |
| 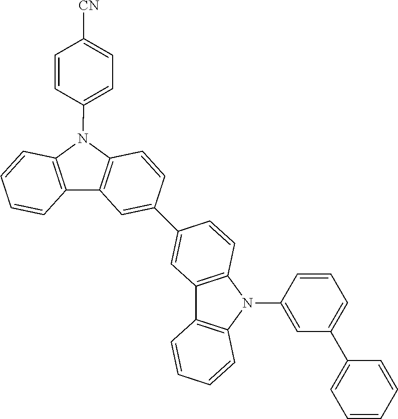 [SMILES: N#Cc1ccc(-n2c3ccccc3c3cc(-c4ccc5c(c4)c4ccccc4n5-c4cccc(-c5ccccc5)c4)ccc32)cc1] | H36 |
| 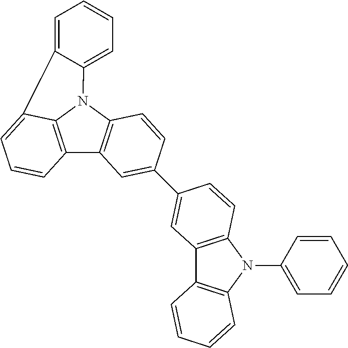 [SMILES: c1ccc(-n2c3ccccc3c3cc(-c4ccc5c(c4)c4cccc6c7ccccc7n5c64)ccc32)cc1] | H37 |
| 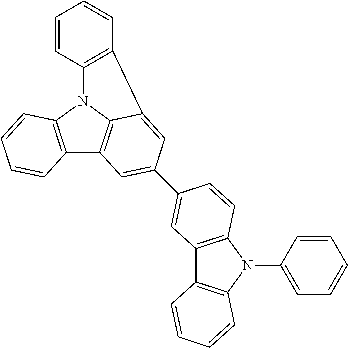 [SMILES: c1ccc(-n2c3ccccc3c3cc(-c4cc5c6ccccc6n6c7ccccc7c(c4)c56)ccc32)cc1] | H38 |
| 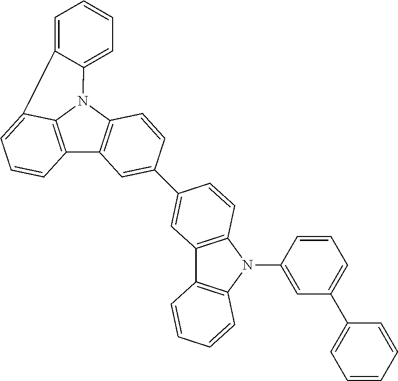 [SMILES: c1ccc(-c2cccc(-n3c4ccccc4c4cc(-c5ccc6c(c5)c5cccc7c8ccccc8n6c75)ccc43)c2)cc1] | H39 |
| 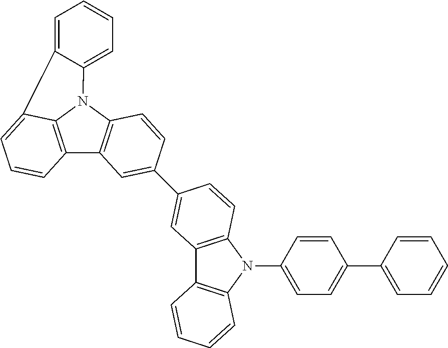 [SMILES: c1ccc(-c2ccc(-n3c4ccccc4c4cc(-c5ccc6c(c5)c5cccc7c8ccccc8n6c75)ccc43)cc2)cc1] | H40 |
| 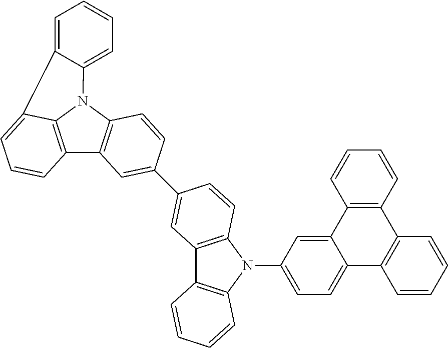 [SMILES: c1ccc2c(c1)c1ccccc1c1cc(-n3c4ccccc4c4cc(-c5ccc6c(c5)c5cccc7c8ccccc8n6c75)ccc43)ccc21] | H41 |
| 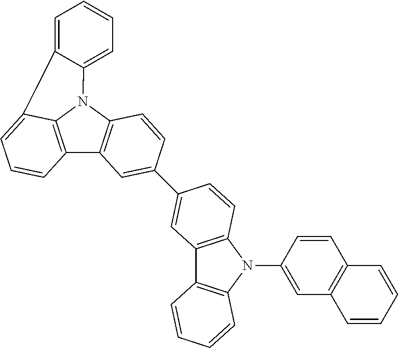 [SMILES: c1ccc2cc(-n3c4ccccc4c4cc(-c5ccc6c(c5)c5cccc7c8ccccc8n6c75)ccc43)ccc2c1] | H42 |
| 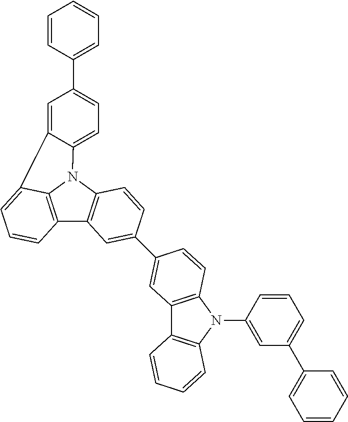 [SMILES: c1ccc(-c2cccc(-n3c4ccccc4c4cc(-c5ccc6c(c5)c5cccc7c8cc(-c9ccccc9)ccc8n6c75)ccc43)c2)cc1] | H43 |
| 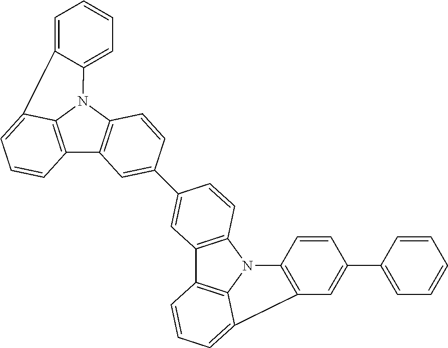 [SMILES: c1ccc(-c2ccc3c(c2)c2cccc4c5cc(-c6ccc7c(c6)c6cccc8c9ccccc9n7c86)ccc5n3c24)cc1] | H44 |
| 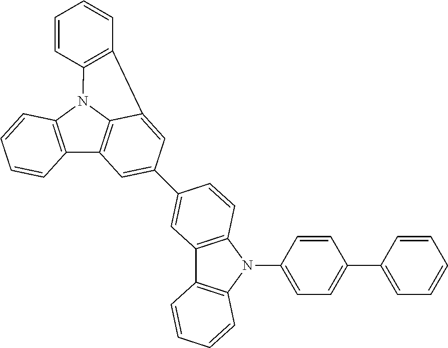 [SMILES: c1ccc(-c2ccc(-n3c4ccccc4c4cc(-c5cc6c7ccccc7n7c8ccccc8c(c5)c67)ccc43)cc2)cc1] | H45 |
| 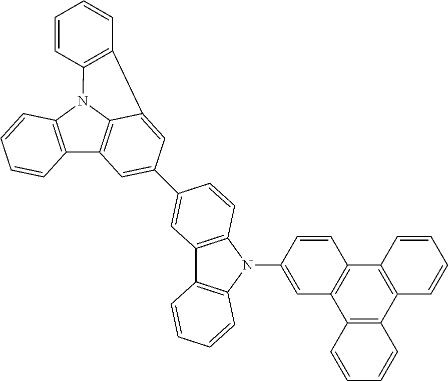 [SMILES: c1ccc2c(c1)c1ccccc1c1cc(-n3c4ccccc4c4cc(-c5cc6c7ccccc7n7c8ccccc8c(c5)c67)ccc43)ccc21] | H46 |
| 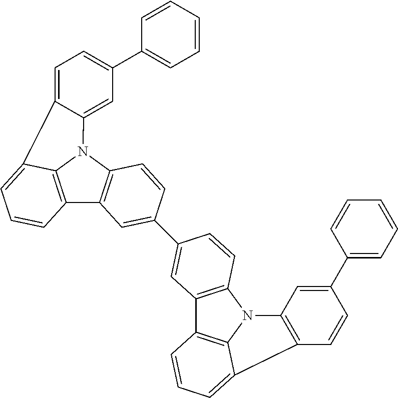 [SMILES: c1ccc(-c2ccc3c4cccc5c6cc(-c7ccc8c(c7)c7cccc9c%10ccc(-c%11ccccc%11)cc%10n8c79)ccc6n(c3c2)c54)cc1] | H47 |
| 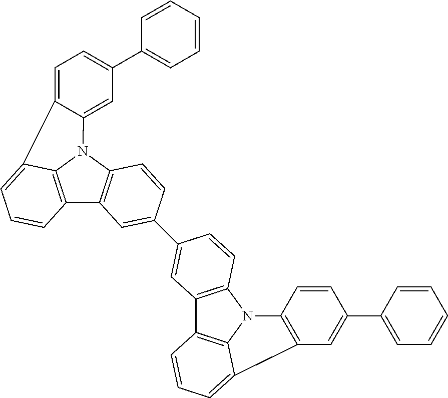 [SMILES: c1ccc(-c2ccc3c(c2)c2cccc4c5cc(-c6ccc7c(c6)c6cccc8c9ccc(-c%10ccccc%10)cc9n7c68)ccc5n3c24)cc1] | H48 |
| 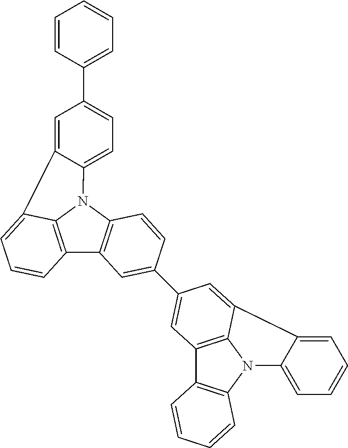 [SMILES: c1ccc(-c2ccc3c(c2)c2cccc4c5cc(-c6cc7c8ccccc8n8c9ccccc9c(c6)c78)ccc5n3c24)cc1] | H49 |
| 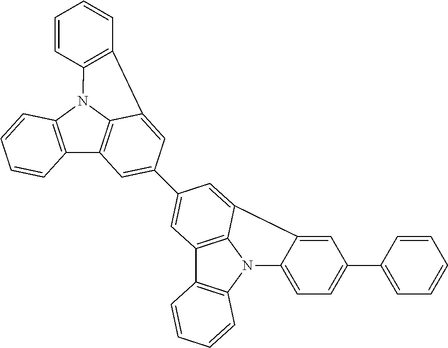 [SMILES: c1ccc(-c2ccc3c(c2)c2cc(-c4cc5c6ccccc6n6c7ccccc7c(c4)c56)cc4c5ccccc5n3c42)cc1] | H50 |
| 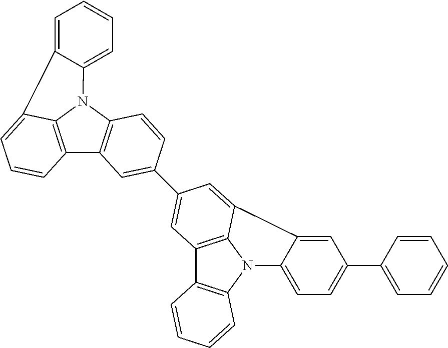 [SMILES: c1ccc(-c2ccc3c(c2)c2cc(-c4ccc5c(c4)c4cccc6c7ccccc7n5c64)cc4c5ccccc5n3c42)cc1] | H51 |
| 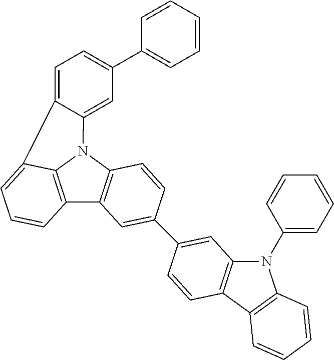 [SMILES: c1ccc(-c2ccc3c4cccc5c6cc(-c7ccc8c9ccccc9n(-c9ccccc9)c8c7)ccc6n(c3c2)c54)cc1] | H52 |
| 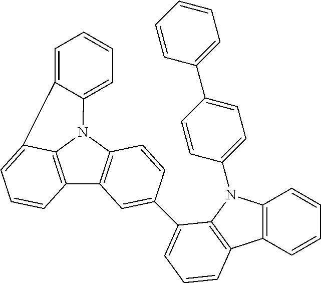 [SMILES: c1ccc(-c2ccc(-n3c4ccccc4c4cccc(-c5ccc6c(c5)c5cccc7c8ccccc8n6c75)c43)cc2)cc1] | H53 |
| 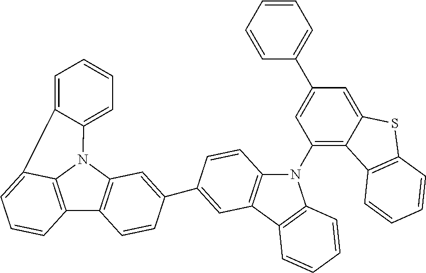 [SMILES: c1ccc(-c2cc(-n3c4ccccc4c4cc(-c5ccc6c7cccc8c9ccccc9n(c6c5)c87)ccc43)c3c(c2)sc2ccccc23)cc1] | H54 |
| 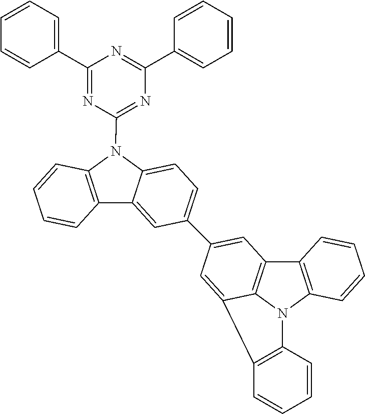 [SMILES: c1ccc(-c2nc(-c3ccccc3)nc(-n3c4ccccc4c4cc(-c5cc6c7ccccc7n7c8ccccc8c(c5)c67)ccc43)n2)cc1] | H55 |
| 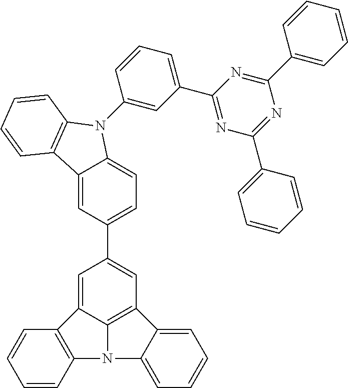 [SMILES: c1ccc(-c2nc(-c3ccccc3)nc(-c3cccc(-n4c5ccccc5c5cc(-c6cc7c8ccccc8n8c9ccccc9c(c6)c78)ccc54)c3)n2)cc1] | H56 |
| 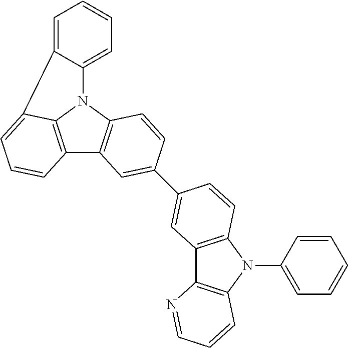 [SMILES: c1ccc(-n2c3ccc(-c4ccc5c(c4)c4cccc6c7ccccc7n5c64)cc3c3ncccc32)cc1] | H57 |

Preferred triazine or pyrimidine derivatives that can be used as a mixture together with the compounds of the invention are the compounds of the following formulae (16) and (17):

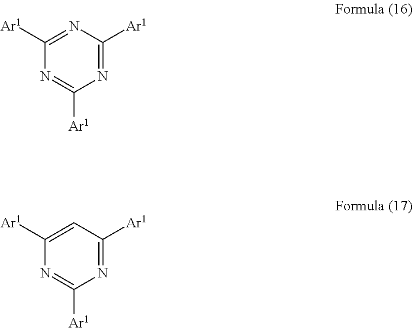

where Ar¹ has the definitions given above.

Particular preference is given to the triazine derivatives of the formula (16).

In a preferred embodiment of the invention, Ar¹ in the formulae (16) and (17) is the same or different at each instance and is an aromatic or heteroaromatic ring system which has 6 to 30 aromatic ring atoms, especially 6 to 24 aromatic ring atoms, and may be substituted by one or more R′ radicals.

Examples of suitable electron-transporting compounds that may be used as matrix materials together with the compounds of the invention are the compounds depicted in the following table:

| | |
|---|---|
| 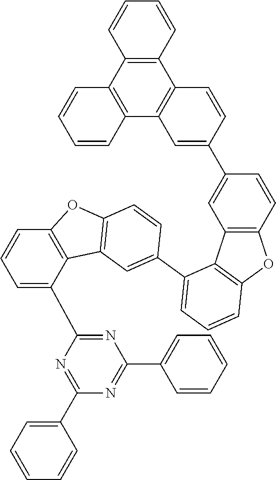 [SMILES: c1ccc(-c2nc(-c3ccccc3)nc(-c3cccc4oc5ccc(-c6cccc7oc8ccc(-c9ccc%10c%11ccccc%11c%11ccccc%11c%10c9)cc8c67)cc5c34)n2)cc1] | E1 |
| 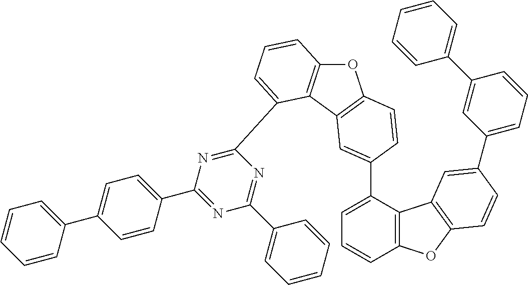 [SMILES: c1ccc(-c2ccc(-c3nc(-c4ccccc4)nc(-c4cccc5oc6ccc(-c7cccc8oc9ccc(-c%10cccc(-c%11ccccc%11)c%10)cc9c78)cc6c45)n3)cc2)cc1] | E2 |
| 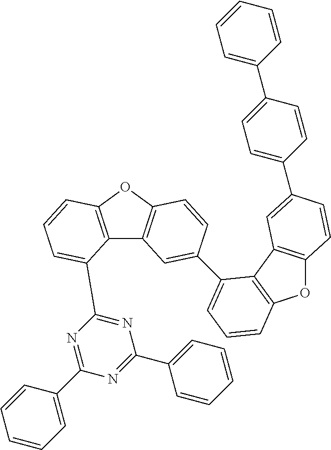 [SMILES: c1ccc(-c2ccc(-c3ccc4oc5cccc(-c6ccc7oc8cccc(-c9nc(-c%10ccccc%10)nc(-c%10ccccc%10)n9)c8c7c6)c5c4c3)cc2)cc1] | E3 |
| 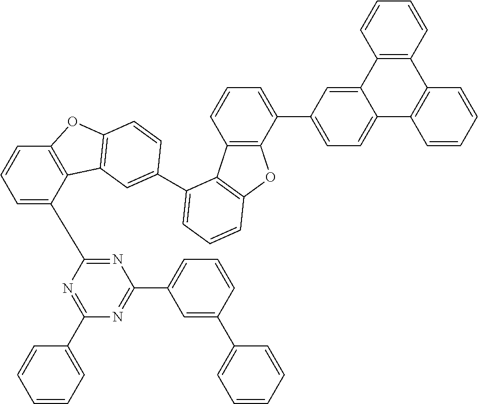 [SMILES: c1ccc(-c2cccc(-c3nc(-c4ccccc4)nc(-c4cccc5oc6ccc(-c7cccc8oc9c(-c%10ccc%11c%12ccccc%12c%12ccccc%12c%11c%10)cccc9c78)cc6c45)n3)c2)cc1] | E4 |
| 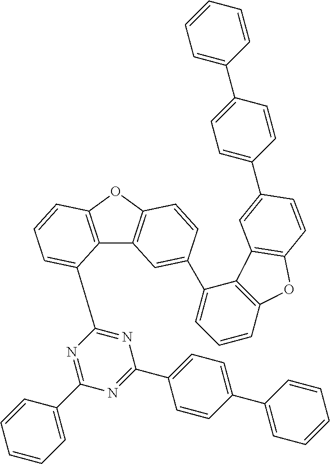 [SMILES: c1ccc(-c2ccc(-c3ccc4oc5cccc(-c6ccc7oc8cccc(-c9nc(-c%10ccccc%10)nc(-c%10ccc(-c%11ccccc%11)cc%10)n9)c8c7c6)c5c4c3)cc2)cc1] | E5 |
| 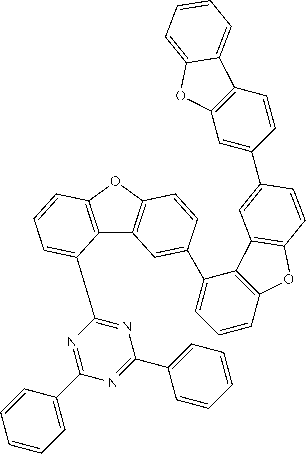 [SMILES: c1ccc(-c2nc(-c3ccccc3)nc(-c3cccc4oc5ccc(-c6cccc7oc8ccc(-c9ccc%10c(c9)oc9ccccc9%10)cc8c67)cc5c34)n2)cc1] | E6 |
| 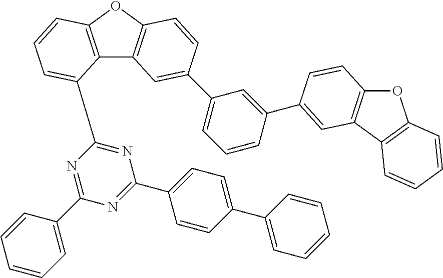 [SMILES: c1ccc(-c2ccc(-c3nc(-c4ccccc4)nc(-c4cccc5oc6ccc(-c7cccc(-c8ccc9oc%10ccccc%10c9c8)c7)cc6c45)n3)cc2)cc1] | E7 |
| 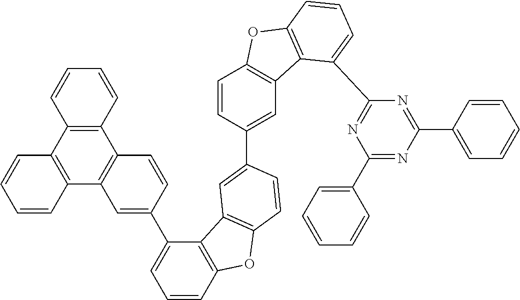 [SMILES: c1ccc(-c2nc(-c3ccccc3)nc(-c3cccc4oc5ccc(-c6ccc7oc8cccc(-c9ccc%10c%11ccccc%11c%11ccccc%11c%10c9)c8c7c6)cc5c34)n2)cc1] | E8 |
| 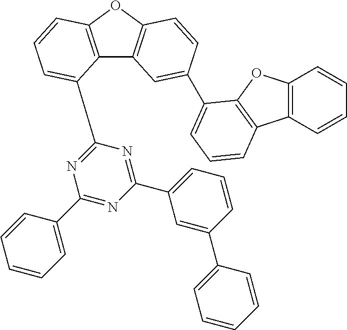 [SMILES: c1ccc(-c2cccc(-c3nc(-c4ccccc4)nc(-c4cccc5oc6ccc(-c7cccc8c7oc7ccccc78)cc6c45)n3)c2)cc1] | E9 |
| 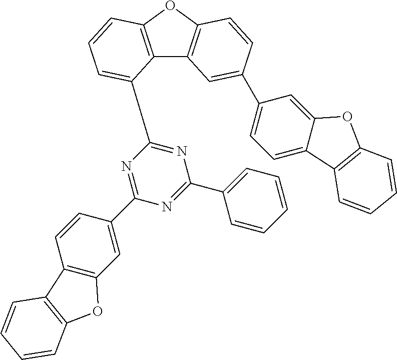 [SMILES: c1ccc(-c2nc(-c3ccc4c(c3)oc3ccccc34)nc(-c3cccc4oc5ccc(-c6ccc7c(c6)oc6ccccc67)cc5c34)n2)cc1] | E10 |
| 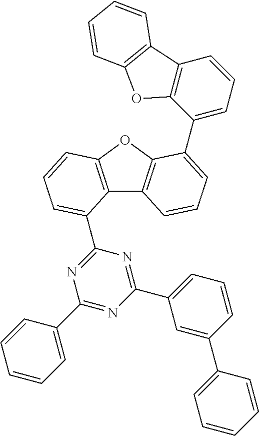 [SMILES: c1ccc(-c2cccc(-c3nc(-c4ccccc4)nc(-c4cccc5oc6c(-c7cccc8c7oc7ccccc78)cccc6c45)n3)c2)cc1] | E11 |
| 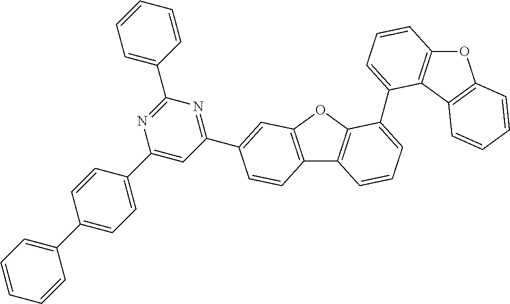 [SMILES: c1ccc(-c2ccc(-c3cc(-c4ccc5c(c4)oc4c(-c6cccc7oc8ccccc8c67)cccc45)nc(-c4ccccc4)n3)cc2)cc1] | E12 |
| 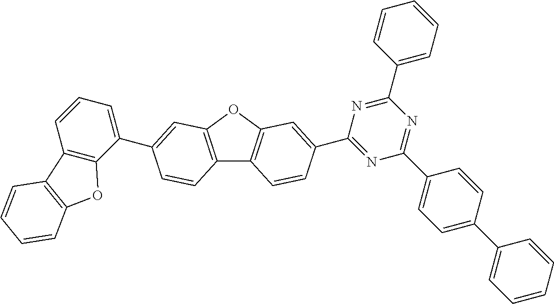 [SMILES: c1ccc(-c2ccc(-c3nc(-c4ccccc4)nc(-c4ccc5c(c4)oc4cc(-c6cccc7c6oc6ccccc67)ccc45)n3)cc2)cc1] | E13 |
| 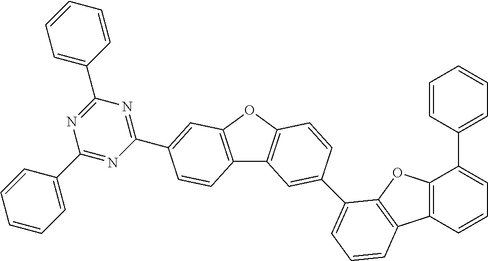 [SMILES: c1ccc(-c2nc(-c3ccccc3)nc(-c3ccc4c(c3)oc3ccc(-c5cccc6c5oc5c(-c7ccccc7)cccc56)cc34)n2)cc1] | E14 |
| 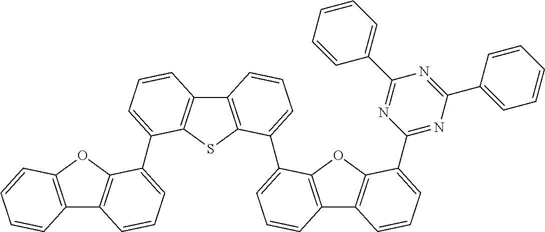 [SMILES: c1ccc(-c2nc(-c3ccccc3)nc(-c3cccc4c3oc3c(-c5cccc6c5sc5c(-c7cccc8c7oc7ccccc78)cccc56)cccc34)n2)cc1] | E15 |
| 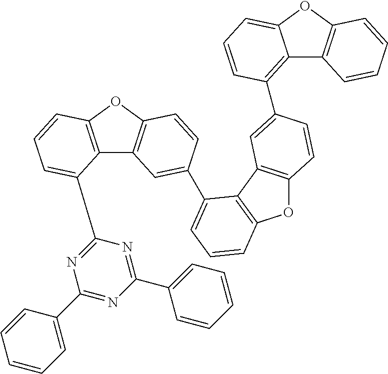 [SMILES: c1ccc(-c2nc(-c3ccccc3)nc(-c3cccc4oc5ccc(-c6cccc7oc8ccc(-c9cccc%10oc%11ccccc%11c9%10)cc8c67)cc5c34)n2)cc1] | E16 |
| 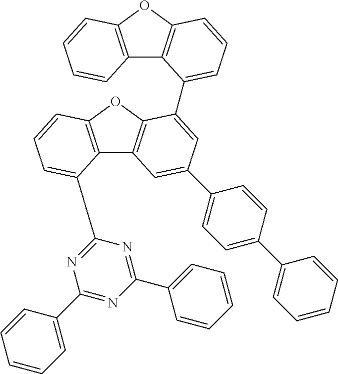 [SMILES: c1ccc(-c2ccc(-c3cc(-c4cccc5oc6ccccc6c45)c4oc5cccc(-c6nc(-c7ccccc7)nc(-c7ccccc7)n6)c5c4c3)cc2)cc1] | E17 |
| 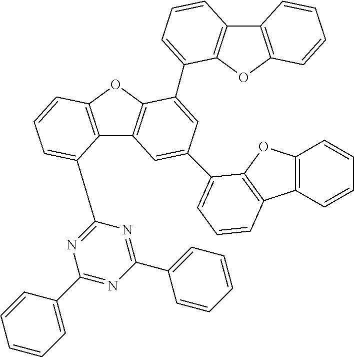 [SMILES: c1ccc(-c2nc(-c3ccccc3)nc(-c3cccc4oc5c(-c6cccc7c6oc6ccccc67)cc(-c6cccc7c6oc6ccccc67)cc5c34)n2)cc1] | E18 |
| 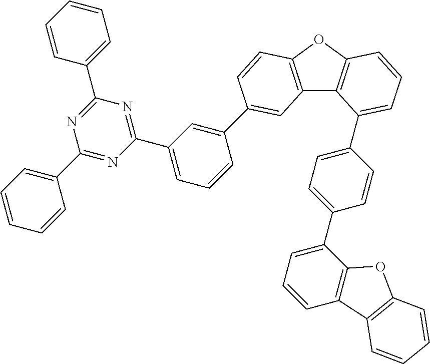 [SMILES: c1ccc(-c2nc(-c3ccccc3)nc(-c3cccc(-c4ccc5oc6cccc(-c7ccc(-c8cccc9c8oc8ccccc89)cc7)c6c5c4)c3)n2)cc1] | E19 |
| 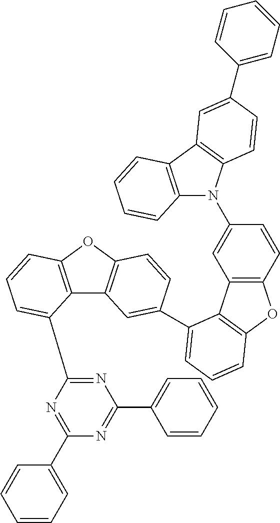 [SMILES: c1ccc(-c2ccc3c(c2)c2ccccc2n3-c2ccc3oc4cccc(-c5ccc6oc7cccc(-c8nc(-c9ccccc9)nc(-c9ccccc9)n8)c7c6c5)c4c3c2)cc1] | E20 |
| 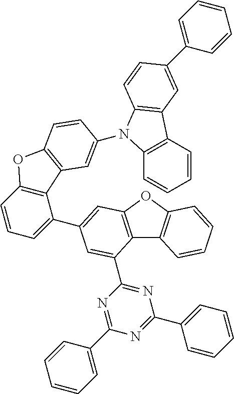 [SMILES: c1ccc(-c2ccc3c(c2)c2ccccc2n3-c2ccc3oc4cccc(-c5cc(-c6nc(-c7ccccc7)nc(-c7ccccc7)n6)c6c(c5)oc5ccccc56)c4c3c2)cc1] | E21 |
| 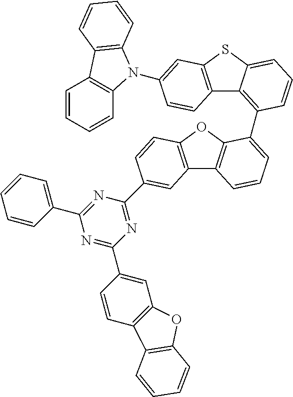 [SMILES: c1ccc(-c2nc(-c3ccc4c(c3)oc3ccccc34)nc(-c3ccc4oc5c(-c6cccc7sc8cc(-n9c%10ccccc%10c%10ccccc%109)ccc8c67)cccc5c4c3)n2)cc1] | E22 |
| 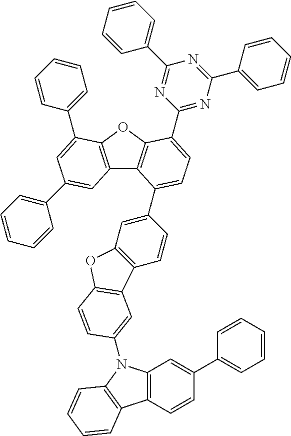 [SMILES: c1ccc(-c2cc(-c3ccccc3)c3oc4c(-c5nc(-c6ccccc6)nc(-c6ccccc6)n5)ccc(-c5ccc6c(c5)oc5ccc(-n7c8ccccc8c8ccc(-c9ccccc9)cc87)cc56)c4c3c2)cc1] | E23 |
| 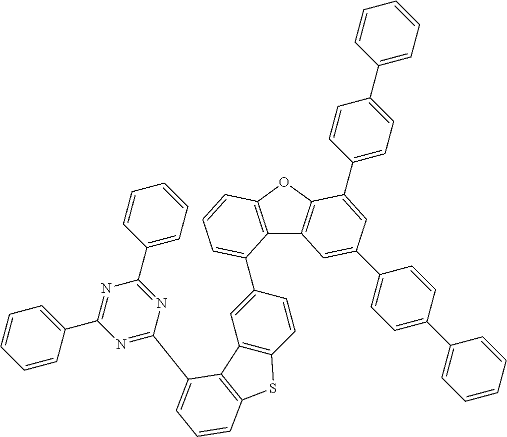 [SMILES: c1ccc(-c2ccc(-c3cc(-c4ccc(-c5ccccc5)cc4)c4oc5cccc(-c6ccc7sc8cccc(-c9nc(-c%10ccccc%10)nc(-c%10ccccc%10)n9)c8c7c6)c5c4c3)cc2)cc1] | E24 |
| 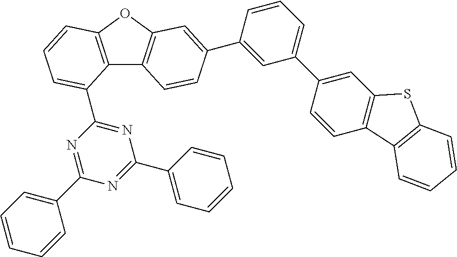 [SMILES: c1ccc(-c2nc(-c3ccccc3)nc(-c3cccc4oc5cc(-c6cccc(-c7ccc8c(c7)sc7ccccc78)c6)ccc5c34)n2)cc1] | E25 |
| 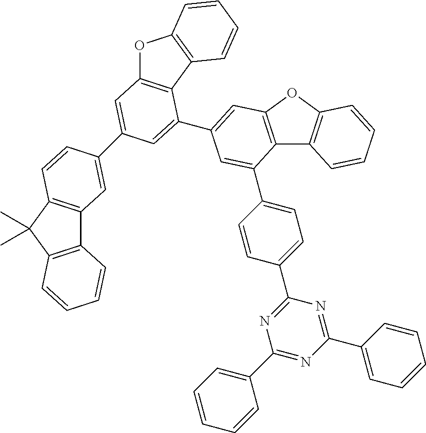 [SMILES: CC1(C)c2ccccc2-c2cc(-c3cc(-c4cc(-c5ccc(-c6nc(-c7ccccc7)nc(-c7ccccc7)n6)cc5)c5c(c4)oc4ccccc45)c4c(c3)oc3ccccc34)ccc21] | E26 |
| 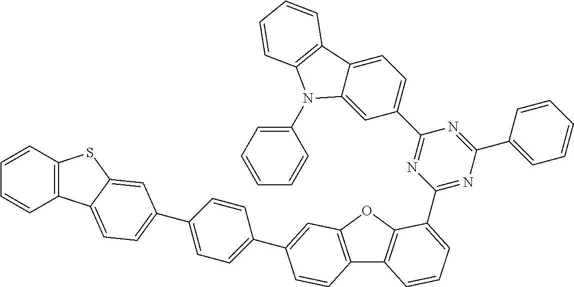 [SMILES: c1ccc(-c2nc(-c3ccc4c5ccccc5n(-c5ccccc5)c4c3)nc(-c3cccc4c3oc3cc(-c5ccc(-c6ccc7c(c6)sc6ccccc67)cc5)ccc34)n2)cc1] | E27 |
| 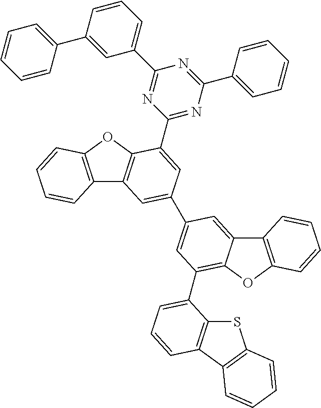 [SMILES: c1ccc(-c2cccc(-c3nc(-c4ccccc4)nc(-c4cc(-c5cc(-c6cccc7c6sc6ccccc67)c6oc7ccccc7c6c5)cc5c4oc4ccccc45)n3)c2)cc1] | E28 |
| 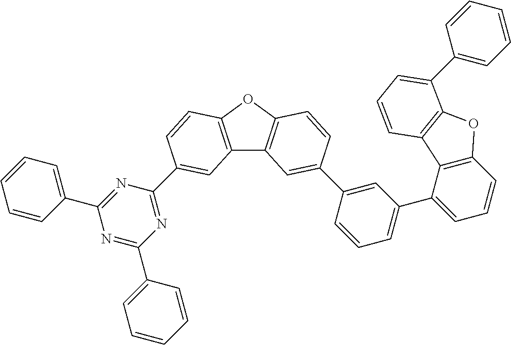 [SMILES: c1ccc(-c2nc(-c3ccccc3)nc(-c3ccc4oc5ccc(-c6cccc(-c7cccc8oc9c(-c%10ccccc%10)cccc9c78)c6)cc5c4c3)n2)cc1] | E29 |
| 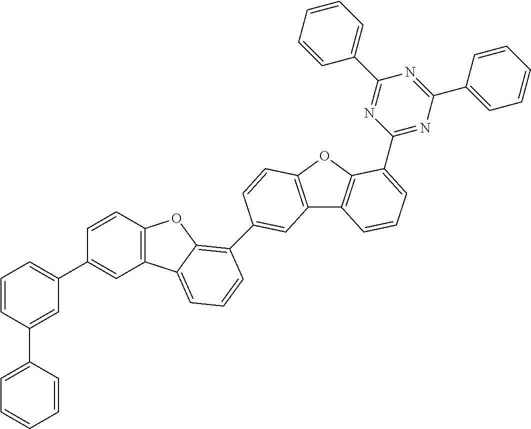 [SMILES: c1ccc(-c2cccc(-c3ccc4oc5c(-c6ccc7oc8c(-c9nc(-c%10ccccc%10)nc(-c%10ccccc%10)n9)cccc8c7c6)cccc5c4c3)c2)cc1] | E30 |
| 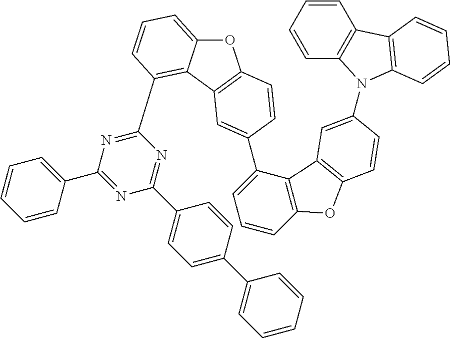 [SMILES: c1ccc(-c2ccc(-c3nc(-c4ccccc4)nc(-c4cccc5oc6ccc(-c7cccc8oc9ccc(-n%10c%11ccccc%11c%11ccccc%11%10)cc9c78)cc6c45)n3)cc2)cc1] | E31 |
| 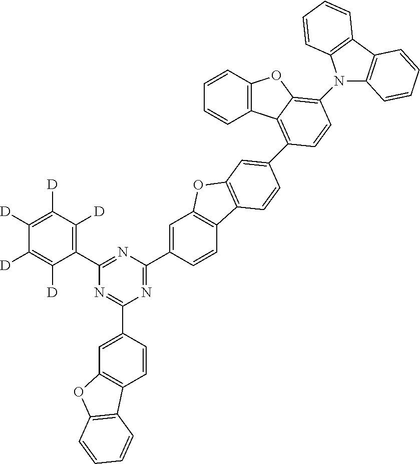 [SMILES: [2H]c1c([2H])c([2H])c(-c2nc(-c3ccc4c(c3)oc3ccccc34)nc(-c3ccc4c(c3)oc3cc(-c5ccc(-n6c7ccccc7c7ccccc76)c6oc7ccccc7c56)ccc34)n2)c([2H])c1[2H]] | E32 |
| 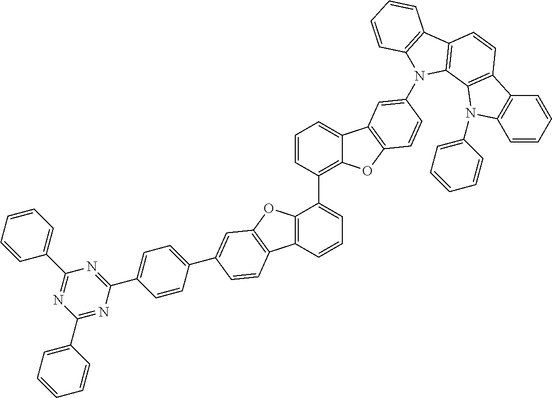 [SMILES: c1ccc(-c2nc(-c3ccccc3)nc(-c3ccc(-c4ccc5c(c4)oc4c(-c6cccc7c6oc6ccc(-n8c9ccccc9c9ccc%10c%11ccccc%11n(-c%11ccccc%11)c%10c98)cc67)cccc45)cc3)n2)cc1] | E33 |
| 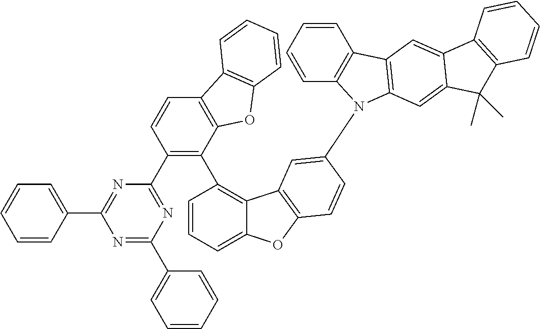 [SMILES: CC1(C)c2ccccc2-c2cc3c4ccccc4n(-c4ccc5oc6cccc(-c7c(-c8nc(-c9ccccc9)nc(-c9ccccc9)n8)ccc8c7oc7ccccc78)c6c5c4)c3cc21] | E34 |
| 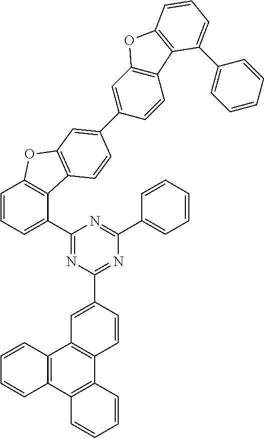 [SMILES: c1ccc(-c2nc(-c3ccc4c5ccccc5c5ccccc5c4c3)nc(-c3cccc4oc5cc(-c6ccc7c(c6)oc6cccc(-c8ccccc8)c67)ccc5c34)n2)cc1] | E35 |
| 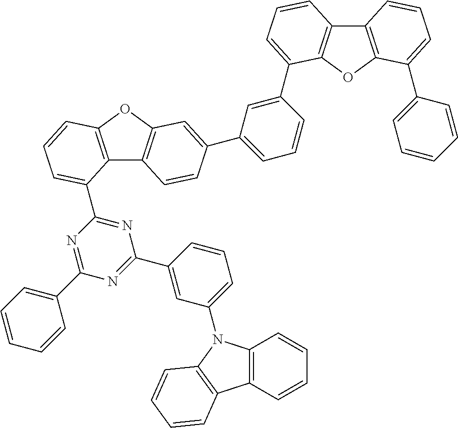 [SMILES: c1ccc(-c2nc(-c3cccc(-n4c5ccccc5c5ccccc54)c3)nc(-c3cccc4oc5cc(-c6cccc(-c7cccc8c7oc7c(-c9ccccc9)cccc78)c6)ccc5c34)n2)cc1] | E36 |
| 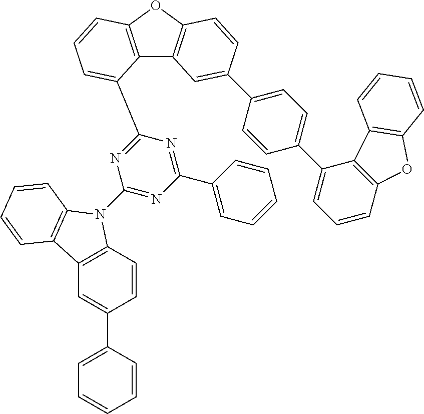 [SMILES: c1ccc(-c2ccc3c(c2)c2ccccc2n3-c2nc(-c3ccccc3)nc(-c3cccc4oc5ccc(-c6ccc(-c7cccc8oc9ccccc9c78)cc6)cc5c34)n2)cc1] | E37 |
| 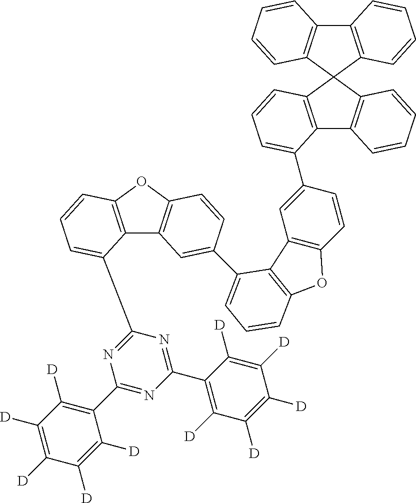 [SMILES: [2H]c1c([2H])c([2H])c(-c2nc(-c3c([2H])c([2H])c([2H])c([2H])c3[2H])nc(-c3cccc4oc5ccc(-c6cccc7oc8ccc(-c9cccc%10c9-c9ccccc9C%109c%10ccccc%10-c%10ccccc%109)cc8c67)cc5c34)n2)c([2H])c1[2H]] | E38 |
| 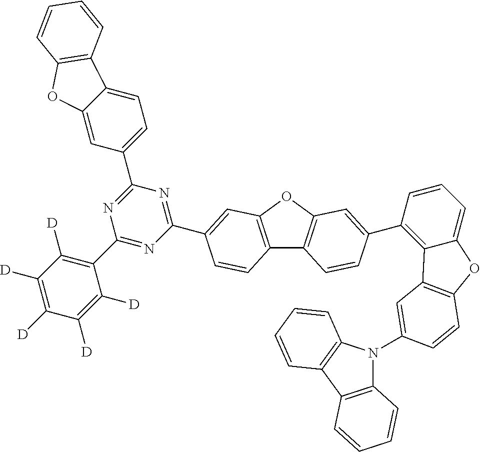 [SMILES: [2H]c1c([2H])c([2H])c(-c2nc(-c3ccc4c(c3)oc3ccccc34)nc(-c3ccc4c(c3)oc3cc(-c5cccc6oc7ccc(-n8c9ccccc9c9ccccc98)cc7c56)ccc34)n2)c([2H])c1[2H]] | E39 |
| 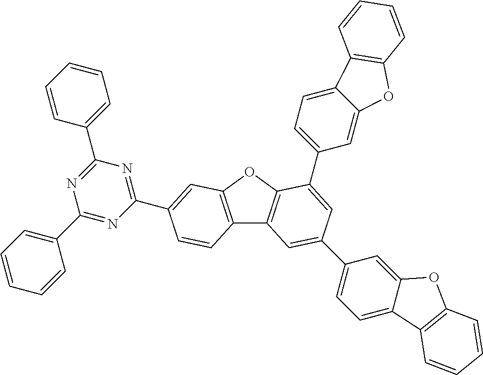 [SMILES: c1ccc(-c2nc(-c3ccccc3)nc(-c3ccc4c(c3)oc3c(-c5ccc6c(c5)oc5ccccc56)cc(-c5ccc6c(c5)oc5ccccc56)cc34)n2)cc1] | E40 |
| 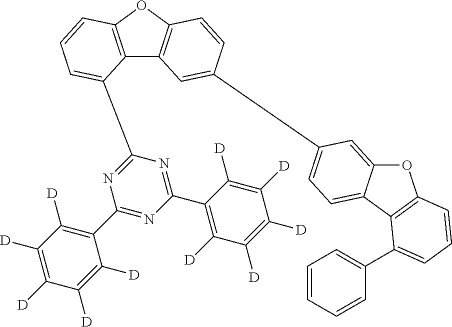 [SMILES: [2H]c1c([2H])c([2H])c(-c2nc(-c3c([2H])c([2H])c([2H])c([2H])c3[2H])nc(-c3cccc4oc5ccc(-c6ccc7c(c6)oc6cccc(-c8ccccc8)c67)cc5c34)n2)c([2H])c1[2H]] | E41 |
| 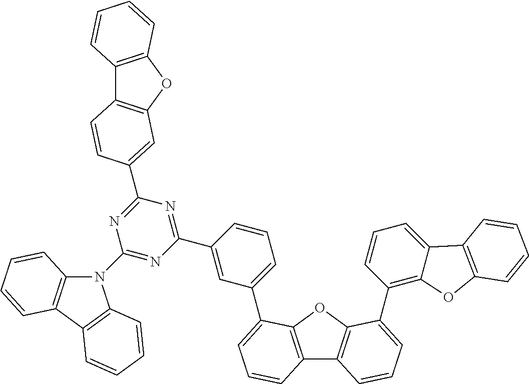 [SMILES: c1cc(-c2nc(-c3ccc4c(c3)oc3ccccc34)nc(-n3c4ccccc4c4ccccc43)n2)cc(-c2cccc3c2oc2c(-c4cccc5c4oc4ccccc45)cccc23)c1] | E42 |
| 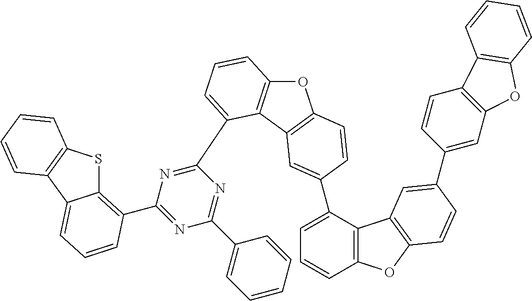 [SMILES: c1ccc(-c2nc(-c3cccc4c3sc3ccccc34)nc(-c3cccc4oc5ccc(-c6cccc7oc8ccc(-c9ccc%10c(c9)oc9ccccc9%10)cc8c67)cc5c34)n2)cc1] | E43 |
| 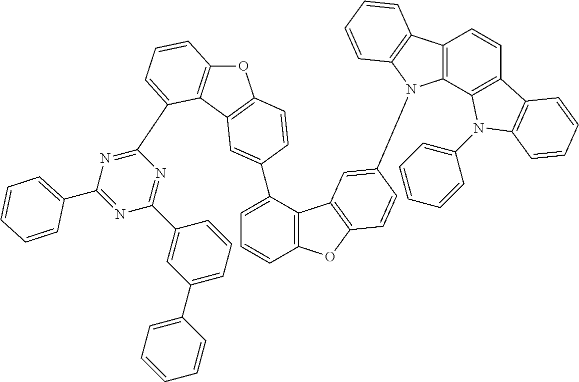 [SMILES: c1ccc(-c2cccc(-c3nc(-c4ccccc4)nc(-c4cccc5oc6ccc(-c7cccc8oc9ccc(-n%10c%11ccccc%11c%11ccc%12c%13ccccc%13n(-c%13ccccc%13)c%12c%11%10)cc9c78)cc6c45)n3)c2)cc1] | E44 |
| 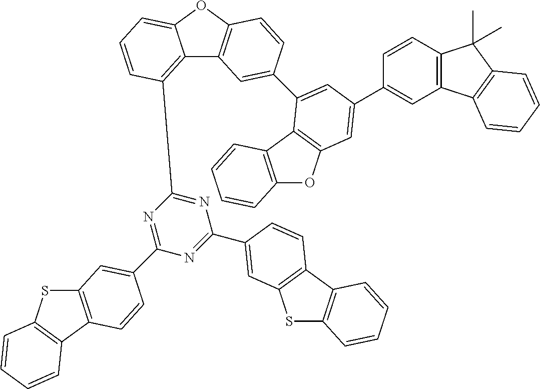 [SMILES: CC1(C)c2ccccc2-c2cc(-c3cc(-c4ccc5oc6cccc(-c7nc(-c8ccc9c(c8)sc8ccccc89)nc(-c8ccc9c(c8)sc8ccccc89)n7)c6c5c4)c4c(c3)oc3ccccc34)ccc21] | E45 |
| 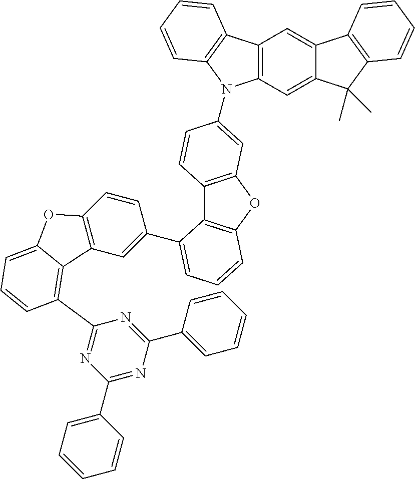 [SMILES: CC1(C)c2ccccc2-c2cc3c4ccccc4n(-c4ccc5c(c4)oc4cccc(-c6ccc7oc8cccc(-c9nc(-c%10ccccc%10)nc(-c%10ccccc%10)n9)c8c7c6)c45)c3cc21] | E46 |
| 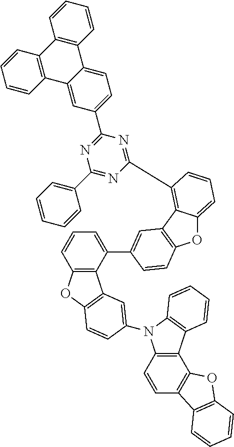 [SMILES: c1ccc(-c2nc(-c3ccc4c5ccccc5c5ccccc5c4c3)nc(-c3cccc4oc5ccc(-c6cccc7oc8ccc(-n9c%10ccccc%10c%10c%11oc%12ccccc%12c%11ccc%109)cc8c67)cc5c34)n2)cc1] | E47 |
| 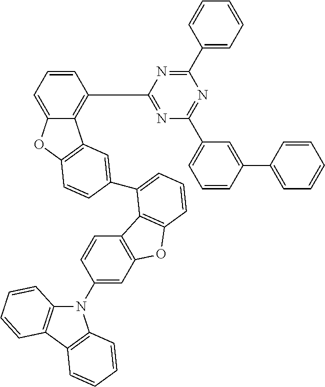 [SMILES: c1ccc(-c2cccc(-c3nc(-c4ccccc4)nc(-c4cccc5oc6ccc(-c7cccc8oc9cc(-n%10c%11ccccc%11c%11ccccc%11%10)ccc9c78)cc6c45)n3)c2)cc1] | E48 |
| 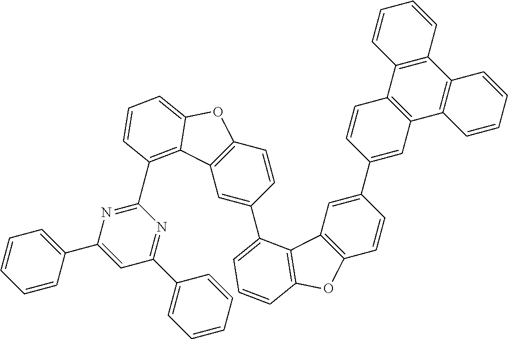 [SMILES: c1ccc(-c2cc(-c3ccccc3)nc(-c3cccc4oc5ccc(-c6cccc7oc8ccc(-c9ccc%10c%11ccccc%11c%11ccccc%11c%10c9)cc8c67)cc5c34)n2)cc1] | E49 |
| 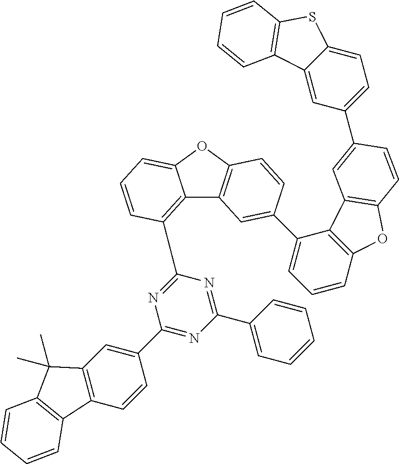 [SMILES: CC1(C)c2ccccc2-c2ccc(-c3nc(-c4ccccc4)nc(-c4cccc5oc6ccc(-c7cccc8oc9ccc(-c%10ccc%11sc%12ccccc%12c%11c%10)cc9c78)cc6c45)n3)cc21] | E50 |
| 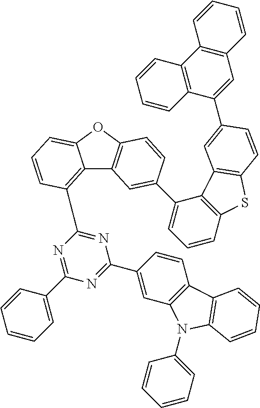 [SMILES: c1ccc(-c2nc(-c3ccc4c5ccccc5n(-c5ccccc5)c4c3)nc(-c3cccc4oc5ccc(-c6cccc7sc8ccc(-c9cc%10ccccc%10c%10ccccc9%10)cc8c67)cc5c34)n2)cc1] | E51 |
| 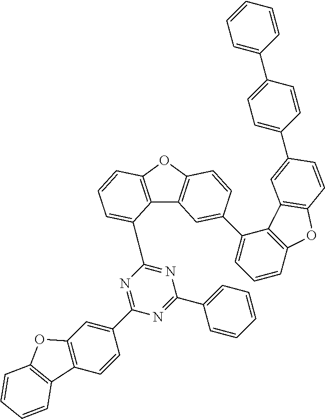 [SMILES: c1ccc(-c2ccc(-c3ccc4oc5cccc(-c6ccc7oc8cccc(-c9nc(-c%10ccccc%10)nc(-c%10ccc%11c(c%10)oc%10ccccc%10%11)n9)c8c7c6)c5c4c3)cc2)cc1] | E52 |
| 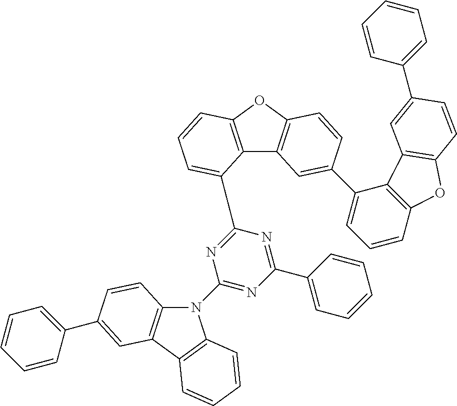 [SMILES: c1ccc(-c2ccc3oc4cccc(-c5ccc6oc7cccc(-c8nc(-c9ccccc9)nc(-n9c%10ccccc%10c%10cc(-c%11ccccc%11)ccc%109)n8)c7c6c5)c4c3c2)cc1] | E53 |
| 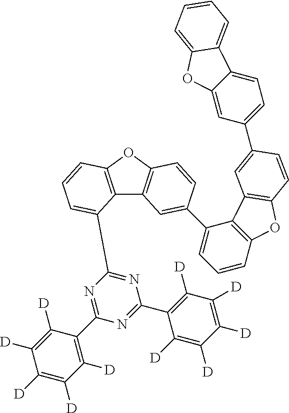 [SMILES: [2H]c1c([2H])c([2H])c(-c2nc(-c3c([2H])c([2H])c([2H])c([2H])c3[2H])nc(-c3cccc4oc5ccc(-c6cccc7oc8ccc(-c9ccc%10c(c9)oc9ccccc9%10)cc8c67)cc5c34)n2)c([2H])c1[2H]] | E54 |
| 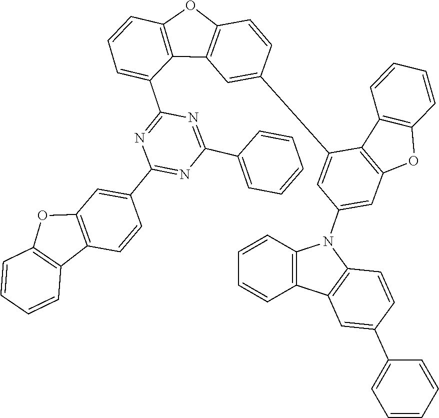 [SMILES: c1ccc(-c2ccc3c(c2)c2ccccc2n3-c2cc(-c3ccc4oc5cccc(-c6nc(-c7ccccc7)nc(-c7ccc8c(c7)oc7ccccc78)n6)c5c4c3)c3c(c2)oc2ccccc23)cc1] | E55 |
| 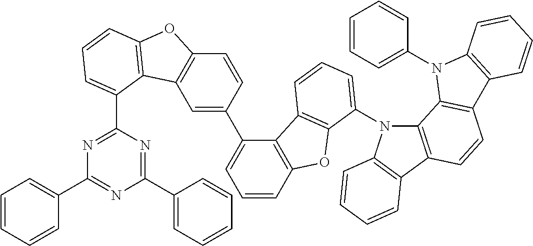 [SMILES: c1ccc(-c2nc(-c3ccccc3)nc(-c3cccc4oc5ccc(-c6cccc7oc8c(-n9c%10ccccc%10c%10ccc%11c%12ccccc%12n(-c%12ccccc%12)c%11c%109)cccc8c67)cc5c34)n2)cc1] | E56 |
| 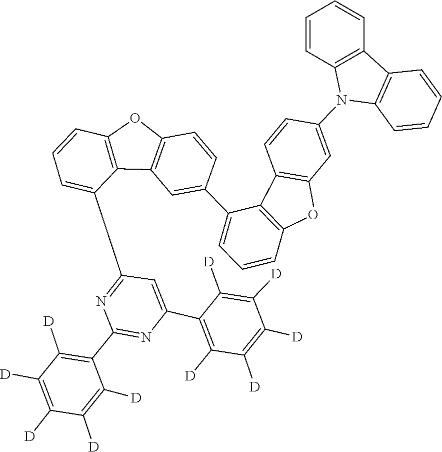 [SMILES: [2H]c1c([2H])c([2H])c(-c2cc(-c3cccc4oc5ccc(-c6cccc7oc8cc(-n9c%10ccccc%10c%10ccccc%109)ccc8c67)cc5c34)nc(-c3c([2H])c([2H])c([2H])c([2H])c3[2H])n2)c([2H])c1[2H]] | E57 |
| 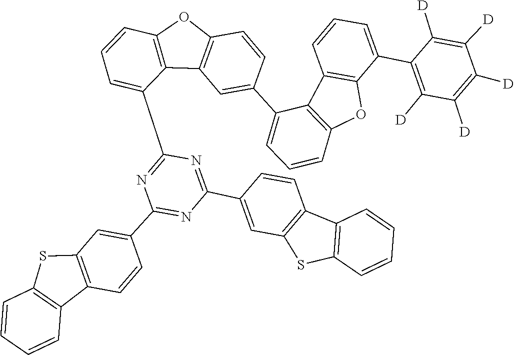 [SMILES: [2H]c1c([2H])c([2H])c(-c2cccc3c2oc2cccc(-c4ccc5oc6cccc(-c7nc(-c8ccc9c(c8)sc8ccccc89)nc(-c8ccc9c(c8)sc8ccccc89)n7)c6c5c4)c23)c([2H])c1[2H]] | E58 |
| 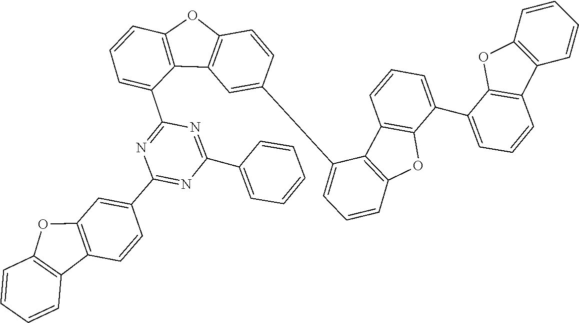 [SMILES: c1ccc(-c2nc(-c3ccc4c(c3)oc3ccccc34)nc(-c3cccc4oc5ccc(-c6cccc7oc8c(-c9cccc%10c9oc9ccccc9%10)cccc8c67)cc5c34)n2)cc1] | E59 |
| 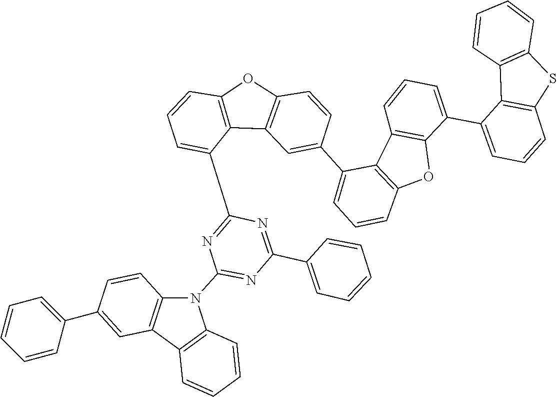 [SMILES: c1ccc(-c2ccc3c(c2)c2ccccc2n3-c2nc(-c3ccccc3)nc(-c3cccc4oc5ccc(-c6cccc7oc8c(-c9cccc%10sc%11ccccc%11c9%10)cccc8c67)cc5c34)n2)cc1] | E60 |
| 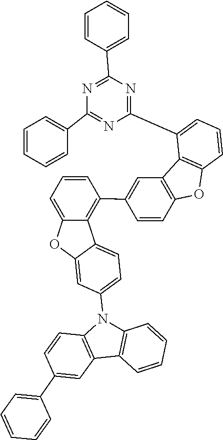 [SMILES: c1ccc(-c2ccc3c(c2)c2ccccc2n3-c2ccc3c(c2)oc2cccc(-c4ccc5oc6cccc(-c7nc(-c8ccccc8)nc(-c8ccccc8)n7)c6c5c4)c23)cc1] | E61 |
| 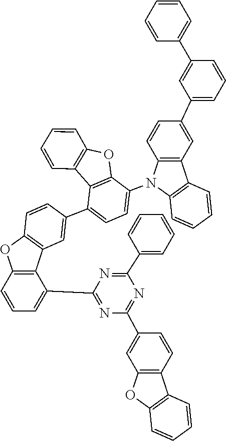 [SMILES: c1ccc(-c2cccc(-c3ccc4c(c3)c3ccccc3n4-c3ccc(-c4ccc5oc6cccc(-c7nc(-c8ccccc8)nc(-c8ccc9c(c8)oc8ccccc89)n7)c6c5c4)c4c3oc3ccccc34)c2)cc1] | E62 |
| 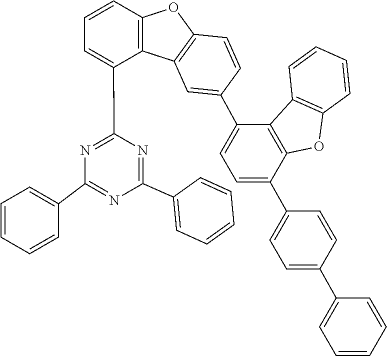 [SMILES: c1ccc(-c2ccc(-c3ccc(-c4ccc5oc6cccc(-c7nc(-c8ccccc8)nc(-c8ccccc8)n7)c6c5c4)c4c3oc3ccccc34)cc2)cc1] | E63 |
| 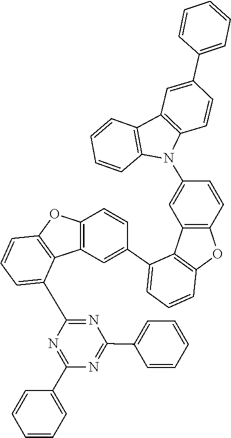 [SMILES: c1ccc(-c2ccc3c(c2)c2ccccc2n3-c2ccc3oc4cccc(-c5ccc6oc7cccc(-c8nc(-c9ccccc9)nc(-c9ccccc9)n8)c7c6c5)c4c3c2)cc1] | E64 |
| 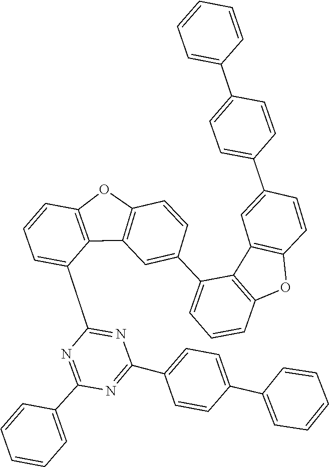 [SMILES: c1ccc(-c2ccc(-c3ccc4oc5cccc(-c6ccc7oc8cccc(-c9nc(-c%10ccccc%10)nc(-c%10ccc(-c%11ccccc%11)cc%10)n9)c8c7c6)c5c4c3)cc2)cc1] | E65 |
| 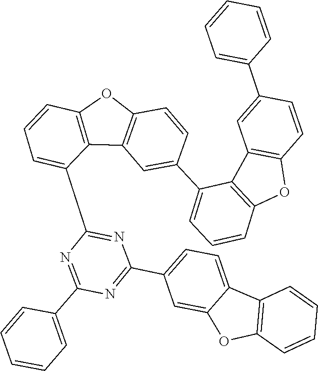 [SMILES: c1ccc(-c2ccc3oc4cccc(-c5ccc6oc7cccc(-c8nc(-c9ccccc9)nc(-c9ccc%10c(c9)oc9ccccc9%10)n8)c7c6c5)c4c3c2)cc1] | E66 |
| 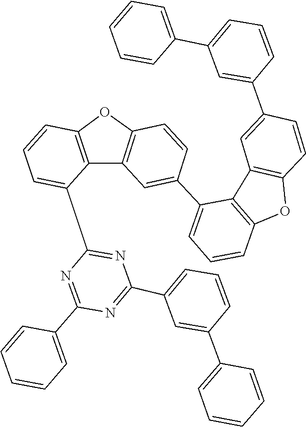 [SMILES: c1ccc(-c2cccc(-c3ccc4oc5cccc(-c6ccc7oc8cccc(-c9nc(-c%10ccccc%10)nc(-c%10cccc(-c%11ccccc%11)c%10)n9)c8c7c6)c5c4c3)c2)cc1] | E67 |
| 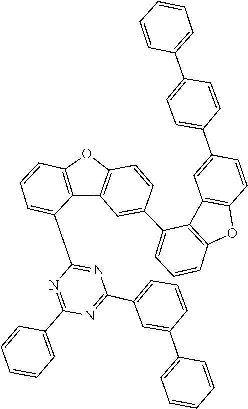 [SMILES: c1ccc(-c2ccc(-c3ccc4oc5cccc(-c6ccc7oc8cccc(-c9nc(-c%10ccccc%10)nc(-c%10cccc(-c%11ccccc%11)c%10)n9)c8c7c6)c5c4c3)cc2)cc1] | E68 |
| 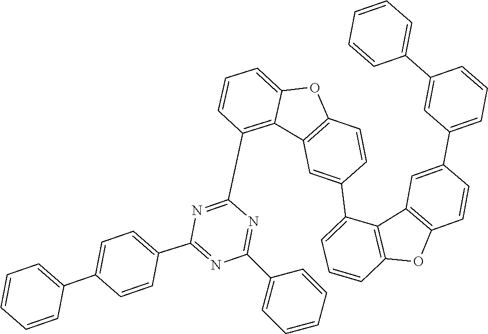 [SMILES: c1ccc(-c2ccc(-c3nc(-c4ccccc4)nc(-c4cccc5oc6ccc(-c7cccc8oc9ccc(-c%10cccc(-c%11ccccc%11)c%10)cc9c78)cc6c45)n3)cc2)cc1] | E69 |
| 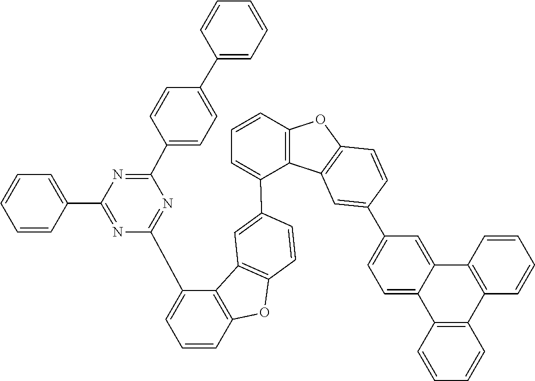 [SMILES: c1ccc(-c2ccc(-c3nc(-c4ccccc4)nc(-c4cccc5oc6ccc(-c7cccc8oc9ccc(-c%10ccc%11c%12ccccc%12c%12ccccc%12c%11c%10)cc9c78)cc6c45)n3)cc2)cc1] | E70 |
| 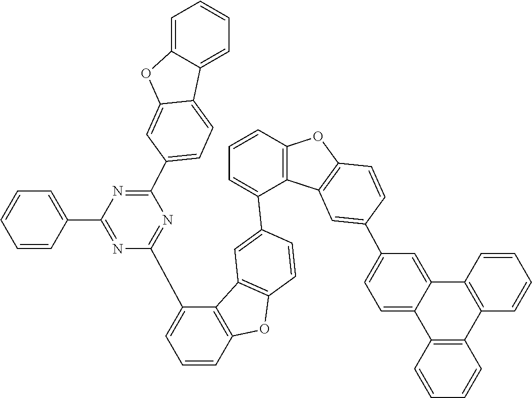 [SMILES: c1ccc(-c2nc(-c3ccc4c(c3)oc3ccccc34)nc(-c3cccc4oc5ccc(-c6cccc7oc8ccc(-c9ccc%10c%11ccccc%11c%11ccccc%11c%10c9)cc8c67)cc5c34)n2)cc1] | E71 |
| 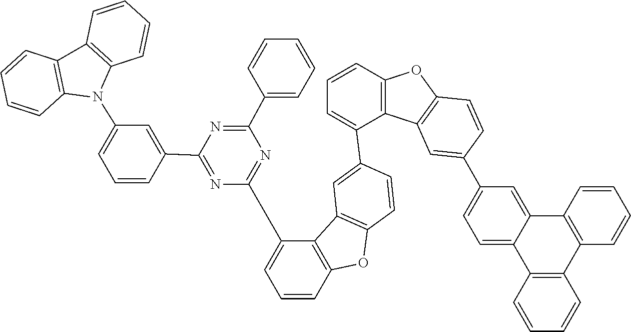 [SMILES: c1ccc(-c2nc(-c3cccc(-n4c5ccccc5c5ccccc54)c3)nc(-c3cccc4oc5ccc(-c6cccc7oc8ccc(-c9ccc%10c%11ccccc%11c%11ccccc%11c%10c9)cc8c67)cc5c34)n2)cc1] | E72 |
| 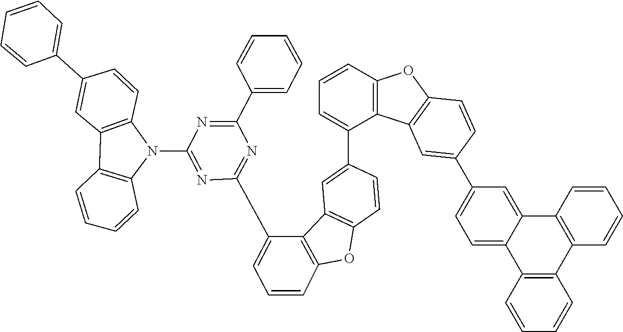 [SMILES: c1ccc(-c2ccc3c(c2)c2ccccc2n3-c2nc(-c3ccccc3)nc(-c3cccc4oc5ccc(-c6cccc7oc8ccc(-c9ccc%10c%11ccccc%11c%11ccccc%11c%10c9)cc8c67)cc5c34)n2)cc1] | E73 |
| 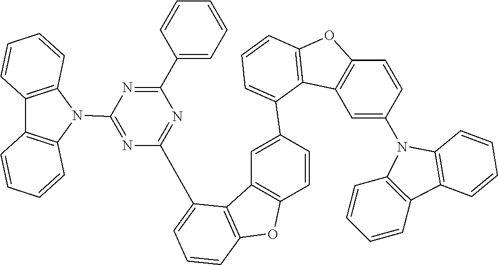 [SMILES: c1ccc(-c2nc(-c3cccc4oc5ccc(-c6cccc7oc8ccc(-n9c%10ccccc%10c%10ccccc%109)cc8c67)cc5c34)nc(-n3c4ccccc4c4ccccc43)n2)cc1] | E74 |
| 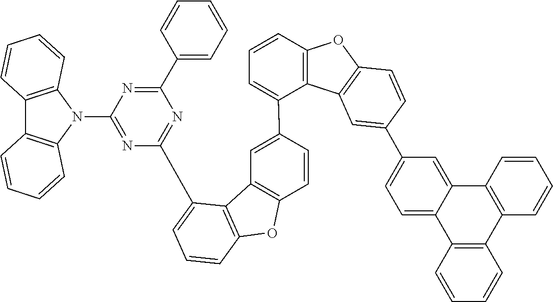 [SMILES: c1ccc(-c2nc(-c3cccc4oc5ccc(-c6cccc7oc8ccc(-c9ccc%10c%11ccccc%11c%11ccccc%11c%10c9)cc8c67)cc5c34)nc(-n3c4ccccc4c4ccccc43)n2)cc1] | E75 |
| 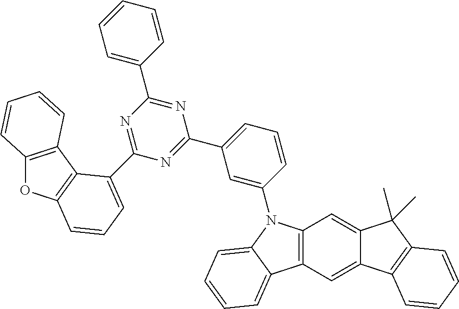 [SMILES: CC1(C)c2ccccc2-c2cc3c4ccccc4n(-c4cccc(-c5nc(-c6ccccc6)nc(-c6cccc7oc8ccccc8c67)n5)c4)c3cc21] | E76 |
| 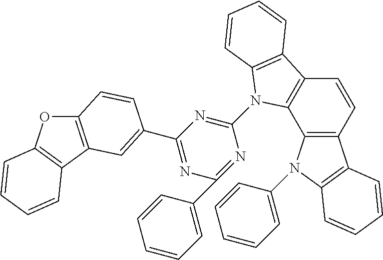 [SMILES: c1ccc(-c2nc(-c3ccc4oc5ccccc5c4c3)nc(-n3c4ccccc4c4ccc5c6ccccc6n(-c6ccccc6)c5c43)n2)cc1] | E77 |
| 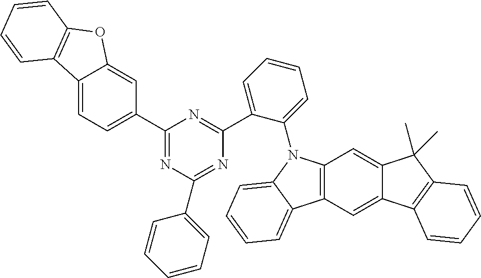 [SMILES: CC1(C)c2ccccc2-c2cc3c4ccccc4n(-c4ccccc4-c4nc(-c5ccccc5)nc(-c5ccc6c(c5)oc5ccccc56)n4)c3cc21] | E78 |
| 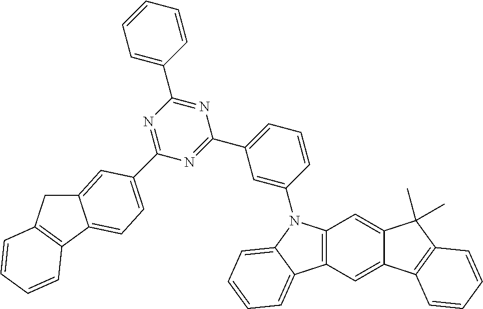 [SMILES: CC1(C)c2ccccc2-c2cc3c4ccccc4n(-c4cccc(-c5nc(-c6ccccc6)nc(-c6ccc7c(c6)Cc6ccccc6-7)n5)c4)c3cc21] | E79 |
| 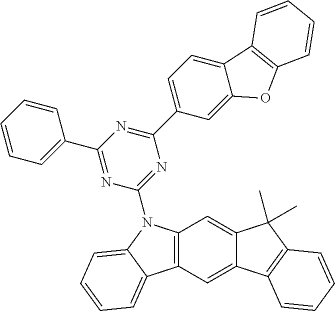 [SMILES: CC1(C)c2ccccc2-c2cc3c4ccccc4n(-c4nc(-c5ccccc5)nc(-c5ccc6c(c5)oc5ccccc56)n4)c3cc21] | E80 |
| 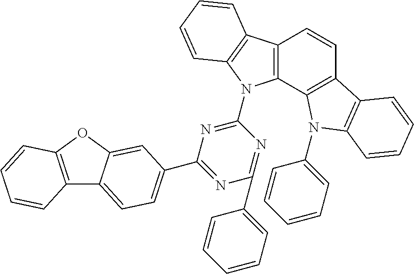 [SMILES: c1ccc(-c2nc(-c3ccc4c(c3)oc3ccccc34)nc(-n3c4ccccc4c4ccc5c6ccccc6n(-c6ccccc6)c5c43)n2)cc1] | E81 |
| 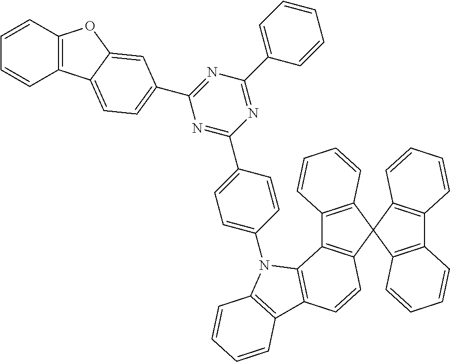 [SMILES: c1ccc(-c2nc(-c3ccc(-n4c5ccccc5c5ccc6c(c54)-c4ccccc4C64c5ccccc5-c5ccccc54)cc3)nc(-c3ccc4c(c3)oc3ccccc34)n2)cc1] | E82 |
| 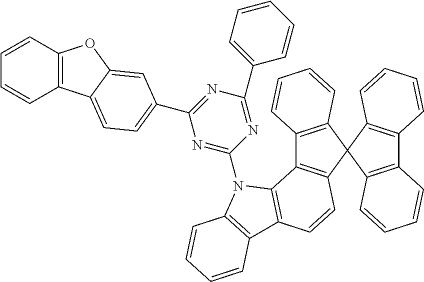 [SMILES: c1ccc(-c2nc(-c3ccc4c(c3)oc3ccccc34)nc(-n3c4ccccc4c4ccc5c(c43)-c3ccccc3C53c4ccccc4-c4ccccc43)n2)cc1] | E82 |
| 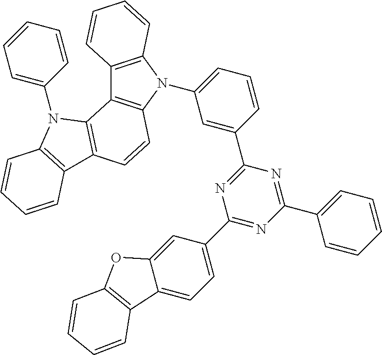 [SMILES: c1ccc(-c2nc(-c3cccc(-n4c5ccccc5c5c4ccc4c6ccccc6n(-c6ccccc6)c45)c3)nc(-c3ccc4c(c3)oc3ccccc34)n2)cc1] | E83 |
| 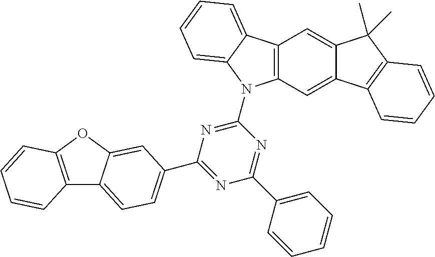 [SMILES: CC1(C)c2ccccc2-c2cc3c(cc21)c1ccccc1n3-c1nc(-c2ccccc2)nc(-c2ccc3c(c2)oc2ccccc23)n1] | E84 |
| 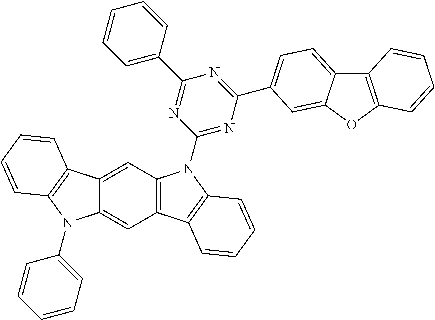 [SMILES: c1ccc(-c2nc(-c3ccc4c(c3)oc3ccccc34)nc(-n3c4ccccc4c4cc5c(cc43)c3ccccc3n5-c3ccccc3)n2)cc1] | E85 |
| 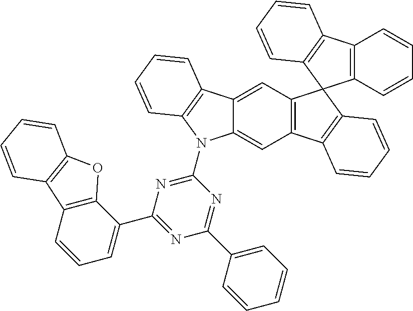 [SMILES: c1ccc(-c2nc(-c3cccc4c3oc3ccccc34)nc(-n3c4ccccc4c4cc5c(cc43)-c3ccccc3C53c4ccccc4-c4ccccc43)n2)cc1] | E86 |
| 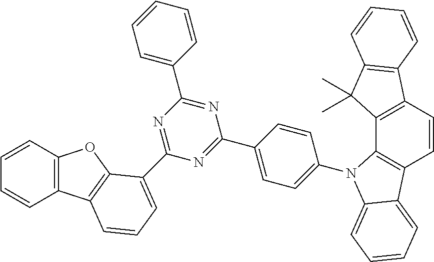 [SMILES: CC1(C)c2ccccc2-c2ccc3c4ccccc4n(-c4ccc(-c5nc(-c6ccccc6)nc(-c6cccc7c6oc6ccccc67)n5)cc4)c3c21] | E87 |
| 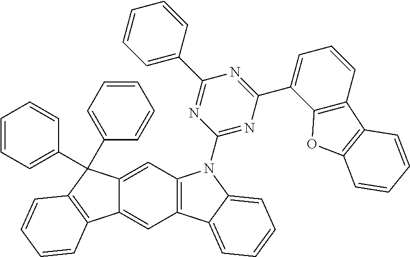 [SMILES: c1ccc(-c2nc(-c3cccc4c3oc3ccccc34)nc(-n3c4ccccc4c4cc5c(cc43)C(c3ccccc3)(c3ccccc3)c3ccccc3-5)n2)cc1] | E88 |
| 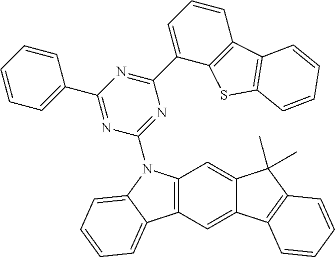 [SMILES: CC1(C)c2ccccc2-c2cc3c4ccccc4n(-c4nc(-c5ccccc5)nc(-c5cccc6c5sc5ccccc56)n4)c3cc21] | E89 |
| 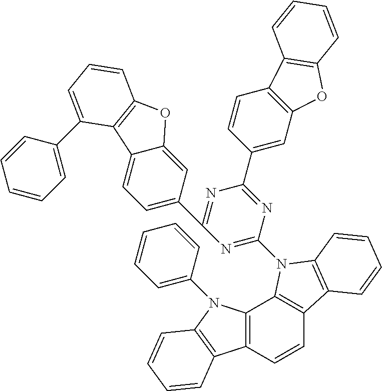 [SMILES: c1ccc(-c2cccc3oc4cc(-c5nc(-c6ccc7c(c6)oc6ccccc67)nc(-n6c7ccccc7c7ccc8c9ccccc9n(-c9ccccc9)c8c76)n5)ccc4c23)cc1] | E90 |
| 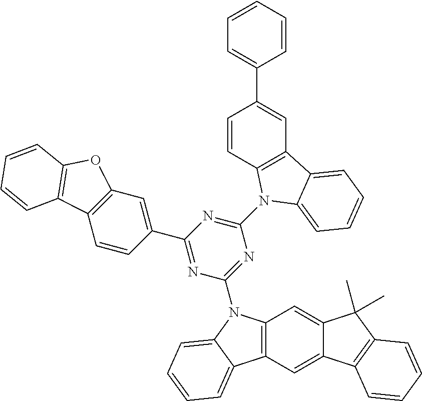 [SMILES: CC1(C)c2ccccc2-c2cc3c4ccccc4n(-c4nc(-c5ccc6c(c5)oc5ccccc56)nc(-n5c6ccccc6c6cc(-c7ccccc7)ccc65)n4)c3cc21] | E91 |
| 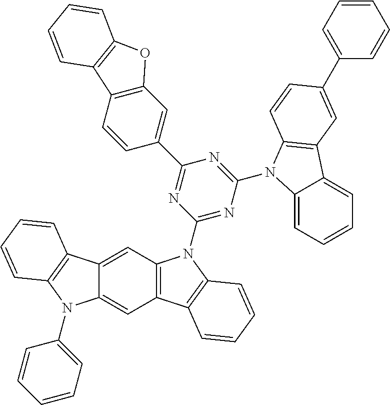 [SMILES: c1ccc(-c2ccc3c(c2)c2ccccc2n3-c2nc(-c3ccc4c(c3)oc3ccccc34)nc(-n3c4ccccc4c4cc5c(cc43)c3ccccc3n5-c3ccccc3)n2)cc1] | E92 |
| 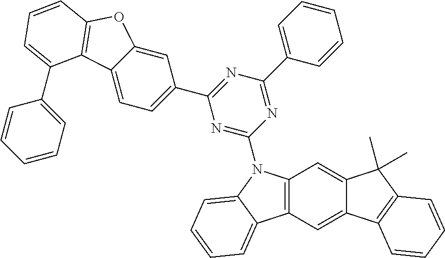 [SMILES: CC1(C)c2ccccc2-c2cc3c4ccccc4n(-c4nc(-c5ccccc5)nc(-c5ccc6c(c5)oc5cccc(-c7ccccc7)c56)n4)c3cc21] | E93 |
| 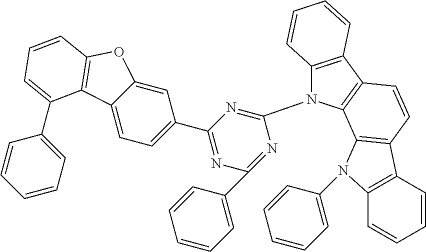 [SMILES: c1ccc(-c2nc(-c3ccc4c(c3)oc3cccc(-c5ccccc5)c34)nc(-n3c4ccccc4c4ccc5c6ccccc6n(-c6ccccc6)c5c43)n2)cc1] | E94 |
| 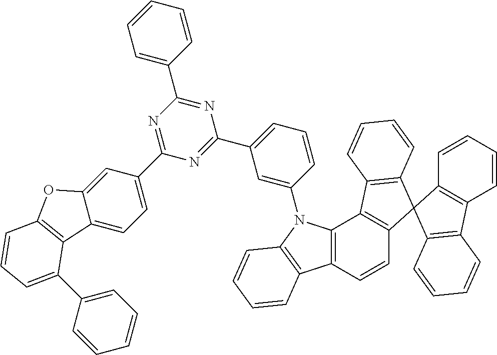 [SMILES: c1ccc(-c2nc(-c3cccc(-n4c5ccccc5c5ccc6c(c54)-c4ccccc4C64c5ccccc5-c5ccccc54)c3)nc(-c3ccc4c(c3)oc3cccc(-c5ccccc5)c34)n2)cc1] | E95 |
| 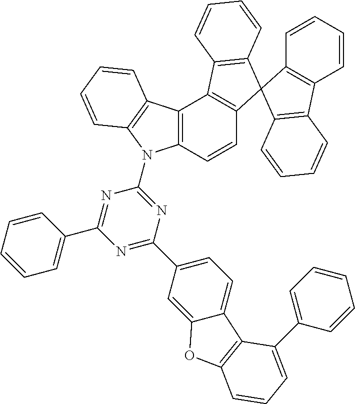 [SMILES: c1ccc(-c2nc(-c3ccc4c(c3)oc3cccc(-c5ccccc5)c34)nc(-n3c4ccccc4c4c5c(ccc43)C3(c4ccccc4-c4ccccc43)c3ccccc3-5)n2)cc1] | E96 |
| 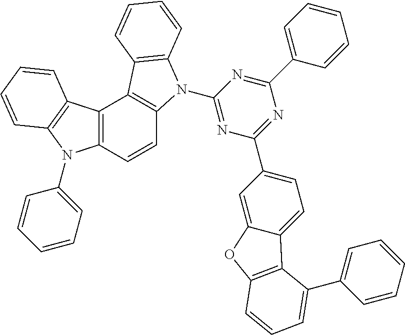 [SMILES: c1ccc(-c2nc(-c3ccc4c(c3)oc3cccc(-c5ccccc5)c34)nc(-n3c4ccccc4c4c5c6ccccc6n(-c6ccccc6)c5ccc43)n2)cc1] | E97 |
| 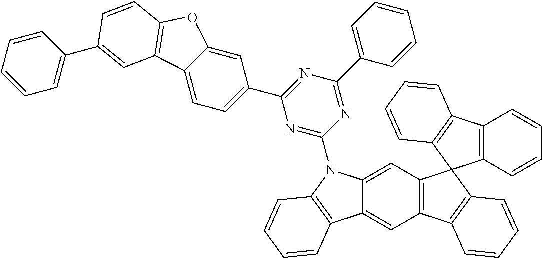 [SMILES: c1ccc(-c2ccc3oc4cc(-c5nc(-c6ccccc6)nc(-n6c7ccccc7c7cc8c(cc76)C6(c7ccccc7-c7ccccc76)c6ccccc6-8)n5)ccc4c3c2)cc1] | E98 |
| 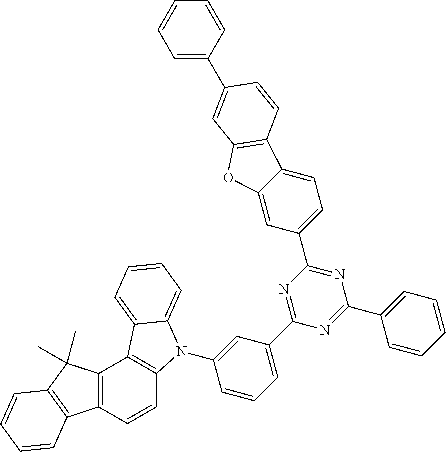 [SMILES: CC1(C)c2ccccc2-c2ccc3c(c21)c1ccccc1n3-c1cccc(-c2nc(-c3ccccc3)nc(-c3ccc4c(c3)oc3cc(-c5ccccc5)ccc34)n2)c1] | E99 |
| 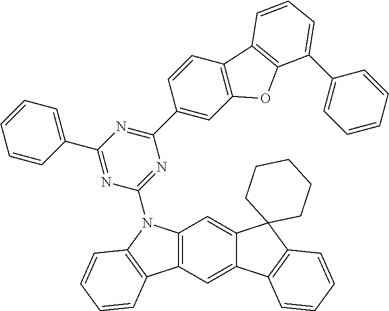 [SMILES: c1ccc(-c2nc(-c3ccc4c(c3)oc3c(-c5ccccc5)cccc34)nc(-n3c4ccccc4c4cc5c(cc43)C3(CCCCC3)c3ccccc3-5)n2)cc1] | E100 |
| 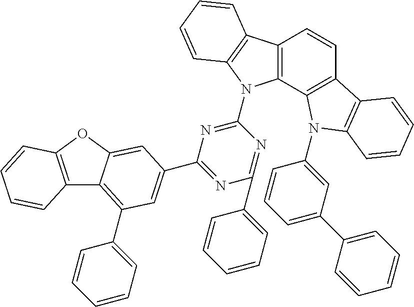 [SMILES: c1ccc(-c2cccc(-n3c4ccccc4c4ccc5c6ccccc6n(-c6nc(-c7ccccc7)nc(-c7cc(-c8ccccc8)c8c(c7)oc7ccccc78)n6)c5c43)c2)cc1] | E101 |
| 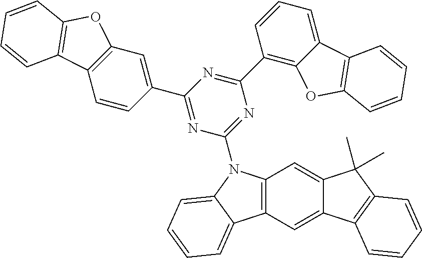 [SMILES: CC1(C)c2ccccc2-c2cc3c4ccccc4n(-c4nc(-c5ccc6c(c5)oc5ccccc56)nc(-c5cccc6c5oc5ccccc56)n4)c3cc21] | E102 |
| 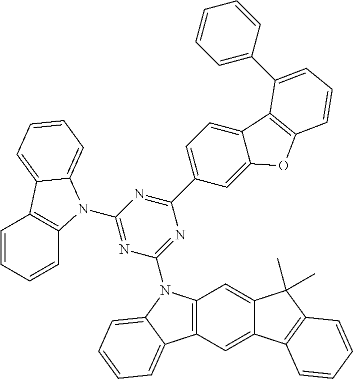 [SMILES: CC1(C)c2ccccc2-c2cc3c4ccccc4n(-c4nc(-c5ccc6c(c5)oc5cccc(-c7ccccc7)c56)nc(-n5c6ccccc6c6ccccc65)n4)c3cc21] | E103 |
| 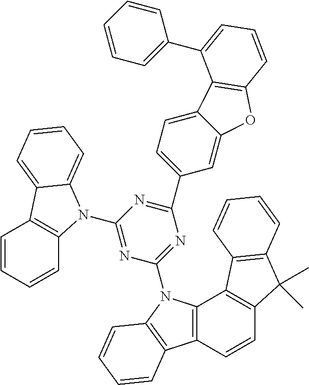 [SMILES: CC1(C)c2ccccc2-c2c1ccc1c3ccccc3n(-c3nc(-c4ccc5c(c4)oc4cccc(-c6ccccc6)c45)nc(-n4c5ccccc5c5ccccc54)n3)c21] | E104 |
| 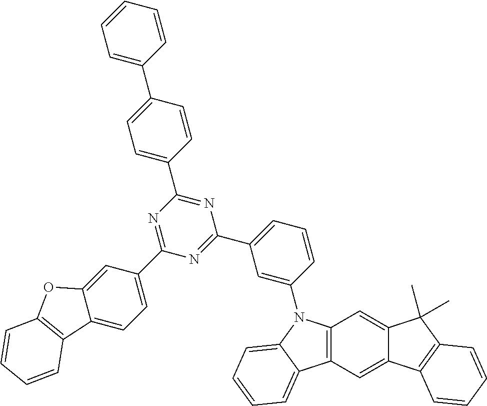 [SMILES: CC1(C)c2ccccc2-c2cc3c4ccccc4n(-c4cccc(-c5nc(-c6ccc(-c7ccccc7)cc6)nc(-c6ccc7c(c6)oc6ccccc67)n5)c4)c3cc21] | E105 |
| 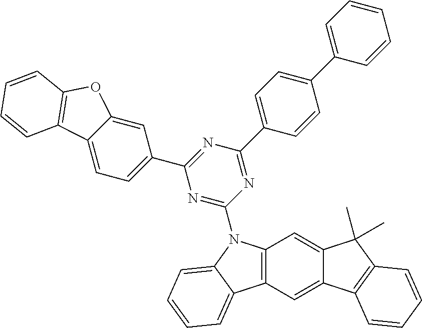 [SMILES: CC1(C)c2ccccc2-c2cc3c4ccccc4n(-c4nc(-c5ccc(-c6ccccc6)cc5)nc(-c5ccc6c(c5)oc5ccccc56)n4)c3cc21] | E106 |
| 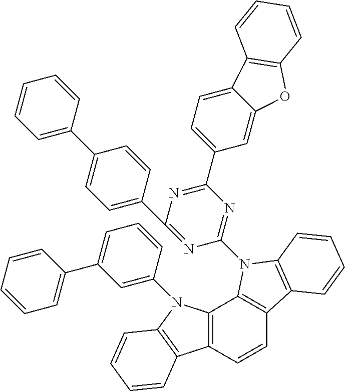 [SMILES: c1ccc(-c2ccc(-c3nc(-c4ccc5c(c4)oc4ccccc45)nc(-n4c5ccccc5c5ccc6c7ccccc7n(-c7cccc(-c8ccccc8)c7)c6c54)n3)cc2)cc1] | E107 |
| 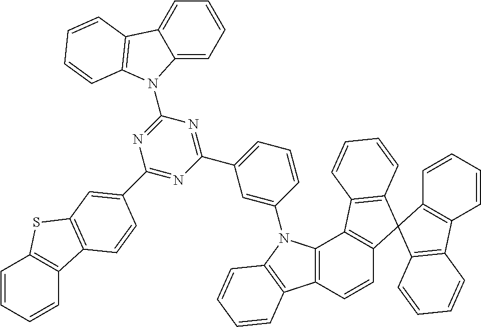 [SMILES: c1cc(-c2nc(-c3ccc4c(c3)sc3ccccc34)nc(-n3c4ccccc4c4ccccc43)n2)cc(-n2c3ccccc3c3ccc4c(c32)-c2ccccc2C42c3ccccc3-c3ccccc32)c1] | E108 |
| 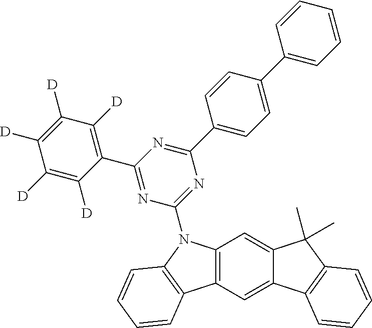 [SMILES: [2H]c1c([2H])c([2H])c(-c2nc(-c3ccc(-c4ccccc4)cc3)nc(-n3c4ccccc4c4cc5c(cc43)C(C)(C)c3ccccc3-5)n2)c([2H])c1[2H]] | E109 |
| 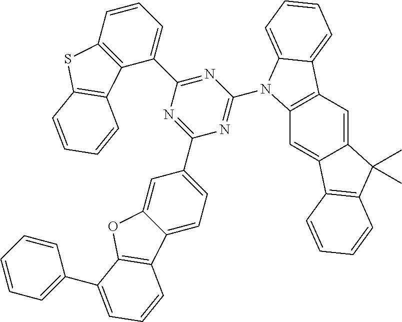 [SMILES: CC1(C)c2ccccc2-c2cc3c(cc21)c1ccccc1n3-c1nc(-c2ccc3c(c2)oc2c(-c4ccccc4)cccc23)nc(-c2cccc3sc4ccccc4c23)n1] | E110 |
| 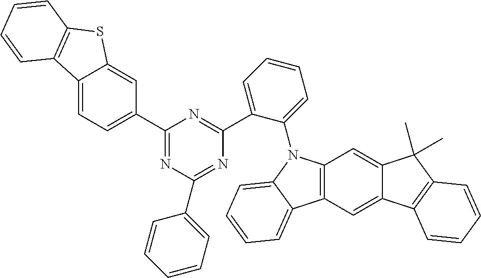 [SMILES: CC1(C)c2ccccc2-c2cc3c4ccccc4n(-c4ccccc4-c4nc(-c5ccccc5)nc(-c5ccc6c(c5)sc5ccccc56)n4)c3cc21] | E111 |
| 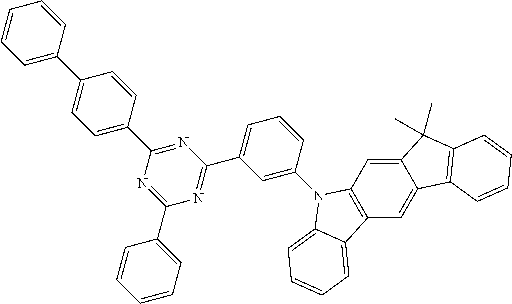 [SMILES: CC1(C)c2ccccc2-c2cc3c4ccccc4n(-c4cccc(-c5nc(-c6ccccc6)nc(-c6ccc(-c7ccccc7)cc6)n5)c4)c3cc21] | E112 |
| 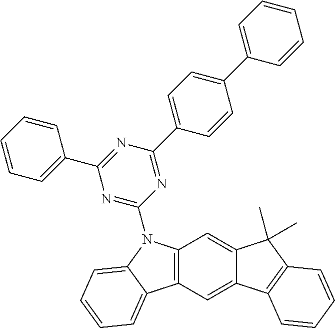 [SMILES: CC1(C)c2ccccc2-c2cc3c4ccccc4n(-c4nc(-c5ccccc5)nc(-c5ccc(-c6ccccc6)cc5)n4)c3cc21] | E113 |
| 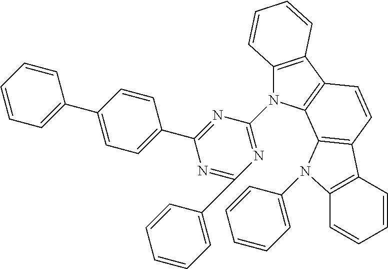 [SMILES: c1ccc(-c2ccc(-c3nc(-c4ccccc4)nc(-n4c5ccccc5c5ccc6c7ccccc7n(-c7ccccc7)c6c54)n3)cc2)cc1] | E114 |
| 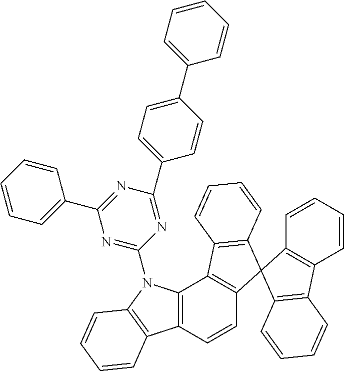 [SMILES: c1ccc(-c2ccc(-c3nc(-c4ccccc4)nc(-n4c5ccccc5c5ccc6c(c54)-c4ccccc4C64c5ccccc5-c5ccccc54)n3)cc2)cc1] | E115 |
| 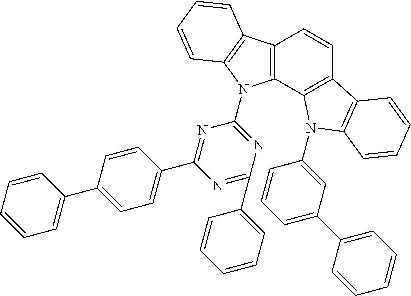 [SMILES: c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1] | E116 |
| 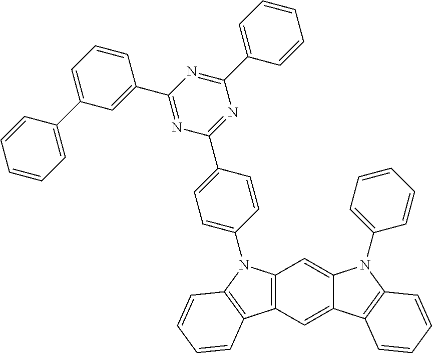 [SMILES: c1ccc(-c2cccc(-c3nc(-c4ccccc4)nc(-c4ccc(-n5c6ccccc6c6cc7c8ccccc8n(-c8ccccc8)c7cc65)cc4)n3)c2)cc1] | E117 |
| 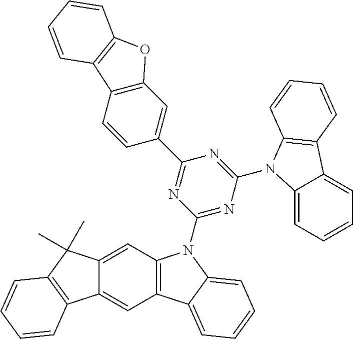 [SMILES: CC1(C)c2ccccc2-c2cc3c4ccccc4n(-c4nc(-c5ccc6c(c5)oc5ccccc56)nc(-n5c6ccccc6c6ccccc65)n4)c3cc21] | E118 |
| 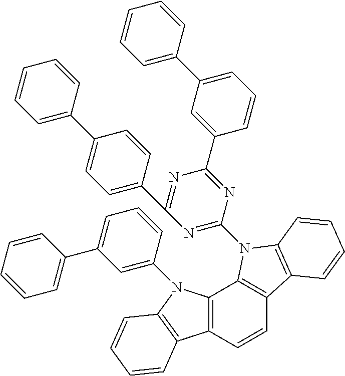 [SMILES: c1ccc(-c2ccc(-c3nc(-c4cccc(-c5ccccc5)c4)nc(-n4c5ccccc5c5ccc6c7ccccc7n(-c7cccc(-c8ccccc8)c7)c6c54)n3)cc2)cc1] | E119 |
| 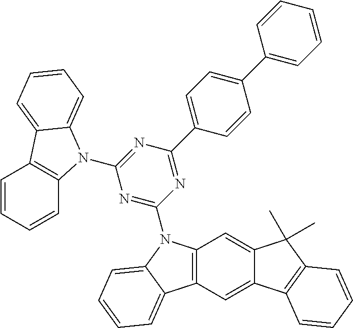 [SMILES: CC1(C)c2ccccc2-c2cc3c4ccccc4n(-c4nc(-c5ccc(-c6ccccc6)cc5)nc(-n5c6ccccc6c6ccccc65)n4)c3cc21] | E120 |
| 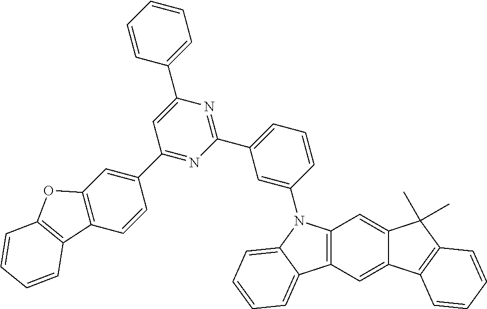 [SMILES: CC1(C)c2ccccc2-c2cc3c4ccccc4n(-c4cccc(-c5nc(-c6ccccc6)cc(-c6ccc7c(c6)oc6ccccc67)n5)c4)c3cc21] | E121 |
| 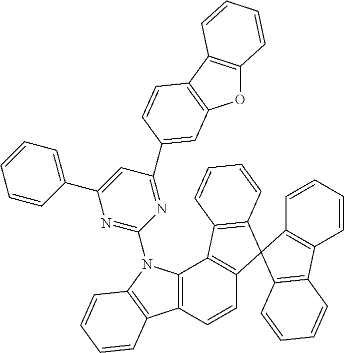 [SMILES: c1ccc(-c2cc(-c3ccc4c(c3)oc3ccccc34)nc(-n3c4ccccc4c4ccc5c(c43)-c3ccccc3C53c4ccccc4-c4ccccc43)n2)cc1] | E122 |
| 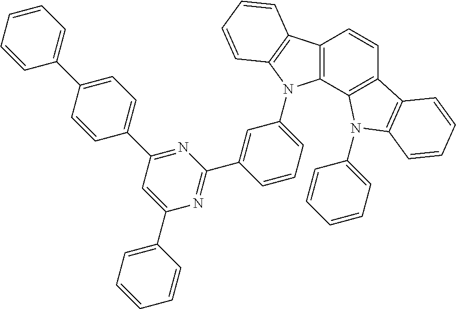 [SMILES: c1ccc(-c2ccc(-c3cc(-c4ccccc4)nc(-c4cccc(-n5c6ccccc6c6ccc7c8ccccc8n(-c8ccccc8)c7c65)c4)n3)cc2)cc1] | E123 |
| 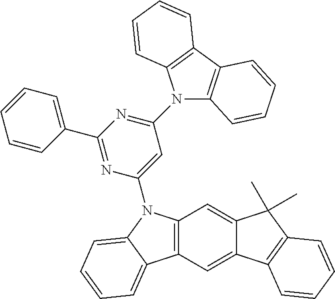 [SMILES: CC1(C)c2ccccc2-c2cc3c4ccccc4n(-c4cc(-n5c6ccccc6c6ccccc65)nc(-c5ccccc5)n4)c3cc21] | E124 |
| 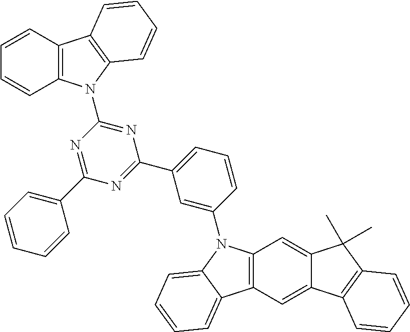 [SMILES: CC1(C)c2ccccc2-c2cc3c4ccccc4n(-c4cccc(-c5nc(-c6ccccc6)nc(-n6c7ccccc7c7ccccc76)n5)c4)c3cc21] | E125 |
| 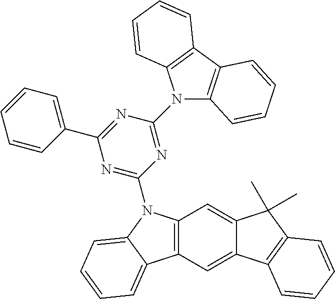 [SMILES: CC1(C)c2ccccc2-c2cc3c4ccccc4n(-c4nc(-c5ccccc5)nc(-n5c6ccccc6c6ccccc65)n4)c3cc21] | E126 |
| 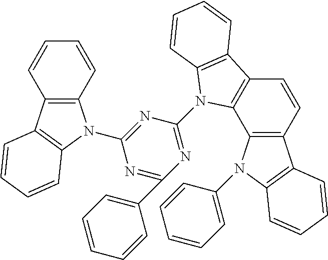 [SMILES: c1ccc(-c2nc(-n3c4ccccc4c4ccccc43)nc(-n3c4ccccc4c4ccc5c6ccccc6n(-c6ccccc6)c5c43)n2)cc1] | E127 |
| 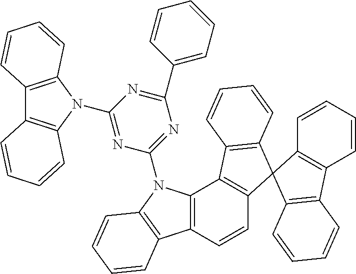 [SMILES: c1ccc(-c2nc(-n3c4ccccc4c4ccccc43)nc(-n3c4ccccc4c4ccc5c(c43)-c3ccccc3C53c4ccccc4-c4ccccc43)n2)cc1] | E128 |
| 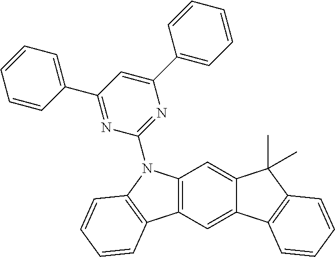 [SMILES: CC1(C)c2ccccc2-c2cc3c4ccccc4n(-c4nc(-c5ccccc5)cc(-c5ccccc5)n4)c3cc21] | E129 |
| 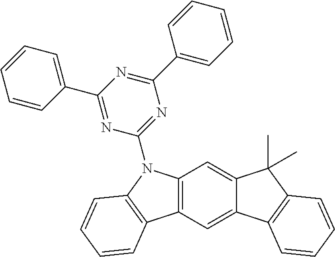 [SMILES: CC1(C)c2ccccc2-c2cc3c4ccccc4n(-c4nc(-c5ccccc5)nc(-c5ccccc5)n4)c3cc21] | E130 |
| 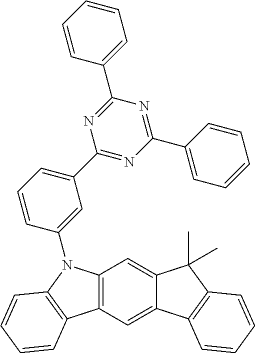 [SMILES: CC1(C)c2ccccc2-c2cc3c4ccccc4n(-c4cccc(-c5nc(-c6ccccc6)nc(-c6ccccc6)n5)c4)c3cc21] | E131 |
| 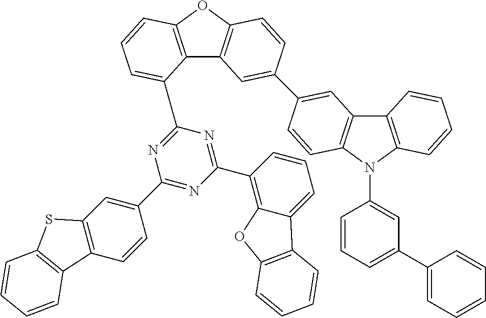 [SMILES: c1ccc(-c2cccc(-n3c4ccccc4c4cc(-c5ccc6oc7cccc(-c8nc(-c9ccc%10c(c9)sc9ccccc9%10)nc(-c9cccc%10c9oc9ccccc9%10)n8)c7c6c5)ccc43)c2)cc1] | E132 |
| 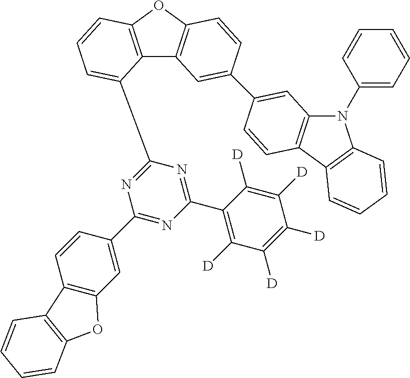 [SMILES: [2H]c1c([2H])c([2H])c(-c2nc(-c3ccc4c(c3)oc3ccccc34)nc(-c3cccc4oc5ccc(-c6ccc7c8ccccc8n(-c8ccccc8)c7c6)cc5c34)n2)c([2H])c1[2H]] | E133 |
| 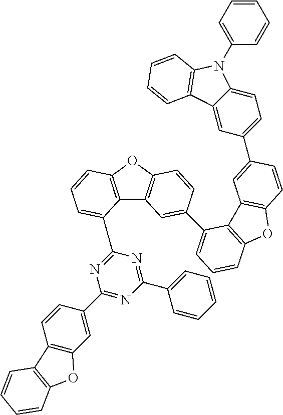 [SMILES: c1ccc(-c2nc(-c3ccc4c(c3)oc3ccccc34)nc(-c3cccc4oc5ccc(-c6cccc7oc8ccc(-c9ccc%10c(c9)c9ccccc9n%10-c9ccccc9)cc8c67)cc5c34)n2)cc1] | E134 |
| 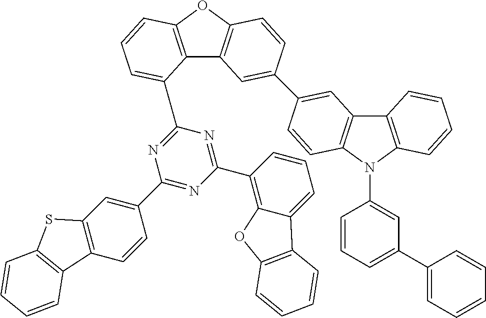 [SMILES: c1ccc(-c2cccc(-n3c4ccccc4c4cc(-c5ccc6oc7cccc(-c8nc(-c9ccc%10c(c9)sc9ccccc9%10)nc(-c9cccc%10c9oc9ccccc9%10)n8)c7c6c5)ccc43)c2)cc1] | E135 |
| 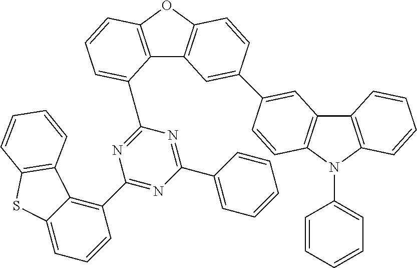 [SMILES: c1ccc(-c2nc(-c3cccc4oc5ccc(-c6ccc7c(c6)c6ccccc6n7-c6ccccc6)cc5c34)nc(-c3cccc4sc5ccccc5c34)n2)cc1] | E136 |
| 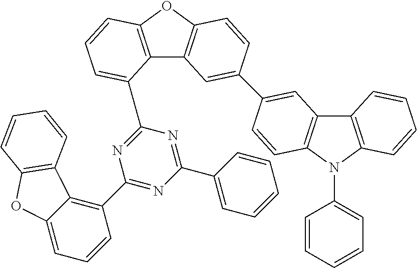 [SMILES: c1ccc(-c2nc(-c3cccc4oc5ccccc5c34)nc(-c3cccc4oc5ccc(-c6ccc7c(c6)c6ccccc6n7-c6ccccc6)cc5c34)n2)cc1] | E137 |
| 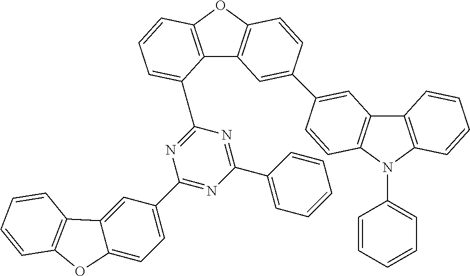 [SMILES: c1ccc(-c2nc(-c3ccc4oc5ccccc5c4c3)nc(-c3cccc4oc5ccc(-c6ccc7c(c6)c6ccccc6n7-c6ccccc6)cc5c34)n2)cc1] | E138 |
| 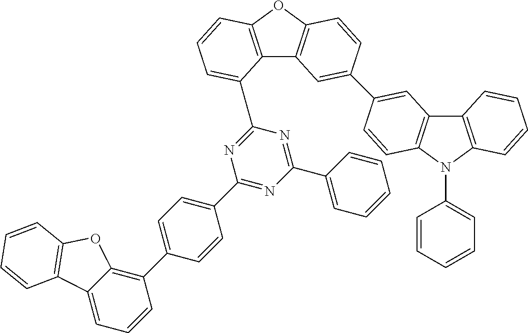 [SMILES: c1ccc(-c2nc(-c3ccc(-c4cccc5c4oc4ccccc45)cc3)nc(-c3cccc4oc5ccc(-c6ccc7c(c6)c6ccccc6n7-c6ccccc6)cc5c34)n2)cc1] | E139 |
| 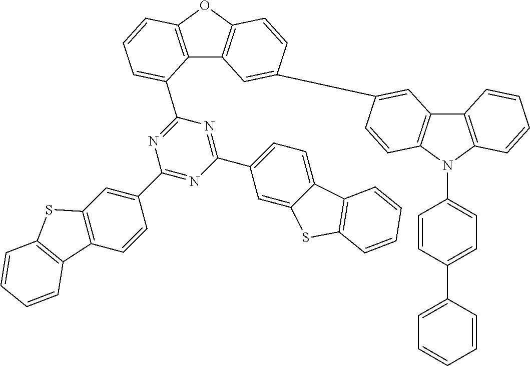 [SMILES: c1ccc(-c2ccc(-n3c4ccccc4c4cc(-c5ccc6oc7cccc(-c8nc(-c9ccc%10c(c9)sc9ccccc9%10)nc(-c9ccc%10c(c9)sc9ccccc9%10)n8)c7c6c5)ccc43)cc2)cc1] | E140 |
| 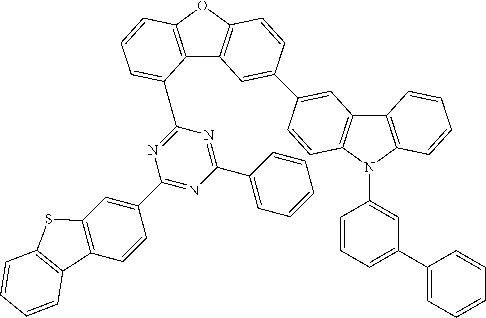 [SMILES: c1ccc(-c2cccc(-n3c4ccccc4c4cc(-c5ccc6oc7cccc(-c8nc(-c9ccccc9)nc(-c9ccc%10c(c9)sc9ccccc9%10)n8)c7c6c5)ccc43)c2)cc1] | E141 |
| 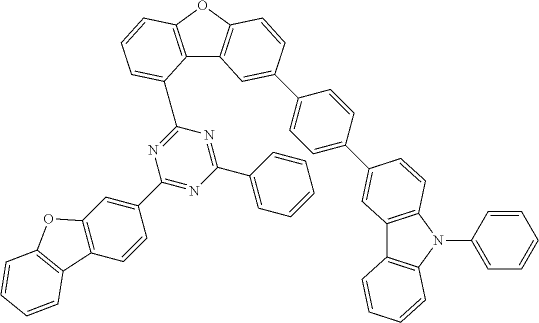 [SMILES: c1ccc(-c2nc(-c3ccc4c(c3)oc3ccccc34)nc(-c3cccc4oc5ccc(-c6ccc(-c7ccc8c(c7)c7ccccc7n8-c7ccccc7)cc6)cc5c34)n2)cc1] | E142 |
| 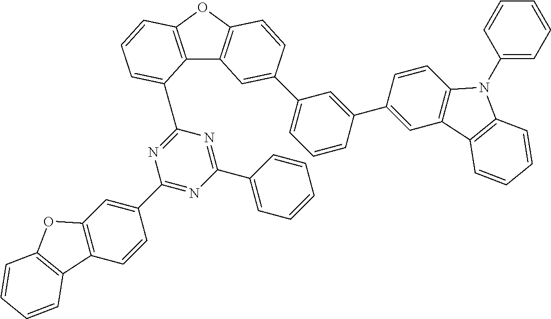 [SMILES: c1ccc(-c2nc(-c3ccc4c(c3)oc3ccccc34)nc(-c3cccc4oc5ccc(-c6cccc(-c7ccc8c(c7)c7ccccc7n8-c7ccccc7)c6)cc5c34)n2)cc1] | E143 |
| 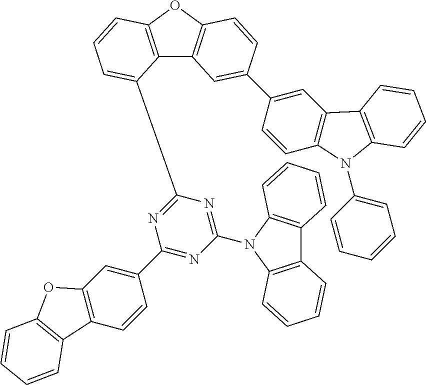 [SMILES: c1ccc(-n2c3ccccc3c3cc(-c4ccc5oc6cccc(-c7nc(-c8ccc9c(c8)oc8ccccc89)nc(-n8c9ccccc9c9ccccc98)n7)c6c5c4)ccc32)cc1] | E144 |
| 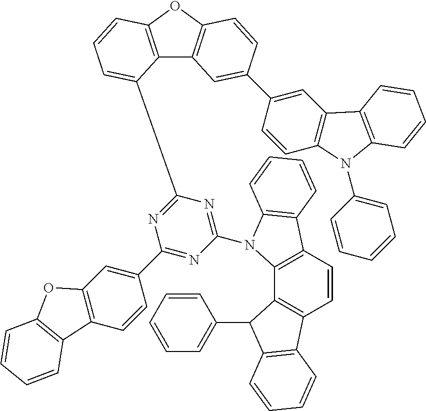 [SMILES: c1ccc(C2c3ccccc3-c3ccc4c5ccccc5n(-c5nc(-c6ccc7c(c6)oc6ccccc67)nc(-c6cccc7oc8ccc(-c9ccc%10c(c9)c9ccccc9n%10-c9ccccc9)cc8c67)n5)c4c32)cc1] | E145 |
| 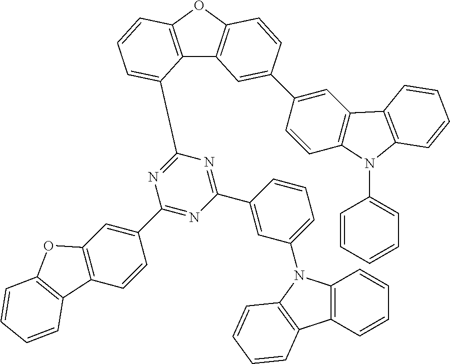 [SMILES: c1ccc(-n2c3ccccc3c3cc(-c4ccc5oc6cccc(-c7nc(-c8cccc(-n9c%10ccccc%10c%10ccccc%109)c8)nc(-c8ccc9c(c8)oc8ccccc89)n7)c6c5c4)ccc32)cc1] | E146 |
| 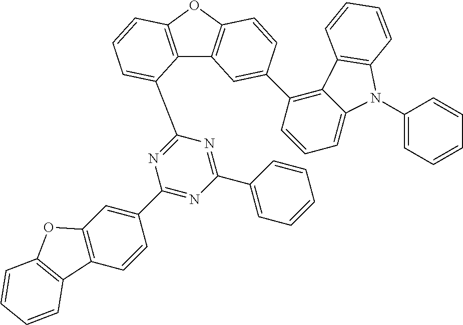 [SMILES: c1ccc(-c2nc(-c3ccc4c(c3)oc3ccccc34)nc(-c3cccc4oc5ccc(-c6cccc7c6c6ccccc6n7-c6ccccc6)cc5c34)n2)cc1] | E147 |
| 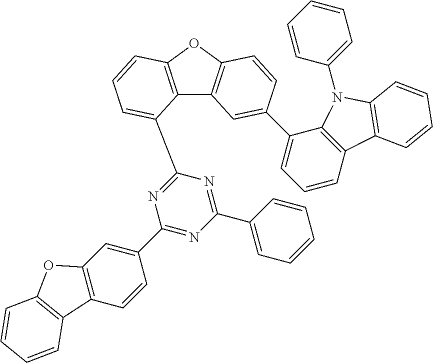 [SMILES: c1ccc(-c2nc(-c3ccc4c(c3)oc3ccccc34)nc(-c3cccc4oc5ccc(-c6cccc7c8ccccc8n(-c8ccccc8)c67)cc5c34)n2)cc1] | E148 |
| 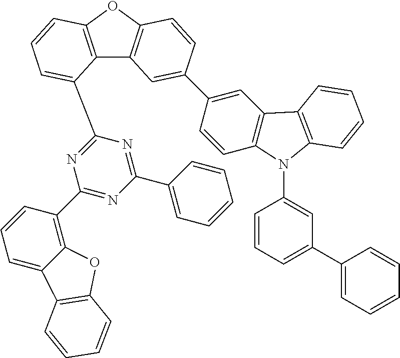 [SMILES: c1ccc(-c2cccc(-n3c4ccccc4c4cc(-c5ccc6oc7cccc(-c8nc(-c9ccccc9)nc(-c9cccc%10c9oc9ccccc9%10)n8)c7c6c5)ccc43)c2)cc1] | E149 |
| 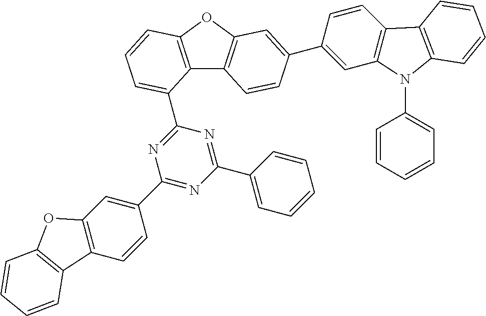 [SMILES: c1ccc(-c2nc(-c3ccc4c(c3)oc3ccccc34)nc(-c3cccc4oc5cc(-c6ccc7c8ccccc8n(-c8ccccc8)c7c6)ccc5c34)n2)cc1] | E150 |
| 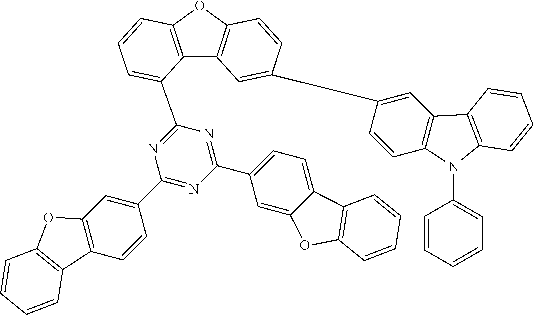 [SMILES: c1ccc(-n2c3ccccc3c3cc(-c4ccc5oc6cccc(-c7nc(-c8ccc9c(c8)oc8ccccc89)nc(-c8ccc9c(c8)oc8ccccc89)n7)c6c5c4)ccc32)cc1] | E151 |
| 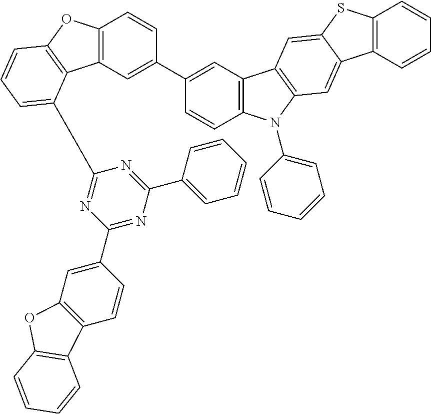 [SMILES: c1ccc(-c2nc(-c3ccc4c(c3)oc3ccccc34)nc(-c3cccc4oc5ccc(-c6ccc7c(c6)c6cc8sc9ccccc9c8cc6n7-c6ccccc6)cc5c34)n2)cc1] | E152 |
| 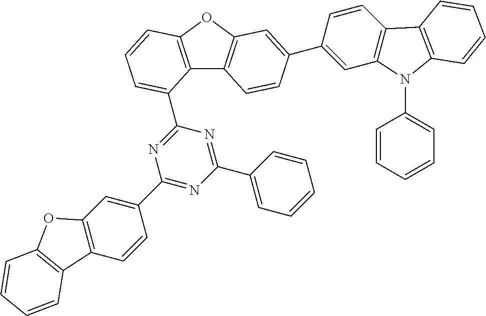 [SMILES: c1ccc(-c2nc(-c3ccc4c(c3)oc3ccccc34)nc(-c3cccc4oc5cc(-c6ccc7c8ccccc8n(-c8ccccc8)c7c6)ccc5c34)n2)cc1] | E153 |
| 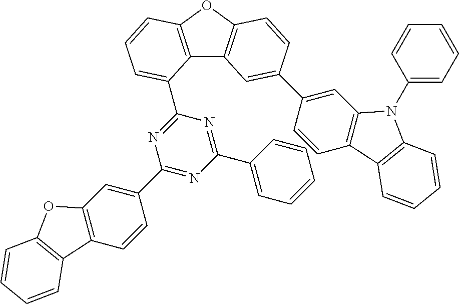 [SMILES: c1ccc(-c2nc(-c3ccc4c(c3)oc3ccccc34)nc(-c3cccc4oc5ccc(-c6ccc7c8ccccc8n(-c8ccccc8)c7c6)cc5c34)n2)cc1] | E154 |
| 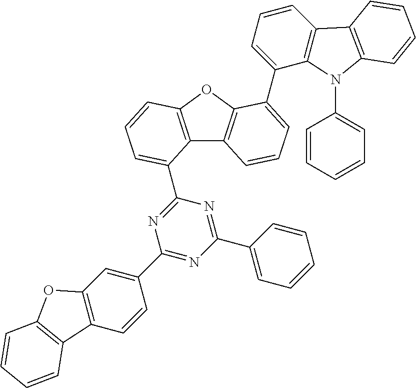 [SMILES: c1ccc(-c2nc(-c3ccc4c(c3)oc3ccccc34)nc(-c3cccc4oc5c(-c6cccc7c8ccccc8n(-c8ccccc8)c67)cccc5c34)n2)cc1] | E155 |
| 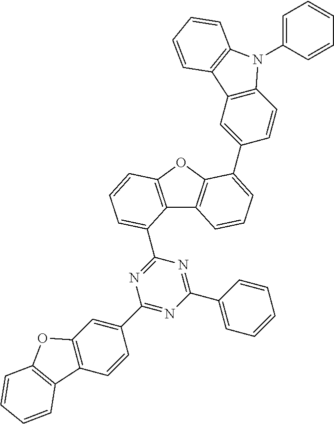 [SMILES: c1ccc(-c2nc(-c3ccc4c(c3)oc3ccccc34)nc(-c3cccc4oc5c(-c6ccc7c(c6)c6ccccc6n7-c6ccccc6)cccc5c34)n2)cc1] | E156 |
| 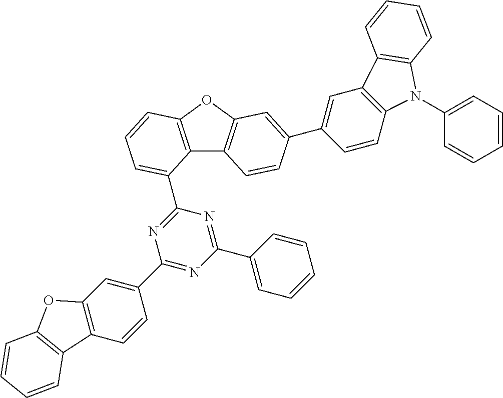 [SMILES: c1ccc(-c2nc(-c3ccc4c(c3)oc3ccccc34)nc(-c3cccc4oc5cc(-c6ccc7c(c6)c6ccccc6n7-c6ccccc6)ccc5c34)n2)cc1] | E157 |
| 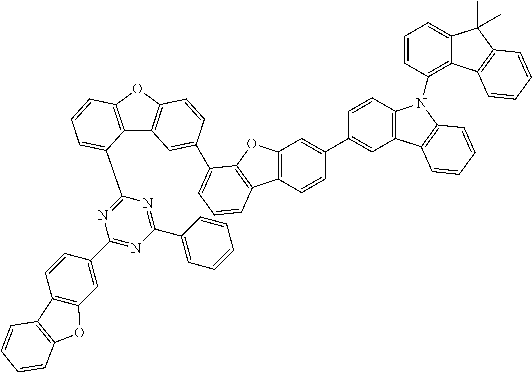 [SMILES: CC1(C)c2ccccc2-c2c(-n3c4ccccc4c4cc(-c5ccc6c(c5)oc5c(-c7ccc8oc9cccc(-c%10nc(-c%11ccccc%11)nc(-c%11ccc%12c(c%11)oc%11ccccc%11%12)n%10)c9c8c7)cccc56)ccc43)cccc21] | E158 |
| 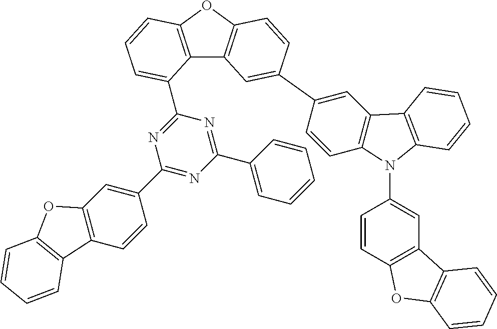 [SMILES: c1ccc(-c2nc(-c3ccc4c(c3)oc3ccccc34)nc(-c3cccc4oc5ccc(-c6ccc7c(c6)c6ccccc6n7-c6ccc7oc8ccccc8c7c6)cc5c34)n2)cc1] | E159 |
| 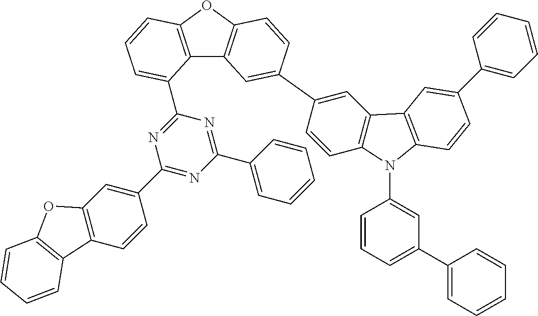 [SMILES: c1ccc(-c2cccc(-n3c4ccc(-c5ccccc5)cc4c4cc(-c5ccc6oc7cccc(-c8nc(-c9ccccc9)nc(-c9ccc%10c(c9)oc9ccccc9%10)n8)c7c6c5)ccc43)c2)cc1] | E160 |
| 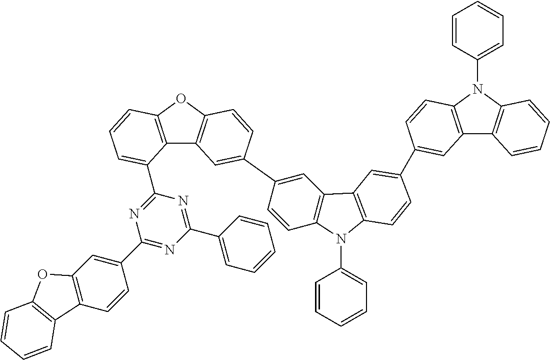 [SMILES: c1ccc(-c2nc(-c3ccc4c(c3)oc3ccccc34)nc(-c3cccc4oc5ccc(-c6ccc7c(c6)c6cc(-c8ccc9c(c8)c8ccccc8n9-c8ccccc8)ccc6n7-c6ccccc6)cc5c34)n2)cc1] | E161 |
| 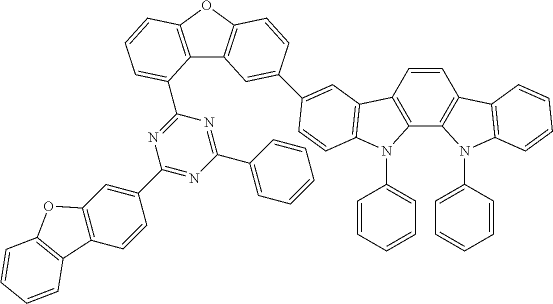 [SMILES: c1ccc(-c2nc(-c3ccc4c(c3)oc3ccccc34)nc(-c3cccc4oc5ccc(-c6ccc7c(c6)c6ccc8c9ccccc9n(-c9ccccc9)c8c6n7-c6ccccc6)cc5c34)n2)cc1] | E162 |
| 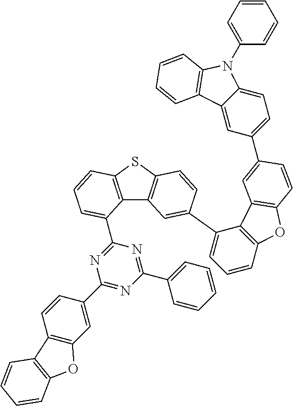 [SMILES: c1ccc(-c2nc(-c3ccc4c(c3)oc3ccccc34)nc(-c3cccc4sc5ccc(-c6cccc7oc8ccc(-c9ccc%10c(c9)c9ccccc9n%10-c9ccccc9)cc8c67)cc5c34)n2)cc1] | E163 |
| 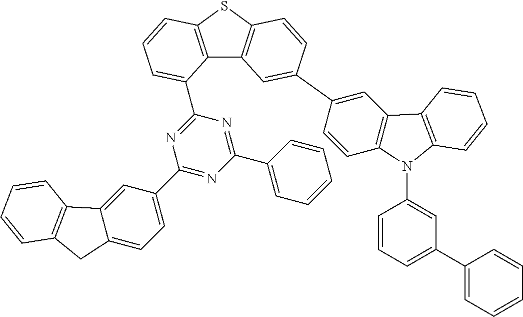 [SMILES: c1ccc(-c2cccc(-n3c4ccccc4c4cc(-c5ccc6sc7cccc(-c8nc(-c9ccccc9)nc(-c9ccc%10c(c9)-c9ccccc9C%10)n8)c7c6c5)ccc43)c2)cc1] | E164 |
| 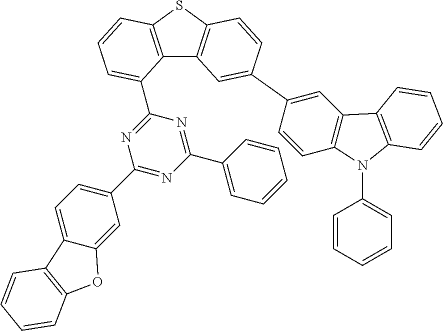 [SMILES: c1ccc(-c2nc(-c3ccc4c(c3)oc3ccccc34)nc(-c3cccc4sc5ccc(-c6ccc7c(c6)c6ccccc6n7-c6ccccc6)cc5c34)n2)cc1] | E165 |
| 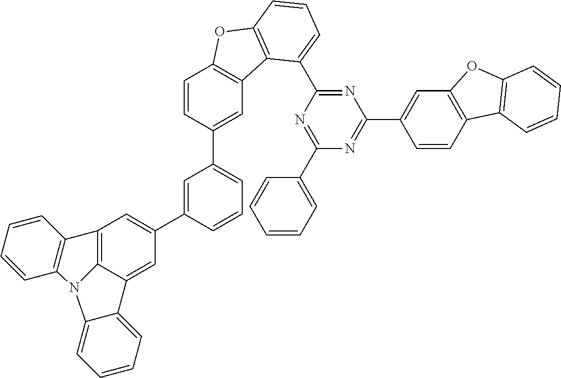 [SMILES: c1ccc(-c2nc(-c3ccc4c(c3)oc3ccccc34)nc(-c3cccc4oc5ccc(-c6cccc(-c7cc8c9ccccc9n9c%10ccccc%10c(c7)c89)c6)cc5c34)n2)cc1] | E166 |
| 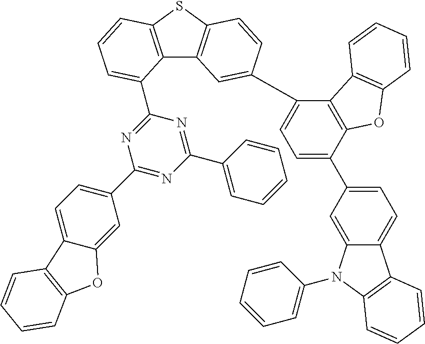 [SMILES: c1ccc(-c2nc(-c3ccc4c(c3)oc3ccccc34)nc(-c3cccc4sc5ccc(-c6ccc(-c7ccc8c9ccccc9n(-c9ccccc9)c8c7)c7oc8ccccc8c67)cc5c34)n2)cc1] | E167 |
| 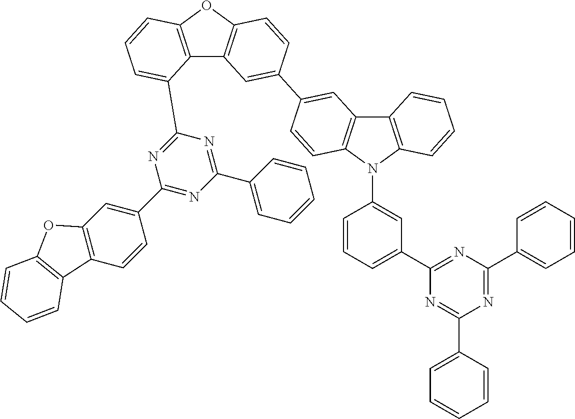 [SMILES: c1ccc(-c2nc(-c3ccccc3)nc(-c3cccc(-n4c5ccccc5c5cc(-c6ccc7oc8cccc(-c9nc(-c%10ccccc%10)nc(-c%10ccc%11c(c%10)oc%10ccccc%10%11)n9)c8c7c6)ccc54)c3)n2)cc1] | E168 |
| 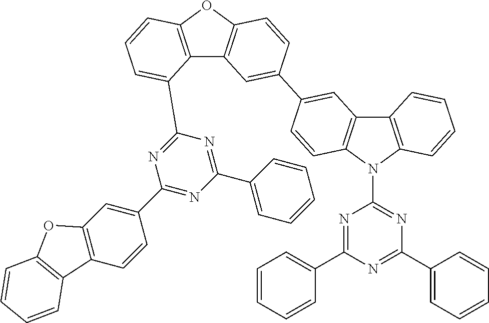 [SMILES: c1ccc(-c2nc(-c3ccc4c(c3)oc3ccccc34)nc(-c3cccc4oc5ccc(-c6ccc7c(c6)c6ccccc6n7-c6nc(-c7ccccc7)nc(-c7ccccc7)n6)cc5c34)n2)cc1] | E169 |
| 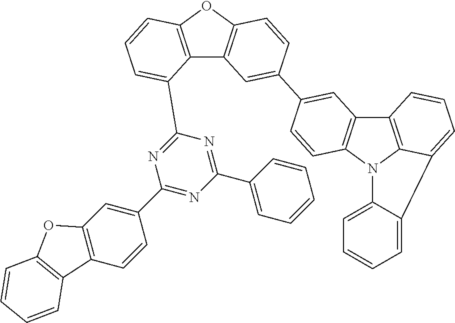 [SMILES: c1ccc(-c2nc(-c3ccc4c(c3)oc3ccccc34)nc(-c3cccc4oc5ccc(-c6ccc7c(c6)c6cccc8c9ccccc9n7c86)cc5c34)n2)cc1] | E170 |
| 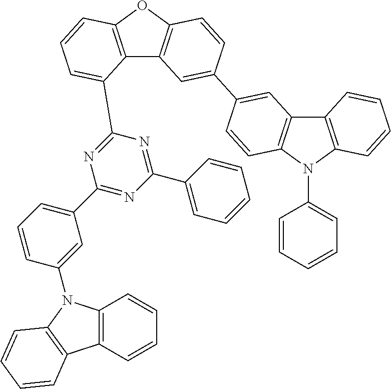 [SMILES: c1ccc(-c2nc(-c3cccc(-n4c5ccccc5c5ccccc54)c3)nc(-c3cccc4oc5ccc(-c6ccc7c(c6)c6ccccc6n7-c6ccccc6)cc5c34)n2)cc1] | E171 |
| 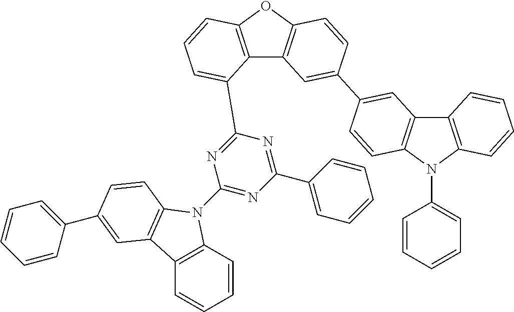 [SMILES: c1ccc(-c2ccc3c(c2)c2ccccc2n3-c2nc(-c3ccccc3)nc(-c3cccc4oc5ccc(-c6ccc7c(c6)c6ccccc6n7-c6ccccc6)cc5c34)n2)cc1] | E172 |
| 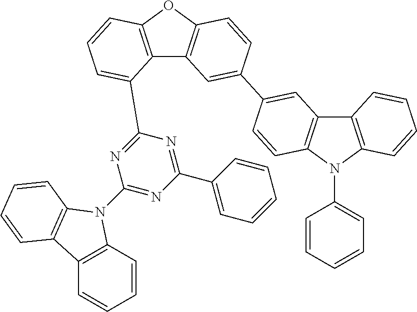 [SMILES: c1ccc(-c2nc(-c3cccc4oc5ccc(-c6ccc7c(c6)c6ccccc6n7-c6ccccc6)cc5c34)nc(-n3c4ccccc4c4ccccc43)n2)cc1] | E173 |
| 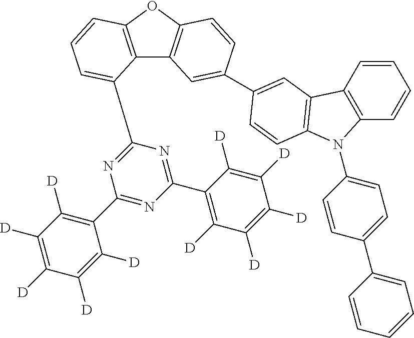 [SMILES: [2H]c1c([2H])c([2H])c(-c2nc(-c3c([2H])c([2H])c([2H])c([2H])c3[2H])nc(-c3cccc4oc5ccc(-c6ccc7c(c6)c6ccccc6n7-c6ccc(-c7ccccc7)cc6)cc5c34)n2)c([2H])c1[2H]] | E174 |
| 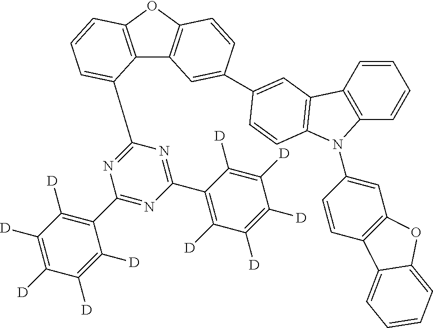 [SMILES: [2H]c1c([2H])c([2H])c(-c2nc(-c3c([2H])c([2H])c([2H])c([2H])c3[2H])nc(-c3cccc4oc5ccc(-c6ccc7c(c6)c6ccccc6n7-c6ccc7c(c6)oc6ccccc67)cc5c34)n2)c([2H])c1[2H]] | E175 |
| 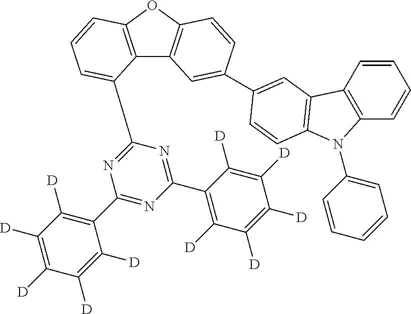 [SMILES: [2H]c1c([2H])c([2H])c(-c2nc(-c3c([2H])c([2H])c([2H])c([2H])c3[2H])nc(-c3cccc4oc5ccc(-c6ccc7c(c6)c6ccccc6n7-c6ccccc6)cc5c34)n2)c([2H])c1[2H]] | E176 |
| 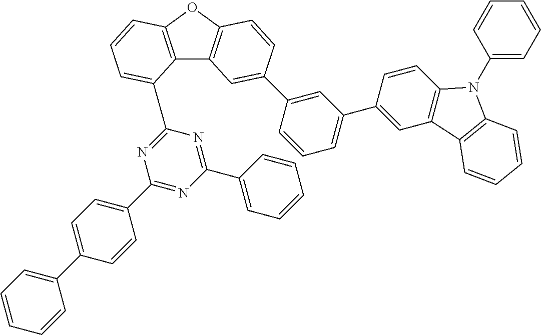 [SMILES: c1ccc(-c2ccc(-c3nc(-c4ccccc4)nc(-c4cccc5oc6ccc(-c7cccc(-c8ccc9c(c8)c8ccccc8n9-c8ccccc8)c7)cc6c45)n3)cc2)cc1] | E177 |
| 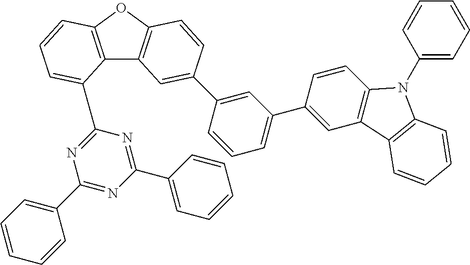 [SMILES: c1ccc(-c2nc(-c3ccccc3)nc(-c3cccc4oc5ccc(-c6cccc(-c7ccc8c(c7)c7ccccc7n8-c7ccccc7)c6)cc5c34)n2)cc1] | E178 |
| 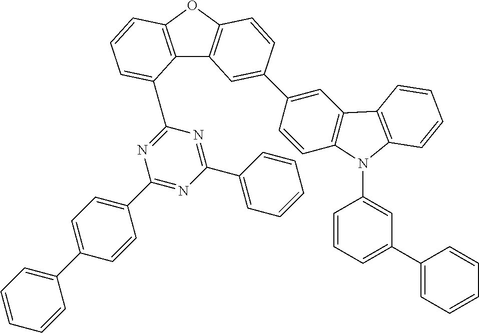 [SMILES: c1ccc(-c2ccc(-c3nc(-c4ccccc4)nc(-c4cccc5oc6ccc(-c7ccc8c(c7)c7ccccc7n8-c7cccc(-c8ccccc8)c7)cc6c45)n3)cc2)cc1] | E179 |
| 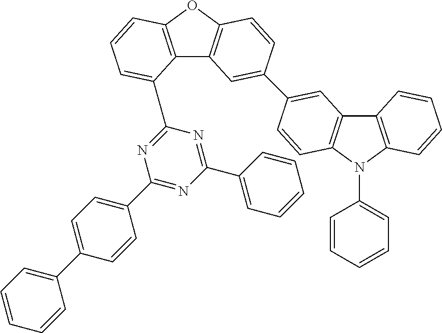 [SMILES: c1ccc(-c2ccc(-c3nc(-c4ccccc4)nc(-c4cccc5oc6ccc(-c7ccc8c(c7)c7ccccc7n8-c7ccccc7)cc6c45)n3)cc2)cc1] | E180 |
| 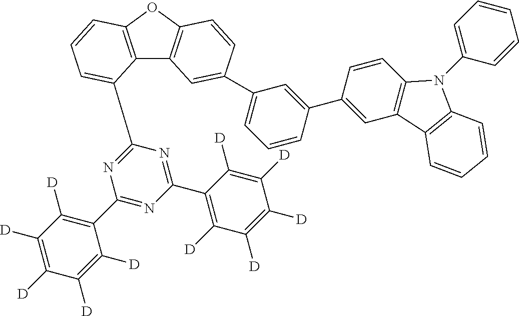 [SMILES: [2H]c1c([2H])c([2H])c(-c2nc(-c3c([2H])c([2H])c([2H])c([2H])c3[2H])nc(-c3cccc4oc5ccc(-c6cccc(-c7ccc8c(c7)c7ccccc7n8-c7ccccc7)c6)cc5c34)n2)c([2H])c1[2H]] | E181 |
| 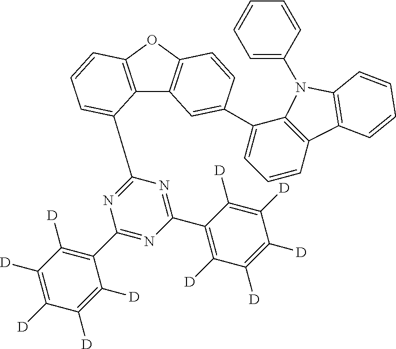 [SMILES: [2H]c1c([2H])c([2H])c(-c2nc(-c3c([2H])c([2H])c([2H])c([2H])c3[2H])nc(-c3cccc4oc5ccc(-c6cccc7c8ccccc8n(-c8ccccc8)c67)cc5c34)n2)c([2H])c1[2H]] | E182 |
| 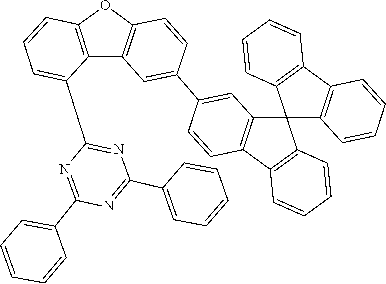 [SMILES: c1ccc(-c2nc(-c3ccccc3)nc(-c3cccc4oc5ccc(-c6ccc7c(c6)C6(c8ccccc8-c8ccccc86)c6ccccc6-7)cc5c34)n2)cc1] | E183 |
| 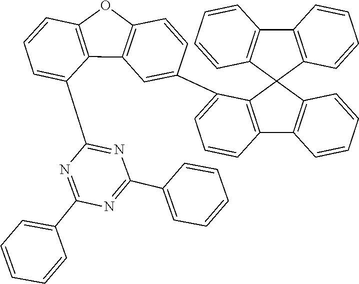 [SMILES: c1ccc(-c2nc(-c3ccccc3)nc(-c3cccc4oc5ccc(-c6cccc7c6C6(c8ccccc8-c8ccccc86)c6ccccc6-7)cc5c34)n2)cc1] | E184 |
| 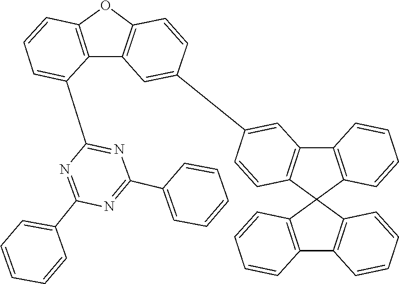 [SMILES: c1ccc(-c2nc(-c3ccccc3)nc(-c3cccc4oc5ccc(-c6ccc7c(c6)-c6ccccc6C76c7ccccc7-c7ccccc76)cc5c34)n2)cc1] | E185 |
| 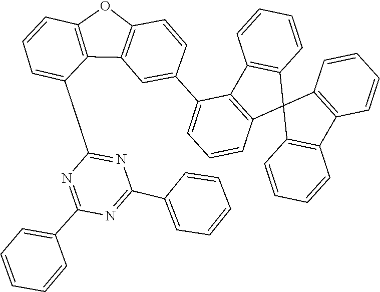 [SMILES: c1ccc(-c2nc(-c3ccccc3)nc(-c3cccc4oc5ccc(-c6cccc7c6-c6ccccc6C76c7ccccc7-c7ccccc76)cc5c34)n2)cc1] | E186 |
| 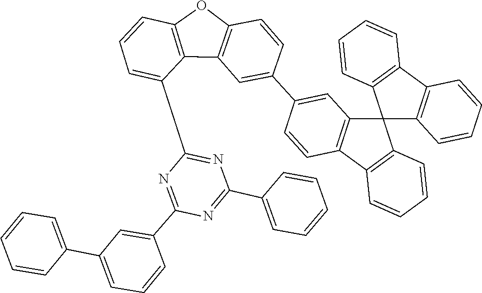 [SMILES: c1ccc(-c2cccc(-c3nc(-c4ccccc4)nc(-c4cccc5oc6ccc(-c7ccc8c(c7)C7(c9ccccc9-c9ccccc97)c7ccccc7-8)cc6c45)n3)c2)cc1] | E187 |
| 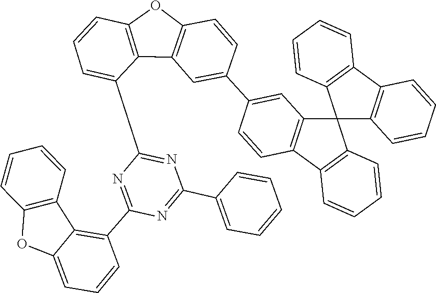 [SMILES: c1ccc(-c2nc(-c3cccc4oc5ccccc5c34)nc(-c3cccc4oc5ccc(-c6ccc7c(c6)C6(c8ccccc8-c8ccccc86)c6ccccc6-7)cc5c34)n2)cc1] | E188 |
| 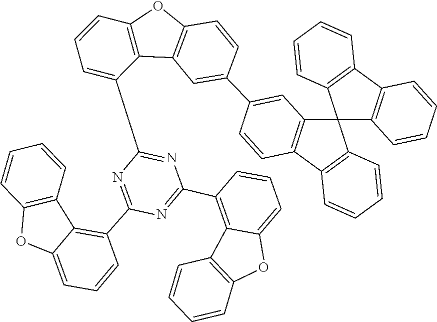 [SMILES: c1ccc2c(c1)-c1ccccc1C21c2ccccc2-c2ccc(-c3ccc4oc5cccc(-c6nc(-c7cccc8oc9ccccc9c78)nc(-c7cccc8oc9ccccc9c78)n6)c5c4c3)cc21] | E189 |
| 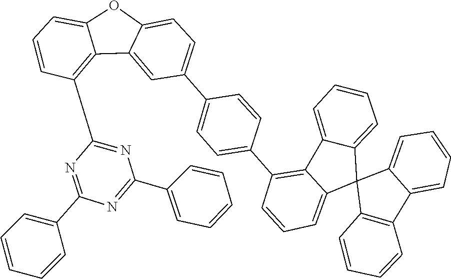 [SMILES: c1ccc(-c2nc(-c3ccccc3)nc(-c3cccc4oc5ccc(-c6ccc(-c7cccc8c7-c7ccccc7C87c8ccccc8-c8ccccc87)cc6)cc5c34)n2)cc1] | E190 |
| 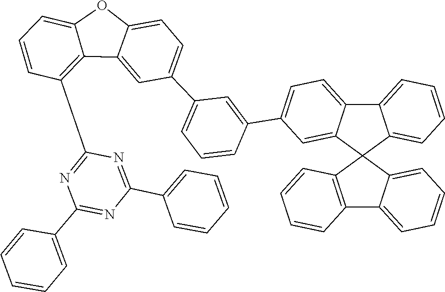 [SMILES: c1ccc(-c2nc(-c3ccccc3)nc(-c3cccc4oc5ccc(-c6cccc(-c7ccc8c(c7)C7(c9ccccc9-c9ccccc97)c7ccccc7-8)c6)cc5c34)n2)cc1] | E191 |
| 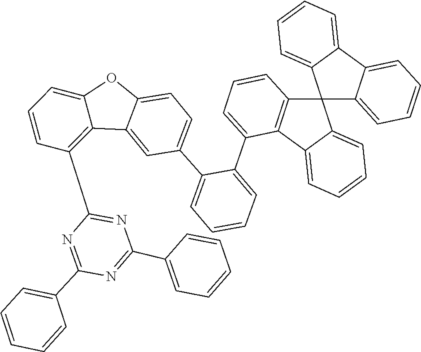 [SMILES: c1ccc(-c2nc(-c3ccccc3)nc(-c3cccc4oc5ccc(-c6ccccc6-c6cccc7c6-c6ccccc6C76c7ccccc7-c7ccccc76)cc5c34)n2)cc1] | E192 |
| 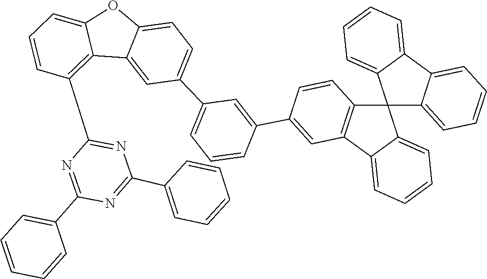 [SMILES: c1ccc(-c2nc(-c3ccccc3)nc(-c3cccc4oc5ccc(-c6cccc(-c7ccc8c(c7)-c7ccccc7C87c8ccccc8-c8ccccc87)c6)cc5c34)n2)cc1] | E193 |
| 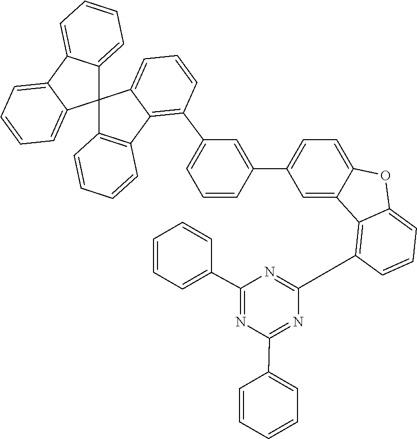 [SMILES: c1ccc(-c2nc(-c3ccccc3)nc(-c3cccc4oc5ccc(-c6cccc(-c7cccc8c7-c7ccccc7C87c8ccccc8-c8ccccc87)c6)cc5c34)n2)cc1] | E194 |
| 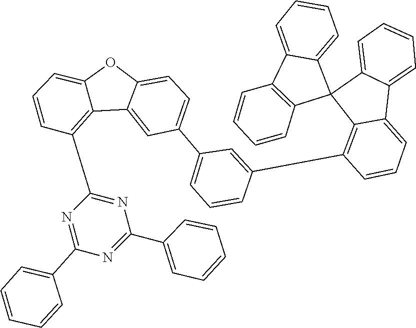 [SMILES: c1ccc(-c2nc(-c3ccccc3)nc(-c3cccc4oc5ccc(-c6cccc(-c7cccc8c7C7(c9ccccc9-c9ccccc97)c7ccccc7-8)c6)cc5c34)n2)cc1] | E195 |
| 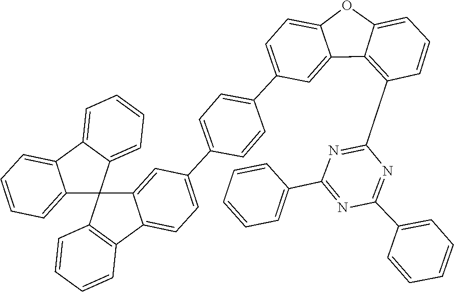 [SMILES: c1ccc(-c2nc(-c3ccccc3)nc(-c3cccc4oc5ccc(-c6ccc(-c7ccc8c(c7)C7(c9ccccc9-c9ccccc97)c7ccccc7-8)cc6)cc5c34)n2)cc1] | E196 |
| 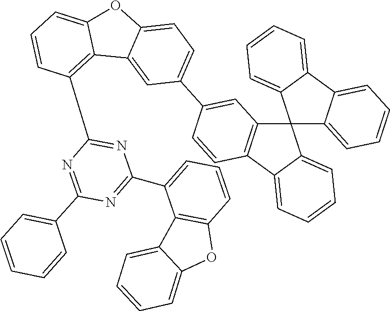 [SMILES: c1ccc(-c2nc(-c3cccc4oc5ccccc5c34)nc(-c3cccc4oc5ccc(-c6ccc7c(c6)C6(c8ccccc8-c8ccccc86)c6ccccc6-7)cc5c34)n2)cc1] | E197 |
| 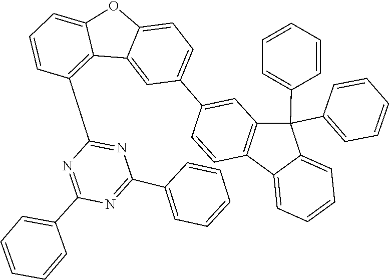 [SMILES: c1ccc(-c2nc(-c3ccccc3)nc(-c3cccc4oc5ccc(-c6ccc7c(c6)C(c6ccccc6)(c6ccccc6)c6ccccc6-7)cc5c34)n2)cc1] | E198 |
| 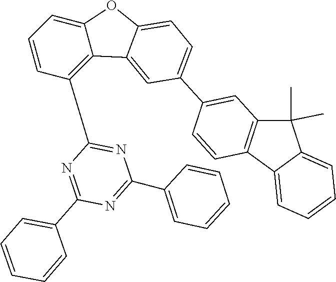 [SMILES: CC1(C)c2ccccc2-c2ccc(-c3ccc4oc5cccc(-c6nc(-c7ccccc7)nc(-c7ccccc7)n6)c5c4c3)cc21] | E199 |
| 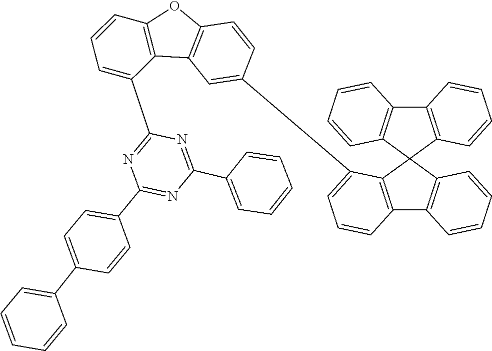 [SMILES: c1ccc(-c2ccc(-c3nc(-c4ccccc4)nc(-c4cccc5oc6ccc(-c7cccc8c7C7(c9ccccc9-c9ccccc97)c7ccccc7-8)cc6c45)n3)cc2)cc1] | E200 |
| 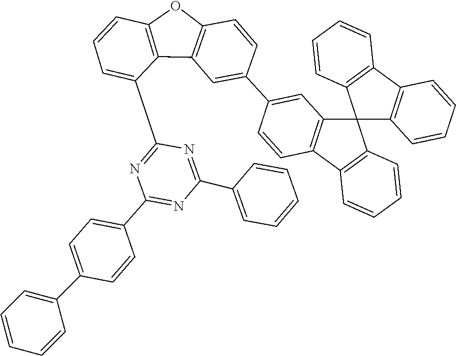 [SMILES: c1ccc(-c2ccc(-c3nc(-c4ccccc4)nc(-c4cccc5oc6ccc(-c7ccc8c(c7)C7(c9ccccc9-c9ccccc97)c7ccccc7-8)cc6c45)n3)cc2)cc1] | E201 |
| 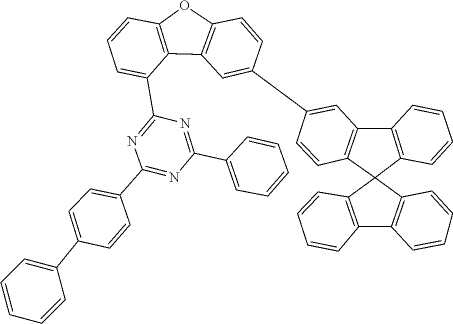 [SMILES: c1ccc(-c2ccc(-c3nc(-c4ccccc4)nc(-c4cccc5oc6ccc(-c7ccc8c(c7)-c7ccccc7C87c8ccccc8-c8ccccc87)cc6c45)n3)cc2)cc1] | E202 |
| 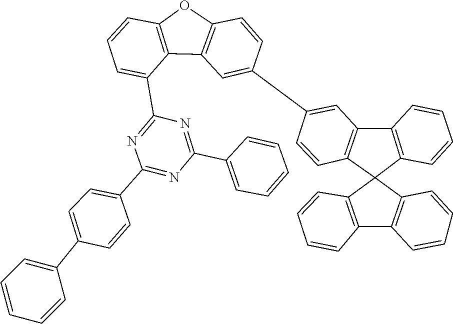 [SMILES: c1ccc(-c2ccc(-c3nc(-c4ccccc4)nc(-c4cccc5oc6ccc(-c7ccc8c(c7)-c7ccccc7C87c8ccccc8-c8ccccc87)cc6c45)n3)cc2)cc1] | E203 |
| 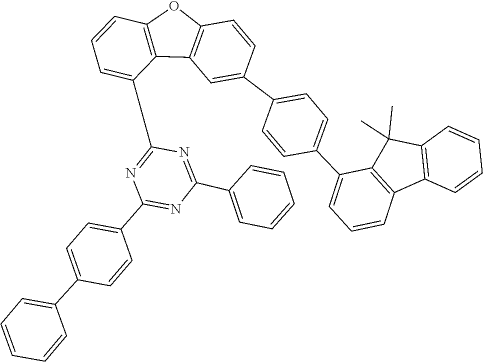 [SMILES: CC1(C)c2ccccc2-c2cccc(-c3ccc(-c4ccc5oc6cccc(-c7nc(-c8ccccc8)nc(-c8ccc(-c9ccccc9)cc8)n7)c6c5c4)cc3)c21] | E204 |
| 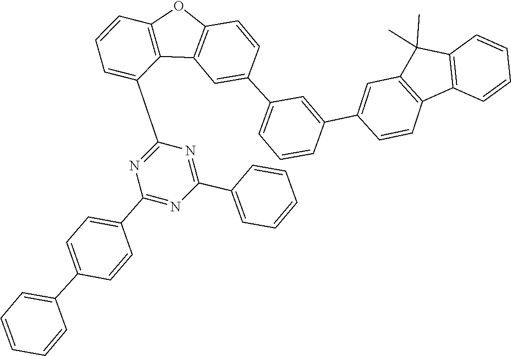 [SMILES: CC1(C)c2ccccc2-c2ccc(-c3cccc(-c4ccc5oc6cccc(-c7nc(-c8ccccc8)nc(-c8ccc(-c9ccccc9)cc8)n7)c6c5c4)c3)cc21] | E205 |
| 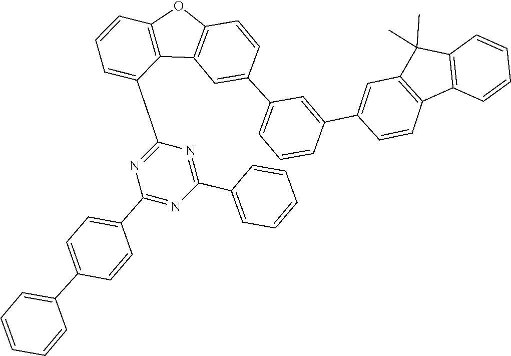 [SMILES: CC1(C)c2ccccc2-c2ccc(-c3cccc(-c4ccc5oc6cccc(-c7nc(-c8ccccc8)nc(-c8ccc(-c9ccccc9)cc8)n7)c6c5c4)c3)cc21] | E206 |
| 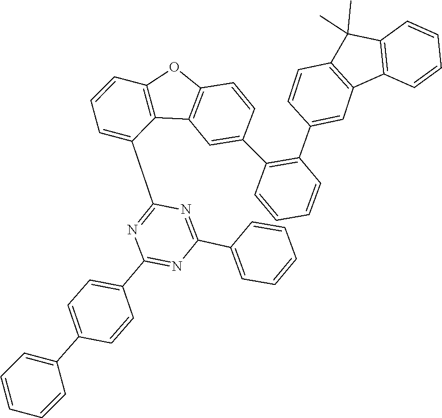 [SMILES: CC1(C)c2ccccc2-c2cc(-c3ccccc3-c3ccc4oc5cccc(-c6nc(-c7ccccc7)nc(-c7ccc(-c8ccccc8)cc7)n6)c5c4c3)ccc21] | E207 |
| 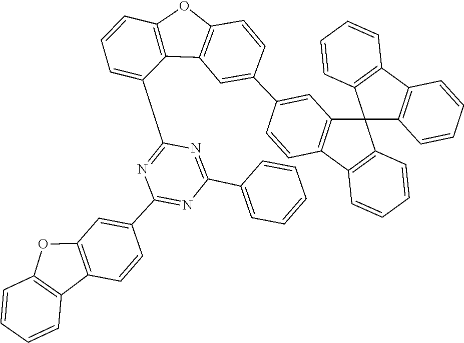 [SMILES: c1ccc(-c2nc(-c3ccc4c(c3)oc3ccccc34)nc(-c3cccc4oc5ccc(-c6ccc7c(c6)C6(c8ccccc8-c8ccccc86)c6ccccc6-7)cc5c34)n2)cc1] | E208 |
| 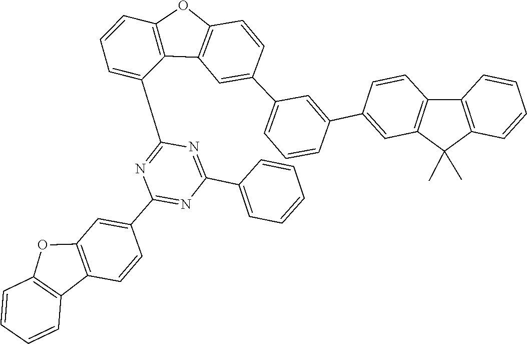 [SMILES: CC1(C)c2ccccc2-c2ccc(-c3cccc(-c4ccc5oc6cccc(-c7nc(-c8ccccc8)nc(-c8ccc9c(c8)oc8ccccc89)n7)c6c5c4)c3)cc21] | E209 |
| 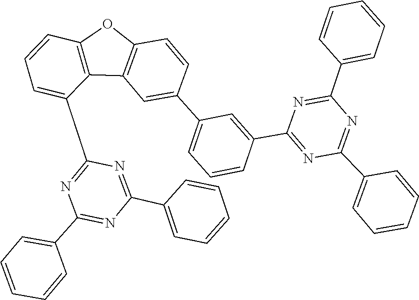 [SMILES: c1ccc(-c2nc(-c3ccccc3)nc(-c3cccc(-c4ccc5oc6cccc(-c7nc(-c8ccccc8)nc(-c8ccccc8)n7)c6c5c4)c3)n2)cc1] | E210 |
| 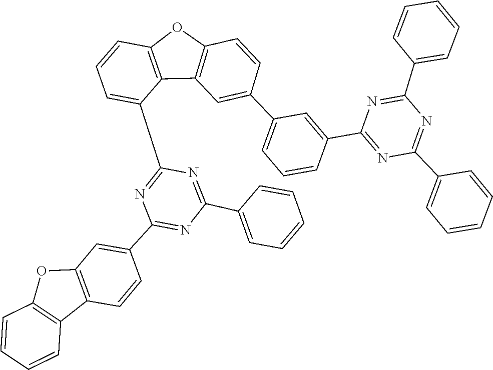 [SMILES: c1ccc(-c2nc(-c3ccccc3)nc(-c3cccc(-c4ccc5oc6cccc(-c7nc(-c8ccccc8)nc(-c8ccc9c(c8)oc8ccccc89)n7)c6c5c4)c3)n2)cc1] | E211 |
| 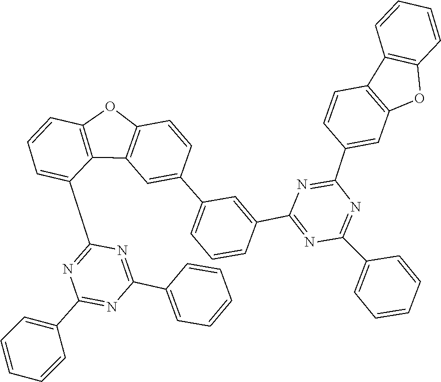 [SMILES: c1ccc(-c2nc(-c3cccc(-c4ccc5oc6cccc(-c7nc(-c8ccccc8)nc(-c8ccccc8)n7)c6c5c4)c3)nc(-c3ccc4c(c3)oc3ccccc34)n2)cc1] | E212 |
| 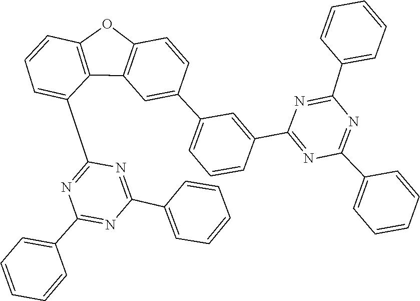 [SMILES: c1ccc(-c2nc(-c3ccccc3)nc(-c3cccc(-c4ccc5oc6cccc(-c7nc(-c8ccccc8)nc(-c8ccccc8)n7)c6c5c4)c3)n2)cc1] | E213 |
| 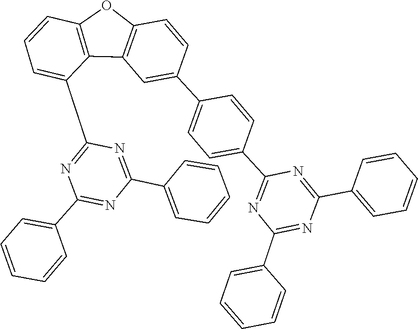 [SMILES: c1ccc(-c2nc(-c3ccccc3)nc(-c3ccc(-c4ccc5oc6cccc(-c7nc(-c8ccccc8)nc(-c8ccccc8)n7)c6c5c4)cc3)n2)cc1] | E214 |
| 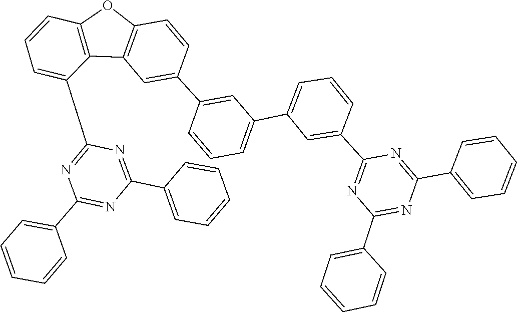 [SMILES: c1ccc(-c2nc(-c3ccccc3)nc(-c3cccc(-c4cccc(-c5ccc6oc7cccc(-c8nc(-c9ccccc9)nc(-c9ccccc9)n8)c7c6c5)c4)c3)n2)cc1] | E215 |
| 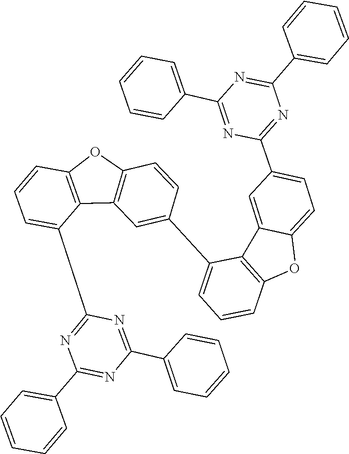 [SMILES: c1ccc(-c2nc(-c3ccccc3)nc(-c3ccc4oc5cccc(-c6ccc7oc8cccc(-c9nc(-c%10ccccc%10)nc(-c%10ccccc%10)n9)c8c7c6)c5c4c3)n2)cc1] | E216 |
| 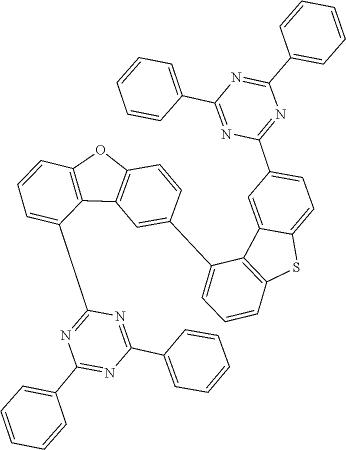 [SMILES: c1ccc(-c2nc(-c3ccccc3)nc(-c3ccc4sc5cccc(-c6ccc7oc8cccc(-c9nc(-c%10ccccc%10)nc(-c%10ccccc%10)n9)c8c7c6)c5c4c3)n2)cc1] | E217 |
| 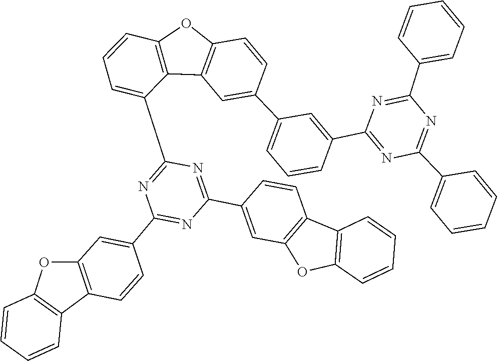 [SMILES: c1ccc(-c2nc(-c3ccccc3)nc(-c3cccc(-c4ccc5oc6cccc(-c7nc(-c8ccc9c(c8)oc8ccccc89)nc(-c8ccc9c(c8)oc8ccccc89)n7)c6c5c4)c3)n2)cc1] | E218 |
| 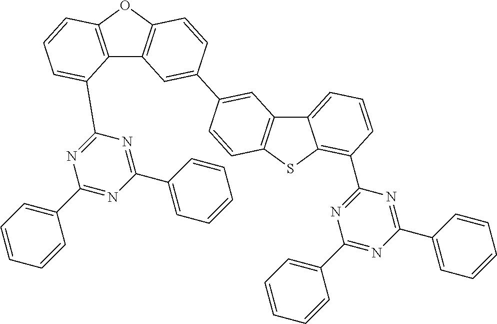 [SMILES: c1ccc(-c2nc(-c3ccccc3)nc(-c3cccc4c3sc3ccc(-c5ccc6oc7cccc(-c8nc(-c9ccccc9)nc(-c9ccccc9)n8)c7c6c5)cc34)n2)cc1] | E219 |
| 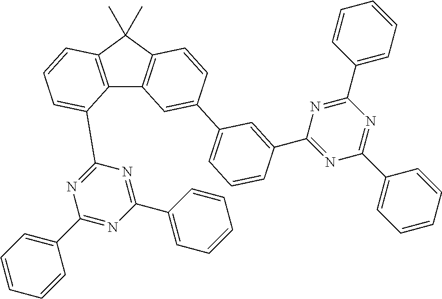 [SMILES: CC1(C)c2ccc(-c3cccc(-c4nc(-c5ccccc5)nc(-c5ccccc5)n4)c3)cc2-c2c(-c3nc(-c4ccccc4)nc(-c4ccccc4)n3)cccc21] | E220 |
| 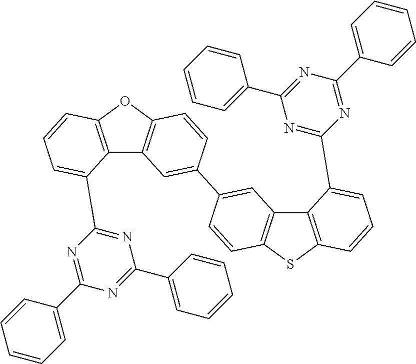 [SMILES: c1ccc(-c2nc(-c3ccccc3)nc(-c3cccc4oc5ccc(-c6ccc7sc8cccc(-c9nc(-c%10ccccc%10)nc(-c%10ccccc%10)n9)c8c7c6)cc5c34)n2)cc1] | E221 |
| 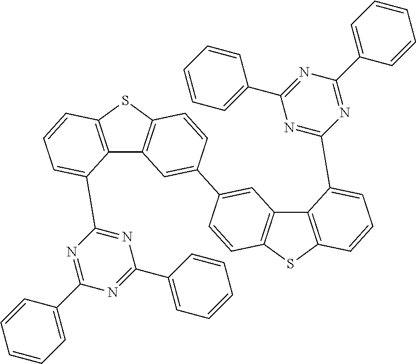 [SMILES: c1ccc(-c2nc(-c3ccccc3)nc(-c3cccc4sc5ccc(-c6ccc7sc8cccc(-c9nc(-c%10ccccc%10)nc(-c%10ccccc%10)n9)c8c7c6)cc5c34)n2)cc1] | E222 |
| 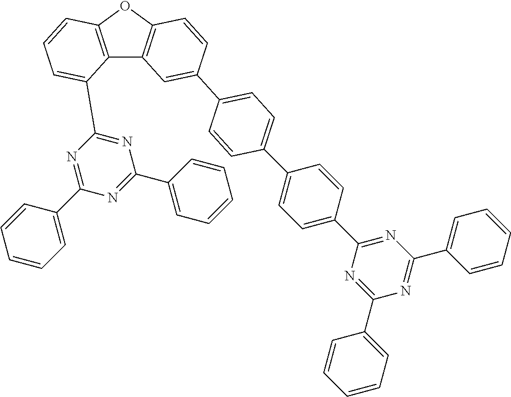 [SMILES: c1ccc(-c2nc(-c3ccccc3)nc(-c3ccc(-c4ccc(-c5ccc6oc7cccc(-c8nc(-c9ccccc9)nc(-c9ccccc9)n8)c7c6c5)cc4)cc3)n2)cc1] | E223 |
| 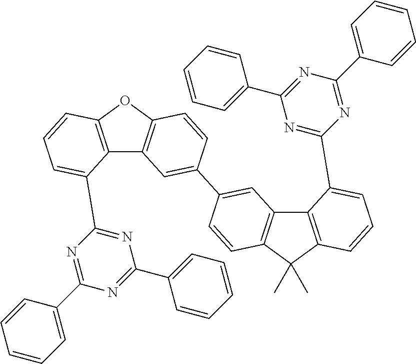 [SMILES: CC1(C)c2ccc(-c3ccc4oc5cccc(-c6nc(-c7ccccc7)nc(-c7ccccc7)n6)c5c4c3)cc2-c2c(-c3nc(-c4ccccc4)nc(-c4ccccc4)n3)cccc21] | E224 |
| 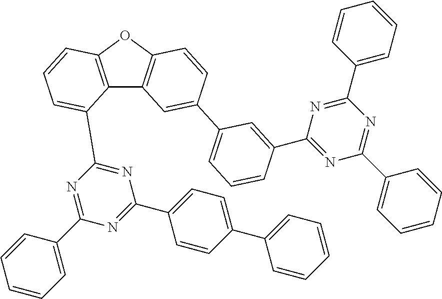 [SMILES: c1ccc(-c2ccc(-c3nc(-c4ccccc4)nc(-c4cccc5oc6ccc(-c7cccc(-c8nc(-c9ccccc9)nc(-c9ccccc9)n8)c7)cc6c45)n3)cc2)cc1] | E225 |
| 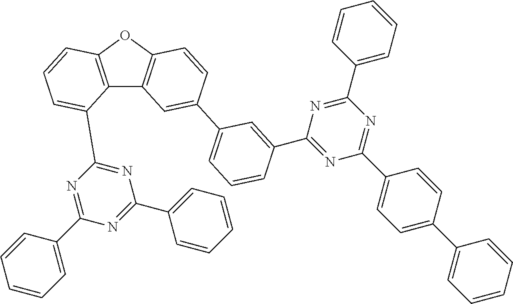 [SMILES: c1ccc(-c2ccc(-c3nc(-c4ccccc4)nc(-c4cccc(-c5ccc6oc7cccc(-c8nc(-c9ccccc9)nc(-c9ccccc9)n8)c7c6c5)c4)n3)cc2)cc1] | E226 |
| 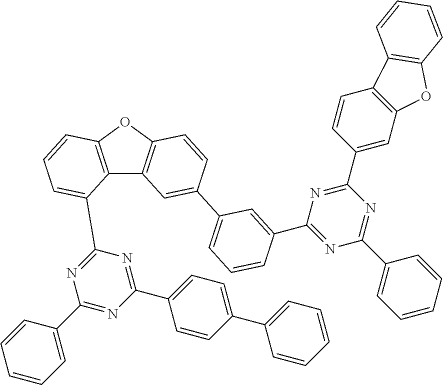 [SMILES: c1ccc(-c2ccc(-c3nc(-c4ccccc4)nc(-c4cccc5oc6ccc(-c7cccc(-c8nc(-c9ccccc9)nc(-c9ccc%10c(c9)oc9ccccc9%10)n8)c7)cc6c45)n3)cc2)cc1] | E227 |
| 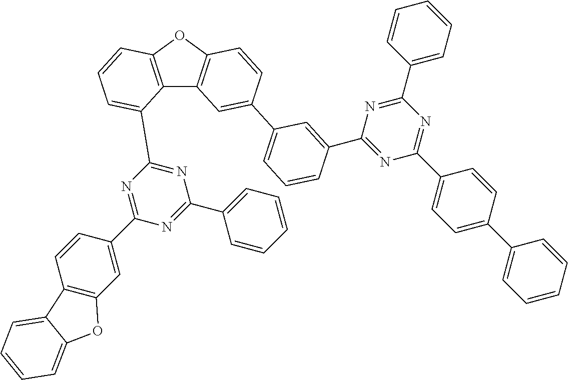 [SMILES: c1ccc(-c2ccc(-c3nc(-c4ccccc4)nc(-c4cccc(-c5ccc6oc7cccc(-c8nc(-c9ccccc9)nc(-c9ccc%10c(c9)oc9ccccc9%10)n8)c7c6c5)c4)n3)cc2)cc1] | E228 |
| 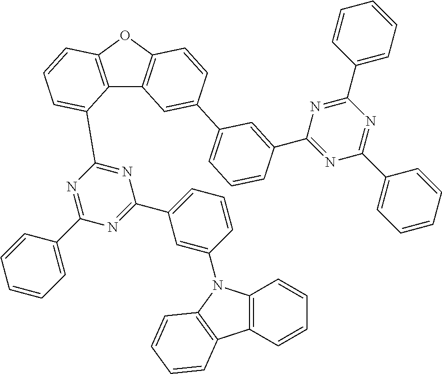 [SMILES: c1ccc(-c2nc(-c3ccccc3)nc(-c3cccc(-c4ccc5oc6cccc(-c7nc(-c8ccccc8)nc(-c8cccc(-n9c%10ccccc%10c%10ccccc%109)c8)n7)c6c5c4)c3)n2)cc1] | E229 |
| 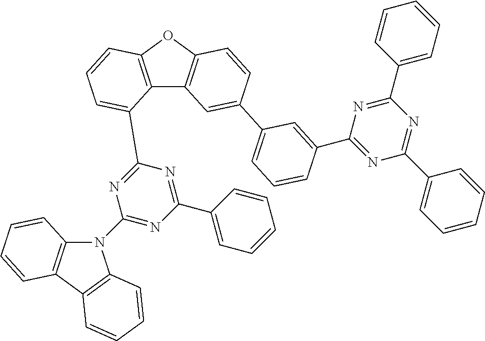 [SMILES: c1ccc(-c2nc(-c3ccccc3)nc(-c3cccc(-c4ccc5oc6cccc(-c7nc(-c8ccccc8)nc(-n8c9ccccc9c9ccccc98)n7)c6c5c4)c3)n2)cc1] | E230 |
| 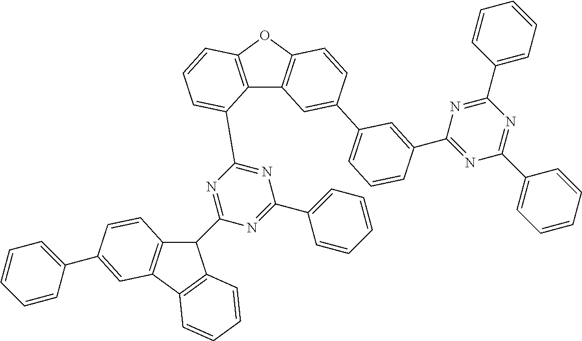 [SMILES: c1ccc(-c2ccc3c(c2)-c2ccccc2C3c2nc(-c3ccccc3)nc(-c3cccc4oc5ccc(-c6cccc(-c7nc(-c8ccccc8)nc(-c8ccccc8)n7)c6)cc5c34)n2)cc1] | E231 |
| 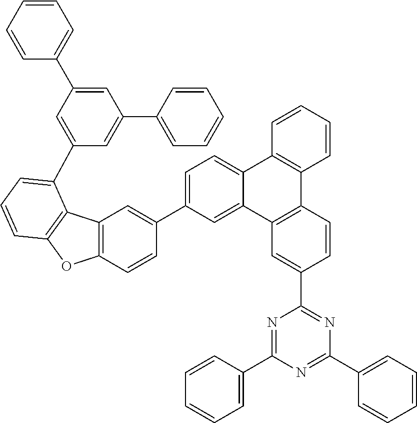 [SMILES: c1ccc(-c2cc(-c3ccccc3)cc(-c3cccc4oc5ccc(-c6ccc7c8ccccc8c8ccc(-c9nc(-c%10ccccc%10)nc(-c%10ccccc%10)n9)cc8c7c6)cc5c34)c2)cc1] | E232 |
| 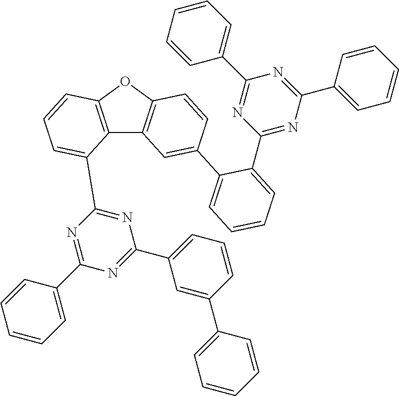 [SMILES: c1ccc(-c2cccc(-c3nc(-c4ccccc4)nc(-c4cccc5oc6ccc(-c7ccccc7-c7nc(-c8ccccc8)nc(-c8ccccc8)n7)cc6c45)n3)c2)cc1] | E233 |
| 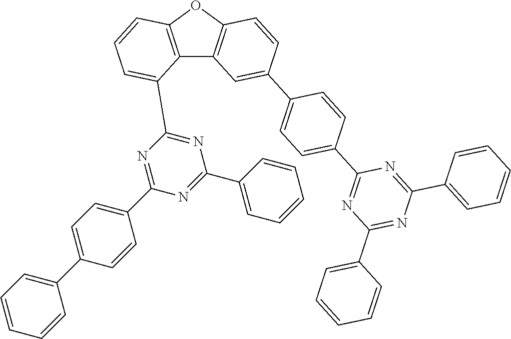 [SMILES: c1ccc(-c2ccc(-c3nc(-c4ccccc4)nc(-c4cccc5oc6ccc(-c7ccc(-c8nc(-c9ccccc9)nc(-c9ccccc9)n8)cc7)cc6c45)n3)cc2)cc1] | E234 |
| 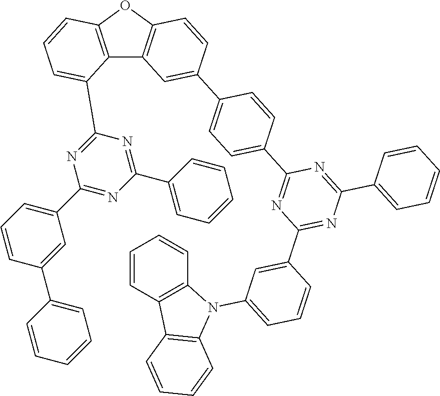 [SMILES: c1ccc(-c2cccc(-c3nc(-c4ccccc4)nc(-c4cccc5oc6ccc(-c7ccc(-c8nc(-c9ccccc9)nc(-c9cccc(-n%10c%11ccccc%11c%11ccccc%11%10)c9)n8)cc7)cc6c45)n3)c2)cc1] | E235 |
| 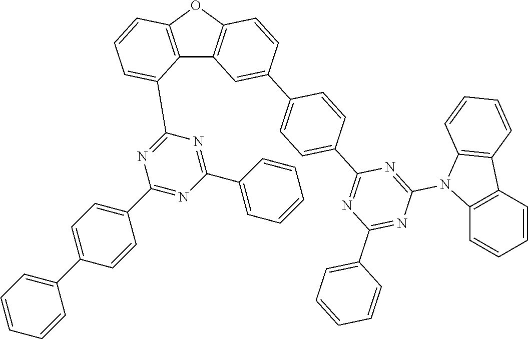 [SMILES: c1ccc(-c2ccc(-c3nc(-c4ccccc4)nc(-c4cccc5oc6ccc(-c7ccc(-c8nc(-c9ccccc9)nc(-n9c%10ccccc%10c%10ccccc%109)n8)cc7)cc6c45)n3)cc2)cc1] | E236 |
| 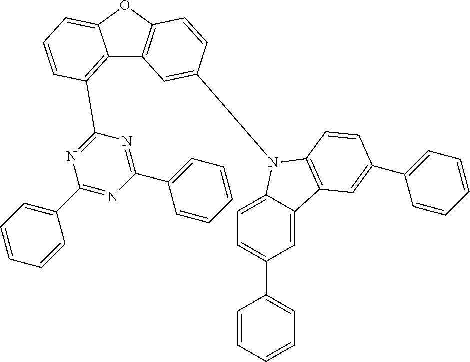 [SMILES: c1ccc(-c2ccc3c(c2)c2cc(-c4ccccc4)ccc2n3-c2ccc3oc4cccc(-c5nc(-c6ccccc6)nc(-c6ccccc6)n5)c4c3c2)cc1] | E237 |
| 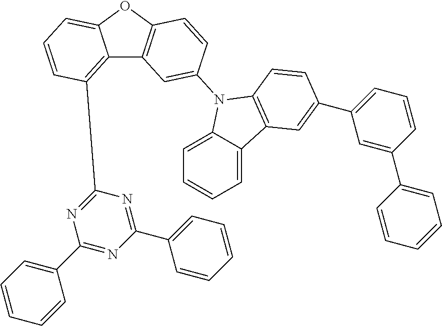 [SMILES: c1ccc(-c2cccc(-c3ccc4c(c3)c3ccccc3n4-c3ccc4oc5cccc(-c6nc(-c7ccccc7)nc(-c7ccccc7)n6)c5c4c3)c2)cc1] | E238 |
| 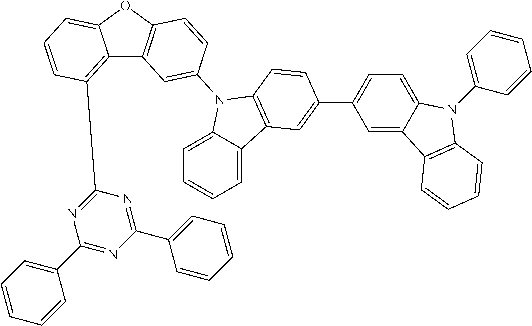 [SMILES: c1ccc(-c2nc(-c3ccccc3)nc(-c3cccc4oc5ccc(-n6c7ccccc7c7cc(-c8ccc9c(c8)c8ccccc8n9-c8ccccc8)ccc76)cc5c34)n2)cc1] | E239 |
| 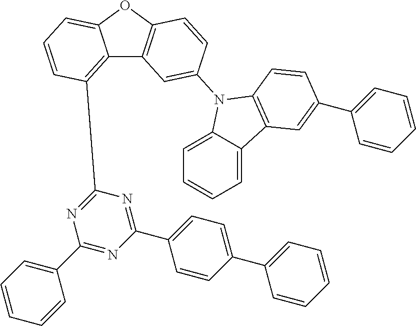 [SMILES: c1ccc(-c2ccc(-c3nc(-c4ccccc4)nc(-c4cccc5oc6ccc(-n7c8ccccc8c8cc(-c9ccccc9)ccc87)cc6c45)n3)cc2)cc1] | E240 |
| 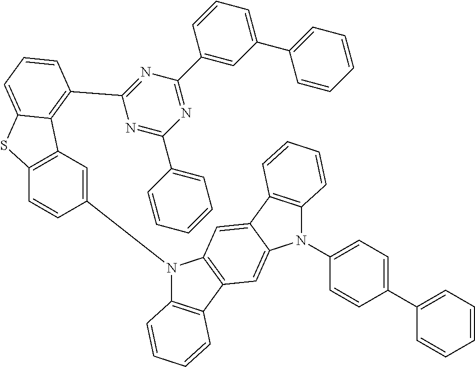 [SMILES: c1ccc(-c2ccc(-n3c4ccccc4c4cc5c(cc43)c3ccccc3n5-c3ccc4sc5cccc(-c6nc(-c7ccccc7)nc(-c7cccc(-c8ccccc8)c7)n6)c5c4c3)cc2)cc1] | E241 |
| 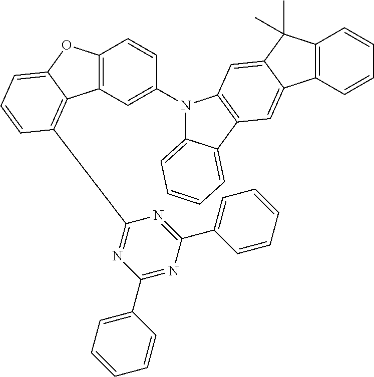 [SMILES: CC1(C)c2ccccc2-c2cc3c4ccccc4n(-c4ccc5oc6cccc(-c7nc(-c8ccccc8)nc(-c8ccccc8)n7)c6c5c4)c3cc21] | E242 |
| 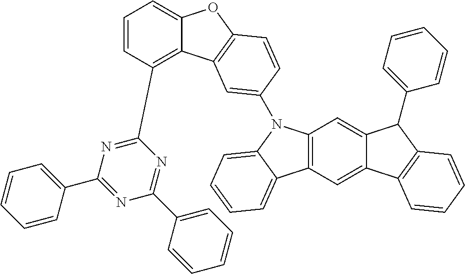 [SMILES: c1ccc(-c2nc(-c3ccccc3)nc(-c3cccc4oc5ccc(-n6c7ccccc7c7cc8c(cc76)C(c6ccccc6)c6ccccc6-8)cc5c34)n2)cc1] | E243 |
| 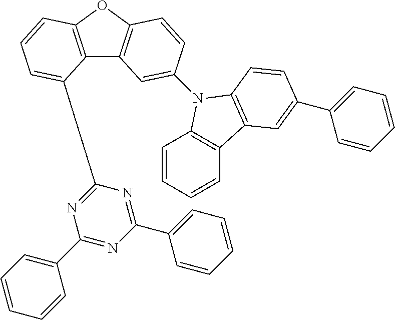 [SMILES: c1ccc(-c2ccc3c(c2)c2ccccc2n3-c2ccc3oc4cccc(-c5nc(-c6ccccc6)nc(-c6ccccc6)n5)c4c3c2)cc1] | E244 |
| 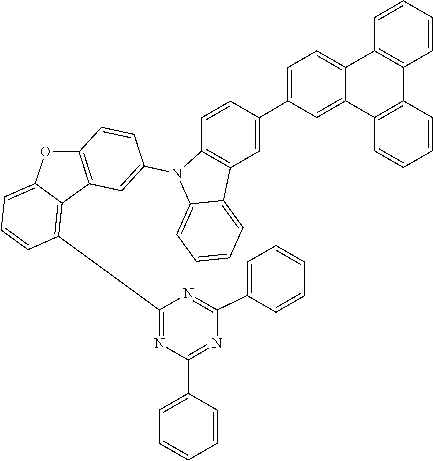 [SMILES: c1ccc(-c2nc(-c3ccccc3)nc(-c3cccc4oc5ccc(-n6c7ccccc7c7cc(-c8ccc9c%10ccccc%10c%10ccccc%10c9c8)ccc76)cc5c34)n2)cc1] | E245 |
| 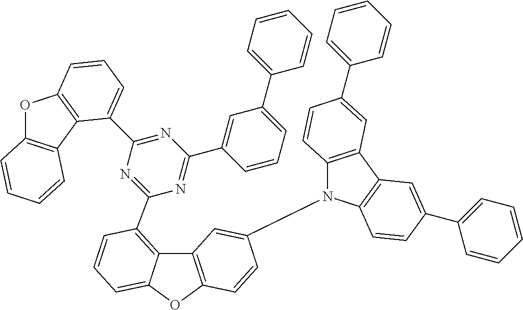 [SMILES: c1ccc(-c2cccc(-c3nc(-c4cccc5oc6ccccc6c45)nc(-c4cccc5oc6ccc(-n7c8ccc(-c9ccccc9)cc8c8cc(-c9ccccc9)ccc87)cc6c45)n3)c2)cc1] | E246 |
| 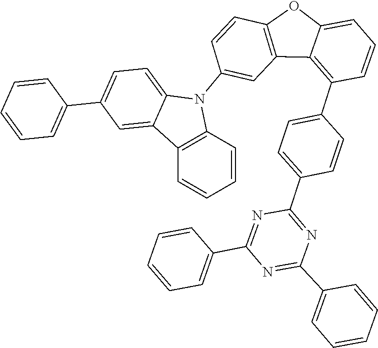 [SMILES: c1ccc(-c2ccc3c(c2)c2ccccc2n3-c2ccc3oc4cccc(-c5ccc(-c6nc(-c7ccccc7)nc(-c7ccccc7)n6)cc5)c4c3c2)cc1] | E247 |
| 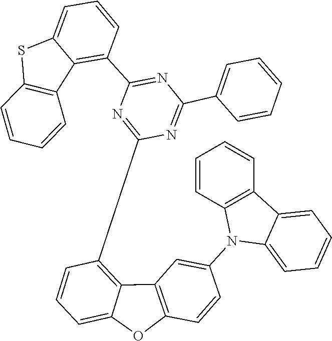 [SMILES: c1ccc(-c2nc(-c3cccc4oc5ccc(-n6c7ccccc7c7ccccc76)cc5c34)nc(-c3cccc4sc5ccccc5c34)n2)cc1] | E248 |
| 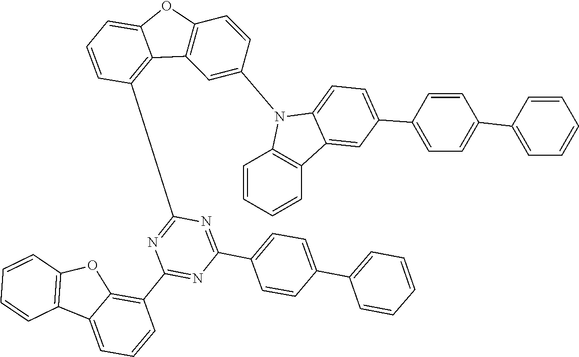 [SMILES: c1ccc(-c2ccc(-c3ccc4c(c3)c3ccccc3n4-c3ccc4oc5cccc(-c6nc(-c7ccc(-c8ccccc8)cc7)nc(-c7cccc8c7oc7ccccc78)n6)c5c4c3)cc2)cc1] | E249 |
| 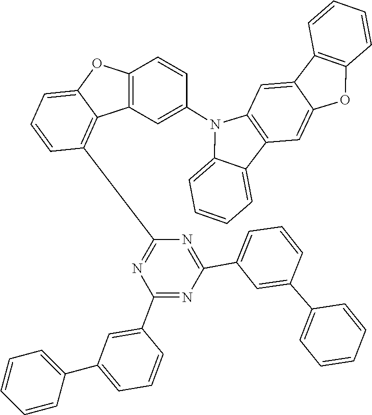 [SMILES: c1ccc(-c2cccc(-c3nc(-c4cccc(-c5ccccc5)c4)nc(-c4cccc5oc6ccc(-n7c8ccccc8c8cc9oc%10ccccc%10c9cc87)cc6c45)n3)c2)cc1] | E250 |
| 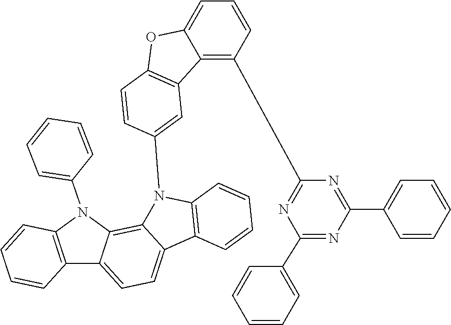 [SMILES: c1ccc(-c2nc(-c3ccccc3)nc(-c3cccc4oc5ccc(-n6c7ccccc7c7ccc8c9ccccc9n(-c9ccccc9)c8c76)cc5c34)n2)cc1] | E251 |
| 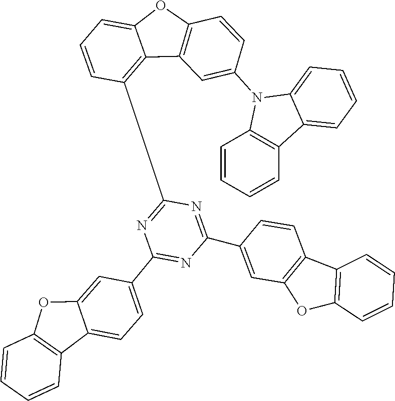 [SMILES: c1ccc2c(c1)oc1cc(-c3nc(-c4ccc5c(c4)oc4ccccc45)nc(-c4cccc5oc6ccc(-n7c8ccccc8c8ccccc87)cc6c45)n3)ccc12] | E252 |
| 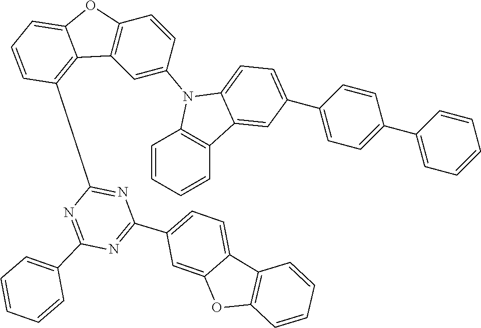 [SMILES: c1ccc(-c2ccc(-c3ccc4c(c3)c3ccccc3n4-c3ccc4oc5cccc(-c6nc(-c7ccccc7)nc(-c7ccc8c(c7)oc7ccccc78)n6)c5c4c3)cc2)cc1] | E253 |
| 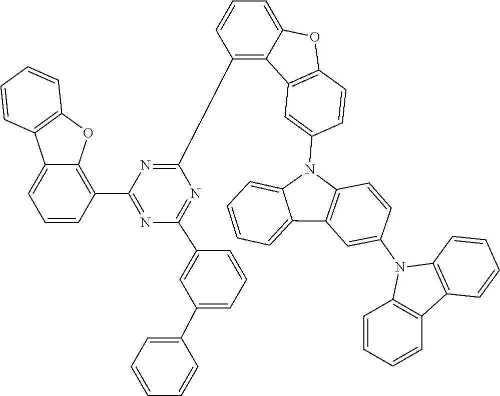 [SMILES: c1ccc(-c2cccc(-c3nc(-c4cccc5c4oc4ccccc45)nc(-c4cccc5oc6ccc(-n7c8ccccc8c8cc(-n9c%10ccccc%10c%10ccccc%109)ccc87)cc6c45)n3)c2)cc1] | E254 |
| 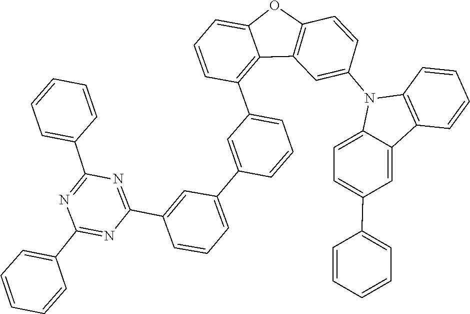 [SMILES: c1ccc(-c2ccc3c(c2)c2ccccc2n3-c2ccc3oc4cccc(-c5cccc(-c6cccc(-c7nc(-c8ccccc8)nc(-c8ccccc8)n7)c6)c5)c4c3c2)cc1] | E255 |
| 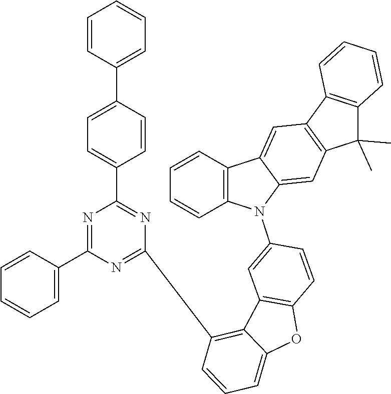 [SMILES: CC1(C)c2ccccc2-c2cc3c4ccccc4n(-c4ccc5oc6cccc(-c7nc(-c8ccccc8)nc(-c8ccc(-c9ccccc9)cc8)n7)c6c5c4)c3cc21] | E256 |
| 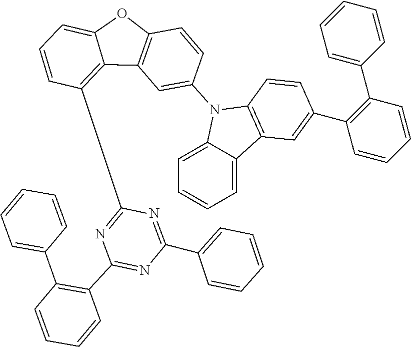 [SMILES: c1ccc(-c2nc(-c3ccccc3-c3ccccc3)nc(-c3cccc4oc5ccc(-n6c7ccccc7c7cc(-c8ccccc8-c8ccccc8)ccc76)cc5c34)n2)cc1] | E257 |
| 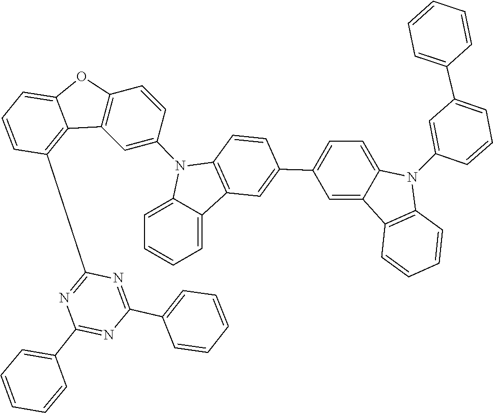 [SMILES: c1ccc(-c2cccc(-n3c4ccccc4c4cc(-c5ccc6c(c5)c5ccccc5n6-c5ccc6oc7cccc(-c8nc(-c9ccccc9)nc(-c9ccccc9)n8)c7c6c5)ccc43)c2)cc1] | E258 |
| 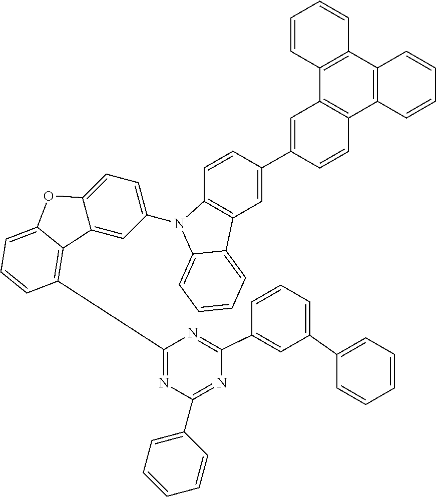 [SMILES: c1ccc(-c2cccc(-c3nc(-c4ccccc4)nc(-c4cccc5oc6ccc(-n7c8ccccc8c8cc(-c9ccc%10c%11ccccc%11c%11ccccc%11c%10c9)ccc87)cc6c45)n3)c2)cc1] | E259 |
| 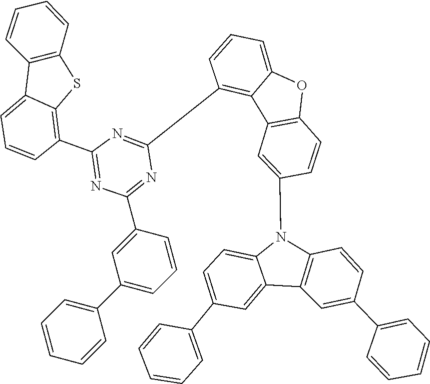 [SMILES: c1ccc(-c2cccc(-c3nc(-c4cccc5c4sc4ccccc45)nc(-c4cccc5oc6ccc(-n7c8ccc(-c9ccccc9)cc8c8cc(-c9ccccc9)ccc87)cc6c45)n3)c2)cc1] | E260 |
| 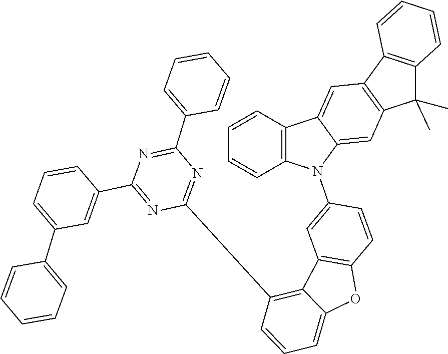 [SMILES: CC1(C)c2ccccc2-c2cc3c4ccccc4n(-c4ccc5oc6cccc(-c7nc(-c8ccccc8)nc(-c8cccc(-c9ccccc9)c8)n7)c6c5c4)c3cc21] | E261 |
| 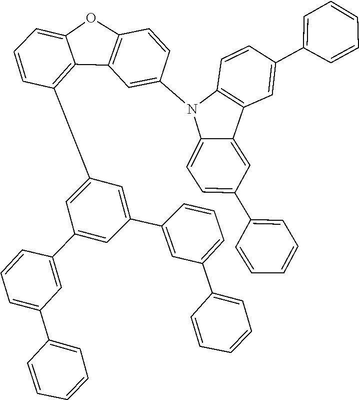 [SMILES: c1ccc(-c2cccc(-c3cc(-c4cccc(-c5ccccc5)c4)cc(-c4cccc5oc6ccc(-n7c8ccc(-c9ccccc9)cc8c8cc(-c9ccccc9)ccc87)cc6c45)c3)c2)cc1] | E262 |
| 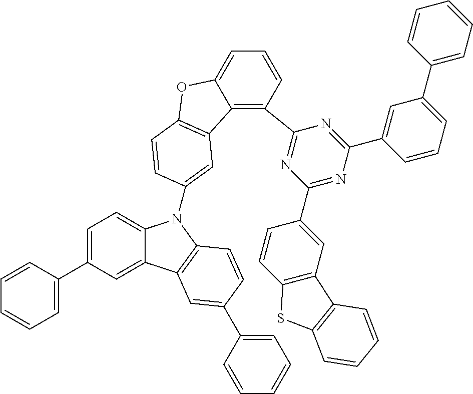 [SMILES: c1ccc(-c2cccc(-c3nc(-c4ccc5sc6ccccc6c5c4)nc(-c4cccc5oc6ccc(-n7c8ccc(-c9ccccc9)cc8c8cc(-c9ccccc9)ccc87)cc6c45)n3)c2)cc1] | E263 |
| 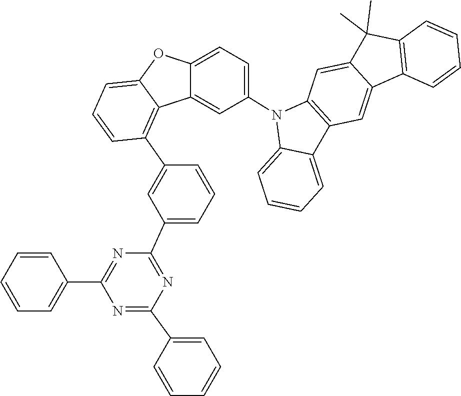 [SMILES: CC1(C)c2ccccc2-c2cc3c4ccccc4n(-c4ccc5oc6cccc(-c7cccc(-c8nc(-c9ccccc9)nc(-c9ccccc9)n8)c7)c6c5c4)c3cc21] | E264 |
| 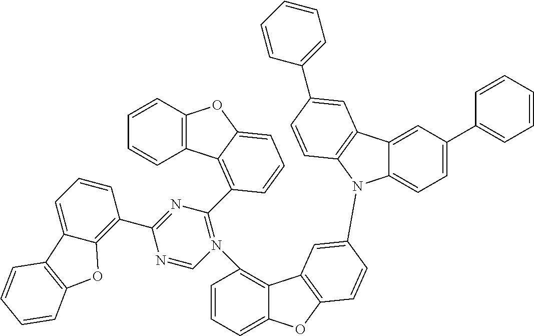 | E265 |
| 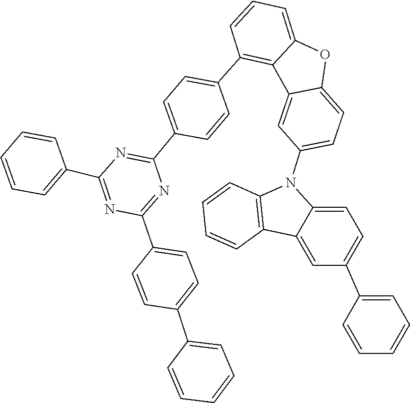 [SMILES: c1ccc(-c2ccc(-c3nc(-c4ccccc4)nc(-c4ccc(-c5cccc6oc7ccc(-n8c9ccccc9c9cc(-c%10ccccc%10)ccc98)cc7c56)cc4)n3)cc2)cc1] | E266 |
| 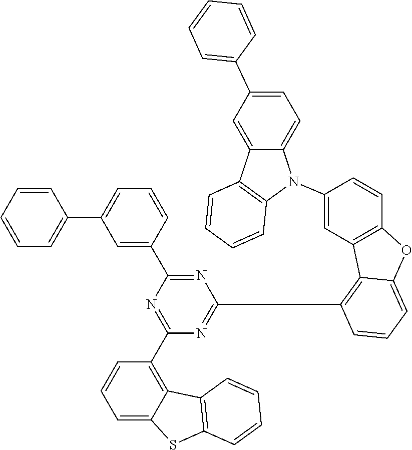 [SMILES: c1ccc(-c2cccc(-c3nc(-c4cccc5oc6ccc(-n7c8ccccc8c8cc(-c9ccccc9)ccc87)cc6c45)nc(-c4cccc5sc6ccccc6c45)n3)c2)cc1] | E267 |
| 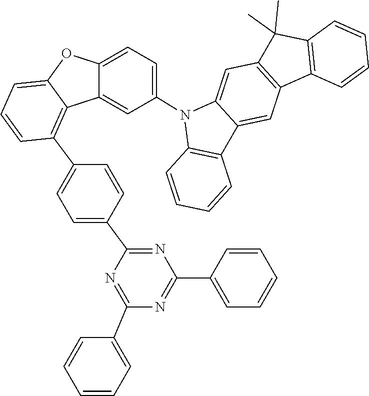 [SMILES: CC1(C)c2ccccc2-c2cc3c4ccccc4n(-c4ccc5oc6cccc(-c7ccc(-c8nc(-c9ccccc9)nc(-c9ccccc9)n8)cc7)c6c5c4)c3cc21] | E268 |
| 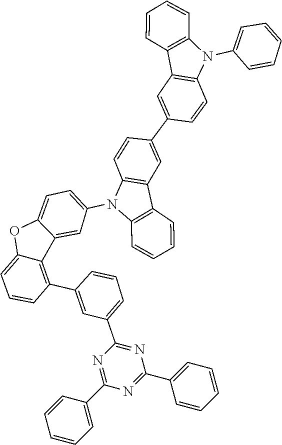 [SMILES: c1ccc(-c2nc(-c3ccccc3)nc(-c3cccc(-c4cccc5oc6ccc(-n7c8ccccc8c8cc(-c9ccc%10c(c9)c9ccccc9n%10-c9ccccc9)ccc87)cc6c45)c3)n2)cc1] | E269 |
| 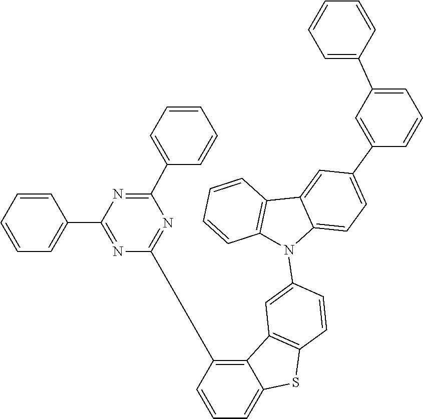 [SMILES: c1ccc(-c2cccc(-c3ccc4c(c3)c3ccccc3n4-c3ccc4sc5cccc(-c6nc(-c7ccccc7)nc(-c7ccccc7)n6)c5c4c3)c2)cc1] | E270 |
| 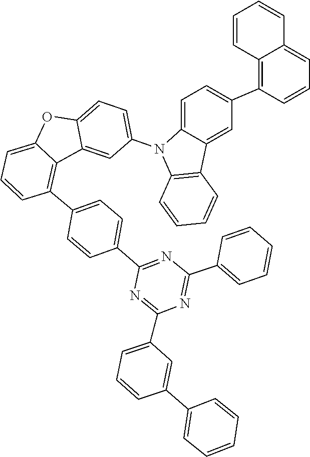 [SMILES: c1ccc(-c2cccc(-c3nc(-c4ccccc4)nc(-c4ccc(-c5cccc6oc7ccc(-n8c9ccccc9c9cc(-c%10cccc%11ccccc%10%11)ccc98)cc7c56)cc4)n3)c2)cc1] | E271 |
| 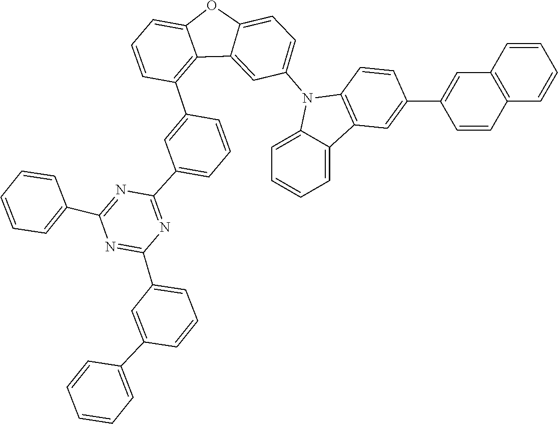 [SMILES: c1ccc(-c2cccc(-c3nc(-c4ccccc4)nc(-c4cccc(-c5cccc6oc7ccc(-n8c9ccccc9c9cc(-c%10ccc%11ccccc%11c%10)ccc98)cc7c56)c4)n3)c2)cc1] | E272 |
| 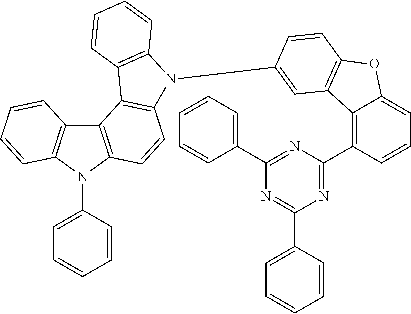 [SMILES: c1ccc(-c2nc(-c3ccccc3)nc(-c3cccc4oc5ccc(-n6c7ccccc7c7c8c9ccccc9n(-c9ccccc9)c8ccc76)cc5c34)n2)cc1] | E273 |
| 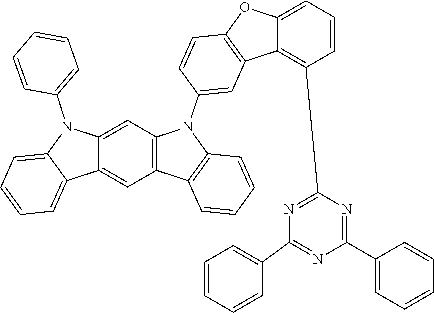 [SMILES: c1ccc(-c2nc(-c3ccccc3)nc(-c3cccc4oc5ccc(-n6c7ccccc7c7cc8c9ccccc9n(-c9ccccc9)c8cc76)cc5c34)n2)cc1] | E274 |
| 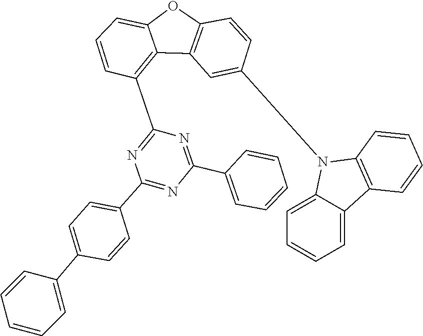 [SMILES: c1ccc(-c2ccc(-c3nc(-c4ccccc4)nc(-c4cccc5oc6ccc(-n7c8ccccc8c8ccccc87)cc6c45)n3)cc2)cc1] | E275 |
| 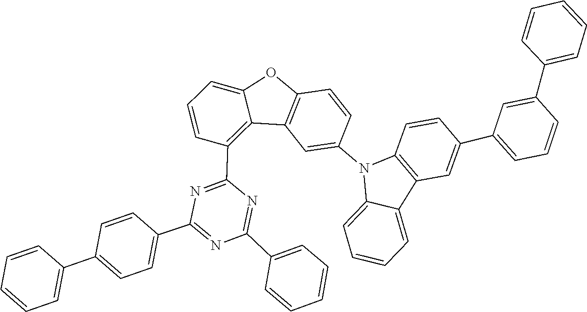 [SMILES: c1ccc(-c2ccc(-c3nc(-c4ccccc4)nc(-c4cccc5oc6ccc(-n7c8ccccc8c8cc(-c9cccc(-c%10ccccc%10)c9)ccc87)cc6c45)n3)cc2)cc1] | E276 |
| 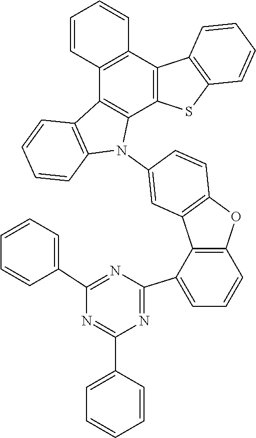 [SMILES: c1ccc(-c2nc(-c3ccccc3)nc(-c3cccc4oc5ccc(-n6c7ccccc7c7c8ccccc8c8c9ccccc9sc8c76)cc5c34)n2)cc1] | E277 |
| 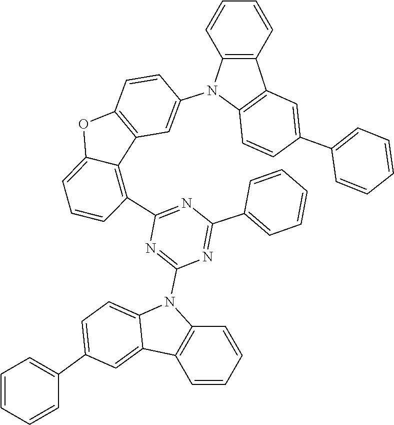 [SMILES: c1ccc(-c2ccc3c(c2)c2ccccc2n3-c2ccc3oc4cccc(-c5nc(-c6ccccc6)nc(-n6c7ccccc7c7cc(-c8ccccc8)ccc76)n5)c4c3c2)cc1] | E278 |
| 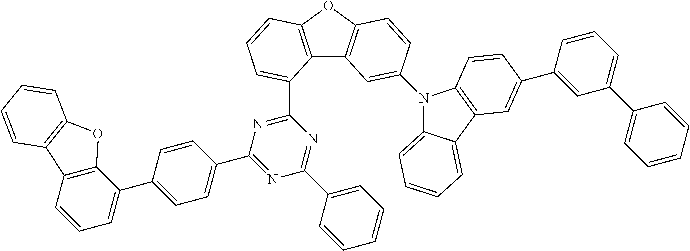 [SMILES: c1ccc(-c2cccc(-c3ccc4c(c3)c3ccccc3n4-c3ccc4oc5cccc(-c6nc(-c7ccccc7)nc(-c7ccc(-c8cccc9c8oc8ccccc89)cc7)n6)c5c4c3)c2)cc1] | E279 |
| 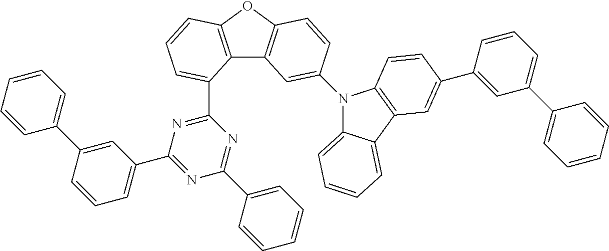 [SMILES: c1ccc(-c2cccc(-c3ccc4c(c3)c3ccccc3n4-c3ccc4oc5cccc(-c6nc(-c7ccccc7)nc(-c7cccc(-c8ccccc8)c7)n6)c5c4c3)c2)cc1] | E280 |
| 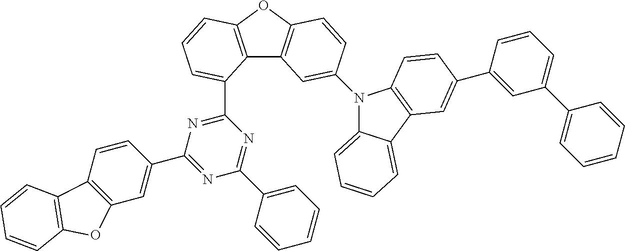 [SMILES: c1ccc(-c2cccc(-c3ccc4c(c3)c3ccccc3n4-c3ccc4oc5cccc(-c6nc(-c7ccccc7)nc(-c7ccc8c(c7)oc7ccccc78)n6)c5c4c3)c2)cc1] | E281 |
| 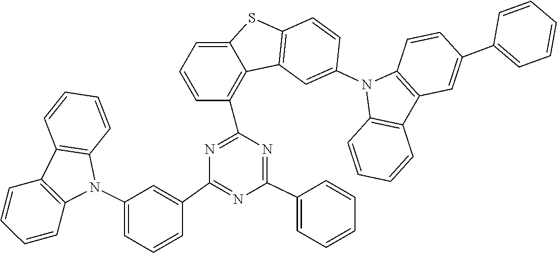 [SMILES: c1ccc(-c2ccc3c(c2)c2ccccc2n3-c2ccc3sc4cccc(-c5nc(-c6ccccc6)nc(-c6cccc(-n7c8ccccc8c8ccccc87)c6)n5)c4c3c2)cc1] | E282 |
| 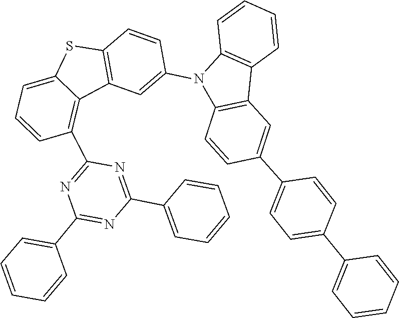 [SMILES: c1ccc(-c2ccc(-c3ccc4c(c3)c3ccccc3n4-c3ccc4sc5cccc(-c6nc(-c7ccccc7)nc(-c7ccccc7)n6)c5c4c3)cc2)cc1] | E283 |
| 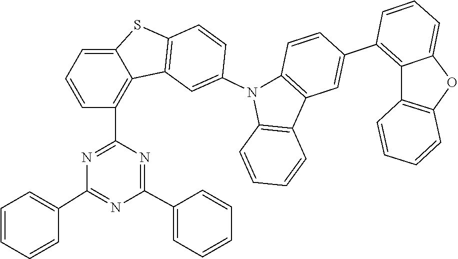 [SMILES: c1ccc(-c2nc(-c3ccccc3)nc(-c3cccc4sc5ccc(-n6c7ccccc7c7cc(-c8cccc9oc%10ccccc%10c89)ccc76)cc5c34)n2)cc1] | E284 |
| 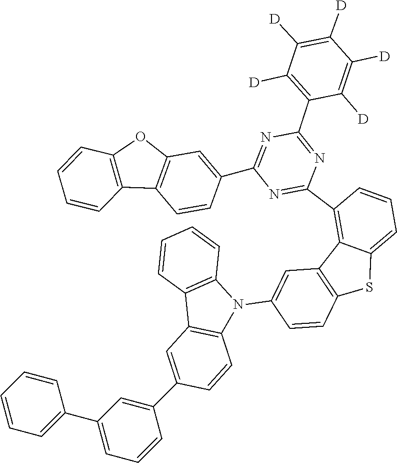 [SMILES: [2H]c1c([2H])c([2H])c(-c2nc(-c3ccc4c(c3)oc3ccccc34)nc(-c3cccc4sc5ccc(-n6c7ccccc7c7cc(-c8cccc(-c9ccccc9)c8)ccc76)cc5c34)n2)c([2H])c1[2H]] | E285 |
| 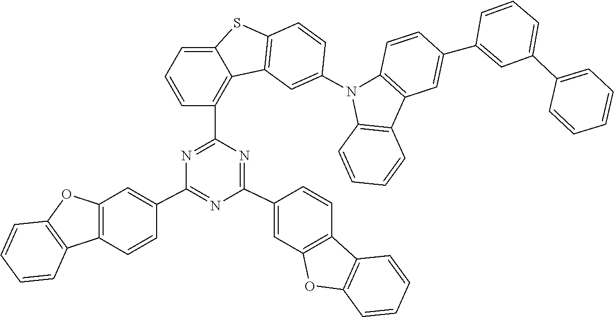 [SMILES: c1ccc(-c2cccc(-c3ccc4c(c3)c3ccccc3n4-c3ccc4sc5cccc(-c6nc(-c7ccc8c(c7)oc7ccccc78)nc(-c7ccc8c(c7)oc7ccccc78)n6)c5c4c3)c2)cc1] | E286 |
| 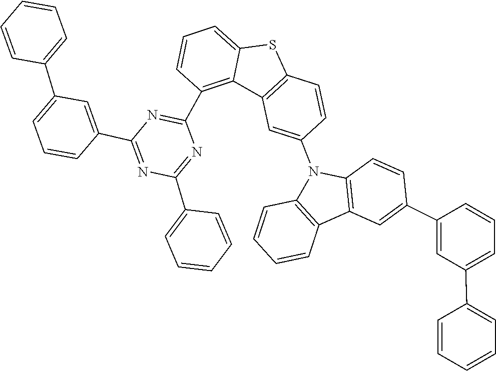 [SMILES: c1ccc(-c2cccc(-c3ccc4c(c3)c3ccccc3n4-c3ccc4sc5cccc(-c6nc(-c7ccccc7)nc(-c7cccc(-c8ccccc8)c7)n6)c5c4c3)c2)cc1] | E287 |
| 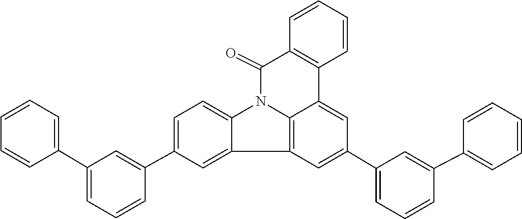 [SMILES: O=c1c2ccccc2c2cc(-c3cccc(-c4ccccc4)c3)cc3c4cc(-c5cccc(-c6ccccc6)c5)ccc4n1c23] | E288 |
| 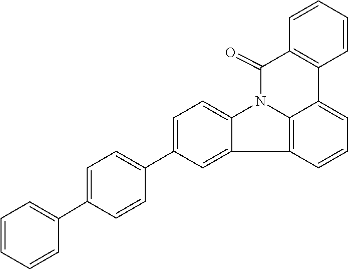 [SMILES: O=c1c2ccccc2c2cccc3c4cc(-c5ccc(-c6ccccc6)cc5)ccc4n1c23] | E289 |
| 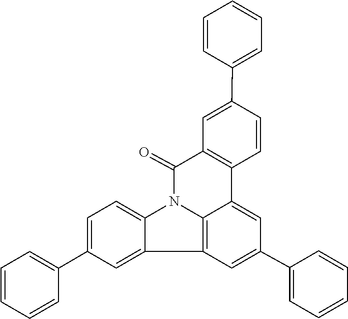 [SMILES: O=c1c2cc(-c3ccccc3)ccc2c2cc(-c3ccccc3)cc3c4cc(-c5ccccc5)ccc4n1c23] | E300 |
| 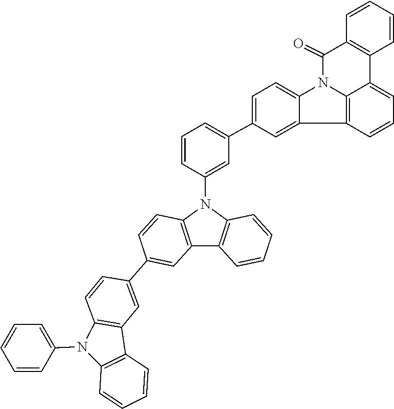 [SMILES: O=c1c2ccccc2c2cccc3c4cc(-c5cccc(-n6c7ccccc7c7cc(-c8ccc9c(c8)c8ccccc8n9-c8ccccc8)ccc76)c5)ccc4n1c23] | E301 |
| 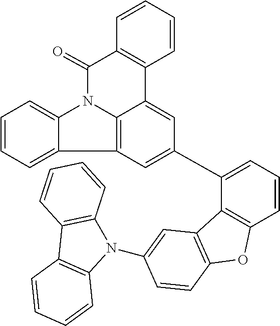 [SMILES: O=c1c2ccccc2c2cc(-c3cccc4oc5ccc(-n6c7ccccc7c7ccccc76)cc5c34)cc3c4ccccc4n1c23] | E302 |
| 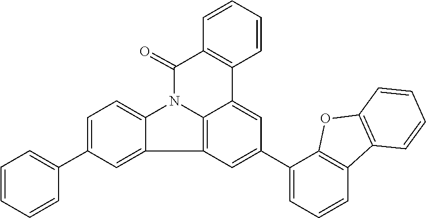 [SMILES: O=c1c2ccccc2c2cc(-c3cccc4c3oc3ccccc34)cc3c4cc(-c5ccccc5)ccc4n1c23] | E303 |

Preferred cathodes are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag, in which case combinations of the metals such as Mg/Ag, Ca/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). Likewise useful for this purpose are organic alkali metal complexes, e.g. Liq (lithium quinolinate). The layer thickness of this layer is preferably between 0.5 and 5 nm.

Preferred anodes are materials having a high work function. Preferably, the anode has a work function of greater than 4.5 eV versus vacuum.

Firstly, metals having a high redox potential are suitable for this purpose, for example Ag, Pt or Au. Secondly, metal/metal oxide electrodes (e.g. Al/Ni/NiOₓ, Al/PtOₓ) may also be preferred. For some applications, at least one of the electrodes has to be transparent or partly transparent in order to enable either the irradiation of the organic material (O-SC) or the emission of light (OLED/PLED, O-LASER). Preferred anode materials here are conductive mixed metal oxides. Particular preference is given to indium tin oxide (ITO) or indium zinc oxide (IZO). Preference is further given to conductive doped organic materials, especially conductive doped polymers, for example PEDOT, PANI or derivatives of these polymers. It is further preferable when a p-doped hole transport material is applied to the anode as hole injection layer, in which case suitable p-dopants are metal oxides, for example MoO₃ or WO₃, or (per)fluorinated electron-deficient aromatic systems. Further suitable p-dopants are HAT-CN (hexacyanohexaazatriphenylene) or the compound NPD9 from Novaled. Such a layer simplifies hole injection into materials having a low HOMO, i.e. a large HOMO in terms of magnitude.

In the further layers, it is generally possible to use any materials as used according to the prior art for the layers, and the person skilled in the art is able, without exercising inventive skill, to combine any of these materials with the materials of the invention in an electronic device.

Suitable charge transport materials as usable in the hole injection or hole transport layer or electron blocker layer or in the electron transport layer of the organic electroluminescent device of the invention are, for example, the compounds disclosed in Y. Shirota et al., Chem. Rev. 2007, 107(4), 953-1010, or other materials as used in these layers according to the prior art. Preferred hole transport materials which can be used in a hole transport, hole injection or electron blocker layer in the electroluminescent device of the invention are indenofluoreneamine derivatives (for example according to WO 06/122630 or WO 06/100896), the amine derivatives disclosed in EP 1661888, hexaazatriphenylene derivatives (for example according to WO 01/049806), amine derivatives having fused aromatic systems (for example according to U.S. Pat. No. 5,061,569), the amine derivatives disclosed in WO 95/09147, monobenzoindenofluoreneamines (for example according to WO 08/006449), dibenzoindenofluoreneamines (for example according to WO 07/140847), spirobifluoreneamines (for example according to WO 2012/034627, WO 2014/056565), fluoreneamines (for example according to EP 2875092, EP 2875699 and EP 2875004), spirodibenzopyranamines (e.g. EP 2780325) and dihydroacridine derivatives (for example according to WO 2012/150001).

The device is correspondingly (according to the application) structured, contact-connected and finally hermetically sealed, since the lifetime of such devices is severely shortened in the presence of water and/or air.

Additionally preferred is an organic electroluminescent device, characterized in that one or more layers are coated by a sublimation process. In this case, the materials are applied by vapor deposition in vacuum sublimation systems at an initial pressure of typically less than 10⁻⁵ mbar, preferably less than 10⁻⁶ mbar. It is also possible that the initial pressure is even lower or even higher, for example less than 10⁻⁷ mbar.

Preference is likewise given to an organic electroluminescent device, characterized in that one or more layers are coated by the OVPD (organic vapor phase deposition) method or with the aid of a carrier gas sublimation. In this case, the materials are applied at a pressure between 10⁻⁵ mbar and 1 bar. A special case of this method is the OVJP (organic vapor jet printing) method, in which the materials are applied directly by a nozzle and thus structured (for example M. S. Arnold et al., Appl.Phys. Lett. 2008, 92, 053301).

Preference is additionally given to an organic electroluminescent device, characterized in that one or more layers are produced from solution, for example by spin-coating, or by any printing method, for example screen printing, flexographic printing, offset printing or nozzle printing, but more preferably LITI (light-induced thermal imaging, thermal transfer printing) or inkjet printing. For this purpose, soluble compounds are needed, which are obtained, for example, through suitable substitution.

The organic electroluminescent device can also be produced as a hybrid system by applying one or more layers from solution and applying one or more other layers by vapor deposition. For example, it is possible to apply an emitting layer comprising a metal complex of the invention and a matrix material from solution, and to apply a hole blocker layer and/or an electron transport layer thereto by vapor deposition under reduced pressure.

These methods are known in general terms to those skilled in the art and can be applied by those skilled in the art without difficulty to organic electroluminescent devices comprising compounds of formula (1) or the above-detailed preferred embodiments.

It is a feature of the electronic devices of the invention, especially organic electroluminescent devices, with respect to the prior art, that they have a significantly improved lifetime compared to comparable structures that do not have a cyano group on the phenyl or biphenyl substituent. At the same time, a slight improvement in efficiency and in voltage is obtained.

The invention is illustrated in detail by the examples which follow, without any intention of restricting it thereby. The person skilled in the art will be able to use the details given, without exercising inventive skill, to produce further electronic devices of the invention and hence to execute the invention over the entire scope claimed.

### EXAMPLES

The syntheses which follow, unless stated otherwise, are conducted under a protective gas atmosphere in dried solvents. The metal complexes are additionally handled with exclusion of light or under yellow light. The solvents and reagents can be purchased, for example, from Sigma-ALDRICH or ABCR. The respective figures in square brackets or the numbers quoted for individual compounds relate to the CAS numbers of the compounds known from the literature. In the case of compounds that can have multiple tautomeric, isomeric, diastereomeric and enantiomeric forms, one form is shown in a representative manner.

### A: Synthesis of the Ligands L

### Example L1

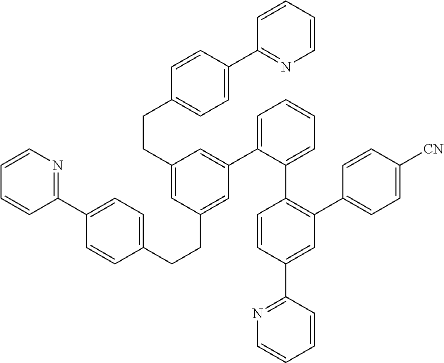 [SMILES: N#Cc1ccc(-c2cc(-c3ccccn3)ccc2-c2ccccc2-c2cc(CCc3ccc(-c4ccccn4)cc3)cc(CCc3ccc(-c4ccccn4)cc3)c2)cc1]

To a mixture of 81.8 g (100 mmol) of 2-(4-{2-[3-(2′-{[trifluoromethanesulfonyl]-4-yl}-4′-(pyridin-2-yl)-[1,1′-biphenyl]-2-yl)-5-{2-[4-(pyridin-2-yl)phenyl]ethyl}phenyl]ethyl}phenyl)pyridine [2375157-32-5], 16.2 g (110 mmol) of 4-cyanophenylboronic acid [126747-14-6], 53.1 g (250 mmol) of tripotassium phosphate, 800 ml of THF and 200 ml of water are added, with vigorous stirring, 1.64 g (4 mmol) of S-Phos and then 449 mg (2 mmol) of palladium(II) acetate, and the mixture is heated under reflux for 12 h. After cooling, the aqueous phase is removed, the organic phase is substantially concentrated under reduced pressure, the residue is taken up in 500 ml of ethyl acetate, and the organic phase is washed twice with 300 ml each time of water, once with 2% aqueous N-acetylcysteine solution and once with 300 ml of saturated sodium chloride solution, and dried over magnesium sulfate. The desiccant is filtered off by means of a silica gel bed in the form of an ethyl acetate slurry, which is washed through with ethyl acetate, the filtrate is concentrated to dryness and the residue is recrystallized from about 200 ml of acetonitrile at boiling. Yield: 50.2 g (65 mmol), 65%; purity: about 98% by ¹H NMR.

The following compounds can be prepared analogously:

| Ex. | Reactants | Product | Yield |
|---|---|---|---|
| L2 | 2375157-34-7 126747-14-6 | 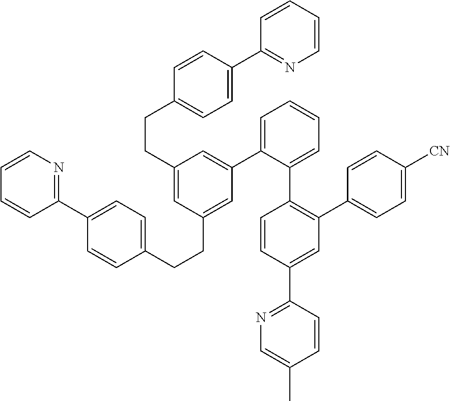 [SMILES: Cc1ccc(-c2ccc(-c3ccccc3-c3cc(CCc4ccc(-c5ccccn5)cc4)cc(CCc4ccc(-c5ccccn5)cc4)c3)c(-c3ccc(C#N)cc3)c2)nc1] | 70% |
| L3 | 2375157-36-9 313546-18-8 | 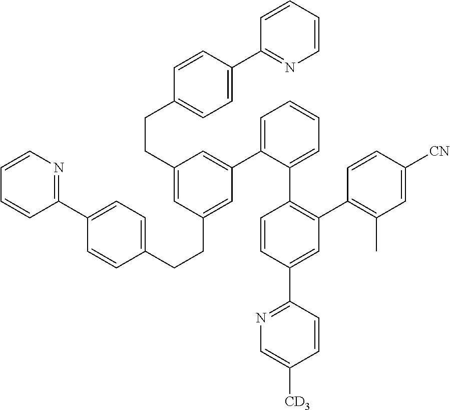 [SMILES: [2H]C([2H])([2H])c1ccc(-c2ccc(-c3ccccc3-c3cc(CCc4ccc(-c5ccccn5)cc4)cc(CCc4ccc(-c5ccccn5)cc4)c3)c(-c3ccc(C#N)cc3C)c2)nc1] | 67% |
| L4 | 2375157-38-1 856255-58-8 | 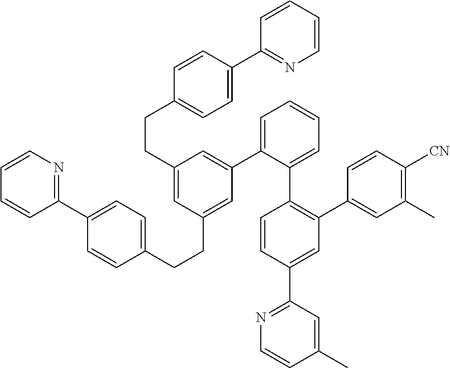 [SMILES: Cc1ccnc(-c2ccc(-c3ccccc3-c3cc(CCc4ccc(-c5ccccn5)cc4)cc(CCc4ccc(-c5ccccn5)cc4)c3)c(-c3ccc(C#N)c(C)c3)c2)c1] | 63% |
| L5 | 2375157-40-5 1384855-53-1 | 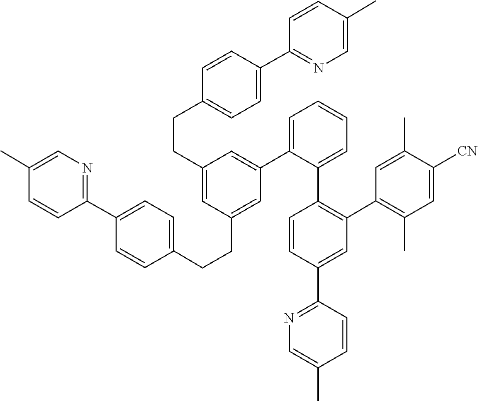 [SMILES: Cc1ccc(-c2ccc(CCc3cc(CCc4ccc(-c5ccc(C)cn5)cc4)cc(-c4ccccc4-c4ccc(-c5ccc(C)cn5)cc4-c4cc(C)c(C#N)cc4C)c3)cc2)nc1] | 69% |
| L6 | 2375157-32-5 1212021-54-9 | 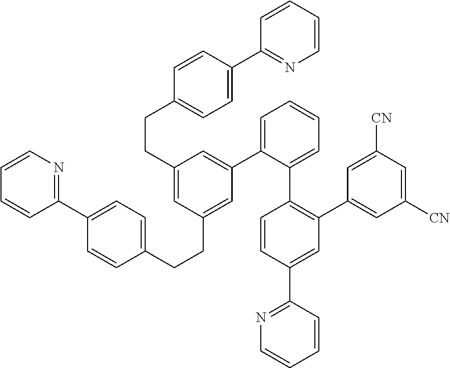 [SMILES: N#Cc1cc(C#N)cc(-c2cc(-c3ccccn3)ccc2-c2ccccc2-c2cc(CCc3ccc(-c4ccccn4)cc3)cc(CCc3ccc(-c4ccccn4)cc3)c2)c1] | 55% |
| L7 | 2375157-36-9 1212021-54-9 | 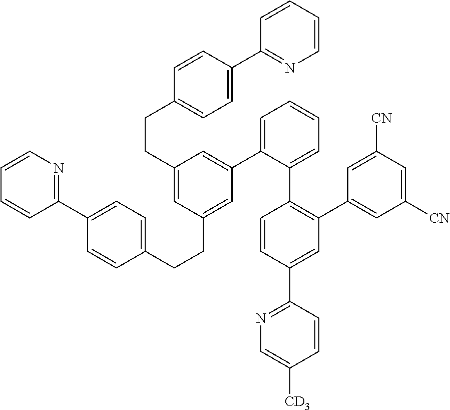 [SMILES: [2H]C([2H])([2H])c1ccc(-c2ccc(-c3ccccc3-c3cc(CCc4ccc(-c5ccccn5)cc4)cc(CCc4ccc(-c5ccccn5)cc4)c3)c(-c3cc(C#N)cc(C#N)c3)c2)nc1] | 58% |
| L-Ref3 | 2375157-36-9 98-80-6 | 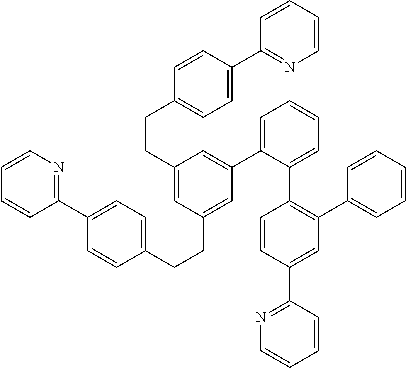 [SMILES: c1ccc(-c2cc(-c3ccccn3)ccc2-c2ccccc2-c2cc(CCc3ccc(-c4ccccn4)cc3)cc(CCc3ccc(-c4ccccn4)cc3)c2)cc1] | 72% |
| L100 | 2375157-32-5 406482-73-3 | 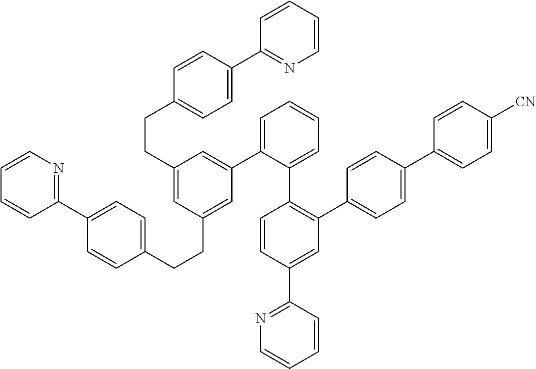 [SMILES: N#Cc1ccc(-c2ccc(-c3cc(-c4ccccn4)ccc3-c3ccccc3-c3cc(CCc4ccc(-c5ccccn5)cc4)cc(CCc4ccc(-c5ccccn5)cc4)c3)cc2)cc1] | 76% |
| L101 | 2375157-34-7 406482-73-3 | 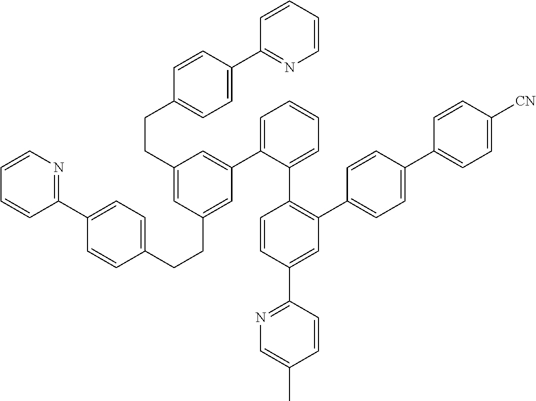 [SMILES: Cc1ccc(-c2ccc(-c3ccccc3-c3cc(CCc4ccc(-c5ccccn5)cc4)cc(CCc4ccc(-c5ccccn5)cc4)c3)c(-c3ccc(-c4ccc(C#N)cc4)cc3)c2)nc1] | 73% |
| L102 | 2375157-36-9 406482-73-3 | 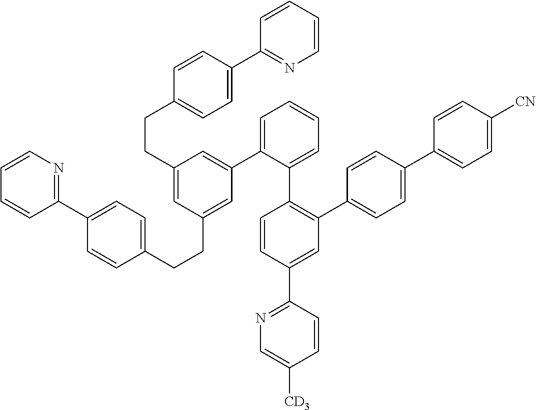 [SMILES: [2H]C([2H])([2H])c1ccc(-c2ccc(-c3ccccc3-c3cc(CCc4ccc(-c5ccccn5)cc4)cc(CCc4ccc(-c5ccccn5)cc4)c3)c(-c3ccc(-c4ccc(C#N)cc4)cc3)c2)nc1] | 75% |
| L103 | 2375157-40-5 406482-73-3 | 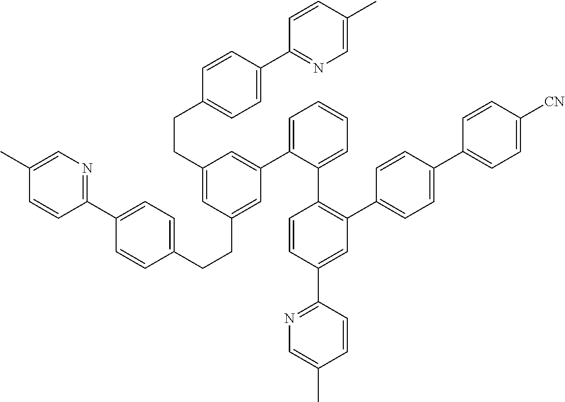 [SMILES: Cc1ccc(-c2ccc(CCc3cc(CCc4ccc(-c5ccc(C)cn5)cc4)cc(-c4ccccc4-c4ccc(-c5ccc(C)cn5)cc4-c4ccc(-c5ccc(C#N)cc5)cc4)c3)cc2)nc1] | 70% |
| L104 | 2375157-42-7 406482-73-3 | 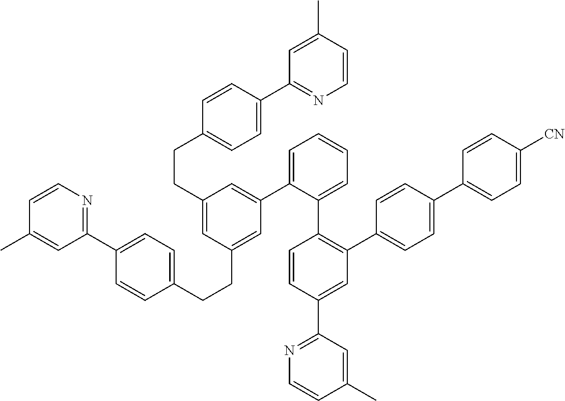 [SMILES: Cc1ccnc(-c2ccc(CCc3cc(CCc4ccc(-c5cc(C)ccn5)cc4)cc(-c4ccccc4-c4ccc(-c5cc(C)ccn5)cc4-c4ccc(-c5ccc(C#N)cc5)cc4)c3)cc2)c1] | 68% |
| L105 | 2375157-44-9 406482-73-3 | 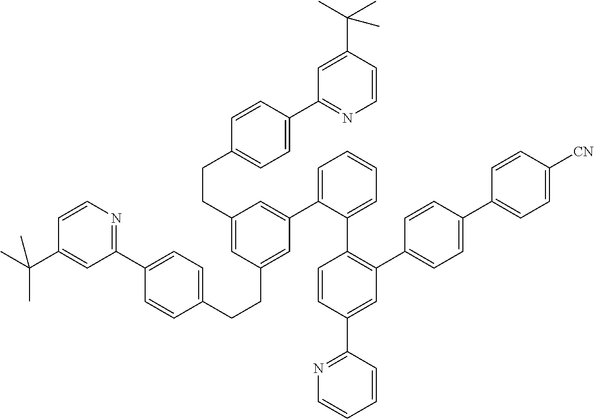 [SMILES: CC(C)(C)c1ccnc(-c2ccc(CCc3cc(CCc4ccc(-c5cc(C(C)(C)C)ccn5)cc4)cc(-c4ccccc4-c4ccc(-c5ccccn5)cc4-c4ccc(-c5ccc(C#N)cc5)cc4)c3)cc2)c1] | 63% |
| L106 | 2375157-34-7 1800587-08-9 | 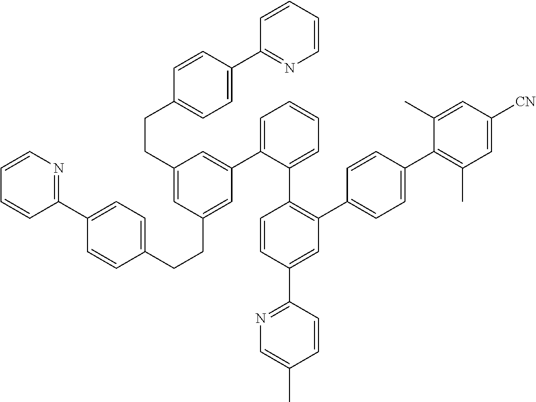 [SMILES: Cc1ccc(-c2ccc(-c3ccccc3-c3cc(CCc4ccc(-c5ccccn5)cc4)cc(CCc4ccc(-c5ccccn5)cc4)c3)c(-c3ccc(-c4c(C)cc(C#N)cc4C)cc3)c2)nc1] | 68% |
| L107 | 2375157-34-7 2380354-21-0 | 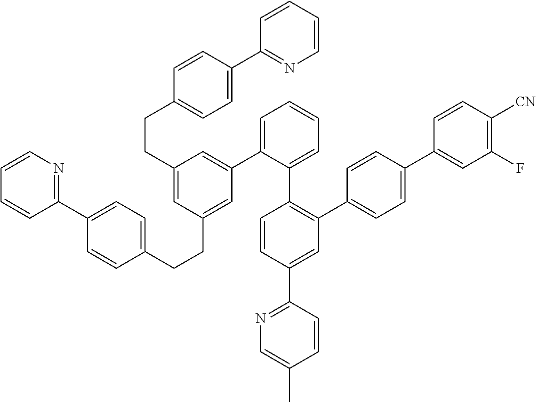 [SMILES: Cc1ccc(-c2ccc(-c3ccccc3-c3cc(CCc4ccc(-c5ccccn5)cc4)cc(CCc4ccc(-c5ccccn5)cc4)c3)c(-c3ccc(-c4ccc(C#N)c(F)c4)cc3)c2)nc1] | 65% |
| L108 | 2375157-34-7 1615713-15-9 | 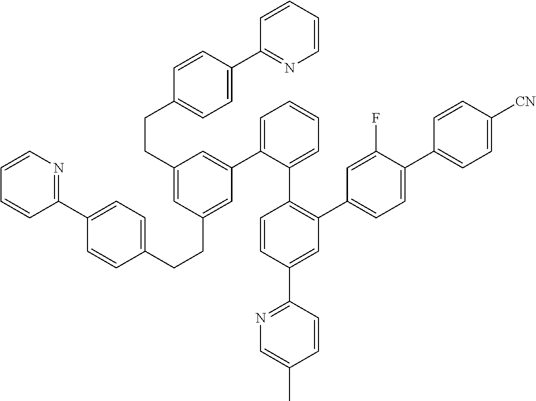 [SMILES: Cc1ccc(-c2ccc(-c3ccccc3-c3cc(CCc4ccc(-c5ccccn5)cc4)cc(CCc4ccc(-c5ccccn5)cc4)c3)c(-c3ccc(-c4ccc(C#N)cc4)c(F)c3)c2)nc1] | 67% |
| L109 | 2375157-42-7 2291171-92-9 | 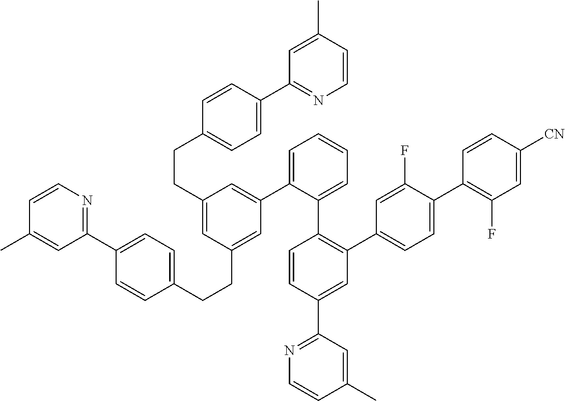 [SMILES: Cc1ccnc(-c2ccc(CCc3cc(CCc4ccc(-c5cc(C)ccn5)cc4)cc(-c4ccccc4-c4ccc(-c5cc(C)ccn5)cc4-c4ccc(-c5ccc(C#N)cc5F)c(F)c4)c3)cc2)c1] | 60% |
| L110 | 2375157-40-5 1352715-67-3 | 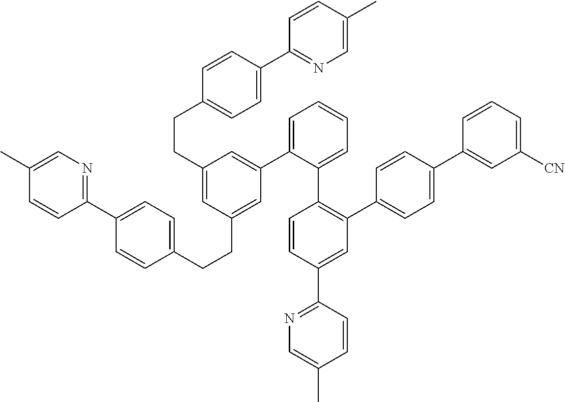 [SMILES: Cc1ccc(-c2ccc(CCc3cc(CCc4ccc(-c5ccc(C)cn5)cc4)cc(-c4ccccc4-c4ccc(-c5ccc(C)cn5)cc4-c4ccc(-c5cccc(C#N)c5)cc4)c3)cc2)nc1] | |
| L111 | 2375157-36-9 2242884-56-4 | 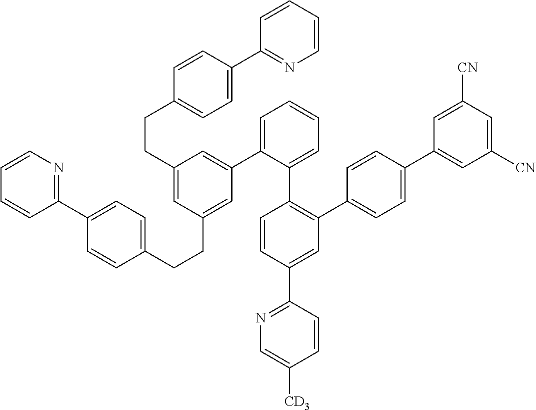 [SMILES: [2H]C([2H])([2H])c1ccc(-c2ccc(-c3ccccc3-c3cc(CCc4ccc(-c5ccccn5)cc4)cc(CCc4ccc(-c5ccccn5)cc4)c3)c(-c3ccc(-c4cc(C#N)cc(C#N)c4)cc3)c2)nc1] | 68% |
| L112 | 2375157-44-9 2242884-55-3 | 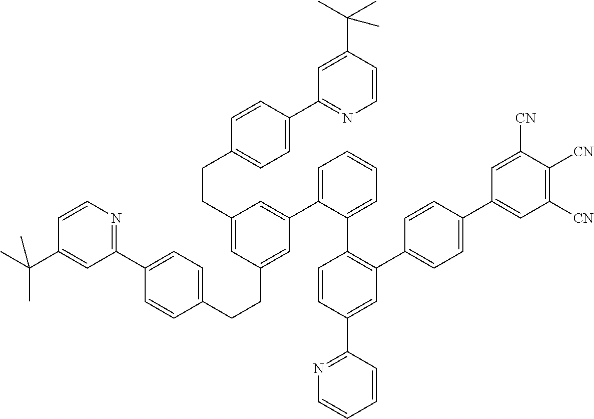 [SMILES: CC(C)(C)c1ccnc(-c2ccc(CCc3cc(CCc4ccc(-c5cc(C(C)(C)C)ccn5)cc4)cc(-c4ccccc4-c4ccc(-c5ccccn5)cc4-c4ccc(-c5cc(C#N)c(C#N)c(C#N)c5)cc4)c3)cc2)c1] | 61% |

### C: Preparation of the Metal Complexes

### Example Ir(L1)

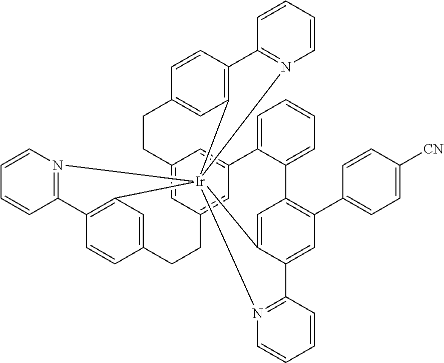

A mixture of 7.71 g (10 mmol) of ligand L1, 4.90 g (10 mmol) of trisacetylacetonatoiridium(III) [15635-87-7] and 120 g of hydroquinone [123-31-9] is initially charged in a 1000 ml two-neck round-bottom flask with a glass-sheathed magnetic bar. The flask is provided with a water separator (for media of lower density than water) and an air condenser with argon blanketing. The flask is placed in a metal heating bath. The apparatus is purged with argon from the top via the argon blanketing system for 15 min, allowing the argon to flow out of the side neck of the two-neck flask. Through the side neck of the two-neck flask, a glass-sheathed Pt-100 thermocouple is introduced into the flask and the end is positioned just above the magnetic stirrer bar. Then the apparatus is thermally insulated with several loose windings of domestic aluminum foil, the insulation being run up to the middle of the riser tube of the water separator. Then the apparatus is heated rapidly with a heated laboratory stirrer system to 240-245° C., measured with the Pt-100 temperature sensor which dips into the molten stirred reaction mixture. Over the next 1 h, the reaction mixture is kept at 240-245° C., in the course of which a small amount of condensate is distilled off and collects in the water separator. After 1 h, the mixture is allowed to cool down to about 190° C., the heating bath is removed, and then 100 ml of ethylene glycol is added dropwise. After cooling to 100° C., 400 ml of methanol is slowly added dropwise. The yellow suspension thus obtained is filtered through a double-ended frit, and the yellow solids are washed three times with 50 ml of methanol and then dried under reduced pressure. The solids thus obtained are dissolved in 200 ml of dichloromethane and filtered through 600 g of silica gel in the form of a dichloromethane slurry (column diameter about 10 cm) with exclusion of air in the dark, leaving dark-colored components at the start. The core fraction is cut out and concentrated on a rotary evaporator, with simultaneous continuous dropwise addition of MeOH until crystallization. After filtration with suction, washing with a little MeOH and drying under reduced pressure, the yellow product is purified further by continuous hot extraction four times with dichloromethane/i-propanol 1:1 (vv) and then hot extraction four times with dichloromethane/acetonitrile (amount initially charged in each case about 200 ml, extraction thimble: standard Soxhlet thimbles made of cellulose from Whatman) with careful exclusion of air and light. The loss into the mother liquor can be adjusted via the ratio of dichloromethane (low boilers and good dissolvers):i-propanol or acetonitrile (high boilers and poor dissolvers). It should typically be 3-6% by weight of the amount used. Hot extraction can also be accomplished using other solvents such as toluene, xylene, ethyl acetate, butyl acetate, etc. Finally, the product is subjected to fractional sublimation under high vacuum at p˜10-6 mbar and T˜330-430° C. Yield: 4.91 g (5.1 mmol), 51%; purity: >99.9% by HPLC.

The metal complexes are typically obtained as a 1:1 mixture of the A and Δ isomers/enantiomers. The images of complexes adduced hereinafter typically show only one isomer. If ligands having three different sub-ligands are used, or chiral ligands are used as a racemate, the metal complexes derived are obtained as a diastereomer mixture. These can be separated by fractional crystallization or by chromatography, for example with an automatic column system (CombiFlash from A. Semrau). If chiral ligands are used in enantiomerically pure form, the metal complexes derived are obtained as a diastereomer mixture, the separation of which by fractional crystallization or chromatography leads to pure enantiomers. The separated diastereomers or enantiomers can be purified further as described above, for example by hot extraction.

The following compounds can be prepared analogously:

| | | Product | |
|---|---|---|---|
| Ex. | Ligand | Variant/extractant | Yield |
| Ir(L2) | L2 | 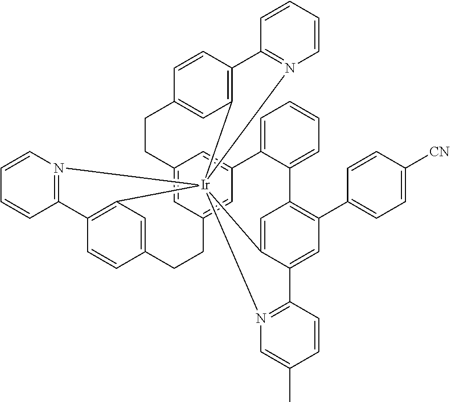 | 55% |
| Ir(L3) | L3 | 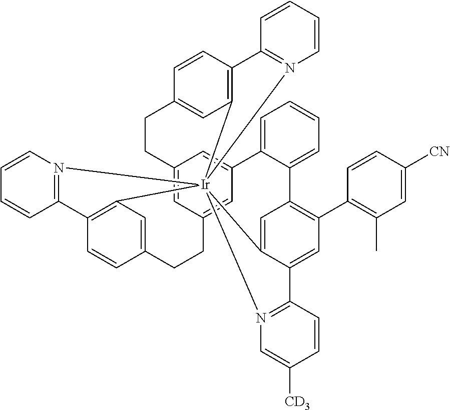 | 53% |
| Ir(L4) | L4 | 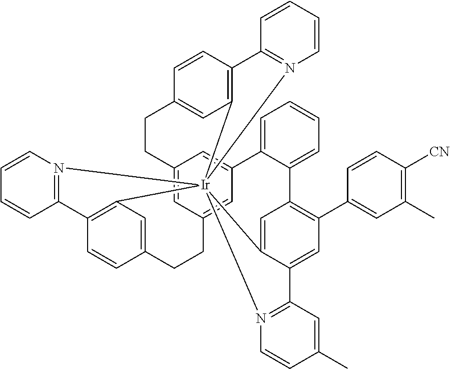 | 64% |
| Ir(L5) | L5 | 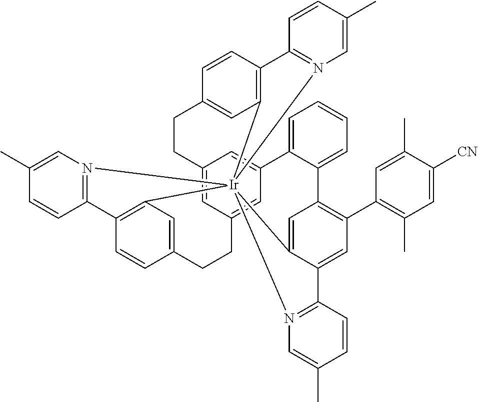 | 65% |
| Ir(L6) | L6 | 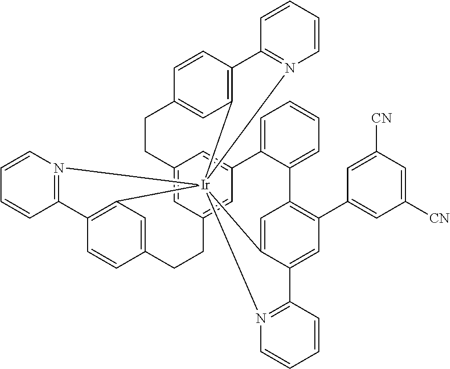 | 57% |
| Ir(L7) | L7 | 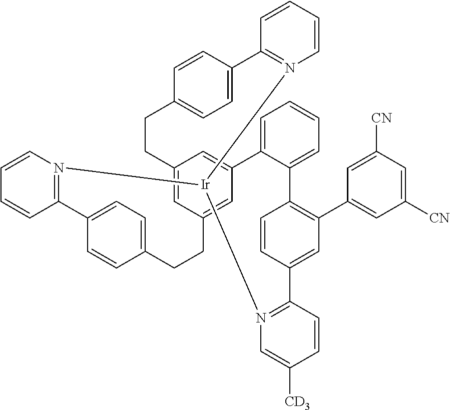 | 53% |
| Ir(L-Ref3) | L-Ref3 | 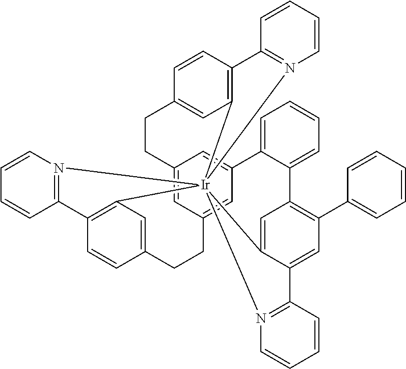 | 78% |
| Ir(L100) | L100 | 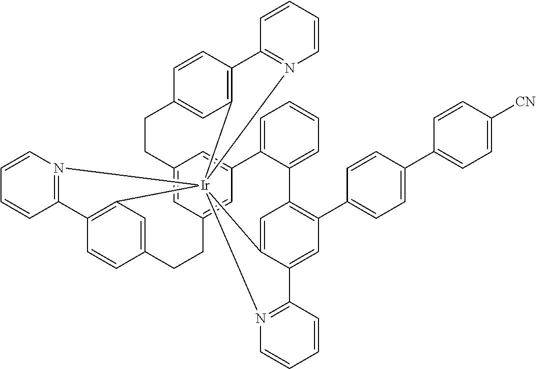 | 57% |
| Ir(L101) | L101 | 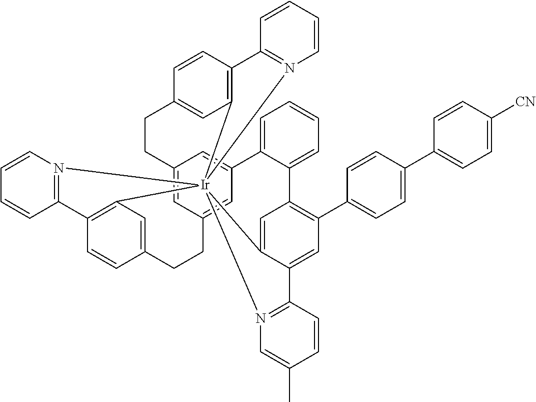 | 53% |
| Ir(L102) | L102 | 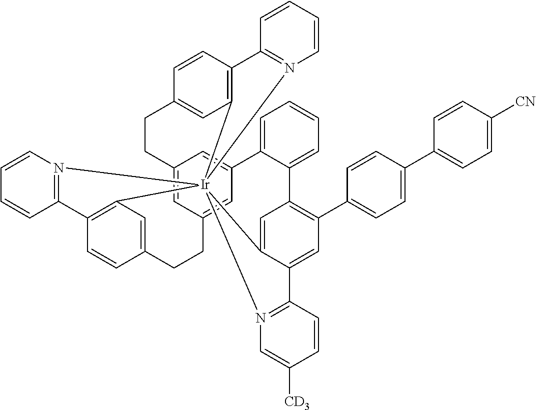 | 56% |
| Ir(L103) | L103 | 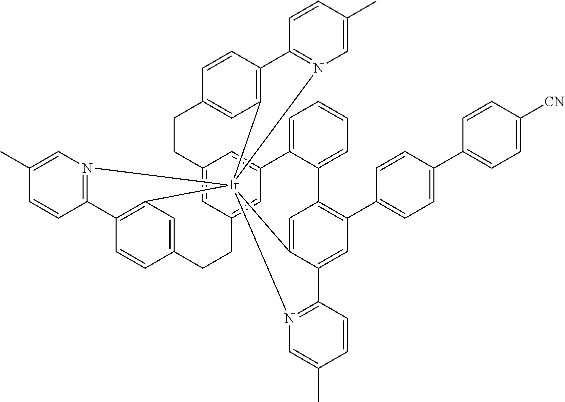 | 59% |
| Ir(L104) | L104 | 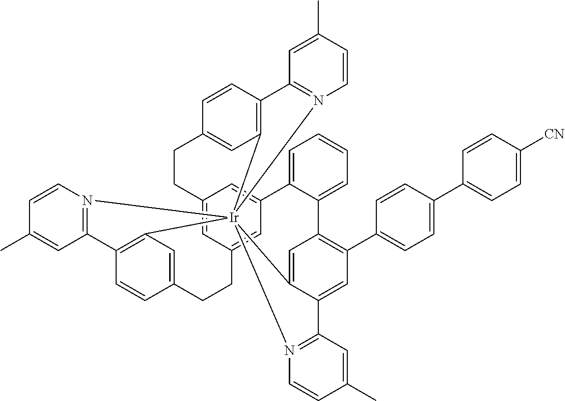 | 61% |
| Ir(L105) | L105 | 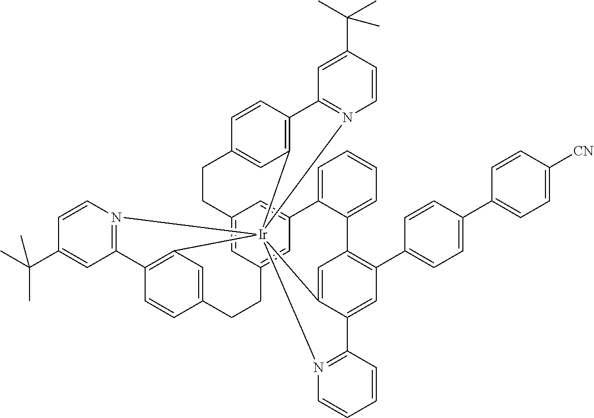 | 56% |
| Ir(L106) | L106 | 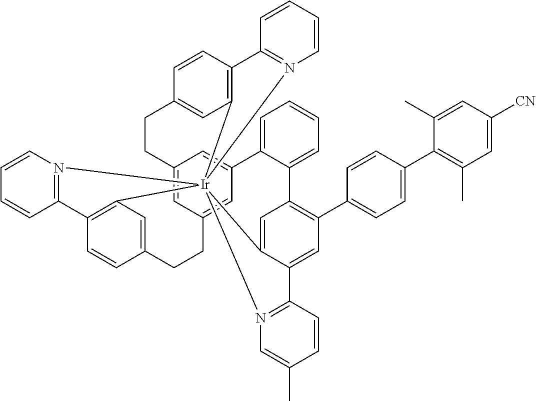 | 60% |
| Ir(L107) | L107 | 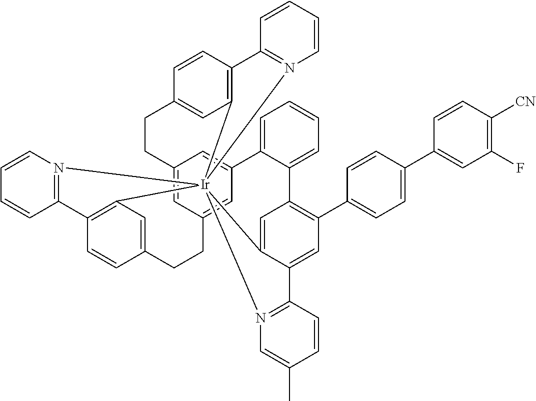 | 64% |
| Ir(L108) | L108 | 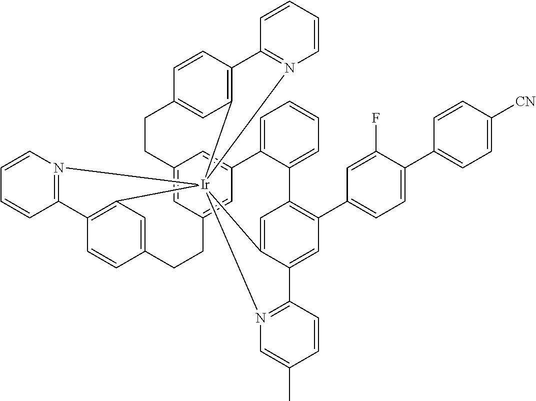 | 57% |
| Ir(L109) | L109 | 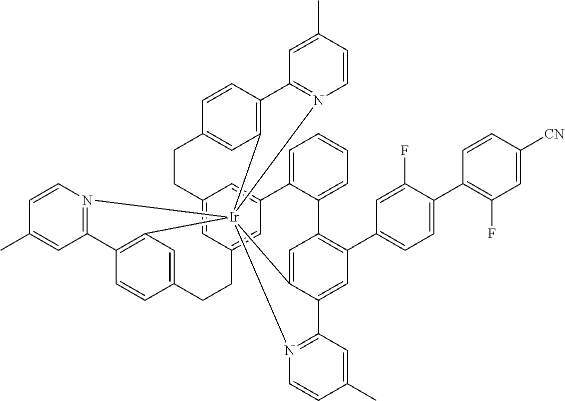 | 61% |
| Ir(L110) | L110 | 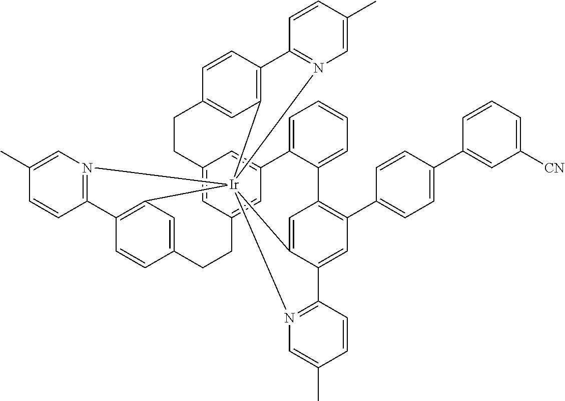 | 60% |
| Ir(L111) | L111 | 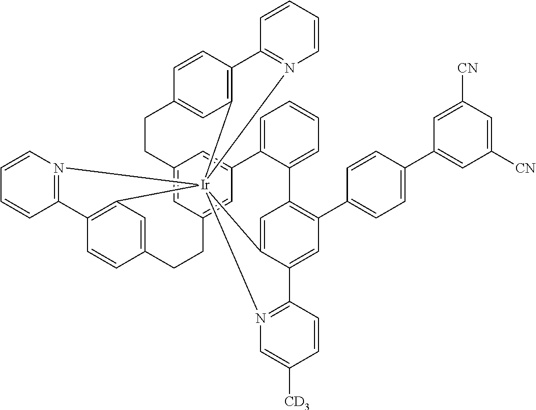 | 55% |
| Ir(L112) | L112 | 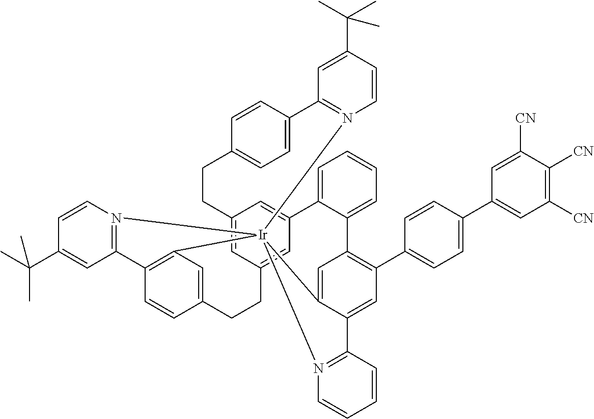 | 49% |

### B: Functionalization of the Metal Complexes

A) Deuteration of the Methyl/Methylene Groups on the Pyridine Ligands:

1 mmol of the clean complex (purity>99.9%) with x methyl/methylene groups and x=1-6 is dissolved in 50 ml of DMSO-d6 (deuteration level>99.8%) by heating to about 180° C. The solution is stirred at 180° C. for 5 min. The solution is left to cool to 80° C., and a mixture of 5 ml of methanol-dl (deuteration level>99.8%) and 10 ml of DMSO-d6 (deuteration level>99.8%) in which 0.3 mmol of sodium hydride has been dissolved is added rapidly to the solution with good stirring. The clear yellow/orange solution is stirred at 80° C. for a further 30 min for complexes having methyl/methylene groups para to the pyridine nitrogen, or for a further 6 h for complexes having methyl/methylene groups meta to the pyridine nitrogen, then the mixture is cooled with the aid of a cold water bath, 20 ml of 1N DCI in D₂O is added dropwise starting from about 60° C., the mixture is left to cool to room temperature and stirred for a further 5 h, and the solids are filtered off with suction and washed three times with 10 ml each time of H₂O/MeOH (1:1, w) and then three times with 10 ml each time of MeOH and dried under reduced pressure. The solids are dissolved in DCM, the solution is filtered through silica gel, and the filtrate is concentrated under reduced pressure while simultaneously adding MeOH dropwise, hence inducing crystallization. Finally, fractional sublimation is effected as described in “C: Preparation of the metal complexes, Variant A”. Yield typically 80-90%, deuteration level>95%.

In an analogous manner, it is possible to prepare the following deuterated complexes:

| Ex. | Reactant | Product | Yield |
|---|---|---|---|
| Ir(L103-D9) | Ir(L103) | 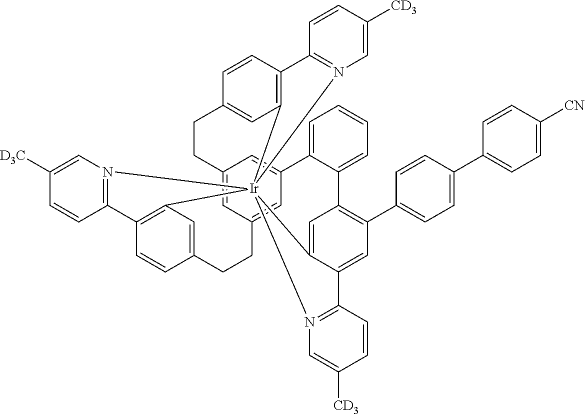 | 78% |
| Ir(L104-D9) | Ir(L104) | 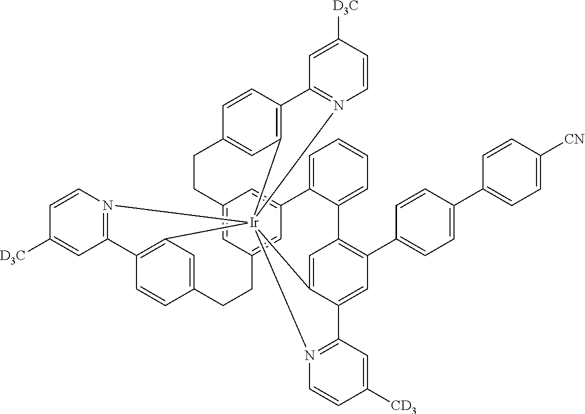 | 85% |

### Example: Production of the OLEDs

1) Vacuum-Processed Devices:

OLEDs of the invention and OLEDs according to the prior art are produced by a general method according to WO 2004/058911, which is adapted to the circumstances described here (variation in layer thickness, materials used).

Cleaned glass plates (cleaning in Miele laboratory glass washer, Merck Extran detergent) coated with structured ITO (indium tin oxide) of thickness 50 nm are baked at 250° C. under nitrogen for 15 minutes. The precleaned ITO substrates are subjected to a two-gas plasma process (oxygen followed by argon), in order to finally clean the ITO surface and to adjust the ITO work function. These coated glass plates form the substrates to which the OLEDs are applied. All materials are applied by thermal vacuum deposition. In this case, the emission layer always consists of at least one matrix material (host material) and an emitting dopant (emitter) which is added to the matrix material(s) in a particular proportion by volume by co-evaporation. Details given in such a form as M1:M2:Ir emitter (29.5%:58.5%:12%) mean here that the material M1 is present in the layer in a proportion by volume of 29.5%, M2 in a proportion by volume of 58.5% and Ir emitter in a proportion by volume of 12%. Analogously, the electron transport layer also consists of a mixture of two materials.

The OLEDs basically have the following layer structure: ITO substrate /hole injection layer 1 (HIL1) consisting of HTM1 doped with 5% NDP-9 (commercially available from Novaled), 20 nm/hole transport layer 1 (HTL1) consisting of HTM1, 40 nm/hole transport layer 2 (HTL2), 20 nm /emission layer (EML), see table 1/hole blocker layer (HBL), see table 1/electron transport layer (ETL), see table 1/electron injection layer (EIL), see table 1/100 nm-thick aluminum layer as cathode. The materials used for production of the OLEDs are shown in table 3.

The OLEDs are characterized in a standard manner. For this purpose, the electroluminescence spectra, the current efficiency (measured in cd/A), the power efficiency (measured in Im/VV) and the external quantum efficiency (EQE, measured in percent) as a function of luminance, calculated from current-voltage-luminance characteristics (IUL characteristics) assuming Lambertian emission characteristics, and also the lifetime are determined. Electroluminescence spectra are determined at a luminance of 1000 cd/m², and these are used to calculate the CIE 1931 x and y color coordinates. The lifetime LT90 is defined as the time after which the luminance in operation has dropped to 90% of the starting luminance with a starting brightness of 10 000 cd/m². The OLEDs can initially also be operated at different starting luminances. The values for the lifetime can then be converted to a figure for other starting luminances with the aid of conversion formulae known to those skilled in the art.

Use of Compounds of the Invention as Emitter Materials in Phosphorescent OLEDs

One use of the compounds of the invention is as phosphorescent emitter materials in the emission layer in OLEDs. The iridium compounds according to Table 3 are used as a comparison according to the prior art. The results for the OLEDs are collated in table 2.

As can be seen from the results, the compounds of the invention, when used as emitter in an OLED, lead to a slight improvement in efficiency and voltage with a simultaneous significant improvement in lifetime, for example an improvement in lifetime by 60% in the case of the inventive complex Ir(L100) compared to the Ir-Ref.1 complex according to the prior art, which has the same structure as Ir(L100), but does not contain a cyano group on the biphenyl substituent.

TABLE 1
Structure of the OLEDs

| | EML | HBL | ETL | |
|---|---|---|---|---|
| Ex. | thickness | thickness | thickness | EIL |
| Ref. D1 | M1:M2:Ir-Ref.1 | HBL1 | ETM1:ETM2 | ETM2 |
| | (29.5%:58.5%:12%) | 5 nm | (50%:50%) | 1 nm |
| | 40 nm | | 30 nm | |
| Ref. D2 | M1:M2:Ir-Ref.2 | HBL1 | ETM1:ETM2 | ETM2 |
| | (29.5%:58.5%:12%) | 5 nm | (50%:50%) | 1 nm |
| | 40 nm | | 30 nm | |
| Ref. D3 | M1:M2:Ir(L-Ref3) | HBL1 | ETM1:ETM2 | ETM2 |
| | (29.5%:58.5%:12%) | 5 nm | (50%:50%) | 1 nm |
| | 40 nm | | 30 nm | |
| D1 | M1:M2:Ir(L1) | HBL1 | ETM1:ETM2 | ETM2 |
| | (29.5%:58.5%:12%) | 5 nm | (50%:50%) | 1 nm |
| | 40 nm | | 30 nm | |
| D2 | M1:M2:Ir(L2) | HBL1 | ETM1:ETM2 | ETM2 |
| | (29.5%:58.5%:12%) | 5 nm | (50%:50%) | 1 nm |
| | 40 nm | | 30 nm | |
| D3 | M1:M2:Ir(L3) | HBL1 | ETM1:ETM2 | ETM2 |
| | (29.5%:58.5%:12%) | 5 nm | (50%:50%) | 1 nm |
| | 40 nm | | 30 nm | |
| D4 | M1:M2:Ir(L4) | HBL1 | ETM1:ETM2 | ETM2 |
| | (29.5%:58.5%:12%) | 5 nm | (50%:50%) | 1 nm |
| | 40 nm | | 30 nm | |
| D5 | M1:M2:Ir(L5) | HBL1 | ETM1:ETM2 | ETM2 |
| | (29.5%:58.5%:12%) | 5 nm | (50%:50%) | 1 nm |
| | 40 nm | | 30 nm | |
| D6 | M1:M2:Ir(L6) | HBL1 | ETM1:ETM2 | ETM2 |
| | (29.5%:58.5%:12%) | 5 nm | (50%:50%) | 1 nm |
| | 40 nm | | 30 nm | |
| D7 | M1:M2:Ir(L7) | HBL1 | ETM1:ETM2 | ETM2 |
| | (29.5%:58.5%:12%) | 5 nm | (50%:50%) | 1 nm |
| | 40 nm | | 30 nm | |
| D100 | M1:M2:Ir(L100) | HBL1 | ETM1:ETM2 | ETM2 |
| | (29.5%:58.5%:12%) | 5 nm | (50%:50%) | 1 nm |
| | 40 nm | | 30 nm | |
| D101 | M1:M2:Ir(L101) | HBL1 | ETM1:ETM2 | ETM2 |
| | (29.5%:58.5%:12%) | 5 nm | (50%:50%) | 1 nm |
| | 40 nm | | 30 nm | |
| D102 | M1:M2:Ir(L102) | HBL1 | ETM1:ETM2 | ETM2 |
| | (29.5%:58.5%:12%) | 5 nm | (50%:50%) | 1 nm |
| | 40 nm | | 30 nm | |
| D103 | M1:M2:Ir(L103) | HBL1 | ETM1:ETM2 | ETM2 |
| | (29.5%:58.5%:12%) | 5 nm | (50%:50%) | 1 nm |
| | 40 nm | | 30 nm | |
| D103-D | M1:M2:Ir(L103-D) | HBL1 | ETM1:ETM2 | ETM2 |
| | (29.5%:58.5%:12%) | 5 nm | (50%:50%) | 1 nm |
| | 40 nm | | 30 nm | |
| D104 | M1:M2:Ir(L104) | HBL1 | ETM1:ETM2 | ETM2 |
| | (29.5%:58.5%:12%) | 5 nm | (50%:50%) | 1 nm |
| | 40 nm | | 30 nm | |
| D104-D | M1:M2:Ir(L104-D) | HBL1 | ETM1:ETM2 | ETM2 |
| | (29.5%:58.5%:12%) | 5 nm | (50%:50%) | 1 nm |
| | 40 nm | | 30 nm | |
| D105 | M1:M2:Ir(L105) | HBL1 | ETM1:ETM2 | ETM2 |
| | (46.0%:46%:8%) | 5 nm | (50%:50%) | 1 nm |
| | 40 nm | | 30 nm | |
| D106 | M1:M2:Ir(L106) | HBL1 | ETM1:ETM2 | ETM2 |
| | (29.5%:58.5%:12%) | 5 nm | (50%:50%) | 1 nm |
| | 40 nm | | 30 nm | |
| D107 | M1:M2:Ir(L107) | HBL1 | ETM1:ETM2 | ETM2 |
| | (29.5%:58.5%:12%) | 5 nm | (50%:50%) | 1 nm |
| | 40 nm | | 30 nm | |
| D108 | M1:M2:Ir(L108) | HBL1 | ETM1:ETM2 | ETM2 |
| | (29.5%:58.5%:12%) | 5 nm | (50%:50%) | 1 nm |
| | 40 nm | | 30 nm | |
| D109 | M1:M2:Ir(L109) | HBL1 | ETM1:ETM2 | ETM2 |
| | (29.5%:58.5%:12%) | 5 nm | (50%:50%) | 1 nm |
| | 40 nm | | 30 nm | |
| D110 | M1:M2:Ir(L110) | HBL1 | ETM1:ETM2 | ETM2 |
| | (29.5%:58.5%:12%) | 5 nm | (50%:50%) | 1 nm |
| | 40 nm | | 30 nm | |
| D110 | M1:M2:Ir(L111) | HBL1 | ETM1:ETM2 | ETM2 |
| | (29.5%:58.5%:12%) | 5 nm | (50%:50%) | 1 nm |
| | 40 nm | | 30 nm | |

TABLE 2
Results for the vacuum-processed OLEDs
(Eff., EQE, voltage, CIE at 1000 cd/m²; lifetime LD90 at 10 000 cd/m²)

| | Eff. | Eff. | EQE | Voltage | CIE | LD90 |
|---|---|---|---|---|---|---|
| Ex. | [cd/A] | [m/W] | [%] | [V] | [x/y] | [h] |
| Ref. D1 | 93.2 | 88.8 | 24.8 | 3.30 | 0.363/0.614 | 1040 |
| Ref. D2 | 89.6 | 94.7 | 24.1 | 3.18 | 0.301/0.650 | 790 |
| Ref. D3 | 82.9 | 86.4 | 21.6 | 3.02 | 0.347/0.626 | 650 |
| D1 | 87.1 | 97.9 | 23.6 | 2.80 | 0.350/0.617 | 730 |
| D2 | 90.2 | 103.2 | 23.4 | 2.75 | 0.346/0.623 | 840 |
| D3 | 89.2 | 96.8 | 23.3 | 2.90 | 0.320/0.664 | 710 |
| D4 | 91.2 | 104.4 | 23.5 | 2.74 | 0.348/0.621 | 860 |
| D5 | 90.0 | 101.8 | 23.4 | 2.73 | 0.350/0.620 | 700 |
| D6 | 84.9 | 100.7 | 22.8 | 2.64 | 0.327/0.637 | 630 |
| D7 | 84.4 | 99.7 | 22.7 | 2.66 | 0.324/0.642 | 630 |
| D100 | 95.2 | 91.8 | 25.2 | 3.26 | 0.363/0.614 | 1660 |
| D101 | 96.6 | 96.3 | 25.8 | 3.15 | 0.340/0.627 | 1700 |
| D102 | 96.0 | 96.1 | 25.8 | 3.17 | 0.341/0.624 | 2000 |
| D103 | 90.9 | 101.3 | 24.5 | 2.82 | 0.348/0.621 | 1370 |
| D103-D | 89.4 | 99.8 | 24.5 | 2.85 | 0.346/0.619 | 1580 |
| D104 | 85.5 | 90.6 | 22.8 | 2.96 | 0.339/0.628 | 1230 |
| D104-D | 84.7 | 89.8 | 22.7 | 2.95 | 0.338/0.626 | 1460 |
| D105 | 93.2 | 97.1 | 24.8 | 3.02 | 0.333/0.634 | 1280 |
| D106 | 92.4 | 92.3 | 24.4 | 3.11 | 0.334/0.635 | 1130 |
| D107 | 93.1 | 93.5 | 24.5 | 3.09 | 0.336/0.632 | 1100 |
| D108 | 93.2 | 94.0 | 24.5 | 3.18 | 0.332/0.633 | 1060 |
| D109 | 90.1 | 94.0 | 23.0 | 3.10 | 0.332/0.633 | 1130 |
| D110 | 90.7 | 100.7 | 24.4 | 2.80 | 0.346/0.624 | 1220 |
| D111 | 97.5 | 99.2 | 25.9 | 3.01 | 0.331/0.636 | 2000 |

TABLE 3
Structural formulae of the materials used

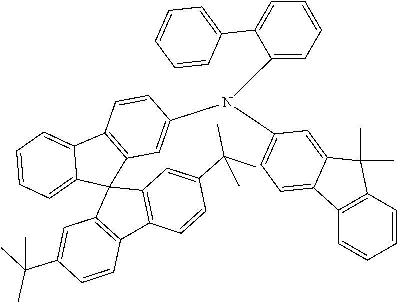 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

HTM1
[1365840-52-3]

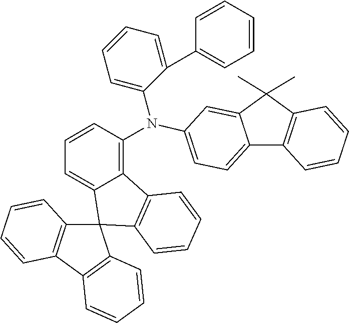 [SMILES: CC1(C)c2ccccc2-c2ccc(N(c3ccccc3-c3ccccc3)c3cccc4c3-c3ccccc3C43c4ccccc4-c4ccccc43)cc21]

HTM2
[1450933-44-4]

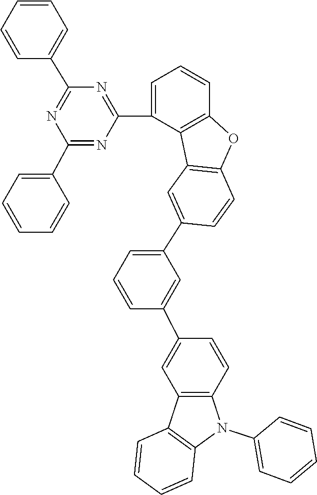 [SMILES: c1ccc(-c2nc(-c3ccccc3)nc(-c3cccc4oc5ccc(-c6cccc(-c7ccc8c(c7)c7ccccc7n8-c7ccccc7)c6)cc5c34)n2)cc1]

M1
[1822310-86-0]

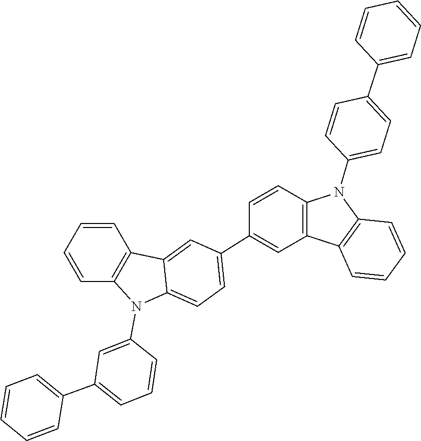 [SMILES: c1ccc(-c2ccc(-n3c4ccccc4c4cc(-c5ccc6c(c5)c5ccccc5n6-c5cccc(-c6ccccc6)c5)ccc43)cc2)cc1]

M2
[1643479-47-3]

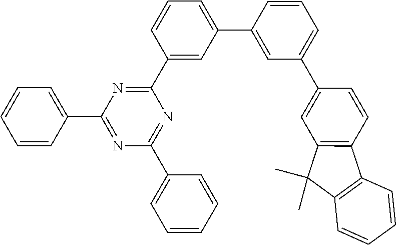 [SMILES: CC1(C)c2ccccc2-c2ccc(-c3cccc(-c4cccc(-c5nc(-c6ccccc6)nc(-c6ccccc6)n5)c4)c3)cc21]

HBL1
[1955543-57-3]

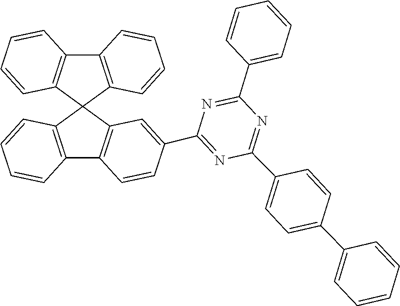 [SMILES: c1ccc(-c2ccc(-c3nc(-c4ccccc4)nc(-c4ccc5c(c4)C4(c6ccccc6-c6ccccc64)c4ccccc4-5)n3)cc2)cc1]

ETM1
[1819335-36-8]

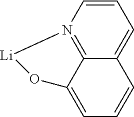

ETM2
[25387-93-3]

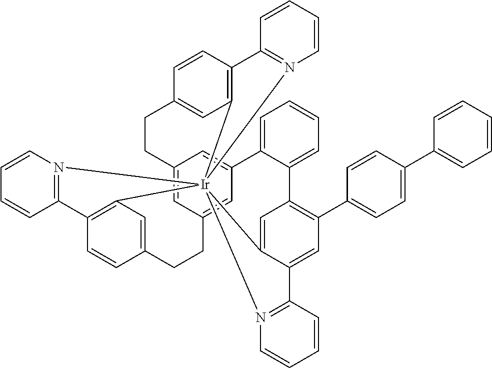

Ir-Ref.1
[2375153-43-6]

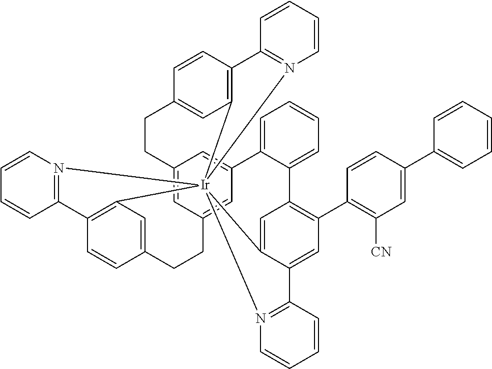

Ir-Ref.2
WO2019/158453

1.-13. (canceled)

14. A compound of the formula (1)
Ir(L) Formula (1)
where the ligand L has a structure of the following formula (2): 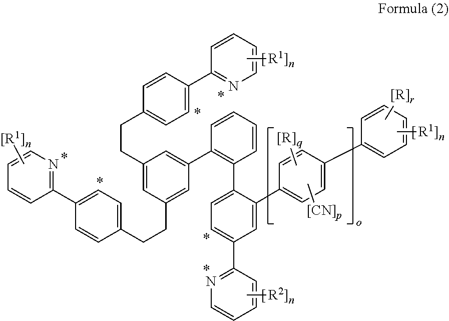
where the ligand L coordinates to the iridium atom via the positions identified by * and where the hydrogen atoms not shown explicitly may also be replaced by D, and where the symbols and indices used are as follows:
R is the same or different at each instance and is H, D, F, a linear alkyl group having 1 to 10 carbon atoms or a branched or cyclic alkyl group having 3 to 10 carbon atoms, where the alkyl group in each case may also be deuterated; optionally two adjacent R radicals together may form a ring system;
R¹ is the same or different at each instance and is H, D, a linear alkyl group having 1 to 10 carbon atoms or a branched or cyclic alkyl group having 3 to 10 carbon atoms, where the alkyl group in each case may also be deuterated; optionally two adjacent R¹ radicals together may form a ring system;
R² is the same or different at each instance and is H, D, a linear alkyl group having 1 to 10 carbon atoms, a branched or cyclic alkyl group having 3 to 10 carbon atoms, where the alkyl group in each case may also be deuterated, or a phenyl or biphenyl group, each of which may be substituted by one or more alkyl groups having 1 to 10 carbon atoms, where the phenyl or biphenyl group, or the alkyl groups, may each also be deuterated; optionally two adjacent R² radicals together may form a ring system;
m is 1, 2 or 3;
n is the same or different at each instance and is 0, 1, 2 or 3;
o is 0 or 1;
p is 0, 1 or 2;
q is 0, 1 or 2; and
r is 0, 1 or 2.

15. A compound as claimed in claim 14, wherein when m=1 the ligand L is a structure of the formula (3a), when m=2 the ligand L is a structure of the formula (3b) or (3c), and when m=3 the ligand L is a structure of the formula (3d) or (3e): 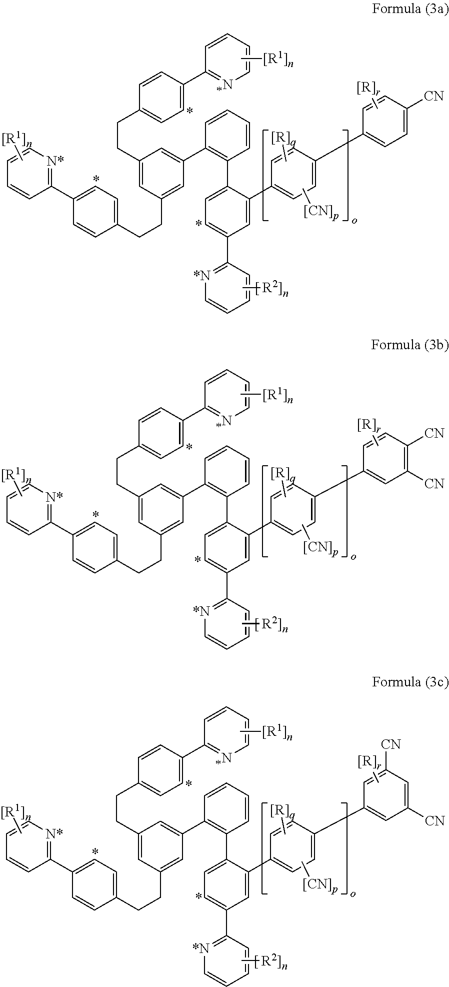 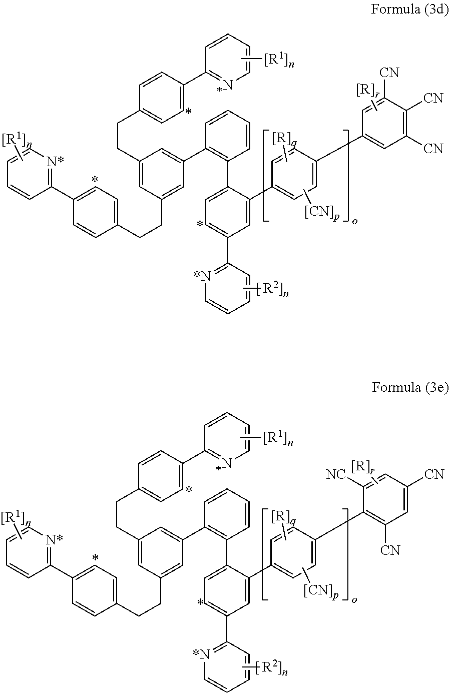
where the hydrogen atoms not shown explicitly may also be replaced by D, and the symbols and indices have the definitions given in claim 14.

16. A compound as claimed in claim 14, wherein the ligand L when o=1 and p=1 has a structure of the formula (4a), and in that the ligand L when o=1 and p=1 has a structure of the formula (4b): 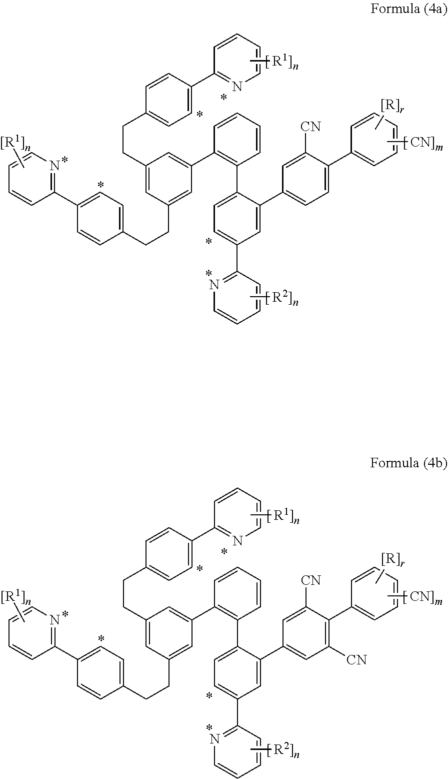
where the hydrogen atoms not shown explicitly may also be replaced by D, and the symbols and indices have the definitions given in claim 14.

17. A compound as claimed in claim 14, wherein the ligand L has a structure of the formula (7): 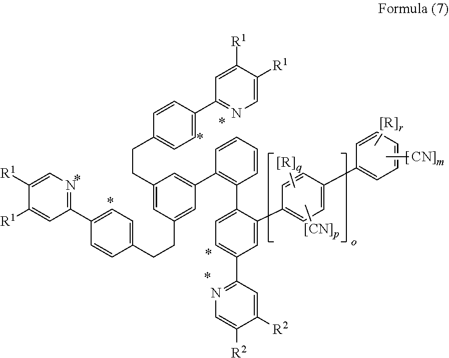
where the hydrogen atoms not shown explicitly may also be replaced by D, and the symbols and indices have the definitions given in claim 14.

18. A compound as claimed in claim 14, wherein the substituents are as follows:
R is the same or different at each instance and is selected from the group consisting of D, a linear alkyl group having 1 to 6 carbon atoms or a branched or cyclic alkyl group having 3 to 6 carbon atoms, where the alkyl groups may each also be deuterated;
R¹ is the same or different at each instance and is selected from the group consisting of D, a linear alkyl group having 1 to 6 carbon atoms or a branched or cyclic alkyl group having 3 to 6 carbon atoms, where the alkyl groups may each also be deuterated; optionally two adjacent R¹ radicals together may form a ring system;
R² is the same or different at each instance and is selected from the group consisting of D, a linear alkyl group having 1 to 6 carbon atoms or a branched or cyclic alkyl group having 3 to 6 carbon atoms, where the alkyl groups may each also be deuterated, or an optionally deuterated phenyl group which may be substituted by one or more optionally deuterated alkyl groups having 1 to 4 carbon atoms; optionally two adjacent R² radicals together may form a ring system.

19. A compound as claimed in claim 14, wherein the symbols and indices are as follows:
R is the same or different at each instance and is selected from the group consisting of D, a linear alkyl group having 1 to 4 carbon atoms or a branched alkyl group having 3 or 4 carbon atoms, where the alkyl groups may each also be deuterated;
R¹ is the same or different at each instance and is selected from the group consisting of D, a linear alkyl group having 1 to 4 carbon atoms or a branched alkyl group having 3 or 4 carbon atoms, where the alkyl groups may each also be deuterated; optionally two adjacent R¹ radicals together may form a ring system;
R² is the same or different at each instance and is selected from the group consisting of D, a linear alkyl group having 1 to 4 carbon atoms or a branched alkyl group having 3 or 4 carbon atoms, where the alkyl groups may each also be deuterated, or an optionally deuterated phenyl group which may be substituted by one or more optionally deuterated alkyl groups having 1 to 4 carbon atoms; optionally two adjacent R² radicals together may form a ring system;
m is 1 or 2;
n is the same or different at each instance and is 0, 1 or 2;
o is 1; or o is 0 or 1 when n on the same ligand=1 and R² is a phenyl group;
p is 0 or 1;
q is 0 or 1; and
r is 0 or 1.

20. A compound as claimed in claim 14, wherein the ligand L has a structure of the formula (8): 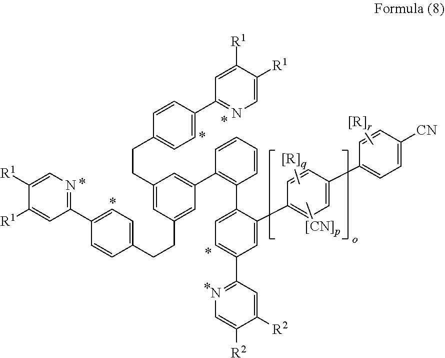
where the hydrogen atoms not shown explicitly may also be replaced by D, R, R¹, R² and o have the definitions given in claim 14, p=0 or 1, q=0 or 1 and r=0 or 1.

21. A compound as claimed in claim 14, wherein the ligand L has a structure of the formula (9): 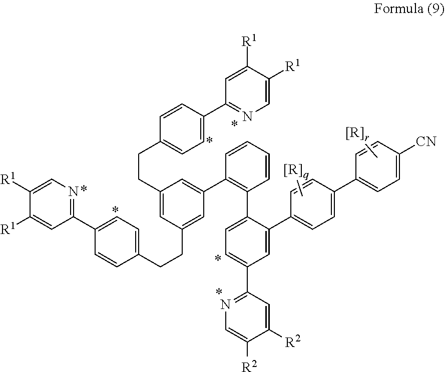
where the hydrogen atoms not shown explicitly may also be replaced by D, R, R¹ and R² have the definitions given in claim 14, q=0 or 1 and r=0 or 1.

22. A process for preparing a compound as claimed in claim 14 by reaction of the free ligand L with iridium alkoxides of the formula (Ir-1), with iridium ketoketonates of the formula (Ir-2), with iridium halides of the formula (Ir-3) or with iridium carboxylates of the formula (Ir-4), or with iridium compounds that bear both alkoxide and/or halide and/or hydroxy and/or ketoketonate radicals, 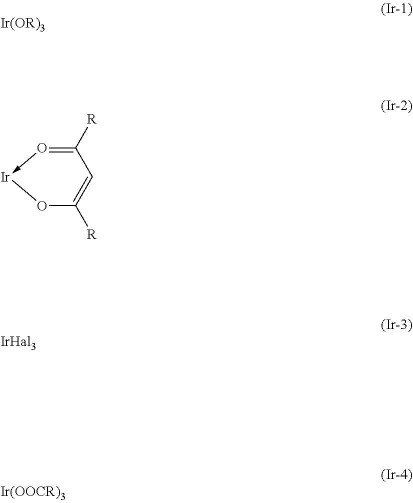
where R has the definitions given in claim 14, Hal=F, Cl, Br or I, and the iridium reactants may also take the form of the corresponding hydrates.

23. A formulation comprising at least one compound as claimed in claim 14 and at least one solvent.

24. A method comprising incorporating the compound as claimed in claim 14 in an electronic device.

25. An electronic device comprising at least one compound as claimed in claim 14.

26. The electronic device as claimed in claim 25 which is an organic electroluminescent device, wherein the compound is used as an emitting compound in one or more emitting layers.
